(19) United States
(12) Patent Application Publication
(10) Pub. No.: US 2013/0095429 A1
(43) Pub. Date: Apr. 18, 2013

(54) ACTINIC-RAY- OR RADIATION-SENSITIVE RESIN COMPOSITION AND METHOD OF FORMING PATTERN USING THE SAME

(71) Applicants: Yusuke Iizuka, Shizuoka (JP); Akinori Shibuya, Shizuoka (JP); Hidenori Takahashi, Shizuoka (JP); Toshiaki Fukuhara, Shizuoka (JP); Kousuke Koshijima, Shizuoka (JP)

(72) Inventors: Yusuke Iizuka, Shizuoka (JP); Akinori Shibuya, Shizuoka (JP); Hidenori Takahashi, Shizuoka (JP); Toshiaki Fukuhara, Shizuoka (JP); Kousuke Koshijima, Shizuoka (JP)

(73) Assignee: FUJIFILM CORPORATION, Minato-ku, Tokyo (JP)

(21) Appl. No.: 13/807,508

(22) PCT Filed: Jul. 7, 2011
(86) PCT No.: PCT/JP2011/066031

§ 371 Date: Dec. 28, 2012

(30) Foreign Application Priority Data
Jul. 13, 2010 (JP) 2010-159093

(51) Int. Cl. G03F 7/004; G03F 7/20

(52) U.S. Cl. CPC G03F 7/004; G03F 7/20; G03F 7/2041
USPC 430/285.1; 430/325

(57) ABSTRACT

Provided is an actinic-ray- or radiation-sensitive resin composition that simultaneously achieves excellent developability and excellent immersion-liquid tracking properties, and a method of forming a pattern using the same. The composition contains a resin (B) containing at least either a fluorine atom or a silicon atom, the resin (B) containing any of repeating units of general formula (I) below.

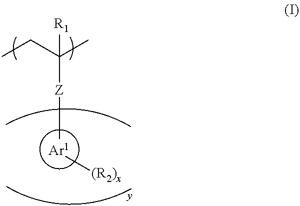

### CROSS-REFERENCE TO RELATED APPLICATIONS

This application is based upon and claims the benefit of priority from prior Japanese Patent Application No. 2010-159093, filed Jul. 13, 2010, the entire contents of which are incorporated herein by reference.

### TECHNICAL FIELD

The present invention generally relates to an actinic-ray- or radiation-sensitive resin composition and a method of forming pattern using the same. More specifically, the present invention relates to, for example, a composition that is suitable for use in an ultramicrolithography process applicable to a process for manufacturing a super-LSI or a high-capacity microchip, a process for fabricating a nanoimprint mold, a process for producing a high-density information recording medium, etc. and other photofabrication processes, and a method of forming pattern using the same. Particularly, the present invention relates to, for example, a composition that is suitable for exposure using a liquid-immersion projection exposure apparatus in which a far-ultraviolet light of wavelength 300 nm or shorter is employed as a light source, and a method of forming pattern using the same.

In the present invention, the terms “actinic rays” and “radiation” mean, for example, a mercury lamp bright line spectrum, far ultraviolet rays represented by an excimer laser, extreme ultraviolet rays, X-rays, electron beams and the like. In the present invention, the term “light” means actinic rays or radiation.

The expression “exposure” used herein, unless otherwise noted, means not only light irradiation using a mercury lamp, far ultraviolet, X-rays, EUV light, etc. but also lithography using particle beams, such as an electron beam and an ion beam.

### BACKGROUND ART

The reduction of the wavelength of an exposure light source and the realization of a high numerical aperture (NA) for a projector lens have been advanced in accordance with the miniaturization of semiconductor elements. To increase resolving power by further reducing wavelength, it is already known to employ a method in which the space between a projector lens and a sample is filled with a liquid of high refractive index (hereinafter also referred to as an “immersion liquid”), generally called a liquid-immersion method. The liquid-immersion method is effective for all pattern shapes. Further, this method can be combined with a super-resolution technology, such as a phase-shift method or a modified illumination method, now under study.

Since the development of the resist for a KrF excimer laser (248 nm), it has been common practice, in order to compensate for any sensitivity deterioration caused by light absorption, to employ an image formation method through chemical amplification as a resist image formation method. A brief description of a positive image formation method through chemical amplification follows by way of example. Upon exposure, an acid generator is decomposed in exposed areas to thereby generate an acid. At the bake after the exposure (post-exposure bake [PEB]), the generated acid is used as a reaction catalyst so that an alkali-insoluble group is converted to an alkali-soluble group. Thereafter, alkali development is carried out to thereby remove the exposed areas. Thus, the relevant image formation method is provided (see, for example, patent references 1 to 5).

The resist for an ArF excimer laser (193 nm) utilizing this chemical amplification mechanism is now becoming mainstream. In this connection, when the exposure is performed by means of a scan-type liquid-immersion exposure machine, the exposure speed is decreased in the event that the immersion liquid fails to move while tracking a moving lens. Thus, an adverse influence thereof on productivity is an issue. When the immersion liquid is water, it is preferable that the resist film be hydrophobic from the viewpoint of superiority in water tracking properties. On the other hand, extreme hydrophobicity invites a lowering of developability. Therefore, it is of importance to achieve a good balance between water tracking properties and developability.

Patent reference 6 describes a resin comprising a repeating unit containing a trifluoromethyl group and an acrylate repeating unit containing at its ester site an alicyclic hydrocarbon substituent. This resin still needs work from the viewpoint of achieving a good balance between water tracking properties and developability.

### CITATION LIST

### Patent Literature

[Patent reference 1] Jpn. Pat. Appln. KOKAI Publication No. (hereinafter referred to as JP-A-) 2008-268931,
[Patent reference 2] JP-A-2009-249293,
[Patent reference 3] JP-A-2009-157338,
[Patent reference 4] JP-A-2010-122579,
[Patent reference 5] JP-A-2007-178848, and
[Patent reference 6] Japanese Patent No. 3748596.

### DISCLOSURE OF INVENTION

An object of the present invention is to provide an actinic-ray- or radiation-sensitive resin composition that simultaneously achieves excellent developability and excellent immersion-liquid tracking properties, and to provide a method of forming pattern using the same.

Some aspects according to the present invention are as follows.

[1] An actinic-ray- or radiation-sensitive resin composition comprising: a resin (B) containing at least either a fluorine atom or a silicon atom, the resin (B) containing any of repeating units of general formula (I) below; a resin (A) that is configured to decompose when acted on by an acid to thereby increase its solubility in an alkali developer; and a compound that is configured to generate an acid when exposed to actinic rays or radiation.

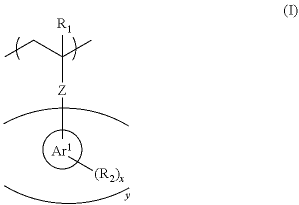

wherein

R₁ represents a hydrogen atom, an alkyl group or a halogen atom,

Ar¹ represents an aromatic ring,

R₂, when x≧2 each independently, represents a substituent,

Z represents a connecting group whose minimum number of connecting atoms is 3 or more,

x is an integer of 0 or greater, and

y is an integer of 1 or greater.

[2] The composition according to [1], wherein the repeating units of general formula (I) above are expressed by general formula (I-A) below,

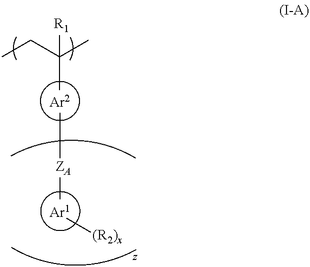

wherein

R₁ represents a hydrogen atom, an alkyl group or a halogen atom,

Ar¹ represents an aromatic ring,

R₂ represents a substituent,

Ar² represents an aromatic ring,

Z_{A} represents a single bond or a connecting group,

x is an integer of 0 or greater, and

z is an integer of 1 or greater.

[3] The composition according to [2], wherein Ar² represents a benzene ring.

[4] The composition according to [1], wherein the repeating units of general formula (I) above are expressed by general formula (I-B) below,

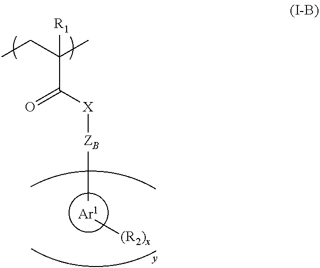

wherein

R₁ represents a hydrogen atom, an alkyl group or a halogen atom,

Ar¹ represents an aromatic ring,

R₂ represents a substituent,

Z_{B} represents a connecting group,

X represents O, NH or NR, in which R represents an alkyl group,

x is an integer of 0 or greater, and

y is an integer of 1 or greater.

[5] The composition according to [4], wherein X represents O.

[6] The composition according to any of [1] to [5], wherein the resin (B) further contains a repeating unit containing at least one group selected from the group consisting of groups (x), (y) and (z) below:

(x) an alkali-soluble group,

(y) a group that is configured to decompose when acted on by an alkali developer to thereby increase its solubility in the alkali developer, and

(z) a group that is configured to decompose when acted on by an acid to thereby increase its solubility in an alkali developer.

[7] The composition according to any of [1] to [5], wherein the resin (B) further contains a repeating unit containing the group (y) that is configured to decompose when acted on by an alkali developer to thereby increase its solubility in the alkali developer.

[8] The composition according to [7], wherein the group (y) contains a lactone structure.

[9] The composition according to any of [1] to [8], wherein the resin (B) is contained in an amount of 0.1 to 10 mass % based on the total solids of the composition.

[10] A resist film formed from the composition according to any of [1] to [9].

[11] A method of forming a pattern, comprising: forming the composition according to any of [1] to [9] into a film, exposing the film to light, and developing the exposed film.

[12] The method according to [11], wherein the exposure is performed through an immersion liquid.

The present invention has made it feasible to provide an actinic-ray- or radiation-sensitive resin composition that simultaneously achieves excellent developability and excellent immersion-liquid tracking properties, and to provide a method of forming a pattern using the same.

### BEST MODE FOR CARRYING OUT THE INVENTION

The present invention will be described below.

Note that, with respect to the expression of a group (or an atomic group) used in this specification, the expression without explicitly referring to whether the group is substituted or unsubstituted encompasses not only groups with no substituents but also groups having one or more substituents. For example, the expression “alkyl group” encompasses not only alkyl groups having no substituents (viz. unsubstituted alkyl groups) but also alkyl groups having one or more substituents (viz. substituted alkyl groups).

<Resin (B)>

The actinic-ray- or radiation-sensitive resin composition according to the present invention comprises a resin (B) having at least either a fluorine atom or a silicon atom.

At least one resin (B) contained in the composition according to the present invention contains any of repeating units of general formula (I) below [hereinafter also referred to as a repeating unit (R)].

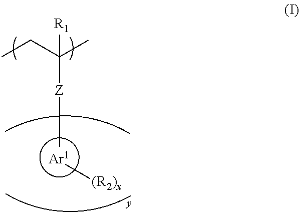

wherein

R₁ represents a hydrogen atom, an alkyl group or a halogen atom,

Ar¹ represents an aromatic ring,

R₂, when x≧2 each independently, represents a substituent,

Z represents a connecting group whose minimum number of connecting atoms is 3 or more,

x is an integer of 0 or greater, and

y is an integer of 1 or greater.

The use of the resin (B) containing the repeating unit (R) makes it feasible to achieve a good balance between developability and immersion-liquid tracking properties. More specifically, when the resin with this structure is employed, not only can the number of development defects be decreased but also the receding contact angle can be increased.

The mechanism thereof has not been elucidated. However, it can be presumed that the reason would be that the degree of freedom of the movement of side chains is increased by employing a relatively long side-chain structure whose minimum number of connecting atoms is 3 or more as Z, so that the moiety of —Ar¹—(R₂)ₓ considered as contributing toward the increase of the receding contact angle tends to come to the surface brought into contact with the immersion liquid in the stage of forming the composition into a film.

The alkyl group represented by R₁ preferably has 1 to 5 carbon atoms, being most preferably a methyl group. A substituent may further be introduced into the alkyl group represented by R₁. As the substituent, there can be mentioned, for example, a halogen atom, a hydroxyl group, or an alkoxy group, such as a methoxy group, an ethoxy group, an isopropoxy group, a t-butoxy or a benzyloxy group. R₁ is preferably a hydrogen atom or an alkyl group, more preferably a hydrogen atom, a methyl group, a hydroxymethyl group or a trifluoromethyl group.

The aromatic ring represented by Ar¹ may be monocyclic or polycyclic. This aromatic ring may be a heterocycle containing a heteroatom, such as a nitrogen atom, an oxygen atom or a sulfur atom.

The aromatic ring represented by Ar¹ preferably has 6 to 30 carbon atoms. As such an aromatic ring, there can be mentioned, for example, a benzene ring, a naphthalene ring, a pentalene ring, an indene ring, an azulene ring, a heptalene ring, an indecene ring, a perylene ring, a pentacene ring, an acenaphthalene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an iodolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, a phenazine ring or the like. Of these, a benzene ring, a naphthalene ring and an anthracene ring are preferred. A benzene ring is more preferred.

It is preferable that at least a part of the substituents represented by R₂ be a hydrophobic group. As the hydrophobic group, there can be mentioned, for example, a fluorine atom, a silicon atom, an alkyl group or a cycloalkyl group.

The alkyl group represented by R₂ may be in the form of a linear chain or branched chain. The alkyl group preferably has 1 to 30 carbon atoms, more preferably 1 to 15 carbon atoms. As such an alkyl group, there can be mentioned, for example, a linear alkyl group, such as a methyl group, an ethyl group, an n-propyl group, an n-butyl group, an n-pentyl group, an n-hexyl group, an n-octyl group, an n-dodecyl group, an n-tetradecyl group or an n-octadecyl group, or a branched alkyl group, such as an isopropyl group, an isobutyl group, a t-butyl group, a neopentyl group or a 2-ethylhexyl group.

The cycloalkyl group represented by R₂ may be monocyclic or polycyclic. This cycloalkyl group may contain in its ring a heteroatom, such as an oxygen atom. The cycloalkyl group preferably has 3 to 20 carbon atoms. As the cycloalkyl group, there can be mentioned, for example, a cyclopropyl group, a cyclopentyl group, a cyclohexyl group, a norbornyl group or an adamantyl group.

R₂ is preferably a fluorine atom, an alkyl group or a cycloalkyl group, more preferably a fluorine atom or an alkyl group and most preferably a branched alkyl group.

A substituent may further be introduced into the groups represented by R₂. As the substituent, there can be mentioned, for example, a halogen atom such as a fluorine atom, or a hydroxyl group.

The alkyl group and cycloalkyl group represented by R₂ in a particular form thereof are an unsubstituted alkyl group and cycloalkyl group. When use is made of an unsubstituted alkyl group and cycloalkyl group, the effect of increasing the receding contact angle after the bake but before the exposure is highly conspicuous, thereby enhancing the immersion-liquid tracking properties.

The alkyl group and cycloalkyl group represented by R₂ in another form thereof are a substituted alkyl group and cycloalkyl group. The substituent is preferably a fluorine atom. When the substitution is effected with a fluorine atom, while maintaining the immersion-liquid tracking properties, the content of repeating unit (R) in all the repeating units can be relatively low. Therefore, the content of other repeating units can be relatively high, so that an enhancement of performance, such as developability, attributed thereto can be expected.

R₂ may be a group that is stable in an acid and an alkali. Also, R₂ may be at least one group selected from the group consisting of (x) an alkali-soluble group, (y) a group that is configured to decompose when acted on by an alkali developer to thereby increase its solubility in the alkali developer and (z) a group that is configured to decompose when acted on by an acid to thereby increase its solubility in an alkali developer to be described hereinafter. When the resin (B) containing the repeating unit (R) further contains the repeating unit (S) to be described hereinafter, it is preferable that R₂ be a group that is stable in an acid and an alkali.

The expression “stable in an acid” used herein means that substantially no decomposition reaction under the action of an acid generated by a photoacid generator to be described hereinafter occurs. The expression “stable in an alkali” used herein means that substantially no decomposition reaction under the action of an alkali developer to be described hereinafter occurs.

As mentioned above, x is an integer of 0 or greater. The upper limit of x is equal to the number of sites of Ar¹ where a substitution is feasible. Preferably, x is in the range of 0 to 5. More preferably, x is in the range of 0 to 3.

In the connecting group represented by Z, the minimum number of connecting atoms is 3 or more. In this case, the mobility of side chains of the repeating unit (R) is increased. As a result, in the stage of coating and/or drying, the hydrophobic moiety represented by —Ar¹—(R₂)ₓ tends to be unevenly distributed in the surface portion. Therefore, in that instance, excellent immersion-liquid tracking properties can be attained.

With respect to Z, the “minimum number of connecting atoms” is the number established in the following manner. Namely, first, determine the first atom directly bonded to the principal chain of the resin (B) and the second atom directly bonded to the aromatic ring represented by Ar¹, among the atoms making up Z. Then, consider a line of atoms connecting the first atom and the second atom (including the first atom and the second atom). Subsequently, find the number of atoms contained in each of such lines. The minimum of the found numbers is referred to as the “minimum number of connecting atoms” of Z.

For example, when Z is —COOCH₂—, the minimum number of connecting atoms thereof is 3. When Z is a 2-methyl-butylene group, the minimum number of connecting atoms thereof is 4. When Z is a 1,4-cyclohexylene group, the minimum number of connecting atoms thereof is 4. When Z is a linear alkylene group, the minimum number of connecting atoms of Z is equal to the number of carbon atoms thereof.

The “minimum number of connecting atoms” of Z is preferably in the range of 3 to 30, more preferably 3 to 20, further more preferably 3 to 15, especially preferably 3 to 10 and most preferably 4 to 10.

The connecting group represented by Z comprises, for example, a group selected from the group consisting of an arylene group, an alkylene group, a cycloalkylene group, —O—, —SO₂—, —CO—, —NH—, —NR—, —NHSO₂— and combinations of two or more of these. In the formula —NR—, R represents an alkyl group, preferably having 1 to 3 carbon atoms.

The connecting group represented by Z preferably comprises an arylene group, an alkylene group, —O— or —COO—. In particular, connecting groups composed of a combination of at least two connecting groups selected from among an arylene group, an alkylene group, —O— or —COO— are preferred. A substituent may further be introduced into each of these groups.

As mentioned above, y is an integer of 1 or greater. The upper limit of y is equal to the number of sites of Z where a substitution is feasible. Preferably, y is in the range of 1 to 3. More preferably, y is 1.

The repeating unit (R) is preferably expressed by general formula (II) below.

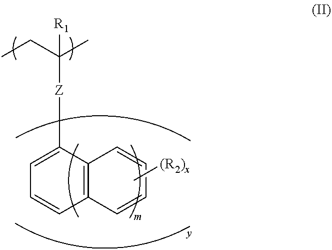

In the formula, R₁, Z, R₂, x and y are as defined above in connection with general formula (I). In the formula, m is an integer of 0 or greater, preferably in the range of 0 to 3, more preferably 0 to 2, especially preferably 0 or 1 and most preferably 0.

When x≧1, it is preferable that at least one of the substituents represented by R₂ be bonded to a p-position to the connecting group represented by Z. In this case, the resin (B) tends to be unevenly distributed in the surface portion of the film with the result that a higher receding contact angle can be attained.

Preferably, the repeating unit (R) is expressed by general formula (I-A) below. In this case, a higher receding contact angle can be attained.

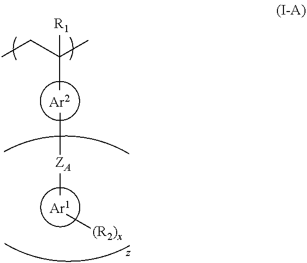

In the formula, R₁, Ar¹, R₂, and x are as defined above in connection with general formula (I).

Ar² represents an aromatic ring. Z_{A} represents a single bond or a connecting group, and z is an integer of 1 or greater. The minimum number of connecting atoms of the group represented by “Ar²—Z_{A}” is 3 or more.

As the aromatic ring represented by Ar², there can be mentioned, for example, those mentioned above as being represented by Ar¹. Ar² is preferably a benzene ring or a naphthalene ring, more preferably a benzene ring. A substituent may further be introduced into the aromatic ring represented by Ar².

As the connecting group represented by Z_{A}, there can be mentioned, for example, those mentioned above as being represented by Z. Z_{A} is preferably a single bond, or a connecting group selected from among an alkylene group, an ether bond, an ester bond, an amido bond, a urethane bond, a urea bond and a combination of two or more of these. More preferably, Z_{A} is a single bond, or a connecting group selected from among an alkylene group, an ether bond, an ester bond and a combination of two or more of these. A substituent may further be introduced into the alkylene group.

In the formula, z is an integer of 1 or greater. The upper limit of z is equal to the number of sites of Ar² where a substitution is feasible. Preferably, z is in the range of 1 to 3. More preferably, z is 1.

When the aromatic ring represented by Ar² comprises a benzene ring directly bonded to the principal chain of the polymer, it is preferable that at least one of the connecting groups represented by Z_{A} be bonded to a p-position thereof. In this case, the resin (B) further tends to be unevenly distributed in the surface portion of the film with the result that a higher receding contact angle can be attained.

More preferably, the repeating unit (R) is expressed by general formula (II-A) below.

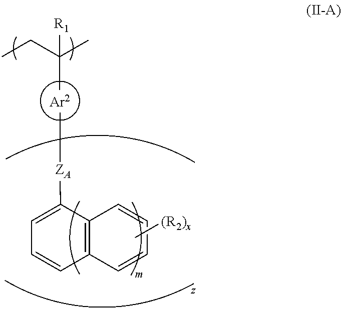

The characters used in the formula are as defined above in connection with general formulae (II) and (I-A).

Also, the repeating unit (R) is preferably expressed by general formula (I-B) below. In this case, the coatability and developability can further be enhanced.

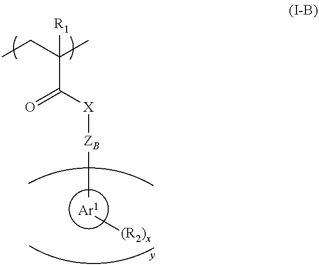

In the formula, R₁, Ar¹, R₂, x and y are as defined above in connection with general formula (I).

Z_{B} represents a connecting group. X represents O, NH or NR, in which R represents an alkyl group.

As the connecting group represented by Z_{B}, there can be mentioned, for example, those mentioned above as being represented by Z. Z_{B} is preferably a connecting group selected from among an alkylene group, an ether bond, an ester bond, an amido bond, a urethane bond, a urea bond and a combination of two or more of these. More preferably, Z_{B} is a connecting group selected from among an alkylene group, an ether bond, an ester bond and a combination of two or more of these. A substituent may further be introduced into the alkylene group.

As mentioned above, X represents O, NH or NR. The alkyl group represented by R preferably has 1 to 3 carbon atoms. When X is O, the coatability can further be enhanced. When X is NH or NR, the developability can further be enhanced.

Further, the repeating unit (R) is more preferably expressed by general formula (II-B) below.

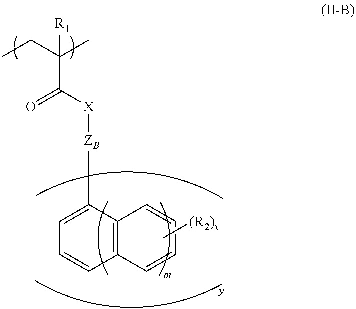

The characters used in the formula are as defined above in connection with general formulae (II) and (I-B).

Particular examples of the repeating units (R) are shown below. In the formulae, Ra has the same meaning as that of R₁ of general formula (I), and n is an integer of 2 or greater, preferably in the range of 2 to 10.

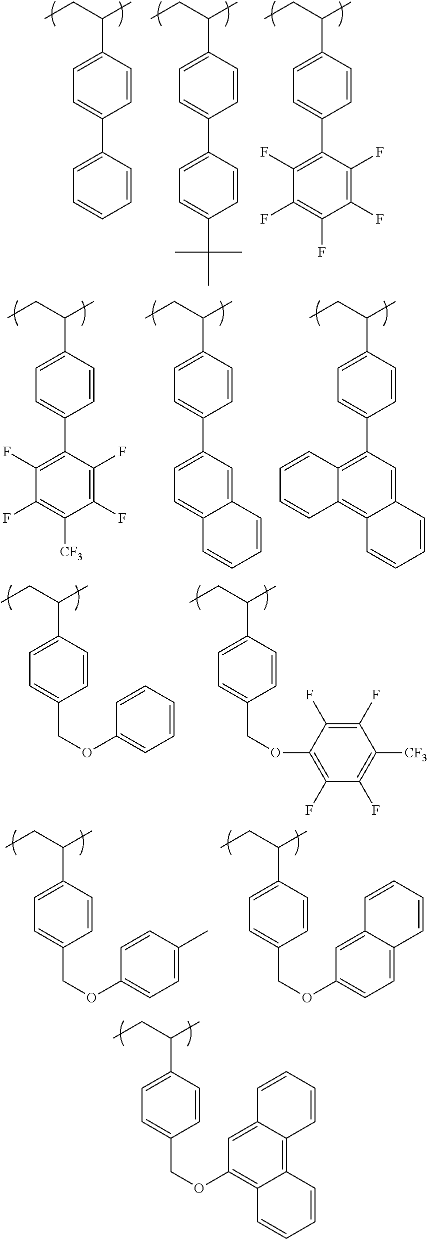

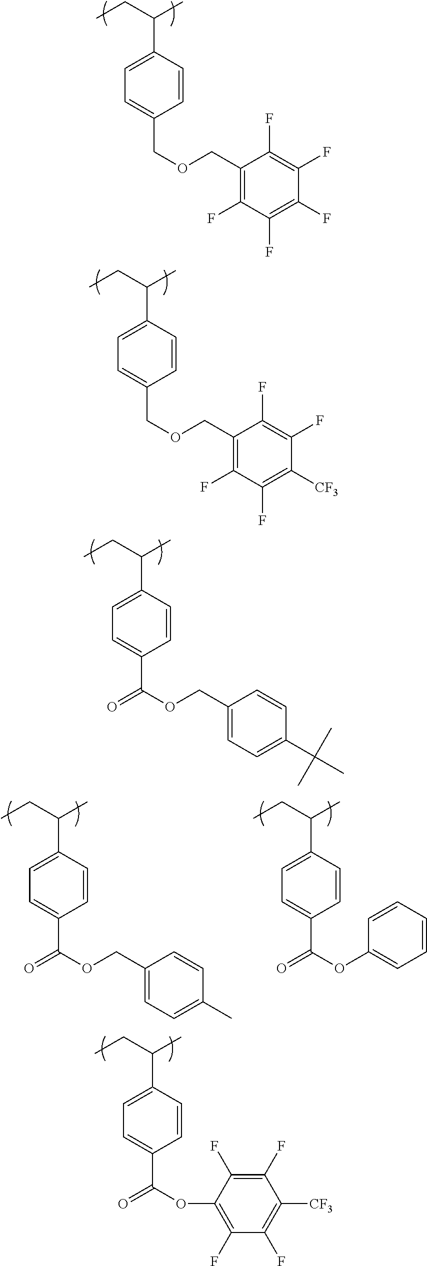

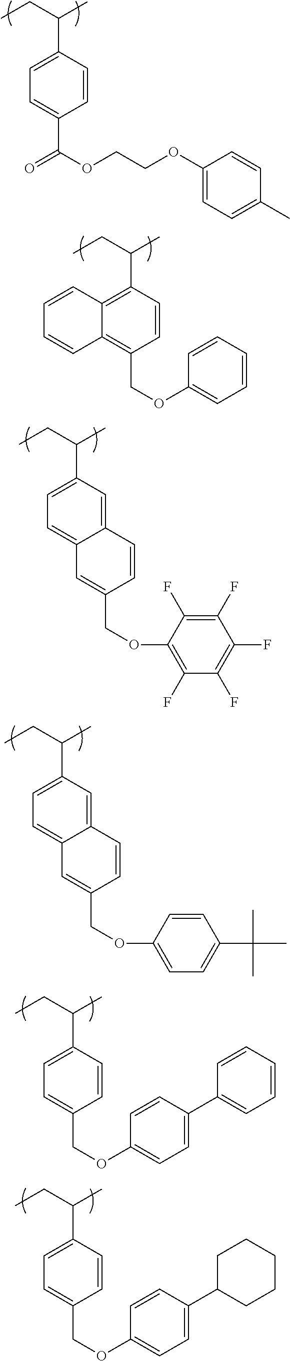

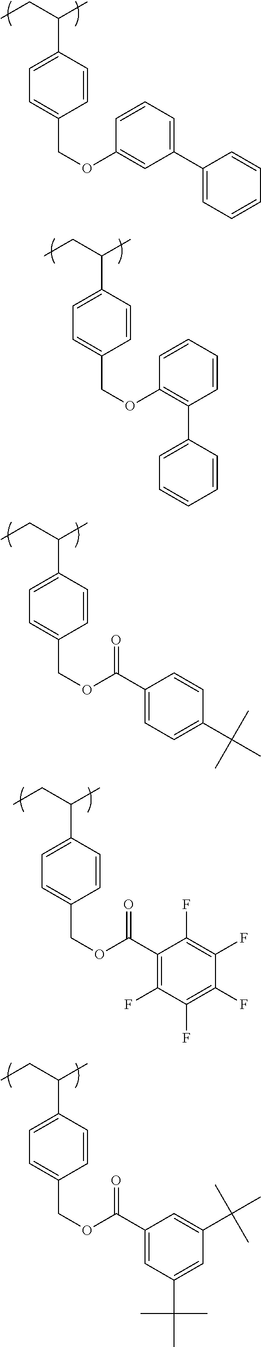

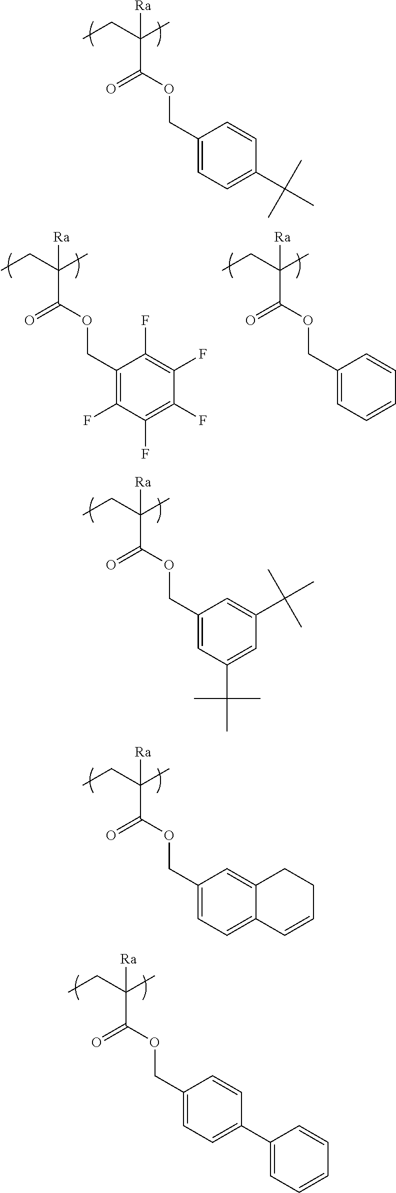

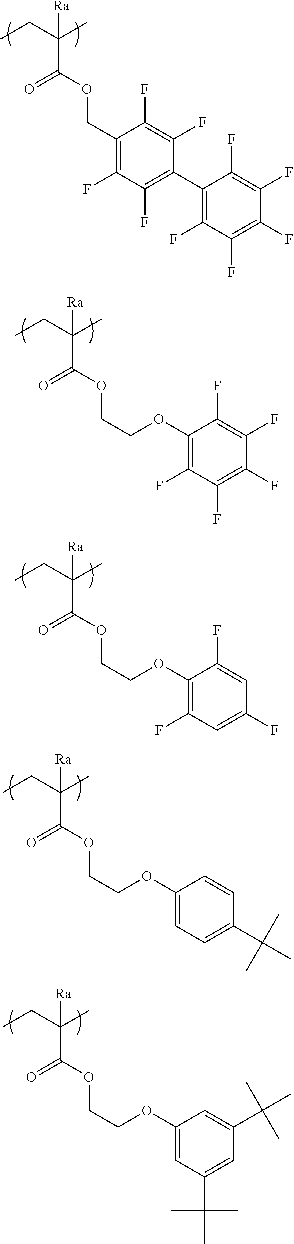

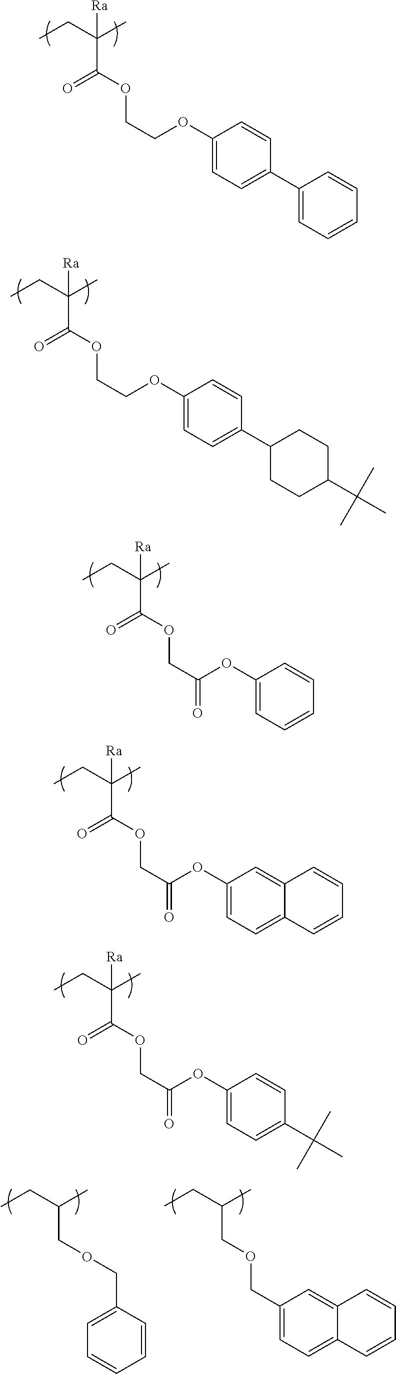

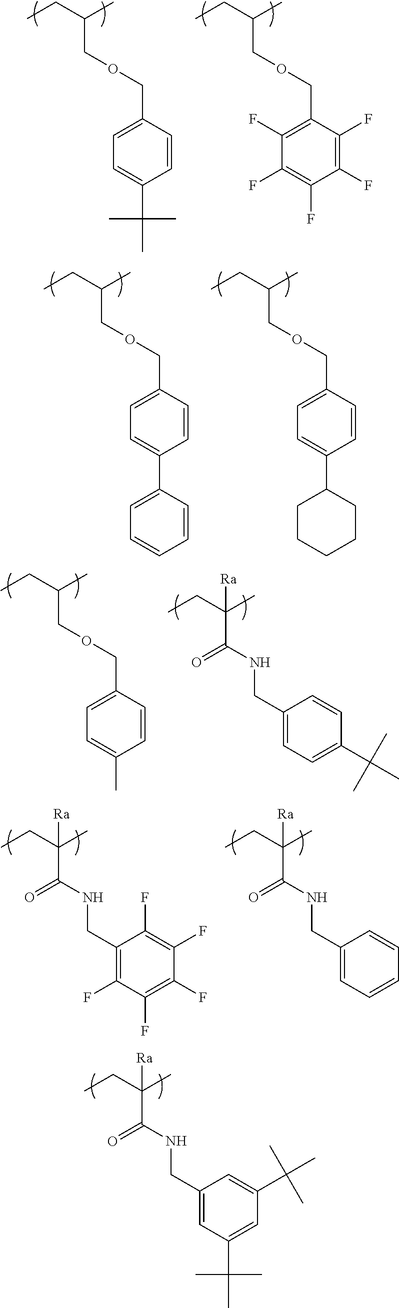

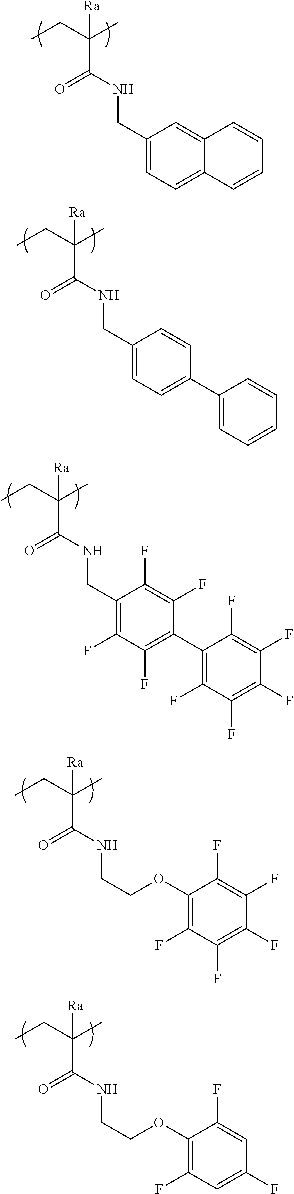

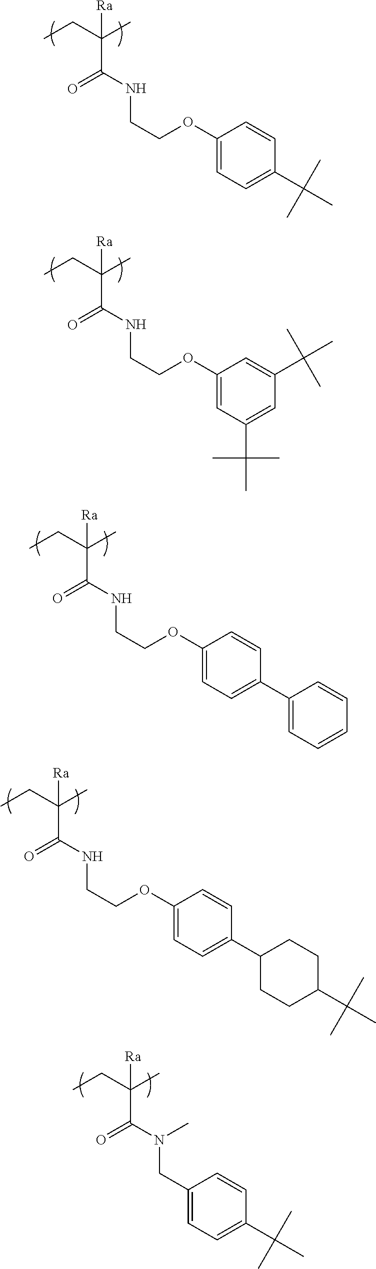

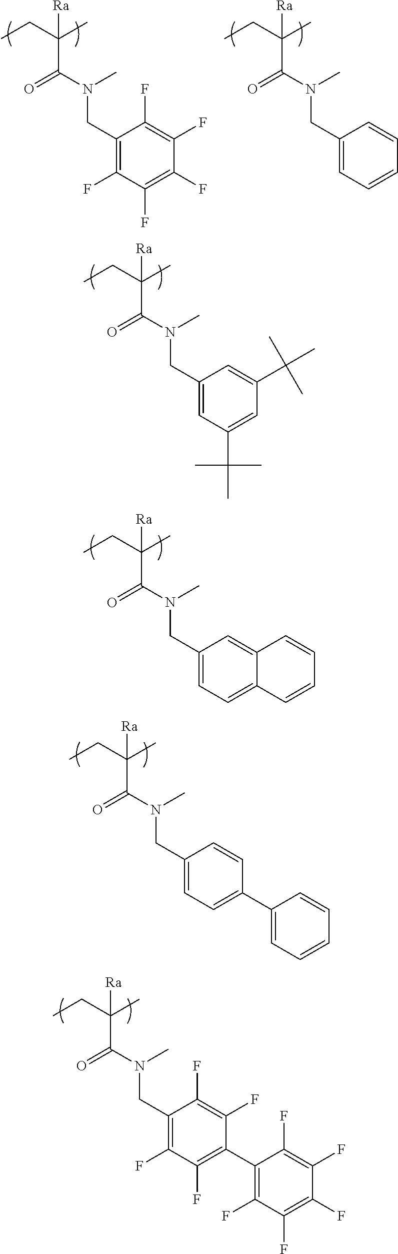

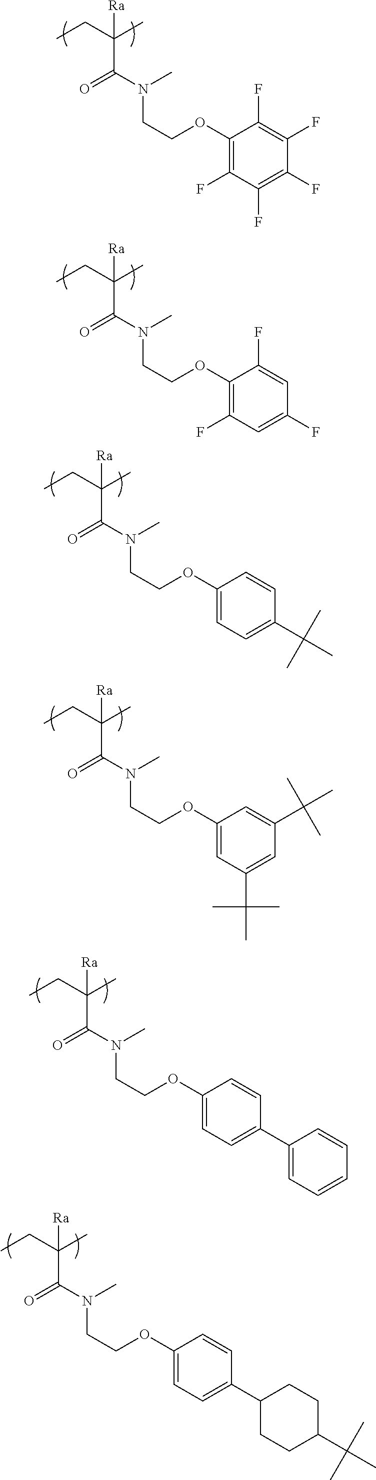

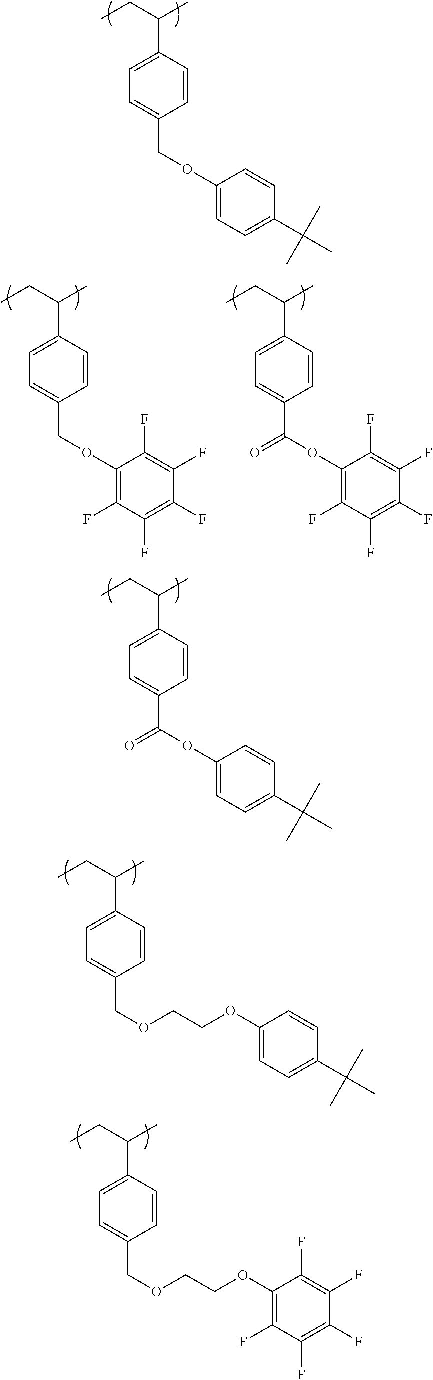

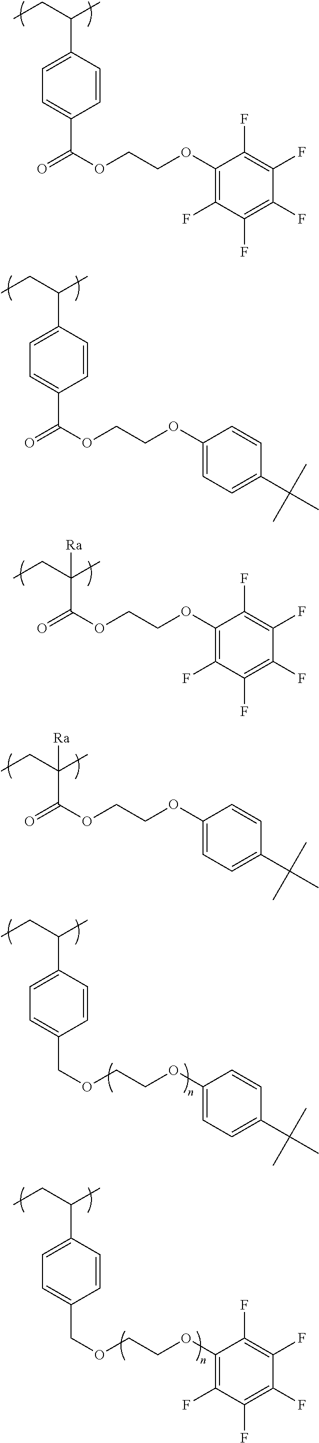

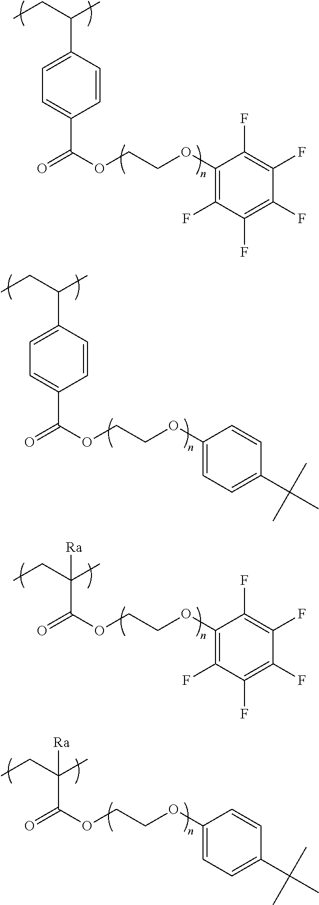

The monomers corresponding to the repeating units (R) can be synthesized by heretofore known methods. Some of the methods are described in detail in Examples to be given hereinafter.

The repeating unit (R) may be used individually or in combination. The content of the repeating unit (R) based on all the repeating units of the resin is preferably in the range of 5 to 100 mol %, more preferably 10 to 75 mol %, and further more preferably 15 to 60 mol %.

The repeating unit containing at least either a fluorine atom or a silicon atom will be described below.

As mentioned hereinbefore, the resin (B) contains at least either a fluorine atom or a silicon atom. The manner in which the fluorine atom or silicon atom is introduced into the resin is not particularly limited. The fluorine atom or silicon atom may be contained in the repeating unit (R), or the repeating unit (S) containing a group selected from the group consisting of groups (x) to (z) to be described hereinafter. Alternatively, the fluorine atom or silicon atom may be contained in other repeating units.

The repeating unit containing a fluorine atom is preferably the one containing, as a partial structure, an alkyl group containing one or more fluorine atoms, a cycloalkyl group containing one or more fluorine atoms, or an aryl group containing one or more fluorine atoms.

The alkyl group containing one or more fluorine atoms is a linear or branched alkyl group having at least one hydrogen atom thereof substituted with one or more fluorine atoms. The group preferably has 1 to 10 carbon atoms, more preferably 1 to 4 carbon atoms. Further, other substituents than fluorine atom may also be contained.

The cycloalkyl group containing one or more fluorine atoms is a monocyclic or polycyclic alkyl group having at least one hydrogen atom thereof substituted with one or more fluorine atoms. Further, other substituents than fluorine atom may also be contained.

The aryl group containing one or more fluorine atoms is an aryl group having at least one hydrogen atom of an aryl group substituted with one or more fluorine atoms. As the aryl group, a phenyl or a naphthyl group can be exemplified. Further, other substituents than fluorine atom may also be contained.

As preferred alkyl groups containing one or more fluorine atoms, cycloalkyl groups containing one or more fluorine atoms and aryl groups containing one or more fluorine atoms, groups of the following general formulae (F2) to (F4) can be exemplified.

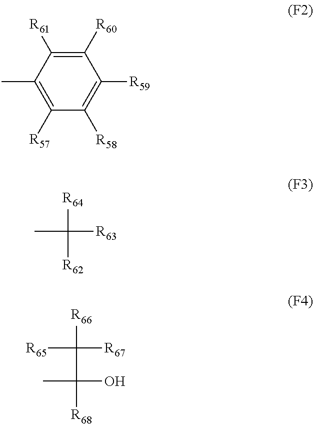

In the general formulae (F2) to (F4),

each of R₅₇ to R₆₈ independently represents a hydrogen atom, a fluorine atom or an alkyl group in condition that: at least one of R₅₇-R₆₁ represents a fluorine atom or an alkyl group having at least one hydrogen atom thereof substituted with one or more fluorine atoms; at least one of R₆₂-R₆₄ represents a fluorine atom or an alkyl group having at least one hydrogen atom thereof substituted with one or more fluorine atoms; and at least one of R₆₅-R₆₈ represents a fluorine atom or an alkyl group having at least one hydrogen atom thereof substituted with one or more fluorine atoms. These alkyl groups preferably are those having 1 to 4 carbon atoms.

It is preferred that all of R₅₇-R₆₁ and R₆₅-R₆₇ represent fluorine atoms. Each of R₆₂, R₆₃ and R₆₈ preferably represents an alkyl group having at least one hydrogen atom thereof substituted with one or more fluorine atoms, more preferably a perfluoroalkyl group having 1 to 4 carbon atoms. R₆₂ and R₆₃ may be bonded to each other to form a ring.

Specific examples of the groups represented by the general formula (F2) include a p-fluorophenyl group, a pentafluorophenyl group, and a 3,5-di(trifluoromethyl)phenyl group.

Specific examples of the groups represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups represented by the general formula (F4) include —C(CF₃)₂OH, —C(C₂F₅)₂OH, —C(CF₃)(CH₃)OH, —CH(CF₃)OH and the like. Of these, —C(CF₃)₂OH is particularly preferred.

The partial structure containing a fluorine atom may be directly bonded to the principal chain of the resin. Alternatively, the partial structure may be indirectly bonded to the principal chain via a connecting group selected from among an alkylene group, a phenylene group, an ether group, a thioether group, a carbonyl group, an ester group, an amido group, a urethane group, a ureylene group, or a combination of at least two thereof.

As preferred repeating units having a fluorine atom, there can be mentioned the repeating units represented by the general formulae below.

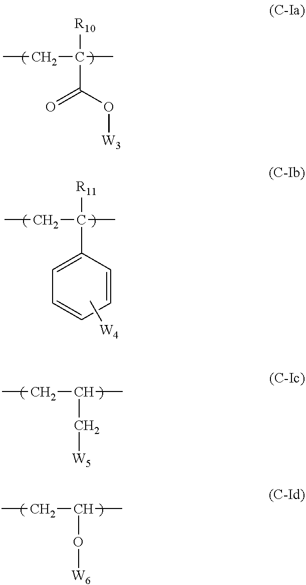

In the formulae, each of R₁₀ and R₁₁ independently represents a hydrogen atom, a fluorine atom or an alkyl group (preferably a linear or branched alkyl group having 1 to 4 carbon atoms; as a substituted alkyl group, there can be mentioned, in particular, a fluorinated alkyl group).

Each of W₃ to W₆ independently represents an organic group containing at least one fluorine atom. As such, for example, there can be mentioned the groups of general formulae (F2) to (F4) above.

Further, besides these, the following units may be introduced as the repeating unit containing a fluorine atom.

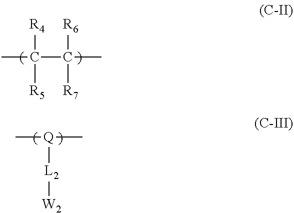

In the formulae, each of R₄ to R₇ independently represents a hydrogen atom, a fluorine atom or an alkyl group (preferably a linear or branched alkyl group having 1 to 4 carbon atoms; as a substituted alkyl group, there can be mentioned, in particular, a fluorinated alkyl group), provided that at least one of R₄ to R₇ represents a fluorine atom. R₄ and R₅, or R₆ and R₇ may cooperate with each other to thereby form a ring.

W₂ represents an organic group containing at least one fluorine atom. As such, for example, there can be mentioned the atomic groups of general formulae (F2) to (F4) above.

L₂ represents a single bond or a bivalent connecting group. As the bivalent connecting group, there can be mentioned a substituted or unsubstituted arylene group, a substituted or unsubstituted alkylene group, a substituted or unsubstituted cycloalkylene group, —O—, —SO₂—, —CO—, —N(R)— (in the formula, R is a hydrogen atom or an alkyl group), —NHSO₂— or a bivalent connecting group consisting of a combination of two or more of these.

Q represents an alicyclic structure. The alicyclic structure may have a substituent, and may be monocyclic or polycyclic. The alicyclic structure when being polycyclic may be a bridged one. The alicyclic structure when being monocyclic is preferably a cycloalkyl group having 3 to 8 carbon atoms. As such, there can be mentioned, for example, a cyclopentyl group, a cyclohexyl group, a cyclobutyl group, a cyclooctyl group or the like. As the polycyclic one, there can be mentioned a group with, for example, a bicyclo, tricyclo or tetracyclo structure having 5 or more carbon atoms. A cycloalkyl group having 6 to 20 carbon atoms is preferred. As such, there can be mentioned, for example, an adamantyl group, a norbornyl group, a dicyclopentyl group, a tricyclodecanyl group, a tetracyclododecyl group or the like. The carbon atoms of the cycloalkyl group may be partially replaced with a heteroatom, such as an oxygen atom. Particularly preferred examples of Q include a norbornyl group, a tricyclodecanyl group, a tetracyclododecyl group or the like.

Repeating units containing a silicon atom will be explained below.

The repeating unit containing a silicon atom is preferably the one containing, as a partial structure containing a silicon atom, an alkylsilyl structure (preferably a trialkylsilyl group) or a cyclosiloxane structure.

As the alkylsilyl structure or cyclosiloxane structure, there can be mentioned, for example, any of the groups of the following general formulae (CS-1) to (CS-3) or the like.

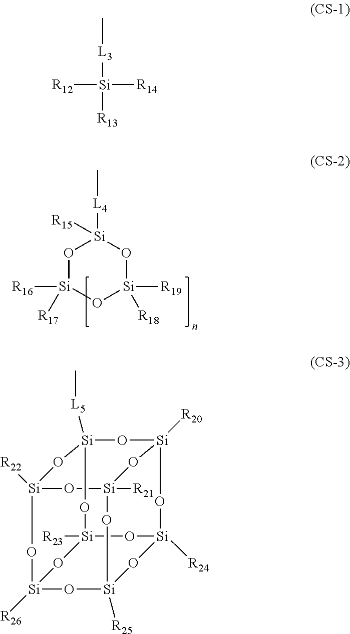

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a ureylene group.

In the formulae, n is an integer of 1 to 5. n is preferably an integer of 2 to 4.

The repeating unit containing at least either of a fluorine atom or a silicon atom is preferably the repeating unit of the (meth)acrylate type.

Specific examples of the repeating units containing a fluorine atom or silicon atom will be shown below. Note that the following specific examples include the repeating unit (S).

In specific examples, X₁ represents a hydrogen atom, —CH₃, —F or —CF₃, and X₂ represents —F or —CF₃.

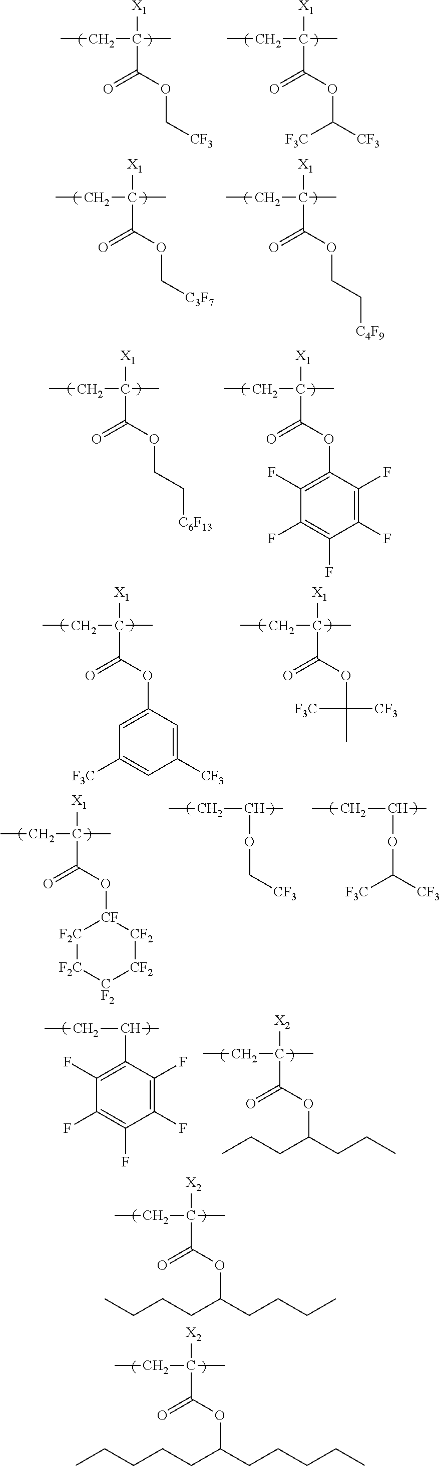

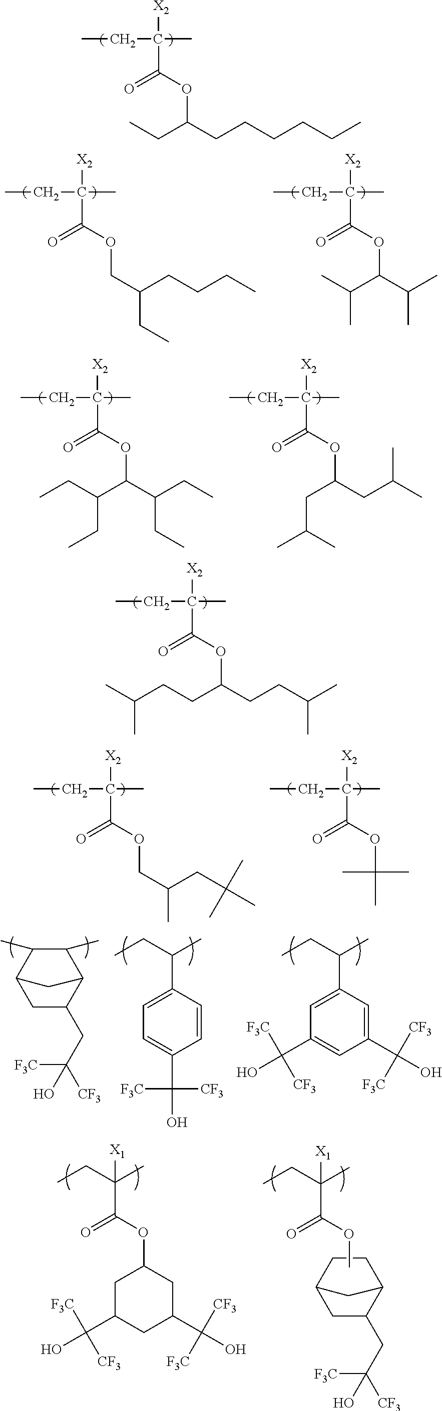

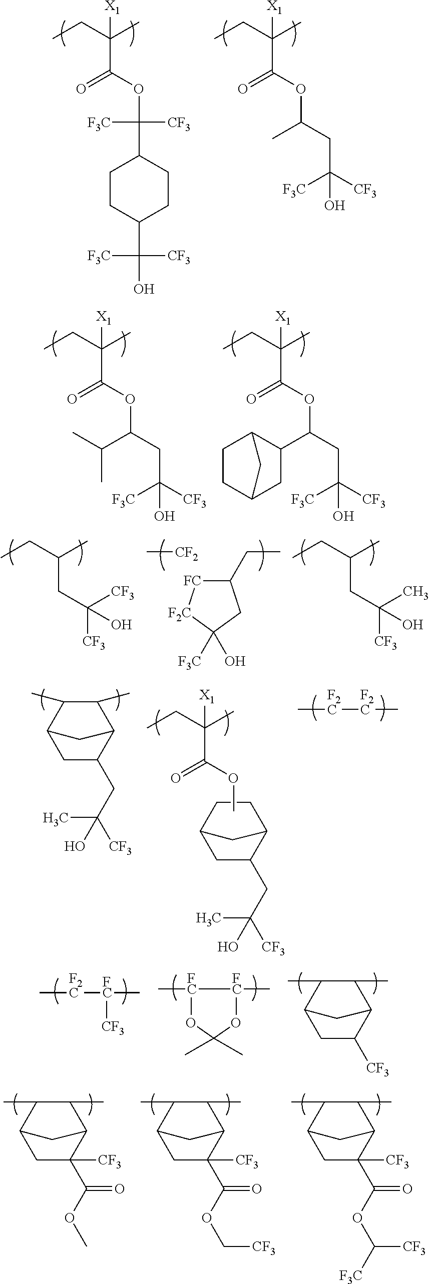

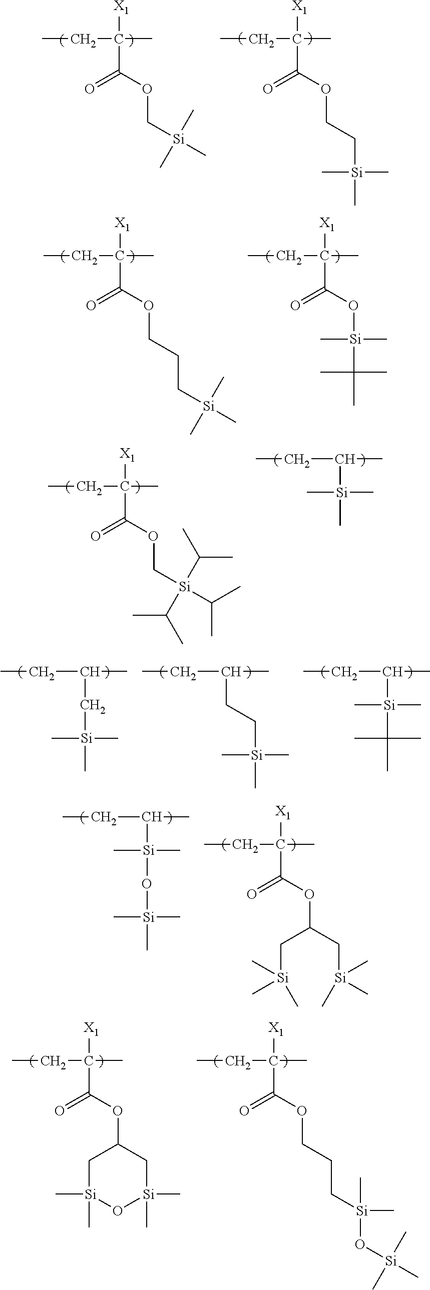

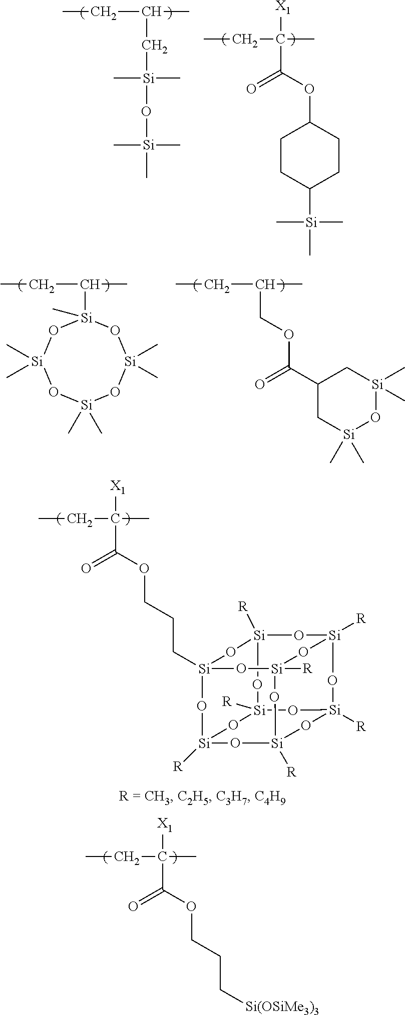

It is preferable that the resin (B) be a copolymer comprising the repeating unit (R) and one or more other repeating units. When this copolymer is used, better immersion-liquid tracking properties than those of the homopolymer of each of the repeating units making up the copolymer can be attained. Namely, when this copolymer is used, the hydrophobicity of the resin (B) as a whole can be increased without any excessive increase of the hydrophobicity of each of the repeating units making up the copolymer. Therefore, in that instance, the immersion-liquid tracking properties and the developability can be balanced at a higher level.

The repeating unit to be combined with the repeating unit (R) is most preferably a repeating unit (S) containing at least one group selected from the group consisting of the following groups (x) to (z). Namely, it is preferable that at least one of the resins (B) contain not only the repeating unit (R) but also the repeating unit (S).

(x) an alkali-soluble group;

(y) a group that is decomposed by the action of an alkali developer, resulting in an increase of solubility in the alkali developer (hereinafter also referred to as “polarity conversion group”); and

(z) a group that is decomposed by the action of an acid.

The resin preferably contains at least either of (x) an alkali-soluble group or (y) a polarity conversion group. More preferably, the resin contains one or more (y) polarity conversion groups.

As the alkali-soluble group (x), a phenolic hydroxy group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group can be exemplified.

As preferred alkali soluble groups, a fluoroalcohol group (preferably hexafluoroisopropanol group), a sulfonimido group, and a bis(carbonyl)methylene group can be exemplified.

As the repeating unit having an alkali soluble group (x), preferred use is made of any of a repeating unit resulting from direct bonding of an alkali soluble group to the principal chain of a resin like a repeating unit of acrylic acid or methacrylic acid; a repeating unit resulting from bonding, via a connecting group, of an alkali soluble group to the principal chain of a resin; and a repeating unit resulting from polymerization with the use of a chain transfer agent or polymerization initiator having an alkali soluble group to introduce the same in a polymer chain terminal.

The content of repeating units having an alkali soluble group (x) based on all the repeating units of the polymer is preferably in the range of 1 to 50 mol %, more preferably 3 to 35 mol %, and still more preferably 5 to 20 mol %.

Specific examples of the repeating units having an alkali soluble group (x) will be shown below, which however in no way limit the scope of the present invention. In the formulae, Rx represents H, CH₃, CF₃ or CH₂OH.

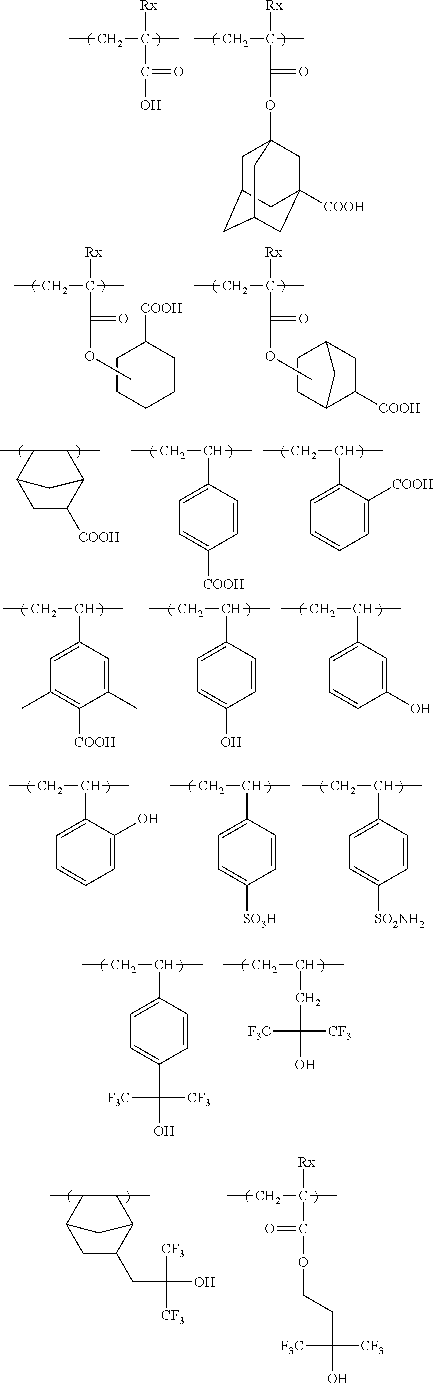

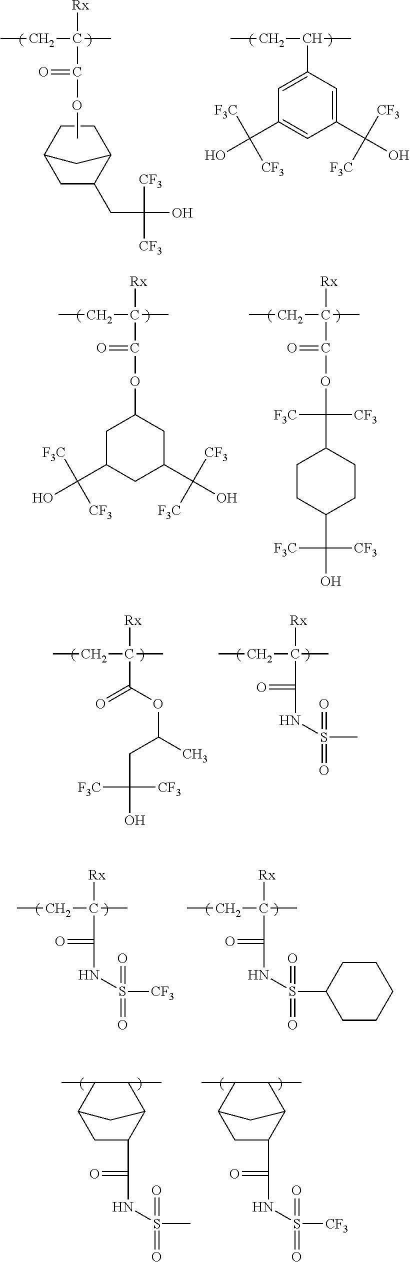

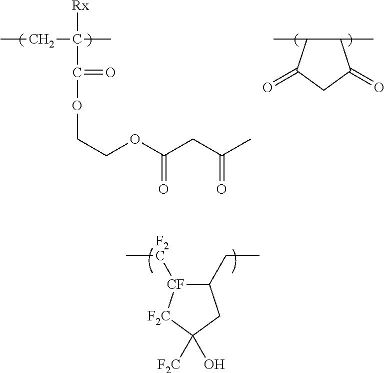

As the group (y) that is configured to decompose by the action of an alkali developer to thereby increase its solubility in the alkali developer (polarity conversion group (y)), there can be mentioned, for example, a lactone group, a carboxylic ester group (—COO—), an acid anhydride group (—C(O)OC(O)—), an acid imido group (—NHCONH—), carboxylic thioester group (—COS—), a carbonic ester group (—OC(O)O—), a sulfuric ester group (—OSO₂O—), a sulfonic ester group (—SO₂O—) or the like. A lactone group is preferred.

The polarity conversion group (y) is contained in, for example, two modes which are both preferred. In one mode, the polarity conversion group (y) is contained in a repeating unit of an acrylic ester or methacrylic ester and introduced in a side chain of a resin. In the other mode, the polarity conversion group is introduced in a terminal of a polymer chain by using a polymerization initiator or chain transfer agent containing the polarity conversion group (y) in the stage of polymerization.

As specific examples of the repeating unit (b) containing a polarity conversion group (y), repeating units with a lactone structure described in the explanation for resin (A) below can be exemplified.

Further, the repeating unit (b) containing the polarity conversion group (y) is preferred to contain at least one of a fluorine atom and a silicon atom. Resins containing such a repeating unit (b) possesses hydrophobicity and particularly preferred from the standpoint of suppressing development defects.

As the repeating unit (b), there can be mentioned, for example, any of the repeating units of formula (K0) below.

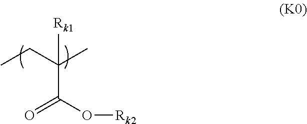

In the formula, Rₖ₁ represents a hydrogen atom, a halogen atom, a hydroxyl group, an alkyl group, a cycloalkyl group, an aryl group or a group containing a polarity conversion group.

Rₖ₂ represents an alkyl group, a cycloalkyl group, an aryl group or a group containing a polarity conversion group.

Here, at least one of Rₖ₁ and Rₖ₂ is a group containing a polarity conversion group.

The polarity conversion group, as mentioned above, refers to a group that is configured to decompose by the action of an alkali developer to thereby increase its solubility in the alkali developer. It is preferred for the polarity conversion group to be a group represented by X in the partial structures of general formulae (KA-1) and (KB-1) below.

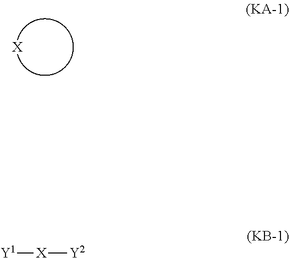

In general formulae (KA-1) and (KB-1), X represents a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—) or a sulfonic ester group (—SO₂O—).

Y¹ and Y² may be identical to or different from each other, and each thereof represents an electron withdrawing group.

The repeating unit (b) contains a preferred group whose solubility in an alkali developer is increased by containing a group with the partial structure of general formula (KA-1) or (KB-1). When the partial structure has no bonding hand as in the case of the partial structure of general formula (KA-1) or the partial structure of general formula (KB-1) in which Y¹ and Y² are monovalent, the above group with the partial structure refers to a group containing a monovalent or higher-valent group resulting from the deletion of at least one arbitrary hydrogen atom from the partial structure.

The partial structure of general formula (KA-1) or (KB-1) is linked at its arbitrary position to the principal chain of the resin (B) via a substituent.

The partial structure of general formula (KA-1) is a structure in which a ring structure is formed in cooperation with a group represented by X.

In general formula (KA-1), X is preferably a carboxylic ester group (namely, in the case of the formation of a lactone ring structure as KA-1), an acid anhydride group or a carbonic ester group. More preferably, X is a carboxylic ester group.

The cyclic structure represented by general formula (KA-1) may contain a substituent. For example, the cyclic structure may contain nka Zₖₐ₁s as substituents.

Zₖₐ₁, or each of a plurality of Zₖₐ₁s independently, represents a halogen atom, an alkyl group, a cycloalkyl group, an ether group, a hydroxyl group, an amido group, an aryl group, a lactone ring group or an electron withdrawing group.

Zₖₐ₁s may be linked to each other to thereby form a ring. As the ring formed by the mutual linkage of Zₖₐ₁s, there can be mentioned, for example, a cycloalkyl ring or a heterocycle (for example, a cycloether ring or a lactone ring).

The above nka is an integer of 0 to 10, preferably 0 to 8, more preferably 0 to 5, further more preferably 1 to 4 and most preferably 1 to 3.

The electron withdrawing groups represented by Zₖₐ₁ are the same as those represented by Y¹ and Y² to be described hereinafter. These electron withdrawing groups may be substituted with other electron withdrawing groups.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be one substituted with, for example, an alkyl group or a cycloalkyl group, namely, to be an alkyl ether group or the like. The electron withdrawing group is as mentioned above.

As the halogen atom represented by Zₖₐ₁, there can be mentioned a fluorine atom, a chlorine atom, a bromine atom, an iodine atom or the like. Among these, a fluorine atom is preferred.

The alkyl group represented by Zₖₐ₁ may contain a substituent, and may be linear or branched. The linear alkyl group preferably has 1 to 30 carbon atoms, more preferably 1 to 20 carbon atoms. As the linear alkyl group, there can be mentioned, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group or the like. The branched alkyl group preferably has 3 to 30 carbon atoms, more preferably 3 to 20 carbon atoms. As the branched alkyl group, there can be mentioned, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl (t-decanoyl) group or the like. It is preferred for the alkyl group represented by Zₖₐ₁ to be one having 1 to 4 carbon atoms, such as a methyl group, an ethyl group, an n-propyl group, an i-propyl group, an n-butyl group, an i-butyl group or a t-butyl group.

The cycloalkyl group represented by Zₖₐ₁ may contain a substituent and may be monocyclic or polycyclic. When polycyclic, the cycloalkyl group may be a bridged one. Namely, in that case, the cycloalkyl group may have a bridged structure. The monocycloalkyl group is preferably a cycloalkyl group having 3 to 8 carbon atoms. As such a cycloalkyl group, there can be mentioned, for example, a cyclopropyl group, a cyclopentyl group, a cyclohexyl group, a cyclobutyl group, a cyclooctyl group or the like. As the polycycloalkyl group, there can be mentioned a group with, for example, a bicyclo, tricyclo or tetracyclo structure having 5 or more carbon atoms. This polycycloalkyl group is preferably a cycloalkyl group having 6 to 20 carbon atoms. As such, there can be mentioned, for example, an adamantyl group, a norbornyl group, an isobornyl group, a camphonyl group, a bicyclopentyl group, an α-pinel group, a tricyclodecanyl group, a tetracyclododecyl group, an androstanyl group, any of the following structures or the like. The carbon atoms of each of the cycloalkyl groups may be partially replaced with a heteroatom, such as an oxygen atom.

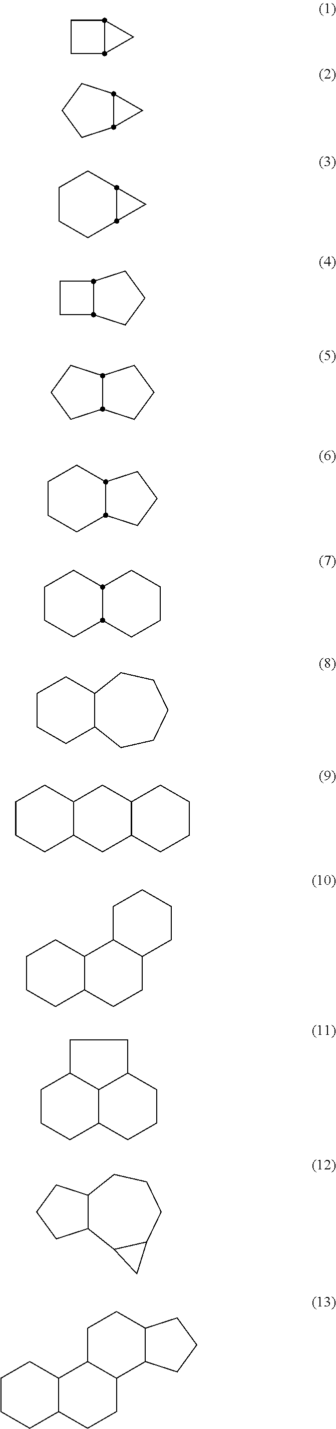

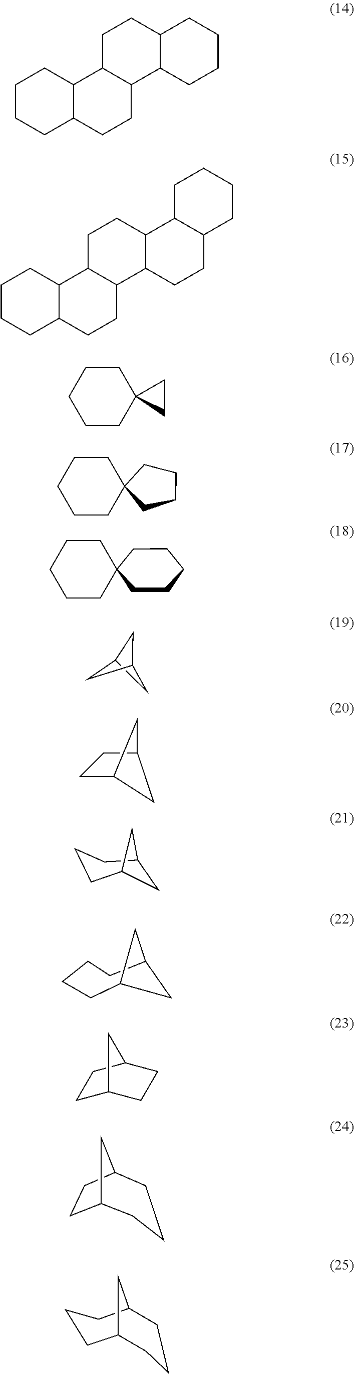

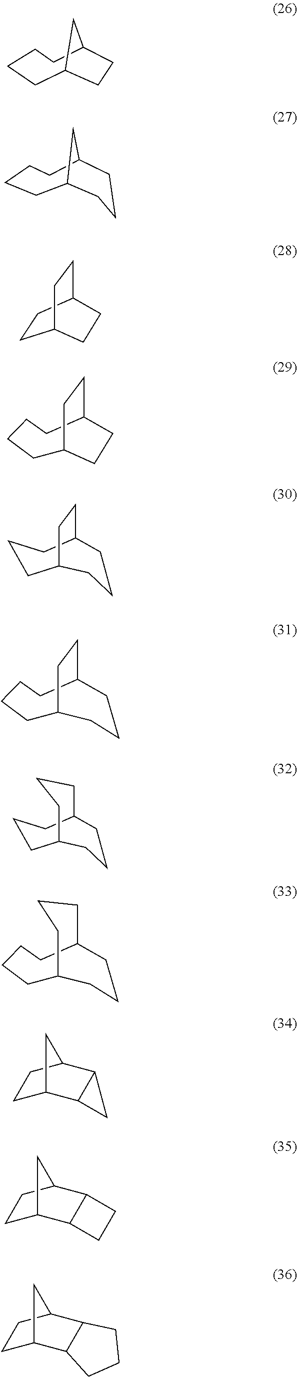

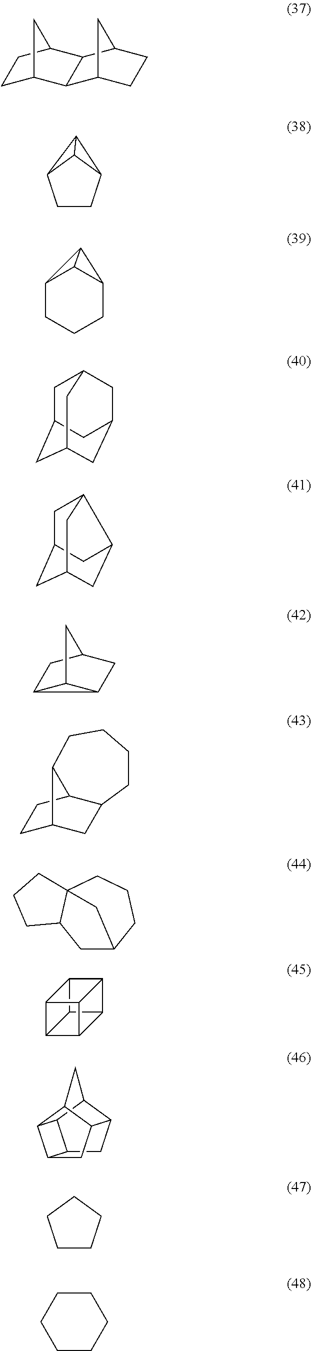

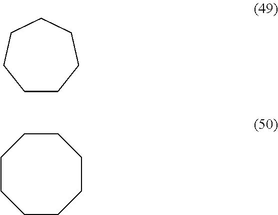

As preferred alicyclic moieties among the above, there can be mentioned an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group. As more preferred alicyclic moieties, there can be mentioned an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group.

As a substituent that can be introduced in these alicyclic structures, there can be mentioned an alkyl group, a halogen atom, a hydroxyl group, an alkoxy group, a carboxyl group or an alkoxycarbonyl group. The alkyl group is preferably a lower alkyl group, such as a methyl group, an ethyl group, a propyl group, an isopropyl group or a butyl group. More preferably, the alkyl group is a methyl group, an ethyl group, a propyl group or an isopropyl group. As preferred alkoxy groups, there can be mentioned those each having 1 to 4 carbon atoms, such as a methoxy group, an ethoxy group, a propoxy group and a butoxy group. As a substituent that may be introduced in these alkyl and alkoxy groups, there can be mentioned a hydroxyl group, a halogen atom, an alkoxy group (preferably having 1 to 4 carbon atoms) or the like.

Further substituents may be introduced in these groups. As further substituents, there can be mentioned a hydroxyl group; a halogen atom (fluorine, chlorine, bromine or iodine); a nitro group; a cyano group; the above alkyl groups; an alkoxy group, such as a methoxy group, an ethoxy group, a hydroxyethoxy group, a propoxy group, a hydroxypropoxy group, an n-butoxy group, an isobutoxy group, a sec-butoxy group or a t-butoxy group; an alkoxycarbonyl group, such as a methoxycarbonyl group or an ethoxycarbonyl group; an aralkyl group, such as a benzyl group, a phenethyl group or a cumyl group; an aralkyloxy group; an acyl group, such as a formyl group, an acetyl group, a butyryl group, a benzoyl group, or a valeryl group; an acyloxy group, such as a butyryloxy group; the above alkenyl groups; an alkenyloxy group, such as a vinyloxy group, a propenyloxy group, an allyloxy group or a butenyloxy group; the above aryl groups; an aryloxy group, such as a phenoxy group; an aryloxycarbonyl group, such as a benzoyloxy group; and the like.

Preferably, X of general formula (KA-1) represents a carboxylic ester group and the partial structure of general formula (KA-1) is a lactone ring. A 5- to 7-membered lactone ring is preferred.

Further, as shown in formulae (KA-1-1) to (KA-1-17) below, the 5- to 7-membered lactone ring as the partial structure of general formula (KA-1) is preferably condensed with another ring structure in such a fashion that a bicyclo structure or a spiro structure is formed.

The peripheral ring structures to which the ring structure of general formula (KA-1) may be bonded can be, for example, those shown in formulae (KA-1-1) to (KA-1-17) below, or those similar to the same.

It is preferred for the structure containing the lactone ring structure of general formula (KA-1) to be the structure of any of formulae (KA-1-1) to (KA-1-17) below. The lactone structure may be directly bonded to the principal chain. As preferred structures, there can be mentioned those of formulae (KA-1-1), (KA-1-4), (KA-1-5), (KA-1-6), (KA-1-13), (KA-1-14) and (KA-1-17).

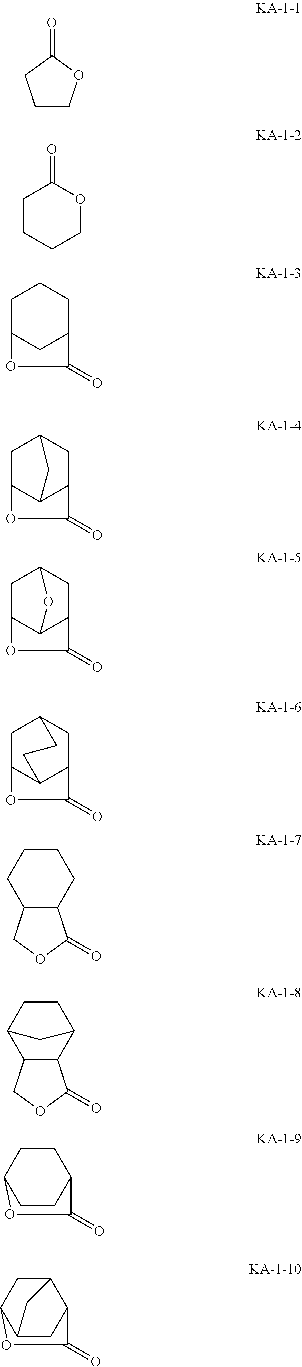

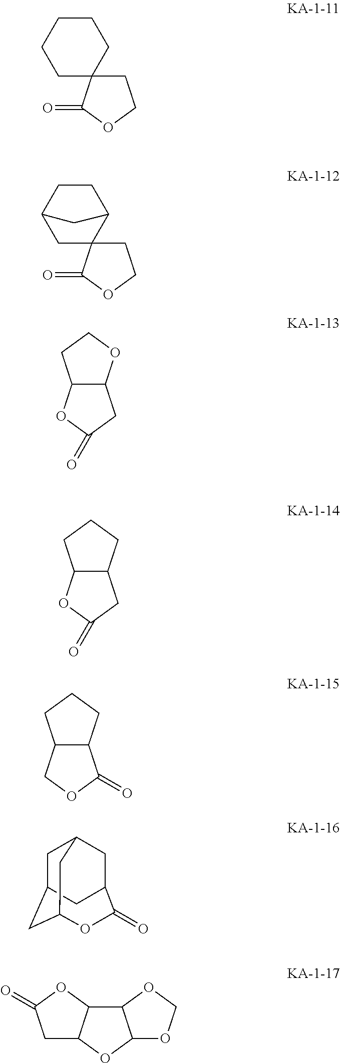

A substituent may optionally be introduced in the above structures containing the lactone ring structure. As preferred substituents, there can be mentioned the same as the substituents Zₖₐ₁ that may be introduced in the ring structure of general formula (KA-1) above.

In general formula (KB-1), X is preferably a carboxylic ester group (—COO—).

In general formula (KB-1), each of Y¹ and Y² independently represents an electron withdrawing group.

The electron withdrawing group has the partial structure of formula (EW) below. In formula (EW), * represents either a bonding hand directly bonded to the structure of general formula (KA-1) or a bonding hand directly bonded to X of general formula (KB-1).

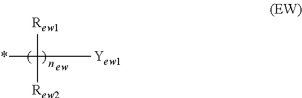

In formula (EW),

n_{ew} is the number of repetitions of each of the connecting groups of the formula —C(R_{ew1})(R_{ew2})—, being an integer of 0 or 1. When n_{ew} is 0, a single bond is represented, indicating the direct bonding of Y_{ew1}.

Y_{ew1} can be any of a halogen atom, a cyano group, a nitrile group, a nitro group, any of the halo(cyclo)alkyl groups or haloaryl groups of the formula —C(R_{f1})(R_{f2})—R_{f3} to be described hereinafter, an oxy group, a carbonyl group, a sulfonyl group, a sulfinyl group and a combination thereof. The electron withdrawing groups may have, for example, the following structures. Herein, the “halo(cyclo)alkyl group” refers to an at least partially halogenated alkyl group or cycloalkyl group. The “haloaryl group” refers to an at least partially halogenated aryl group. In the following structural formulae, each of R_{ew3} and R_{ew4} independently represents an arbitrary structure. Regardless of the types of the structures of R_{ew3} and R_{ew4}, the partial structures of formula (EW) exhibit electron withdrawing properties, and may be linked to, for example, the principal chain of the resin. Preferably, each of R_{ew3} and R_{ew4} is an alkyl group, a cycloalkyl group or a fluoroalkyl group.

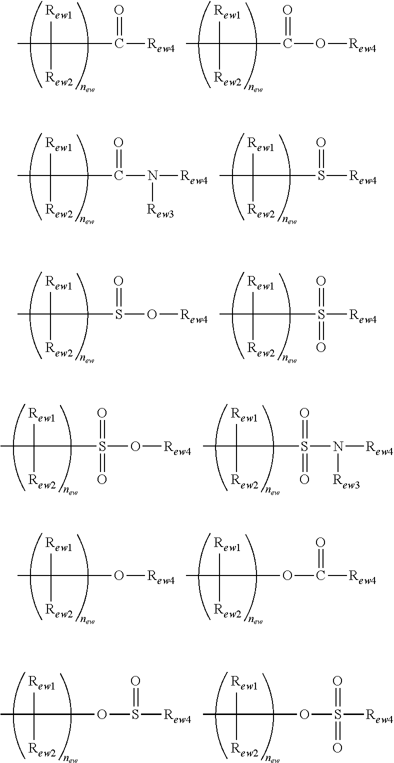

When Y_{ew1} is a bivalent or higher-valent group, the remaining bonding hand or hands form a bond with an arbitrary atom or substituent. At least any of the groups represented by Y_{ew1}, R_{ew1} and R_{ew2} may be linked via a further substituent to the principal chain of the resin (B).

Y_{ew1} is preferably a halogen atom or any of the halo(cyclo)alkyl groups or haloaryl groups of the formula —C(R_{f1})(R_{f2})—R_{f3}.

Each of R_{ew1} and R_{ew2} independently represents an arbitrary substituent, for example, a hydrogen atom, an alkyl group, a cycloalkyl group or an aryl group.

At least two of R_{ew1}, R_{ew2} and Y_{ew1} may be linked to each other to thereby form a ring.

In the above formula, R_{f1} represents a halogen atom, a perhaloalkyl group, a perhalocycloalkyl group or a perhaloaryl group. R_{f1} is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group. R_{f2} and R_{f3} may be linked to each other to thereby form a ring. As the organic group, there can be mentioned, for example, an alkyl group, a cycloalkyl group, an alkoxy group or the like. It is preferred for R_{f2} to represent the same groups as R_{f1} or to be linked to R_{f3} to thereby form a ring.

R_{f1} to R_{f3} may be linked to each other to thereby form a ring. As the formed ring, there can be mentioned a (halo)cycloalkyl ring, a (halo)aryl ring or the like.

As the (halo)alkyl groups represented by R_{f1} to R_{f3}, there can be mentioned, for example, the alkyl groups mentioned above as being represented by Zₖₐ₁ and structures resulting from halogenation thereof.

As the (per)halocycloalkyl groups and (per)haloaryl groups represented by R_{f1} to R_{f3} or contained in the ring formed by the mutual linkage of R_{f2} and R_{f3}, there can be mentioned, for example, structures resulting from halogenation of the cycloalkyl groups mentioned above as being represented by Zₖₐ₁, preferably fluorocycloalkyl groups of the formula —C₍ₙ₎F₍₂ₙ₋₂₎ H and perfluoroaryl groups of the formula —C₍ₙ₎F₍ₙ₋₁₎. The number of carbon atoms, n, is not particularly limited. Preferably, however, it is in the range of 5 to 13, more preferably 6.

As preferred rings that may be formed by the mutual linkage of at least two of R_{ew1}, R_{ew2} and Y_{ew1}, there can be mentioned cycloalkyl groups and heterocyclic groups. Preferred heterocyclic groups are lactone ring groups. As the lactone rings, there can be mentioned, for example, the structures of formulae (KA-1-1) to (KA-1-17) above.

The repeating unit (b) may contain two or more of the partial structures of general formula (KA-1), or two or more of the partial structures of general formula (KB-1), or both any one of the partial structures of general formula (KA-1) and any one of the partial structures of general formula (KB-1).

A part or the whole of any of the partial structures of general formula (KA-1) may double as the electron withdrawing group represented by Y¹ or Y² of general formula (KB-1). For example, when X of general formula (KA-1) is a carboxylic ester group, the carboxylic ester group can function as the electron withdrawing group represented by Y¹ or Y² of general formula (KB-1).

The repeating unit (b) may be a repeating unit (b′) containing at least either a fluorine atom or a silicon atom and a polarity conversion group simultaneously introduced in a side chain thereof, or a repeating unit (b*) containing a polarity conversion group but containing neither a fluorine atom nor a silicon atom, or a repeating unit (b″) in which a polarity conversion group is introduced in its one side chain while at least either a fluorine atom or a silicon atom is introduced in a side chain other than the above side chain within the same repeating unit. However, it is preferred for the resin (B) to contain the repeating unit (b′) as the repeating unit (b).

When the resin (B) contains the repeating unit (b*), it is preferred for the resin (B) to be a copolymer with a repeating unit (repeating unit (b) to be described hereinafter) containing at least either a fluorine atom or a silicon atom. In the repeating unit (b″), it is preferred for the side chain containing a polarity conversion group and the side chain containing at least either a fluorine atom or a silicon atom to be bonded to the same carbon atom of the principal chain, namely to be in a positional relationship shown in formula (K1) below.

In the formula, B1 represents a partial structure containing a group whose solubility is increased in an alkali developer, and B2 represents a partial structure containing at least either a fluorine atom or a silicon atom.

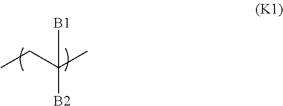

In the repeating unit (b*) and repeating unit (b″), it is highly preferred for the polarity conversion group to be a partial structure represented by —COO— in the structure of general formula (KA-1).

The receding contact angle with water of the resin composition film after alkali development can be decreased by the polarity conversion effected by the decomposition of the polarity conversion group by the action of an alkali developer. The decrease of the receding contact angle between water and the film after alkali development is preferred from the viewpoint of the inhibition of development defects.

The receding contact angle with water of the resin composition film after alkali development is preferably 50° or less, and more preferably 40° or less at 23±3° C. in a humidity of 45±5%.

The receding contact angle refers to a contact angle determined when the contact line at a droplet-substrate interface draws back. It is generally known that the receding contact angle is useful in the simulation of droplet mobility in a dynamic condition. In brief, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

The above receding contact angle of the film after alkali development refers to the contact angle obtained by measuring the following film by the dilation/contraction method. Namely, an organic antireflection film ARC29SR (produced by Nissan Chemical Industries, Ltd.) was applied onto a silicon wafer (8-inch caliber) and baked at 205° C. for 60 seconds, thereby forming a 98 nm-thick antireflection film. Each of the compositions of the present invention was applied thereonto and baked at 120° C. for 60 seconds, thereby forming a 120 nm-thick film. The film was developed with an aqueous solution of tetramethylammonium hydroxide (2.38 mass %) for 30 seconds, rinsed with pure water and spin dried. The contact angle of the thus obtained film was measured in accordance with the dilation/contraction method.

The rate of hydrolysis of the resin (B) in an alkali developer is preferably 0.001 nm/sec or greater, more preferably 0.01 nm/sec or greater, further more preferably 0.1 nm/sec or greater and most preferably 1 nm/sec or greater.

Herein, the rate of hydrolysis of the resin (B) in an alkali developer refers to the rate of decrease of the thickness of a resin film formed from only the resin (B) in 23° C. TMAH (aqueous solution of tetramethylammonium hydroxide) (2.38 mass %).

It is preferable that the resin (B) contains the repeating unit (b) containing at least two polarity conversion groups, and contains at least either of a fluorine atom or a silicon atom.

When the repeating unit (b) contains at least two polarity conversion groups, it is preferred for the repeating unit to contain a group with any of the partial structures having two polarity conversion groups of general formula (KY-1) below. When the structure of general formula (KY-1) has no bonding hand, a group with a mono- or higher-valent group resulting from the removal of at least any arbitrary one of the hydrogen atoms contained in the structure is referred to.

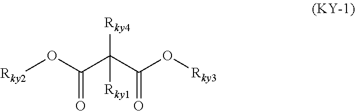

In general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. Alternatively, both R_{ky1} and R_{ky4} may be bonded to the same atom to thereby form a double bond. For example, both R_{ky1} and R_{ky4} may be bonded to the same oxygen atom to thereby form a part (═O) of a carbonyl group.

Each of R_{ky2} and R_{ky3} independently represents an electron withdrawing group. Alternatively, R_{ky1} and R_{ky2} are linked to each other to thereby form a lactone structure, while R_{ky3} is an electron withdrawing group. The formed lactone structure is preferably any of the above-mentioned structures (KA-1-1) to (KA-1-17). As the electron withdrawing group, there can be mentioned any of the same groups as mentioned above with respect to Y¹ and Y² of general formula (KB-1). This electron withdrawing group is preferably a halogen atom, or any of the halo(cyclo)alkyl groups or haloaryl groups of the formula —C(R_{f1})(R_{f2})—R_{f3} above. Preferably, R_{ky3} is a halogen atom, or any of the halo(cyclo)alkyl groups or haloaryl groups of the formula —C(R_{f1})(R_{f2})—R_{f3} above, while R_{ky2} is either linked to R_{ky1} to thereby form a lactone ring, or an electron withdrawing group containing no halogen atom.

R_{ky1}, R_{ky2} and R_{ky4} may be linked to each other to thereby form a monocyclic or polycyclic structure.

As R_{ky1} and R_{ky4}, there can be mentioned, for example, the same groups as set forth above with respect to Zₖₐ₁ of general formula (KA-1).

The lactone rings formed by the mutual linkage of R_{ky1} and R_{ky2} preferably have the structures of formulae (KA-1-1) to (KA-1-17) above. As the electron withdrawing groups, there can be mentioned those mentioned above as being represented by Y¹ and Y² of general formula (KB-1) above.

It is more preferred for the structure of general formula (KY-1) to be the structure of general formula (KY-2) below. The structure of general formula (KY-2) refers to a group with a mono- or higher-valent group resulting from the removal of at least any arbitrary one of the hydrogen atoms contained in the structure.

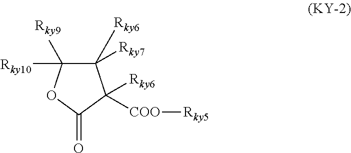

In formula (KY-2),

each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group.

At least two of R_{ky6} to R_{ky10} may be linked to each other to thereby form a monocyclic or polycyclic structure.

R_{ky5} represents an electron withdrawing group. As the electron withdrawing group, there can be mentioned any of the same groups as set forth above with respect to Y¹ and Y². This electron withdrawing group is preferably a halogen atom, or any of the halo(cyclo)alkyl groups or haloaryl groups of the formula —C(R_{f1})(R_{f2})—R_{f3} above.

As R_{ky5} to R_{ky10}, there can be mentioned, for example, the same groups as set forth above with respect to Zₖₐ₁ of formula (KA-1).

It is more preferred for the structure of formula (KY-2) to be the partial structure of general formula (KY-3) below.

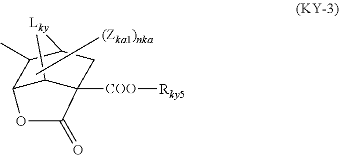

In formula (KY-3), Zₖₐ₁ and nka are as defined above in connection with general formula (KA-1). R_{ky5} is as defined above in connection with formula (KY-2).

L_{ky} represents an alkylene group, an oxygen atom or a sulfur atom. As the alkylene group represented by L_{ky}, there can be mentioned a methylene group, an ethylene group or the like. L_{ky} is preferably an oxygen atom or a methylene group, more preferably a methylene group.

The repeating units (b) are not limited as long as they are derived by polymerization, such as addition polymerization, condensation polymerization or addition condensation. Preferred repeating units are those obtained by the addition polymerization of a carbon to carbon double bond. As such repeating units, there can be mentioned, for example, acrylate repeating units (including the family having a substituent at the α- and/or β-position), styrene repeating units (including the family having a substituent at the α- and/or β-position), vinyl ether repeating units, norbornene repeating units, repeating units of maleic acid derivatives (maleic anhydride, its derivatives, maleimide, etc.) and the like. Of these, acrylate repeating units, styrene repeating units, vinyl ether repeating units and norbornene repeating units are preferred. Acrylate repeating units, vinyl ether repeating units and norbornene repeating units are more preferred. Acrylate repeating units are most preferred.

The repeating unit (b) can be a repeating unit with the following partial structure.

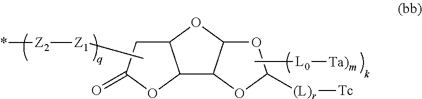

In general formula (bb),

Z₁ represents a single bond, an ether bond, an ester bond, an amido bond, a urethane bond or a urea bond. When there are a plurality of Z₁s, they may be identical to or different from each other. Z₁ is preferably an ester bond.

Z₂ represents a chain- or cycloalkylene group. When there are a plurality of Z₂s, they may be identical to or different from each other. Z₂ is preferably an alkylene group having 1 or 2 carbon atoms and a cycloalkylene group having 5 to 10 carbon atoms.

Ta, or each of Ta's independently, represents an alkyl group, a cycloalkyl group, an alkoxy group, a nitrile group, a hydroxyl group, an amido group, an aryl group or an electron withdrawing group (having the same meaning as that of the electron withdrawing group represented by Y¹ or Y² of general formula (KB-1) above). An alkyl group, a cycloalkyl group and an electron withdrawing group are preferred. An electron withdrawing group is more preferred. Two or more Ta's may be bonded to each other to thereby form a ring.

L₀ represents a single bond or a hydrocarbon group with a valence of m+1 (preferably having 20 or less carbon atoms). A single bond is preferred. L₀ is a single bond when m is 1. The hydrocarbon group with a valence of (m+1) represented by L₀ is, for example, one resulting from the removal of any (m−1) hydrogen atoms from an alkylene group, a cycloalkylene group, a phenylene group or a combination thereof. When k is 2, two L₀s may be bonded to each other to thereby form a ring.

L, or each of L's independently, represents a carbonyl group, a carbonyloxy group or an ether group.

Tc represents a hydrogen atom, an alkyl group, a cycloalkyl group, a nitrile group, a hydroxyl group, an amido group, an aryl group or an electron withdrawing group (having the same meaning as that of the electron withdrawing group represented by Y¹ or Y² of general formula (KB-1)).

In the formula, * represents a bonding hand to the principal chain or a side chain of the resin. Specifically, any of the partial structures of formula (bb) may be directly bonded to the principal chain, or may be bonded to a side chain of the resin.

In the general formula,

m is an integer of 1 to 28, preferably an integer of 1 to 3, more preferably 1;

k is an integer of 0 to 2, preferably 1;

q is an integer of 0 to 5, preferably 1 or 2; and

r is an integer of 0 to 5.

The moiety -(L)r-Tc may be replaced with -L₀-(Ta)m.

Among the lactone structures of general formula (bb), repeating unit (b″) in which a fluorine atom or a group containing a fluorine atom is introduced as a substituent in the location remotest from the above * (location at which the number of intervening atoms is the greatest) and those in which a fluorine atom is introduced in the side chain within the same repeating unit different from the side chain on the lactone side shown in general formula (bb) are also preferred.

As further particular structures of the repeating units (bb), the repeating units with the following partial structures are preferred.

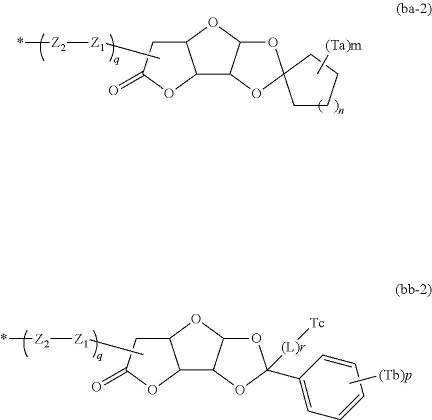

In general formulae (ba-2) and (bb-2),

n is an integer of 0 to 11, and

p is an integer of 0 to 5.

Tb, or each of Tbs independently, represents an alkyl group, a cycloalkyl group, an alkoxy group, a nitrile group, a hydroxyl group, an amido group, an aryl group or an electron withdrawing group (having the same meaning as that of the electron withdrawing group represented by Y¹ or Y² of general formula (KB-1)). When there are a plurality of Tbs, they may be bonded to each other to thereby form a ring.

Z₁, Z₂, Ta, Tc, L, *, m, q and r are as defined above in connection with general formula (bb). Preferred examples thereof are also the same.

The repeating unit (b) can be a repeating unit with the partial structure of general formula (KY-4) below.

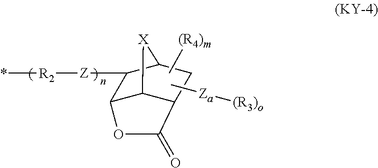

In general formula (KY-4),

R₂ represents an alkylene group or a cycloalkylene group, provided that when there are a plurality of R₂s, they may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of the formula R—C(═O)— or R—C(═O)O— in which R is an alkyl group or a cycloalkyl group. When there are a plurality of R₄s, they may be identical to or different from each other. Two or more R₄s may be bonded to each other to thereby form a ring.

X represents an alkylene group, an oxygen atom or a sulfur atom.

Each of Z and Za represents a single bond, an ether bond, an ester bond, an amido bond, a urethane bond or a urea bond. When there are a plurality thereof, they may be identical to or different from each other.

In the formula, * represents a bonding hand to the principal chain or a side chain of the resin;

o is the number of substituents, being an integer of 1 to 7;

m is the number of substituents, being an integer of 0 to 7; and

n is the number of repetitions, being an integer of 0 to 5.

The structure —R₂—Z— is preferably the structure of formula —(CH₂)₁—COO— in which 1 is an integer of 1 to 5.

More preferably, the repeating unit (b) can be a repeating unit with the partial structure of general formula (KY-5) below.

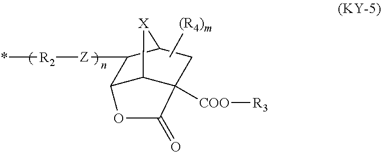

In general formula (KY-5),

R₂ represents an alkylene group or a cycloalkylene group, provided that when there are a plurality of R₂s, they may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of the formula R—C(═O)— or R—C(═O)O— in which R is an alkyl group or a cycloalkyl group. When there are a plurality of R₄s, they may be identical to or different from each other. Two or more R₄s may be bonded to each other to thereby form a ring.

X represents an alkylene group, an oxygen atom or a sulfur atom.

Z represents a single bond, an ether bond, an ester bond, an amido bond, a urethane bond or a urea bond. When there are a plurality thereof, they may be identical to or different from each other.

In the formula, * represents a bonding hand to the principal chain or a side chain of the resin;

m is the number of substituents, being an integer of 0 to 7; and

n is the number of repetitions, being an integer of 0 to 5.

The structure —R₂—Z— is preferably the structure of formula —(CH₂)₁—COO— in which 1 is an integer of 1 to 5.

Moreover, as particular structures of the repeating units (b), there can be mentioned the repeating units with the following partial structures.

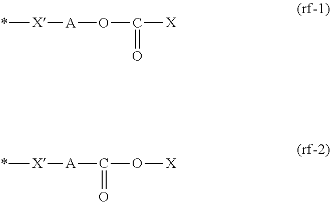

In general formulae (rf-1) and (rf-2),

X′ represents an electron withdrawing substituent, preferably a carbonyloxy group, an oxycarbonyl group, an alkylene group substituted with a fluorine atom or a cycloalkylene group substituted with a fluorine atom.

A represents a single bond or a bivalent connecting group, preferably a single bond, an alkylene group optionally substituted with a fluorine atom, or a cycloalkylene group substituted with a fluorine atom.

X represents an electron withdrawing group, preferably a fluorinated alkyl group, a fluorinated cycloalkyl group, an aryl group substituted with a fluorine atom or a fluorinated alkyl group, or an aralkyl group substituted with a fluorine atom or a fluorinated alkyl group.

* represents a bonding hand to the principal chain or a side chain of the resin, namely, a bonding hand bonded to the principal chain of the resin through a single bond or a connecting group.

When X′ is a carbonyloxy group or an oxycarbonyl group, A is not a single bond.

As the partial structure containing a fluorine atom within the repeating unit (b), there can be mentioned any of those set forth above, preferably the groups of general formulae (F2) to (F4) above.

As the partial structure containing a silicon atom within the repeating unit (b), there can be mentioned any of those set forth above, preferably the groups of general formulae (CS-1) to (CS-3) above.

The content of repeating unit (b) in the resin (B), based on all the repeating units of the resin (B), is preferably in the range of 10 to 99 mol %, more preferably 20 to 97 mol %, further more preferably 30 to 95 mol % and most preferably 40 to 95 mol %.

Specific examples of the repeating units (b) containing a group whose solubility in an alkali developer is increased are shown below, which however in no way limit the scope of the repeating units. Here, Ra represents a hydrogen atom, a fluorine atom, a methyl group, or a trifluoromethyl group.

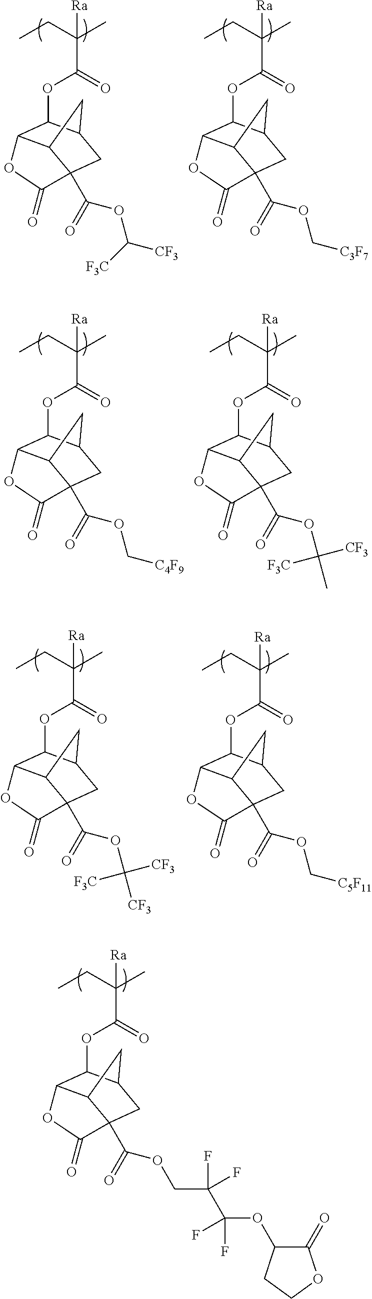

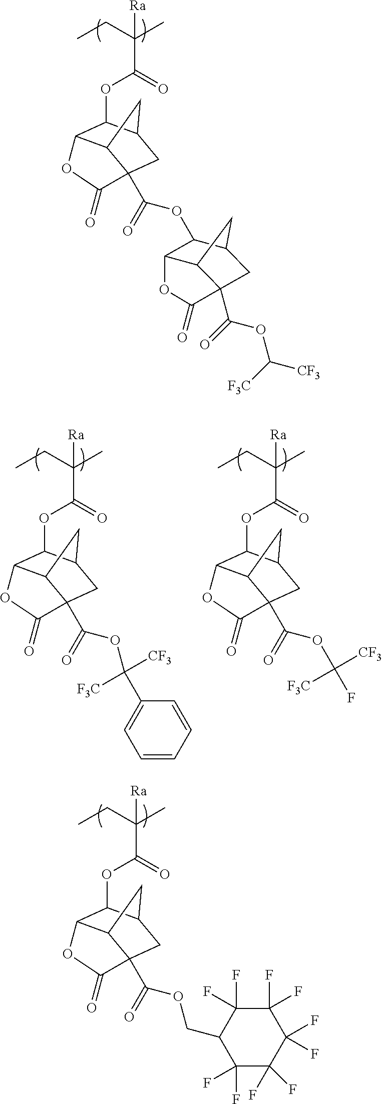

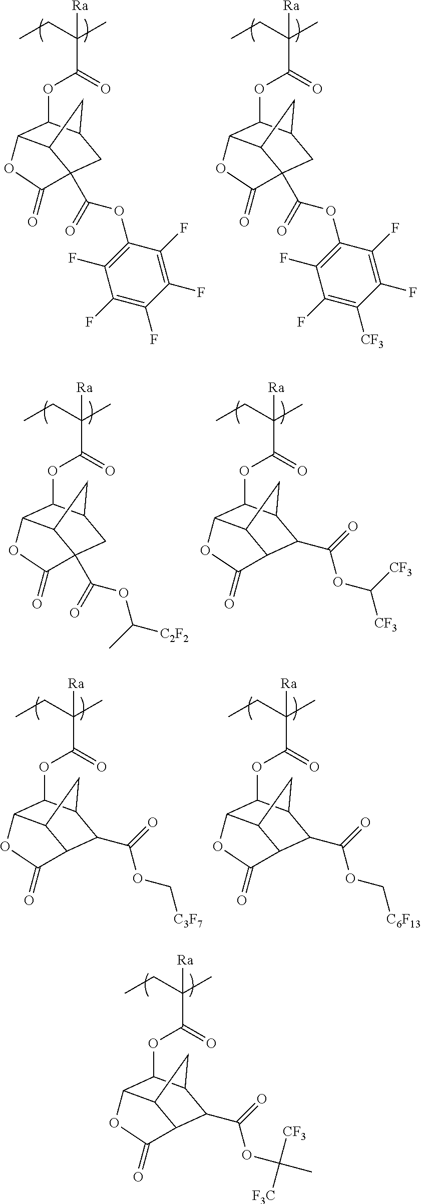

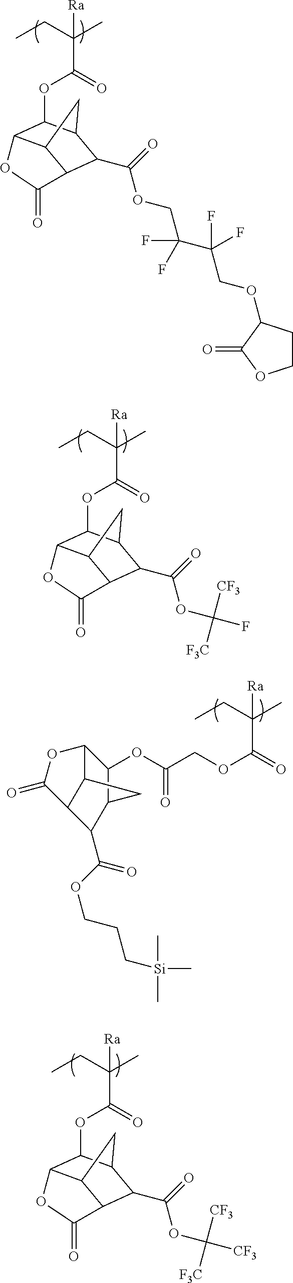

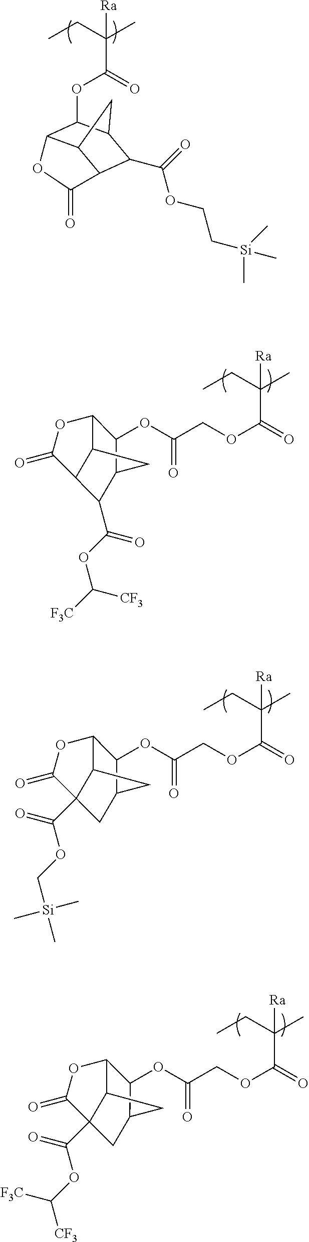

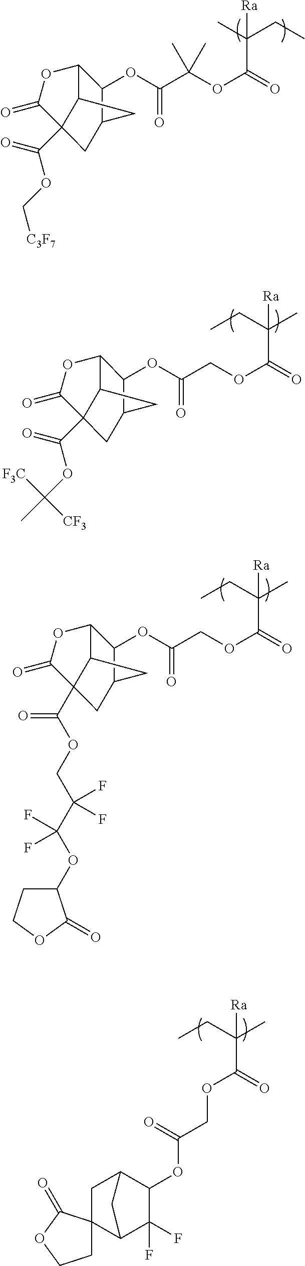

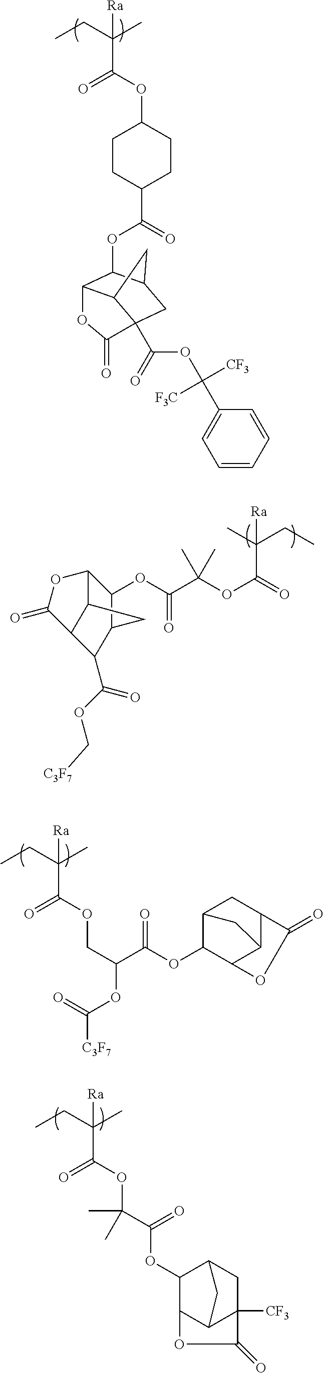

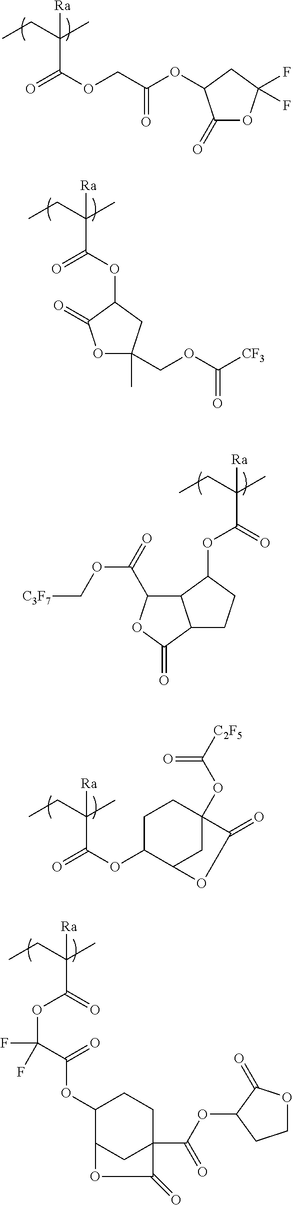

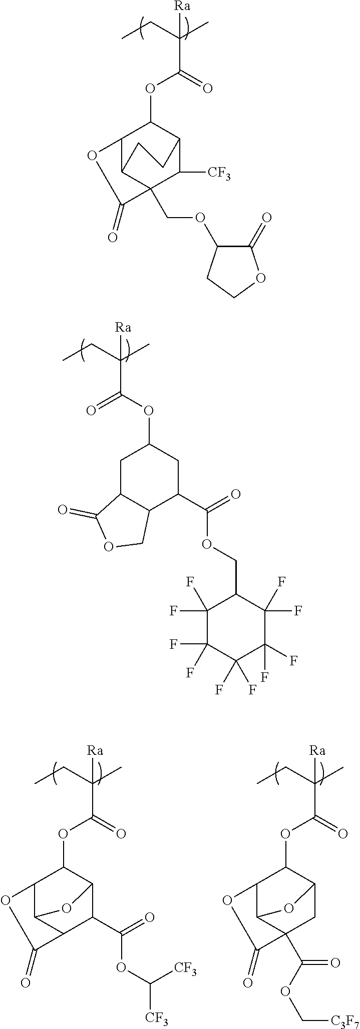

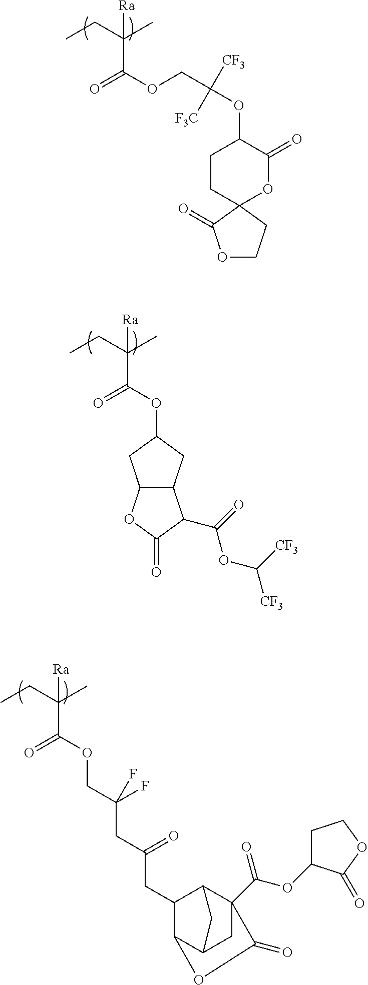

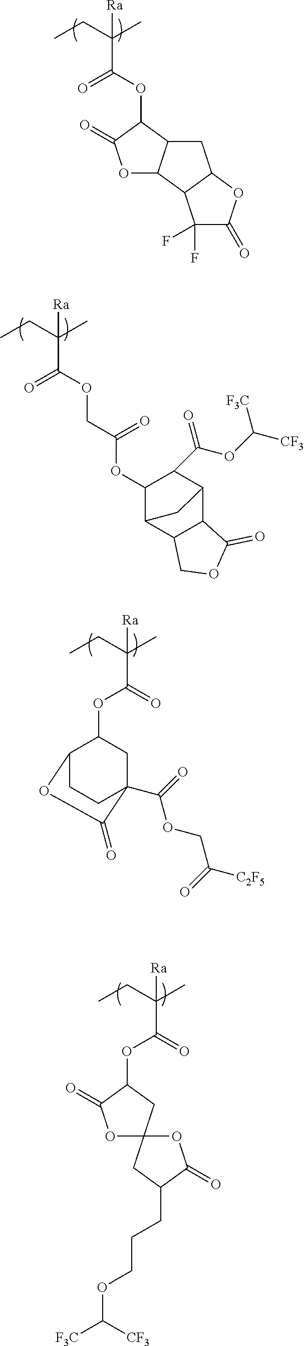

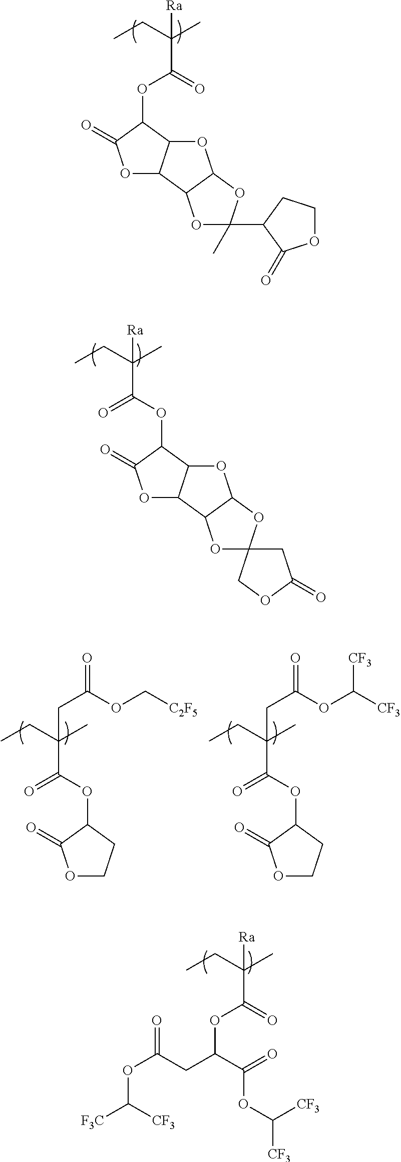

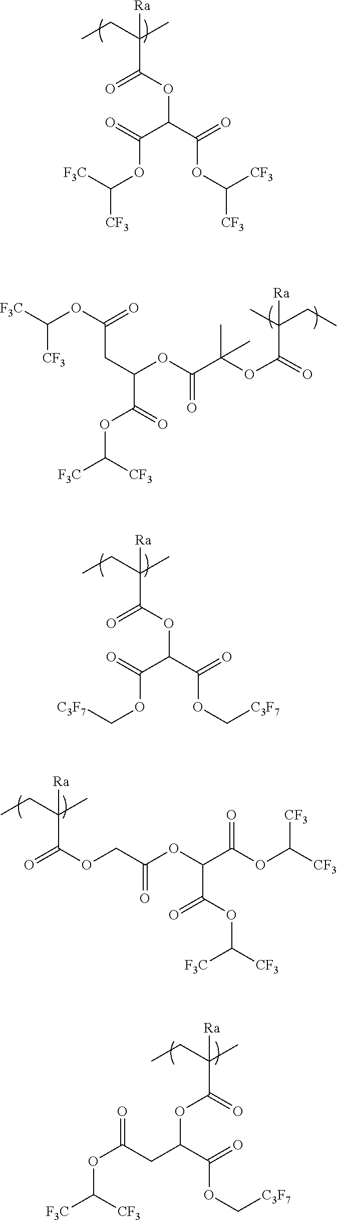

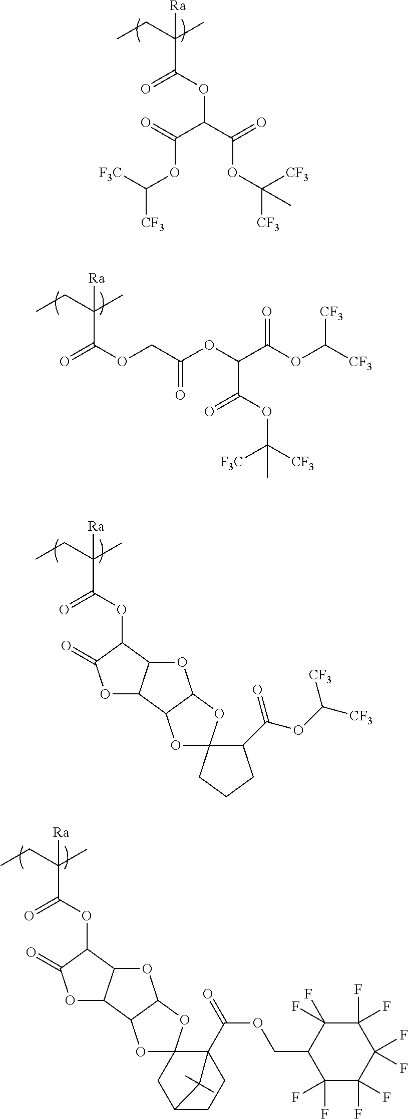

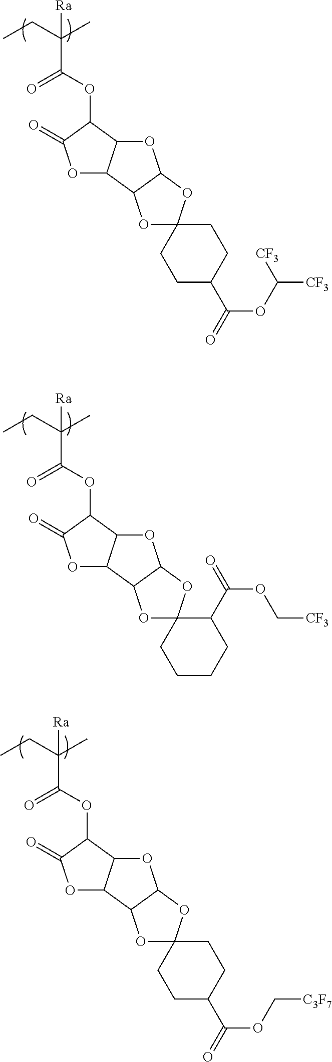

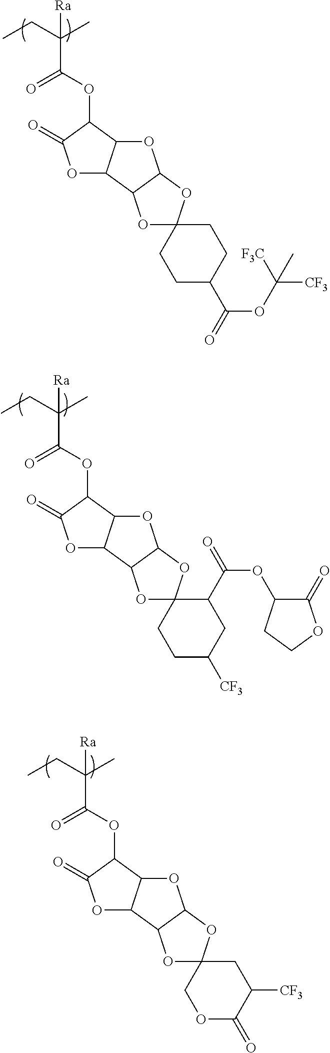

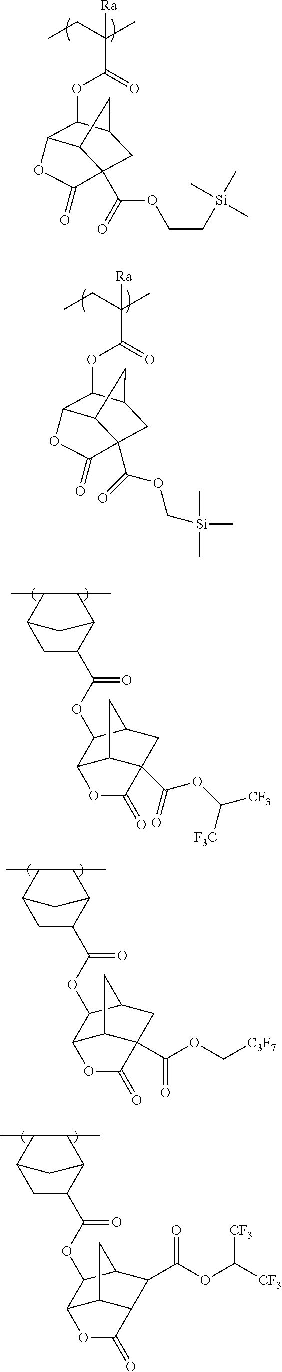

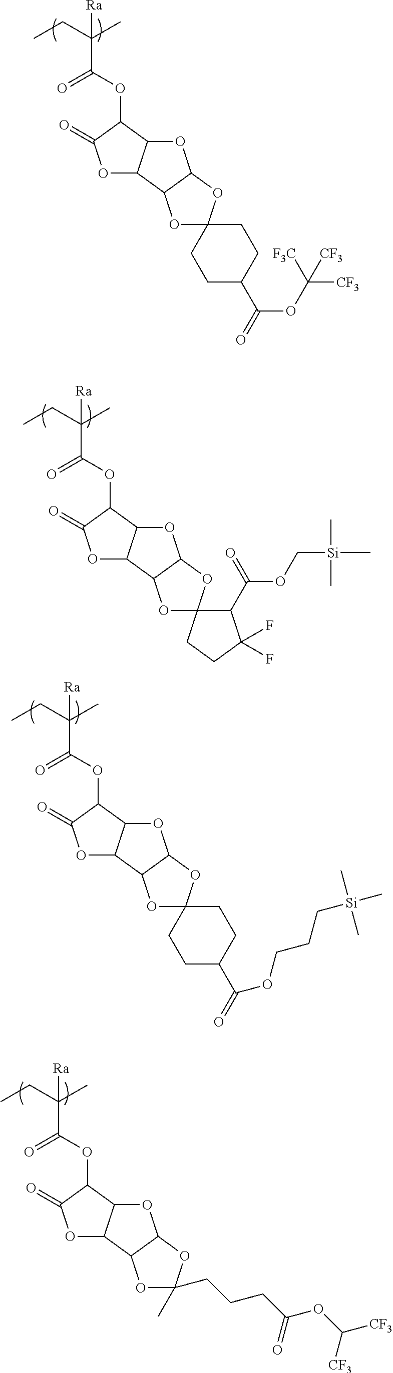

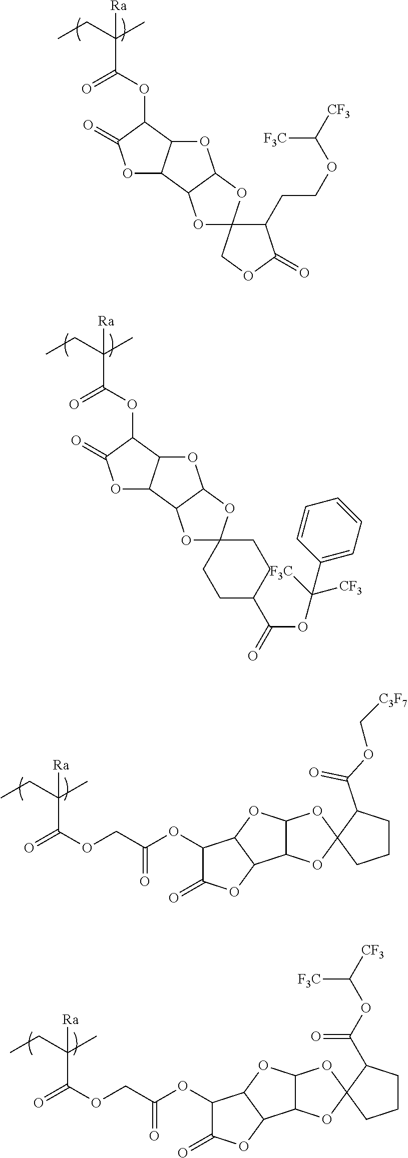

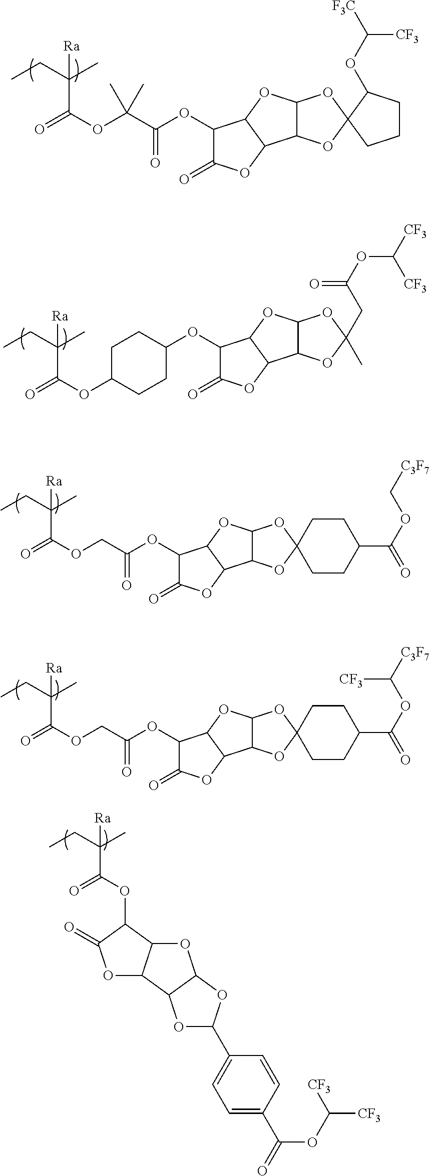

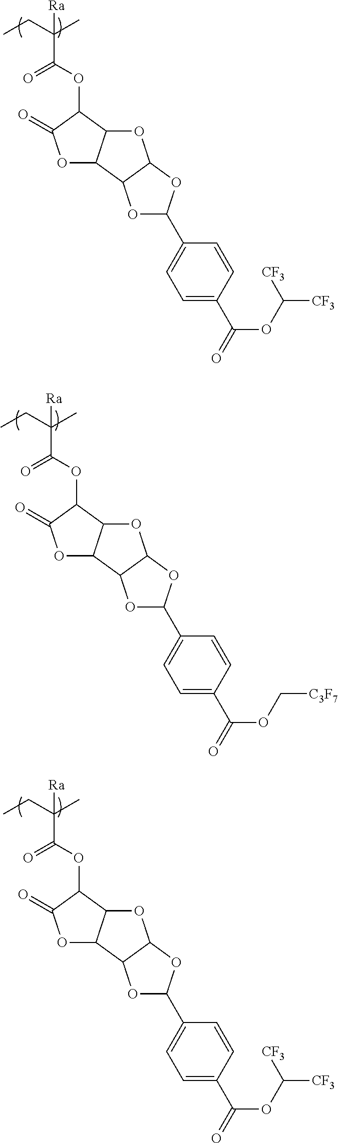

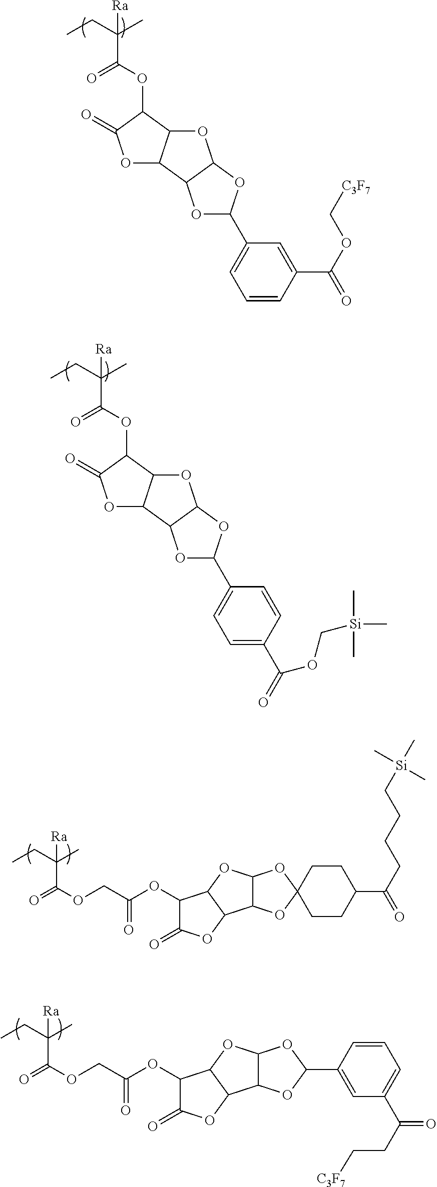

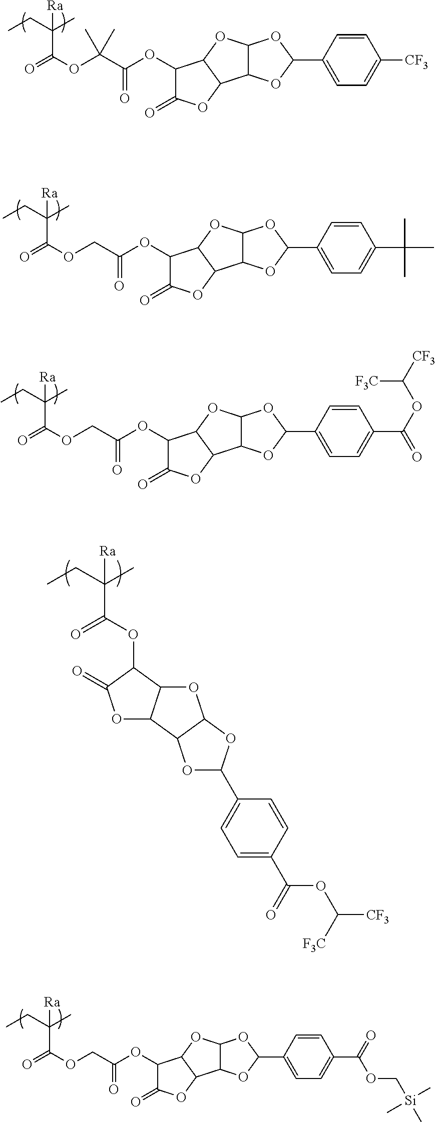

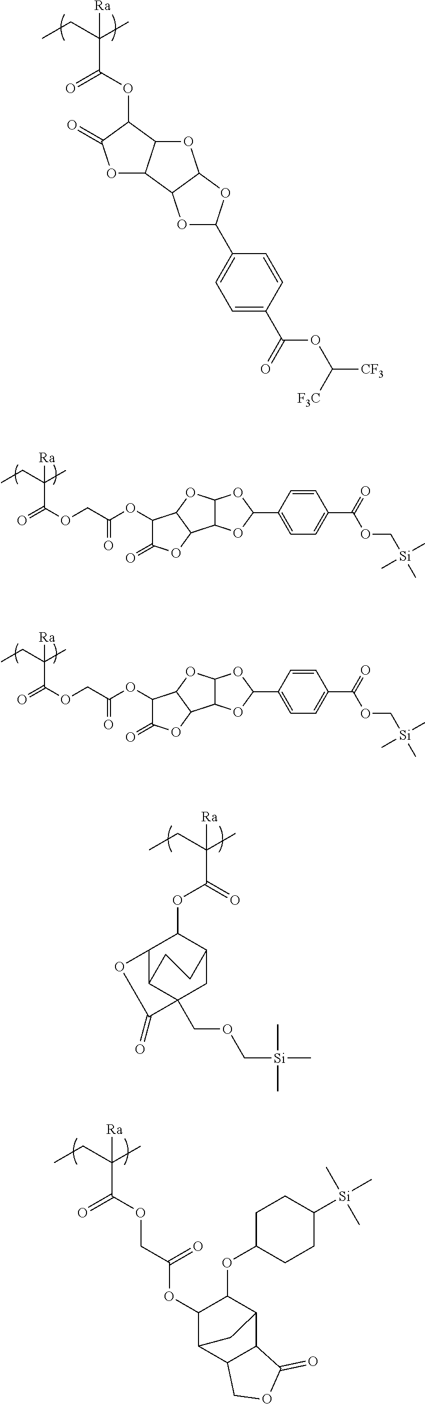

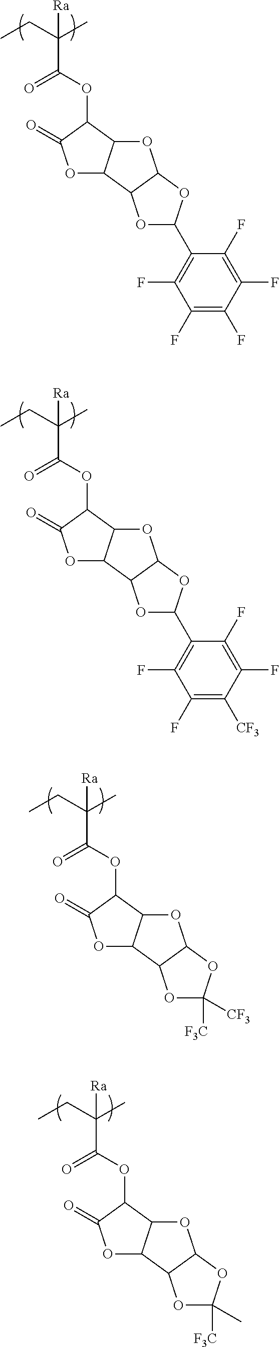

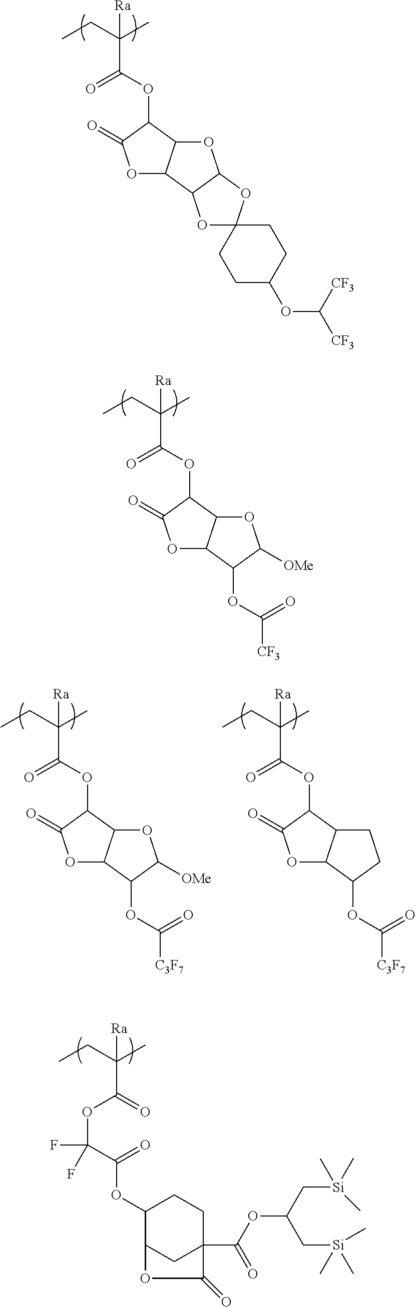

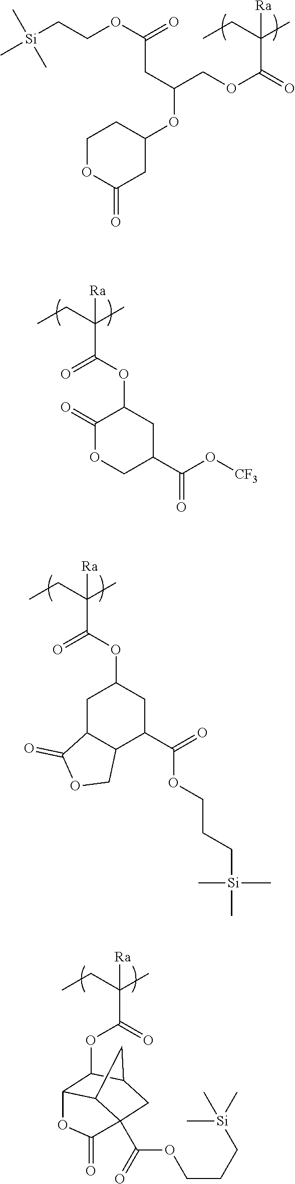

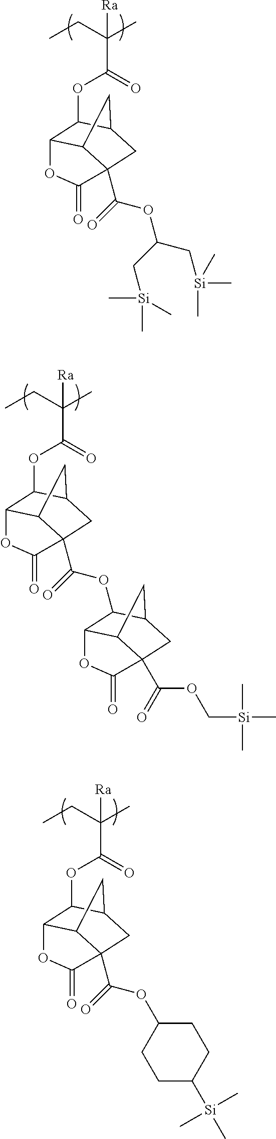

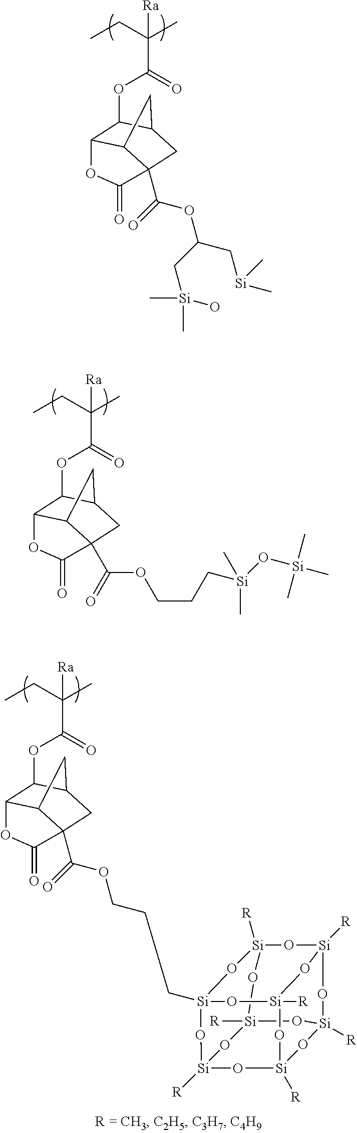

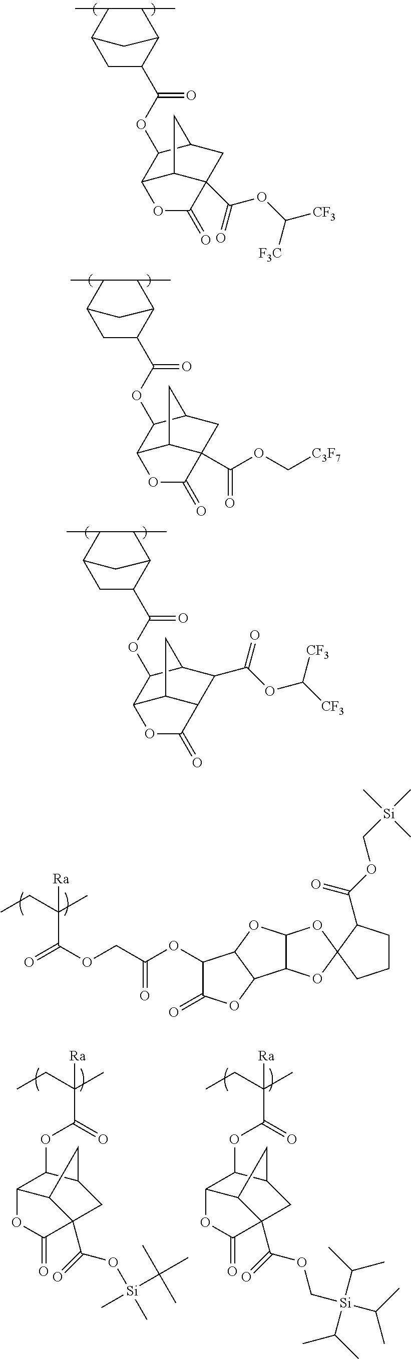

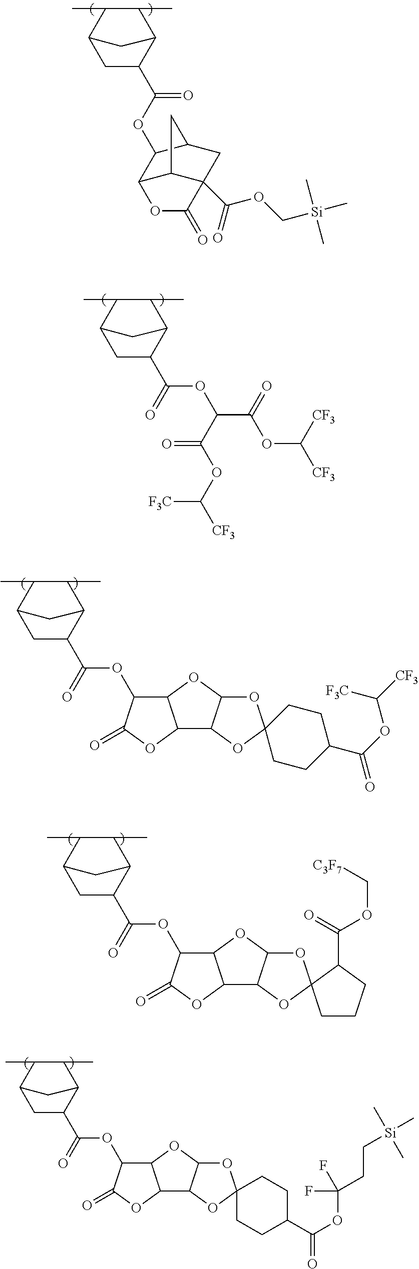

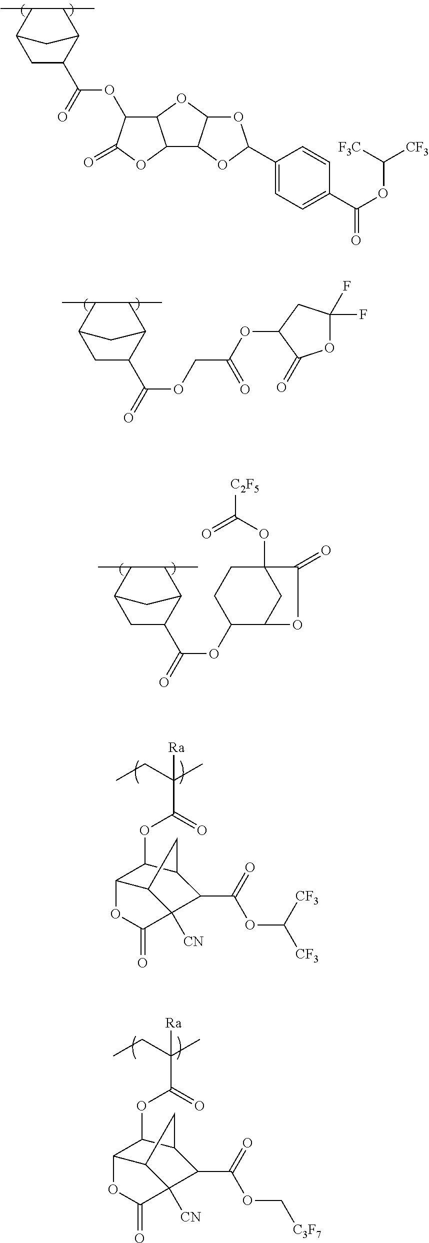

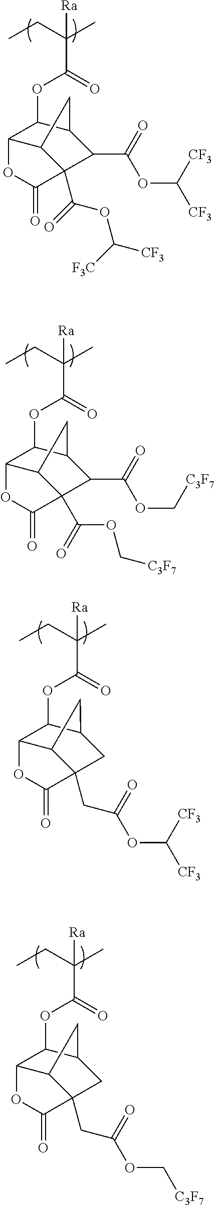

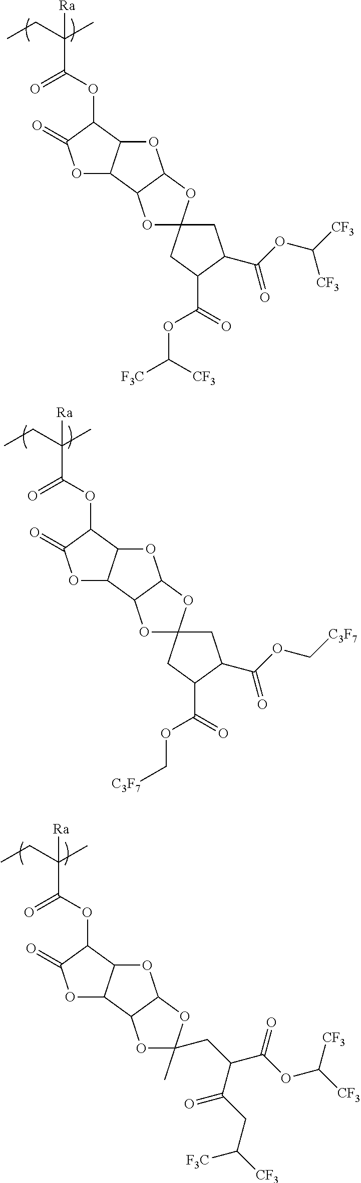

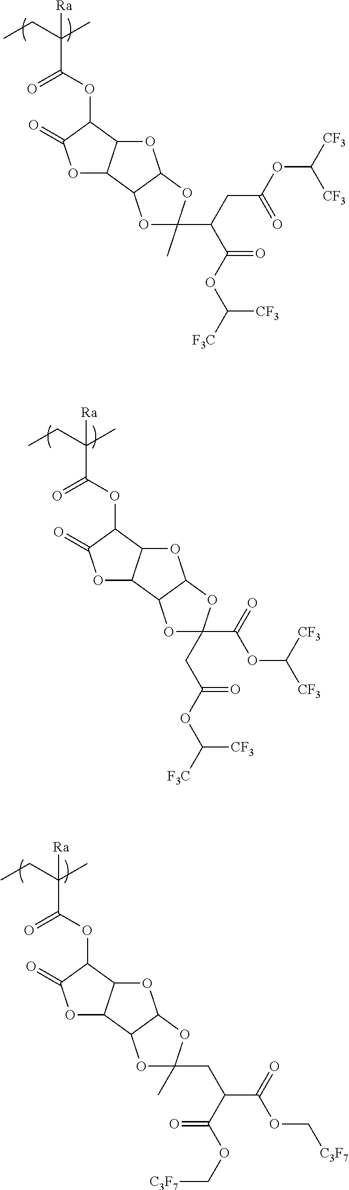

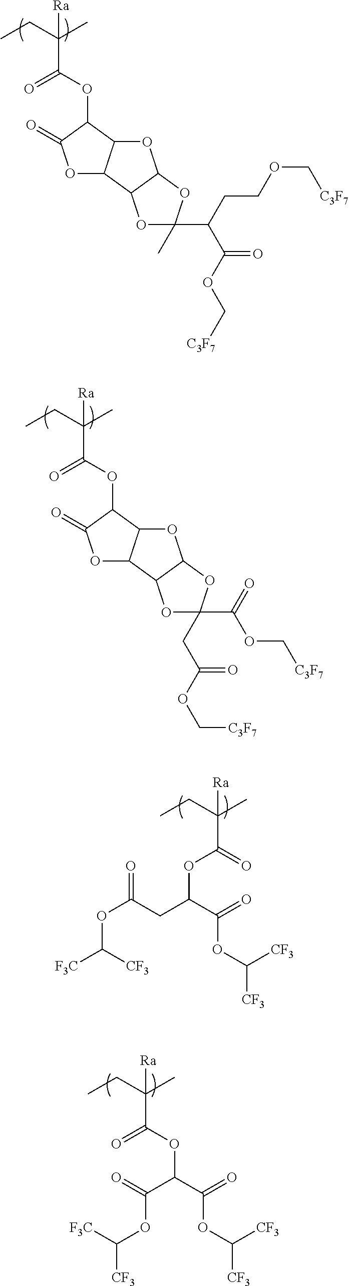

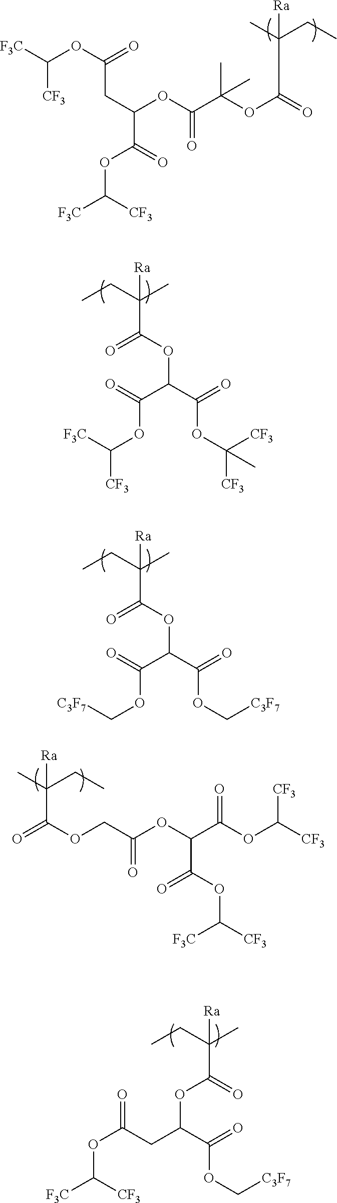

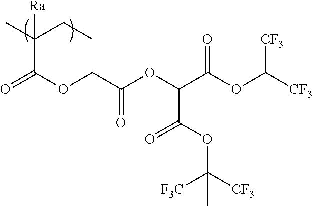

The repeating unit containing a group (z) that is decomposed under the action of an acid, incorporated in the resin (B) can be the same as the repeating unit containing an acid-decomposable group used in the resin (A) to be described hereinafter.

The content of repeating unit containing a group (z) that is decomposed under the action of an acid in the resin (B) is preferably in the range of 1 to 80 mol %, more preferably 10 to 80 mol % and further more preferably 20 to 60 mol % based on all the repeating units of the resin (B).

The content of any one of repeating unit containing an alkali-soluble group (x), repeating unit containing a polarity conversion group (y) and repeating unit containing a group (z) that is decomposed under the action of an acid in the resin (B) is preferably 45 mol % or higher based on all the repeating units of the resin (B). When the content of any one of these repeating units is 45 mol % or higher, enhanced developability can be attained. The content is preferably in the range of 50 to 99 mol %, more preferably 60 to 90 mol %. The repeating unit incorporated in the resin (B) in a content of 45 mol % or higher is preferably a repeating unit containing a polarity conversion group (y).

The resin (B) may further contain any of the repeating units represented by the following general formula (IIIa) or (IIIb).

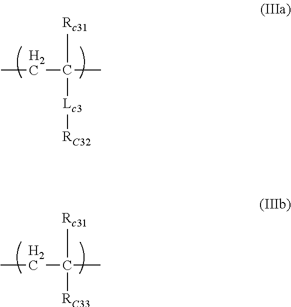

In general formulae (IIIa) and (IIIb),

R_{c31} represents a hydrogen atom, an alkyl group, an alkyl group optionally substituted with one or more fluorine atoms, a cyano group or a group of the formula —CH₂—O—R_{ac2} in which R_{ac2} represents a hydrogen atom, an alkyl group or an acyl group. R_{c31} is preferably a hydrogen atom, a methyl group, a hydroxymethyl group, or a trifluoromethyl group, more preferably a hydrogen atom or a methyl group.

R_{c32} represents a group containing an alkyl group, a cycloalkyl group, an alkenyl group, a cycloalkenyl group, or an aryl group. These groups may be substituted with fluorine atom and/or silicon atom.

L_{c3} represents a single bond or a bivalent connecting group.

R_{c33} represents an aryl group.

The alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

Preferably, R_{c32} represents an unsubstituted alkyl group or an alkyl group substituted with one or more fluorine atoms.

L_{c3} represents a single bond or a bivalent connecting group. As the bivalent connecting group represented by L_{c3}, an alkylene group (preferably having 1 to 5 carbon atoms), an oxy group, a phenylene group, or an ester bond (a group represented by —COO—) can be exemplified.

The aryl group represented by R_{c33} is preferably the one having 6 to 20 carbon atoms such as a phenyl group or a naphthyl group. These groups may have one or more substituents.

The resin (B) may further contain any of the repeating units represented by general formula (BII-AB) below.

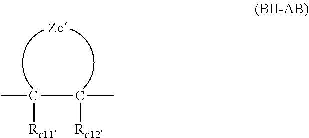

In the formula (BII-AB),

each of R_{c11}′ and R_{c12}′ independently represents a hydrogen atom, a cyano group, a halogen atom or an alkyl group.

Zc′ represents an atomic group required for forming an alicyclic structure in cooperation with two carbon atoms (C—C) to which R_{c11}′ and R_{c12}′ are respectively bonded.

Specific examples of the repeating units represented by the general formulae (IIIa), (IIIb) or (BII-AB) will be shown below. In the formulae, Ra represents H, CH₃, CH₂OH, CF₃ or CN.

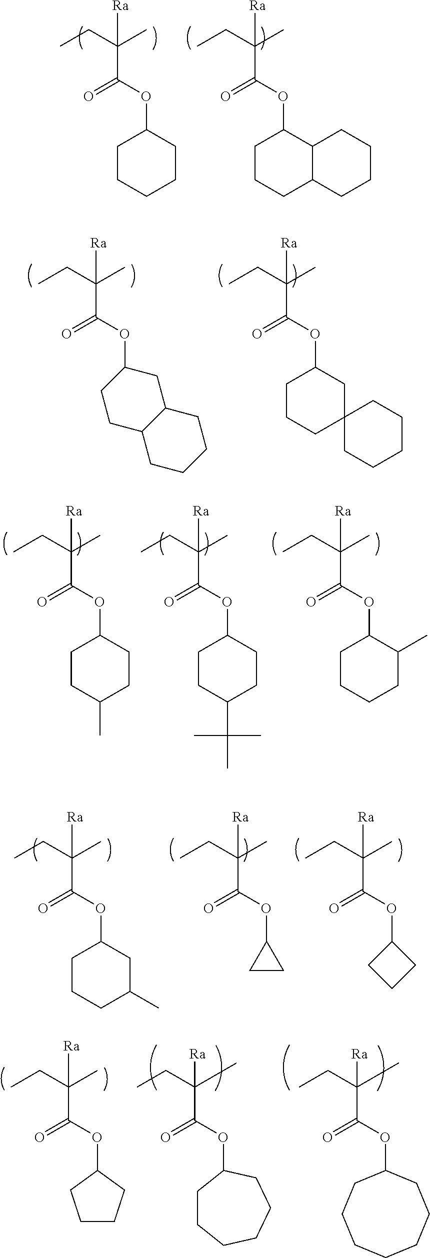

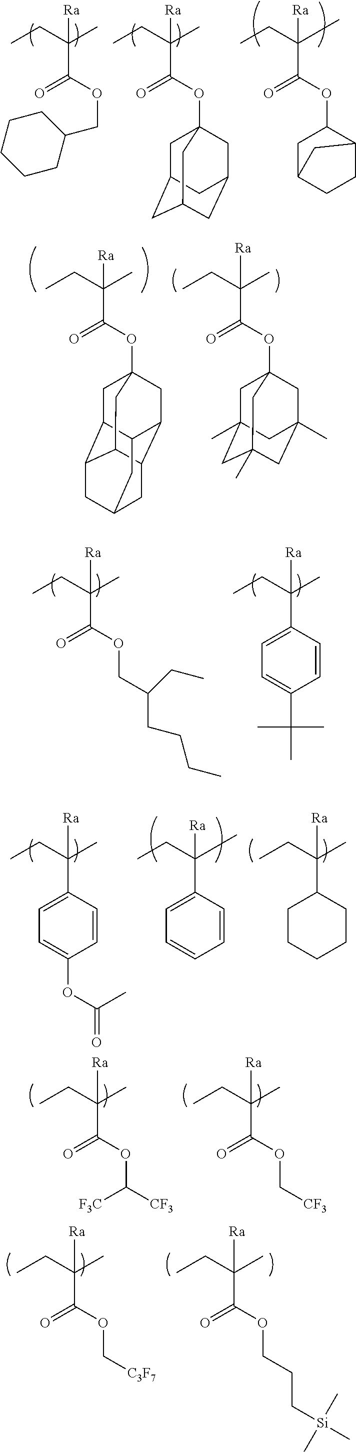

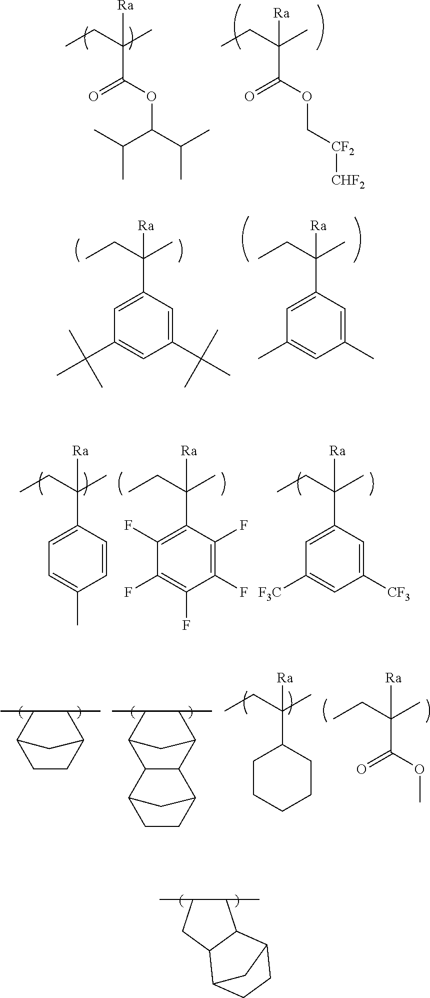

Impurities such as metals in the resin (B) should naturally be of low quantity as in the resin (A) below. The content of residual monomers and oligomer components is preferably in the range of 0 to 10 mass %, more preferably 0 to 5 mass %, and still more preferably 0 to 1 mass %. Accordingly, there can be obtained a composition being free from in-liquid foreign matters and a change in sensitivity, etc. over time. From the viewpoint of resolving power, resist profile, side wall of resist pattern, roughness, etc., the molecular weight distribution (Mw/Mn, also referred to as the degree of dispersal) thereof is preferably in the range of 1 to 3, more preferably 1 to 2, still more preferably 1 to 1.8, and most preferably 1 to 1.5.

A variety of commercially available products can be used as the resin (B), and also the resin can be synthesized in accordance with conventional methods (for example, by radical polymerization). As general synthesizing methods, a batch polymerization method in which a monomer species and an initiator are dissolved in a solvent and heated to carry out polymerization and a dropping polymerization method in which a solution of monomer species and initiator is dropped into a hot solvent over a period of 1 to 10 hours can be exemplified. Of these, the dropping polymerization method is preferred. As a reaction solvent, ethers such as tetrahydrofuran, 1,4-dioxane or diisopropyl ether, ketones such as methyl ethyl ketone or methyl isobutyl ketone, ester solvents such as ethyl acetate, amide solvents such as dimethylformamide or dimethylacetamide, and the aforementioned solvent capable of dissolving the composition according to the present invention, such as propylene glycol monomethyl ether acetate, propylene glycol monomethyl ether or cyclohexanone can be exemplified. Preferably, the polymerization is carried out with the use of the same solvent as that used in the composition according to the present invention. This would inhibit particle generation during storage.

The polymerization reaction is preferably carried out in an atmosphere consisting of an inert gas such as nitrogen or argon. In the initiation of polymerization, a commercially available radical initiator (azo initiator, peroxide, etc.) is used as the polymerization initiator. Among the radical initiators, an azo initiator is preferred, and azo initiators having an ester group, a cyano group and a carboxy group are more preferred. As specific preferred initiators, azobisisobutyronitrile, azobisdimethylvaleronitrile, and dimethyl 2,2′-azobis(2-methylpropionate) can be exemplified. The reaction concentration is in the range of 5 to 50 mass %, preferably 30 to 50 mass %. The reaction temperature is generally in the range of 10° to 150° C., preferably 30° to 120° C., and more preferably 60° to 100° C.

After the completion of the reaction, the mixture is allowed to stand still to cool to room temperature and purified. In the purification, use is made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to coagulate the resin in the poor solvent and thus remove residual monomers, etc. and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to precipitate the resin as a solid.

The solvent for use in the operation of precipitation or re-precipitation from a polymer solution (precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents, and the like. Of these, it is preferred to employ a solvent containing at least an alcohol (especially methanol or the like) or water as the precipitation or re-precipitation solvent.

The amount of precipitation or re-precipitation solvent used can be determined according to intended efficiency, yield, etc. and is generally in the range of 100 to 10,000 parts by mass, preferably 200 to 2,000 parts by mass, and more preferably 300 to 1,000 parts by mass per 100 parts by mass of the polymer solution.

The temperature at which the precipitation or re-precipitation is carried out can be determined according to efficiency and operation easiness, and is generally in the range of about 0° to 50° C., and preferably about room temperature (for example, about 20° to 35° C.). The operation of precipitation or re-precipitation can be carried out by a known method such as a batch or continuous method, with the use of a common mixing vessel such as an agitation vessel.

The polymer obtained by the precipitation or re-precipitation is generally subjected to common solid/liquid separation, such as filtration or centrifugal separation, and dried before use. The filtration is carried out with the use of a filter medium ensuring solvent resistance, preferably under pressure. The drying is performed at about 30° C. to 100° C., preferably about 30° C. to 50° C. at ordinary pressure or reduced pressure (preferably at reduced pressure).

Alternatively, after the resin precipitation and separation, the obtained resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to thereby precipitate a resin (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby precipitate a resin solid (step d), and separating the precipitated resin (step e).

Specific examples of the resin (B) will be shown below. In the specific examples, Ra represents a hydrogen atom, a methyl group, a halogen atom, or a trifluoromethyl group, and n is an integer of 2 or greater and preferably an integer of 2 to 10.

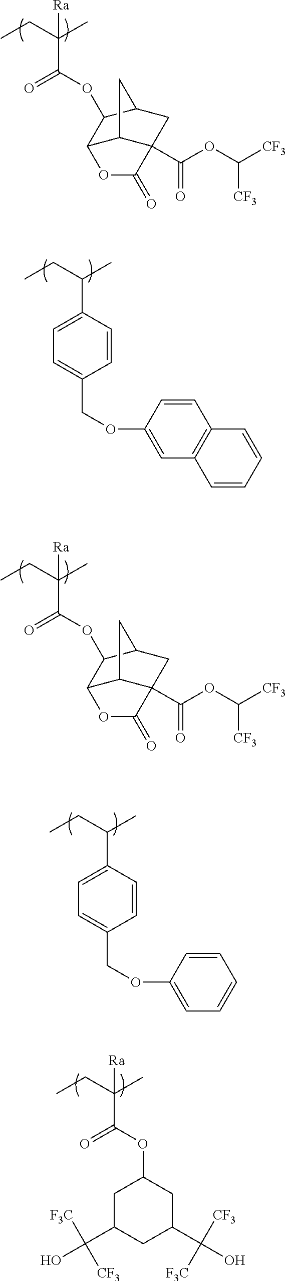

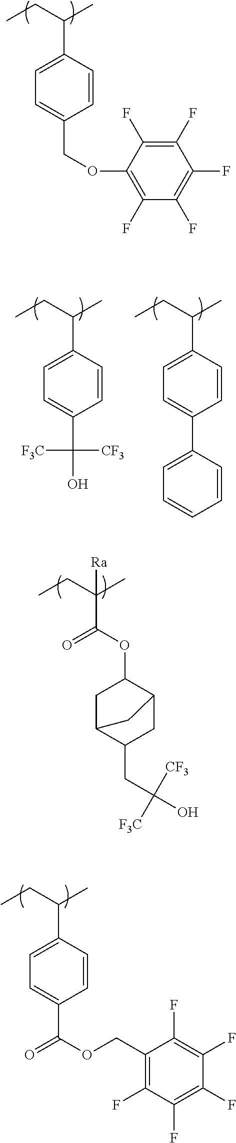

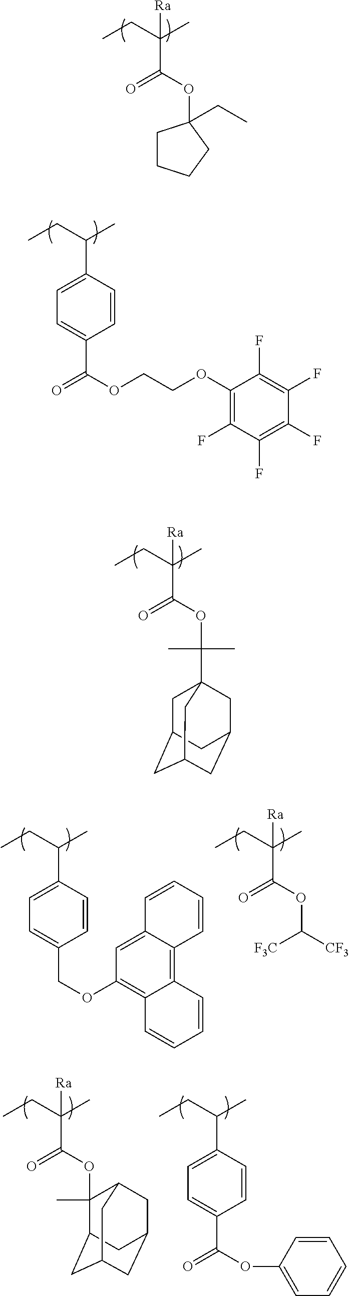

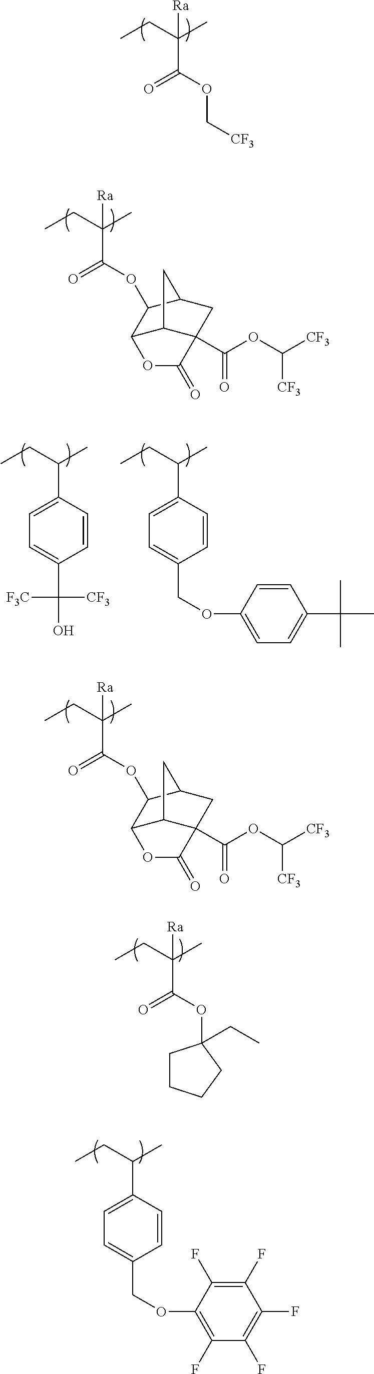

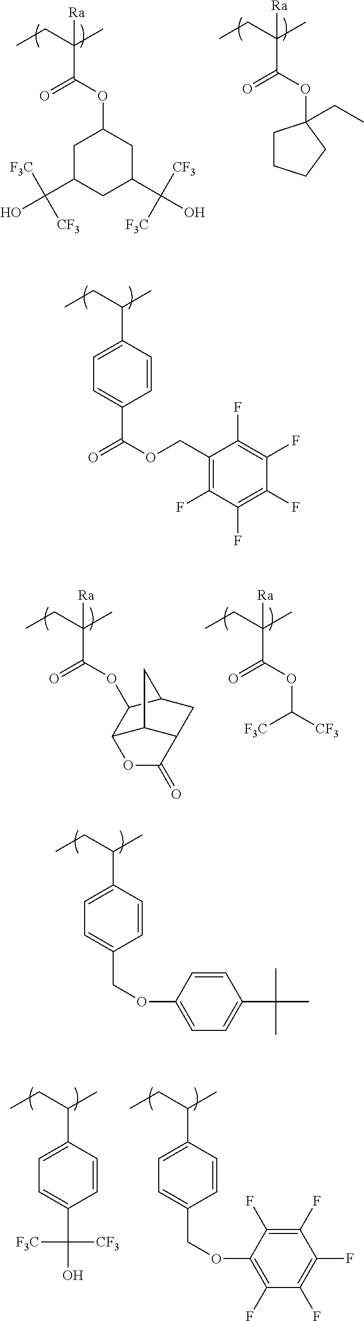

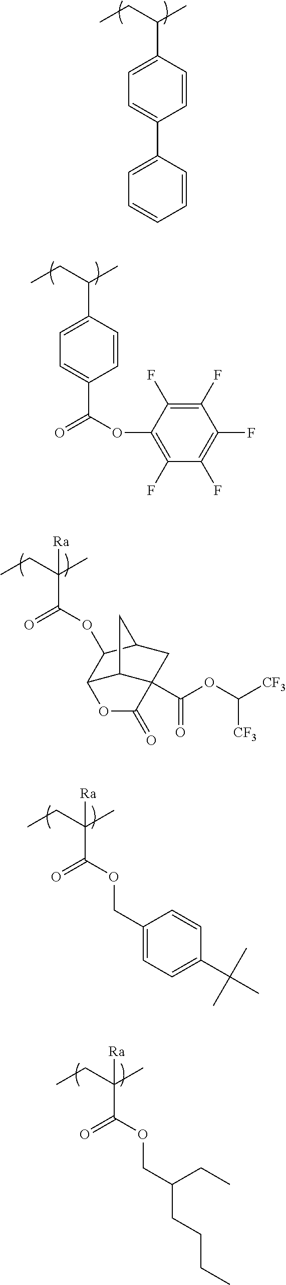

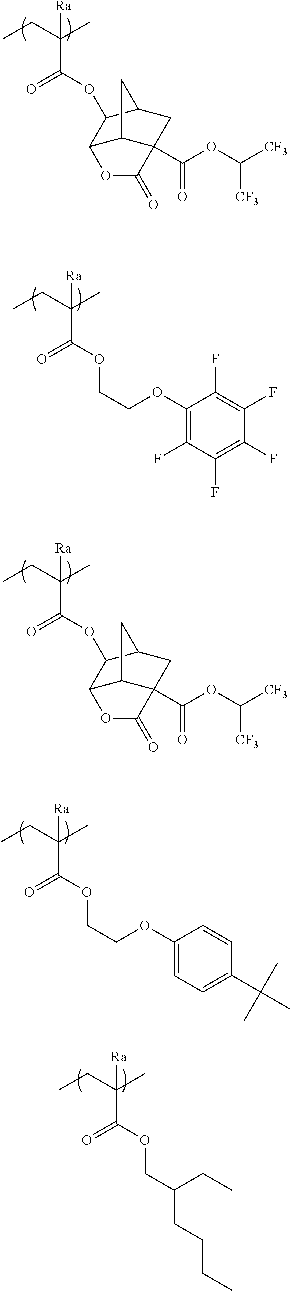

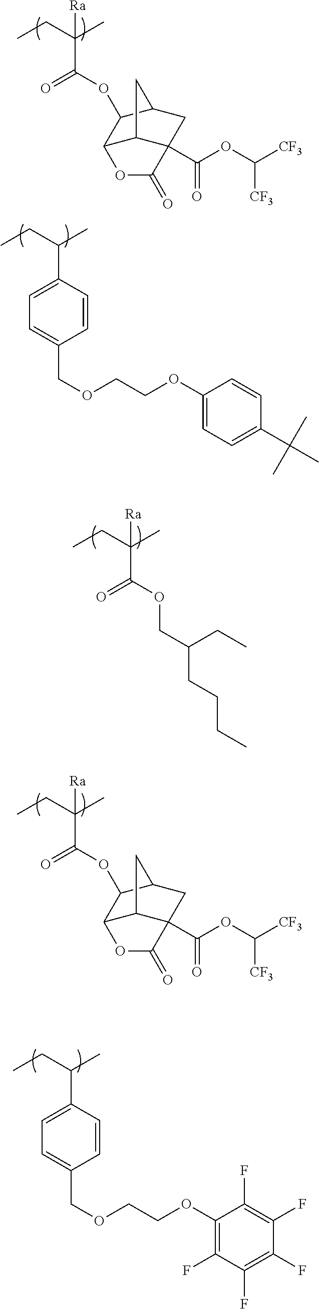

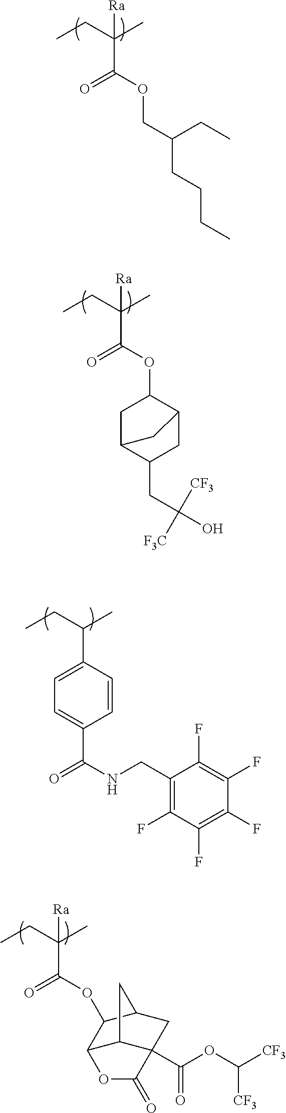

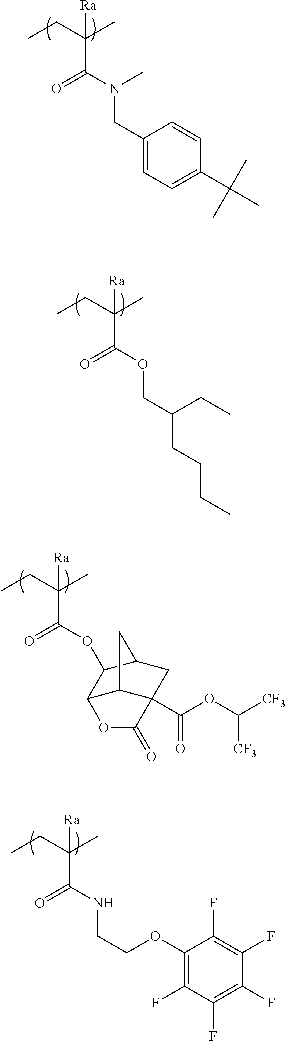

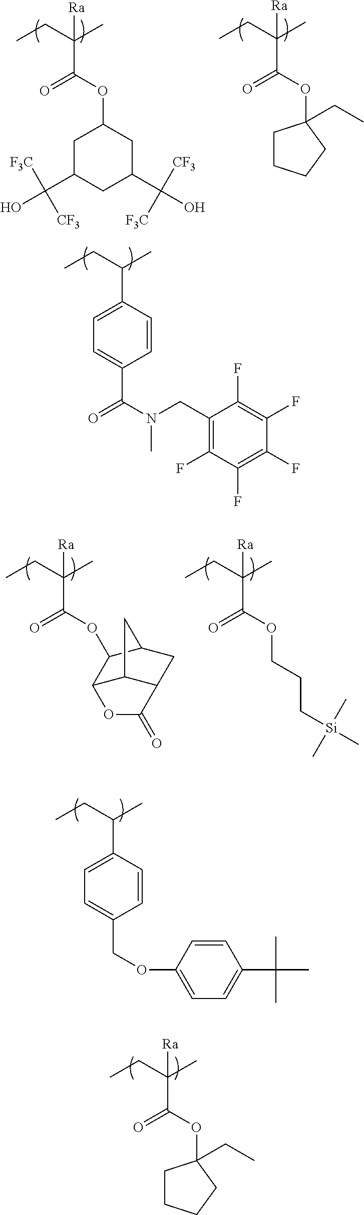

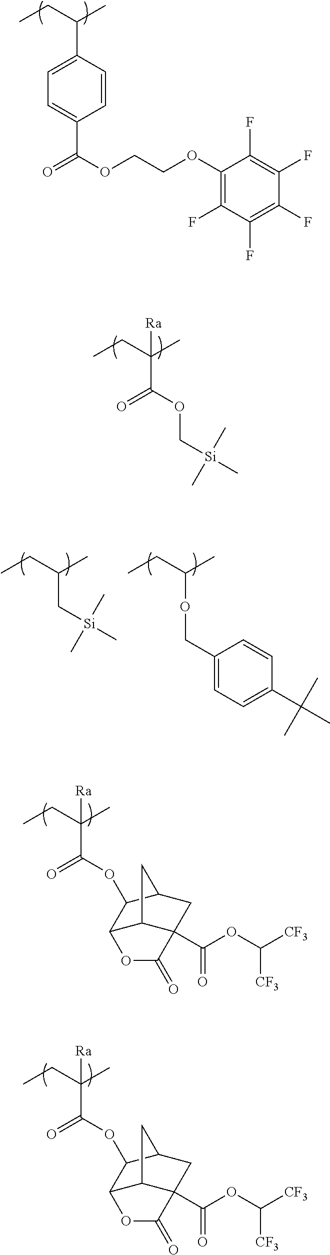

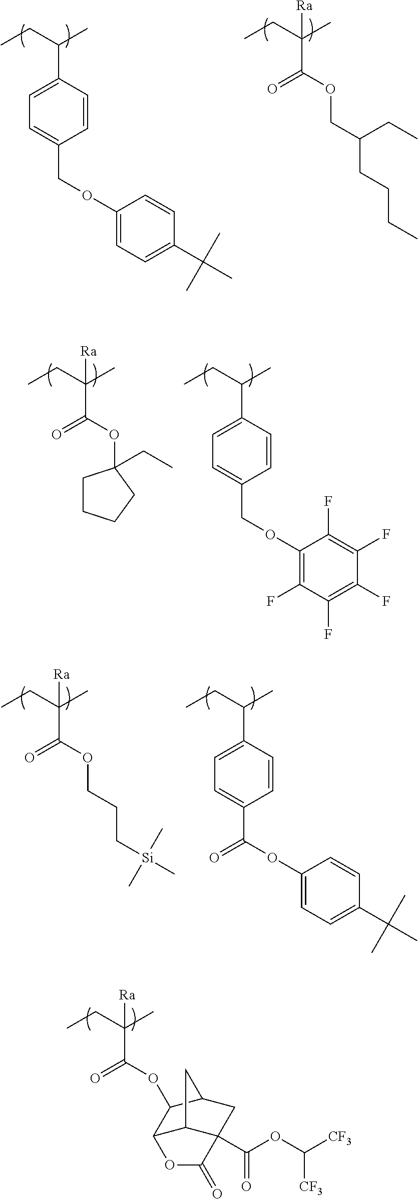

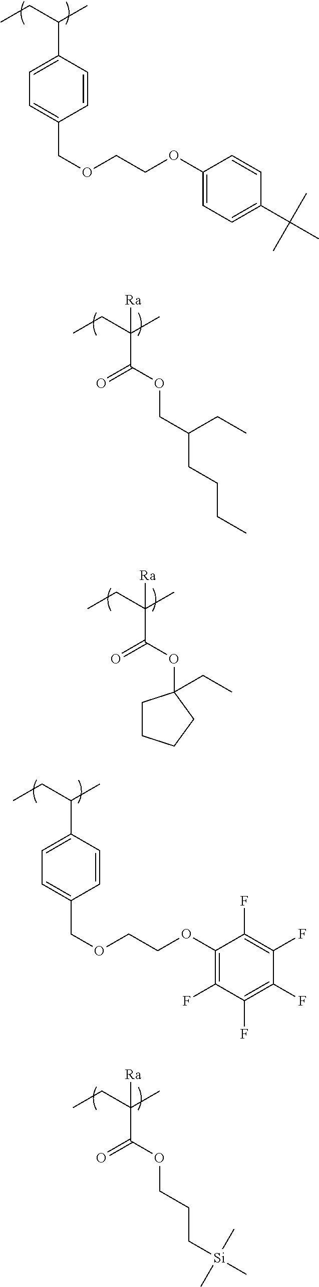

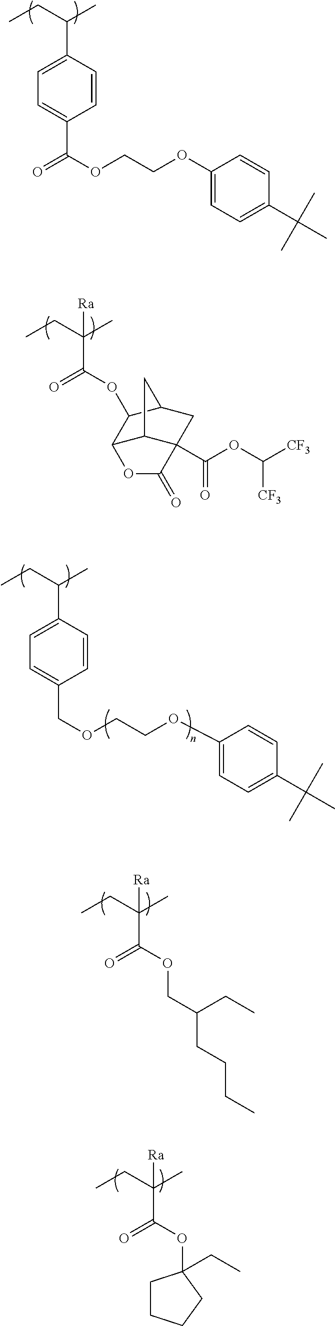

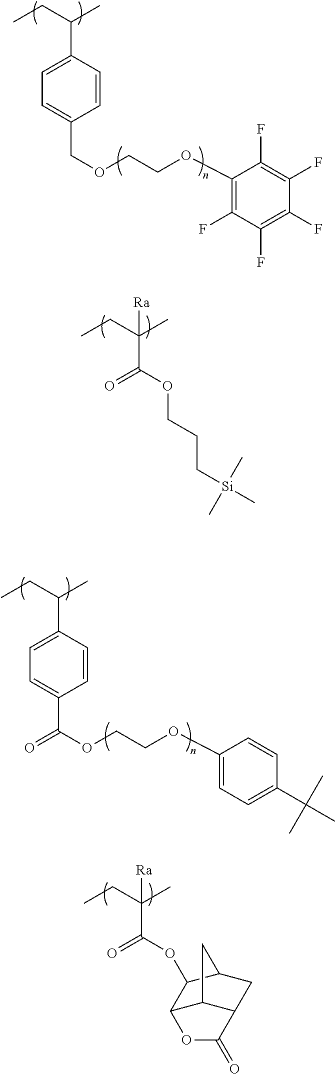

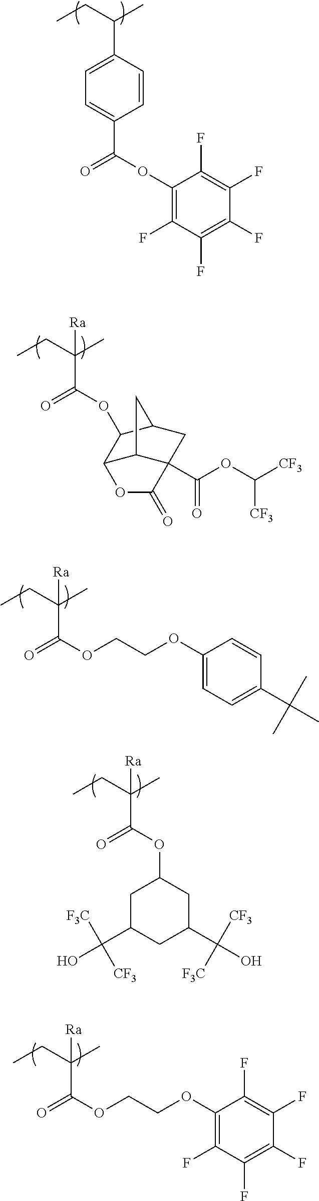

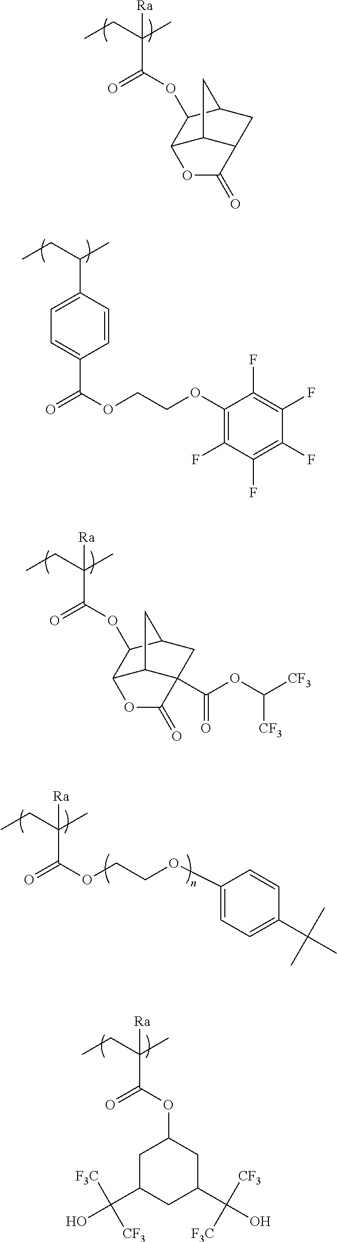

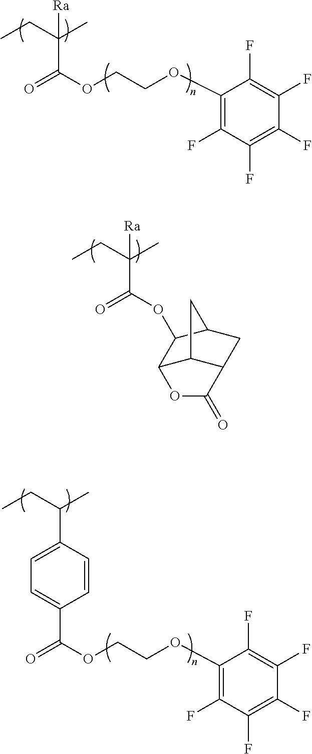

When the hydrophobic resin (B) containing at least either a fluorine atom or a silicon atom is contained in the actinic-ray- or radiation-sensitive resin composition, the resin (B) is unevenly distributed in the surface layer of the film formed from the composition. When the immersion medium is water, the receding contact angle of the surface of the film with respect to water is increased, so that the immersion-water tracking properties can be enhanced.

The receding contact angle of a film after baking and before exposing is preferably in the range of 60° to 90°, more preferably 65° or higher, further more preferably 70° or higher, and particularly preferably 75° or higher as measured under the conditions of temperature 23±3° C. and humidity 45±5%.

Although the resin (B) is unevenly localized on any interface, as different from the surfactant, the hydrophobic resin does not necessarily have to have a hydrophilic group in its molecule and does not need to contribute toward uniform mixing of polar/nonpolar substances.

In the operation of liquid immersion exposure, it is needed for the liquid for liquid immersion to move on a wafer while tracking the movement of an exposure head involving high-speed scanning on the wafer and thus forming an exposure pattern. Therefore, the contact angle of the liquid for liquid immersion with respect to the film in dynamic condition is important, and it is required for the actinic ray-sensitive or radiation-sensitive resin composition to be capable of tracking the high-speed scanning of the exposure head without leaving droplets.

When the resin (B) contains fluorine atoms, the content of the fluorine atoms based on the molecular weight of the resin (B) is preferably in the range of 5 to 80 mass %, and more preferably 10 to 80 mass %. The repeating unit containing fluorine atoms preferably exists in the resin (B) in an amount of 10 to 100 mass %, more preferably 30 to 100 mass %.

When the resin (B) contains silicon atoms, the content of the silicon atoms based on the molecular weight of the resin (B) is preferably in the range of 2 to 50 mass %, more preferably 2 to 30 mass %. The repeating unit containing silicon atoms preferably exists in the resin (B) in an amount of 10 to 90 mass %, more preferably 20 to 80 mass %.

The total content of the fluorine atoms and the silicon atoms based on the molecular weight of the resin (B) is preferably in the range of 5 to 80 mass %, and more preferably 10 to 80 mass %. The repeating unit containing at least either of a fluorine atom or a silicon atom preferably exists in the resin (B) in an amount of 10 to 100 mass %, more preferably 30 to 100 mass %.

The weight average molecular weight of the resin (B) in terms of standard polystyrene molecular weight is preferably in the range of 1,000 to 100,000, more preferably 2,000 to 50,000, and still more preferably 3,000 to 30,000.

The resin (B) either be used individually or in combination. In the latter case, two or more types of resins (B) each comprising the repeating unit (R) may be used. Alternatively, at least one resin (B) comprising the repeating unit (R) may be used in combination with at least one resin (B) comprising no repeating unit (R).

When a resin (B) comprising the repeating unit (R) is used in combination with a resin (B) comprising no repeating unit (R), the mass ratio of the former resin to the latter resin is, for example, 50/50 or greater, typically 70/30 or greater.

The content of resin (B) in the actinic-ray- or radiation-sensitive resin composition, based on the total solids of the actinic-ray- or radiation-sensitive resin composition, is preferably in the range of 0.01 to 20 mass %, more preferably 0.1 to 15 mass %, further more preferably 0.1 to 10 mass % and most preferably 0.5 to 8 mass %.

<Resin (A) that is Configured to Decompose when Acted on by an Acid to Thereby Increase its Solubility in an Alkali Developer>

The actinic-ray- or radiation-sensitive resin composition according to the present invention contains a resin (A) that is configured to decompose when acted on by an acid to thereby increase its solubility in an alkali developer. The resin (A) is different from the resin (B) in constitution, and will also be called as an “acid-decomposable resin”.

The acid-decomposable resin has a group that is configured to decompose when acted on by the action of an acid to thereby produce an alkali-soluble group (hereinafter also referred to as “acid-decomposable group”) in the principal chain and/or side chain of the resin.

The resin (A) is preferably insoluble or poorly soluble in alkali developers.

The acid-decomposable group preferably has a structure in which an alkali-soluble group is protected by a group which is removable by degradation upon the action of acid.

As the alkali-soluble group, there can be mentioned, for example, a phenolic hydroxyl group, a carboxyl group, an alcoholic hydroroxyl group, a fluoroalcohol group, a sulfonate group, a sulfonamido group, a sulfonylimido group, a (alkylsulfonyl)(alkylcarbonyl)methylene group, a (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a carboxyl group, an alcoholic hydroxyl group, a fluoroalcohol group (preferably a hexafluoroisopropanol group) and a sulfonate group.

The acid-decomposable group is preferably a group as obtained by substituting the hydrogen atom of any of these polar groups with a group that is cleaved by the action of an acid.

As a group that is cleaved by the action of an acid, there can be mentioned, for example, a group represented by —C(R₃₆)(R₃₇)(R₃₈), —C(R₃₆)(R₃₇)(OR₃₉) or —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit with an acid-decomposable group is preferably any of those of the following general formula (AI).

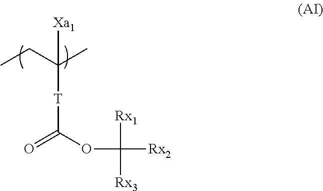

In general formula (AI),

Xa₁ represents a hydrogen atom, a methyl group, or a group represented by —CH₂—R₉. R₉ represents a monovalent organic group. R₉ preferably represents an alkyl or an acyl group having 5 or less carbon atoms, more preferably an alkyl group having 3 or less carbon atoms, and further more preferably a methyl group. Xa₁ preferably represents a hydrogen atom, a methyl group, a trifluoromethyl group or a hydroxymethyl group.

T represents a single bond or a bivalent connecting group.

Each of Rx₁ to Rx₃ independently represents a linear or branched alkyl group or a mono- or polycycloalkyl group.

At least two of Rx₁ to Rx₃ may be bonded to each other to thereby form a mono- or polycycloalkyl group.

As the bivalent connecting group represented by T, there can be mentioned, for example, an alkylene group, a group of the formula —(COO-Rt)- or a group of the formula —(O-Rt)-. In the formulae, Rt represents an alkylene group or a cycloalkylene group.

T is preferably a single bond or a group of the formula —(COO-Rt)-. Rt is preferably an alkylene group having 1 to 5 carbon atoms, more preferably a —CH₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a monocycloalkyl group, such as a cyclopentyl group or a cyclohexyl group, or a polycycloalkyl group, such as a norbornyl group, a tetracyclodecanyl group, a tetracyclododecanyl group or an adamantyl group.

The cycloalkyl group formed by bonding at least two of Rx₁ to Rx₃ is preferably a monocycloalkyl group, such as a cyclopentyl group or a cyclohexyl group, or a polycycloalkyl group, such as a norbornyl group, a tetracyclodecanyl group, a tetracyclododecanyl group or an adamantyl group.

Of these, cycloalkyl groups having 5 or 6 carbon atoms are especially preferred.

In an especially preferred mode, Rx₁ is a methyl group or an ethyl group, and Rx₂ and Rx₃ are bonded to each other to thereby form any of the above-mentioned cycloalkyl groups.

One or more substituents may further be introduced in each of the groups above. As the substituents, there can be mentioned, for example, an alkyl group (preferably having 1 to 4 carbon atoms), a halogen atom, a hydroxy group, an alkoxy group (preferably having 1 to 4 carbon atoms), a carboxyl group, an alkoxycarbonyl group (preferably having 2 to 6 carbon atoms). Preferably, each of the substituents has 8 or less carbon atoms.

The content of repeating unit containing an acid-decomposable group based on all the repeating units of the resin is preferably in the range of 20 to 70 mol %, and more preferably 30 to 50 mol %.

Specific examples of the preferred repeating units containing an acid-decomposable group will be shown below, which however in no way limit the scope of the present invention.

In the specific examples, Rx and Xa1 each represents a hydrogen atom, CH₃, CF₃ or CH₂OH. Each of Rxa and Rxb represents an alkyl group having 1 to 4 carbon atoms. Z or each of Zs independently represents a substituent containing one or more polar groups. p represents 0 or a positive integer.

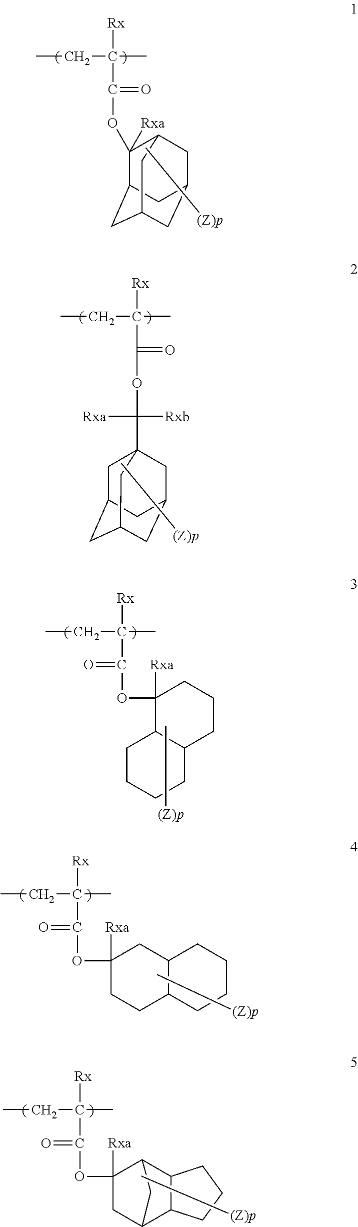

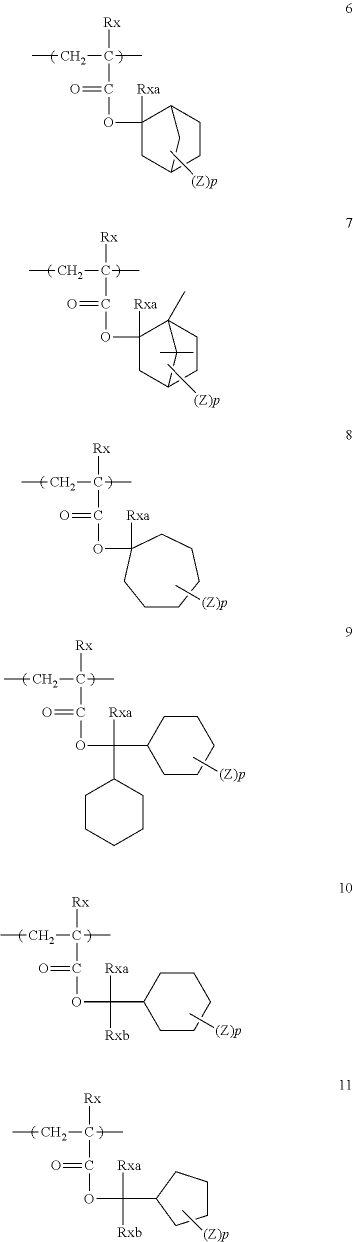

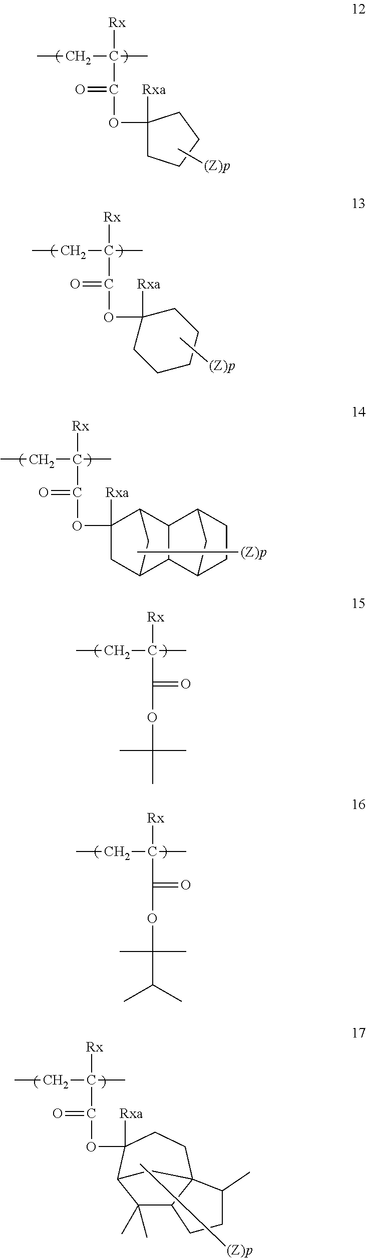

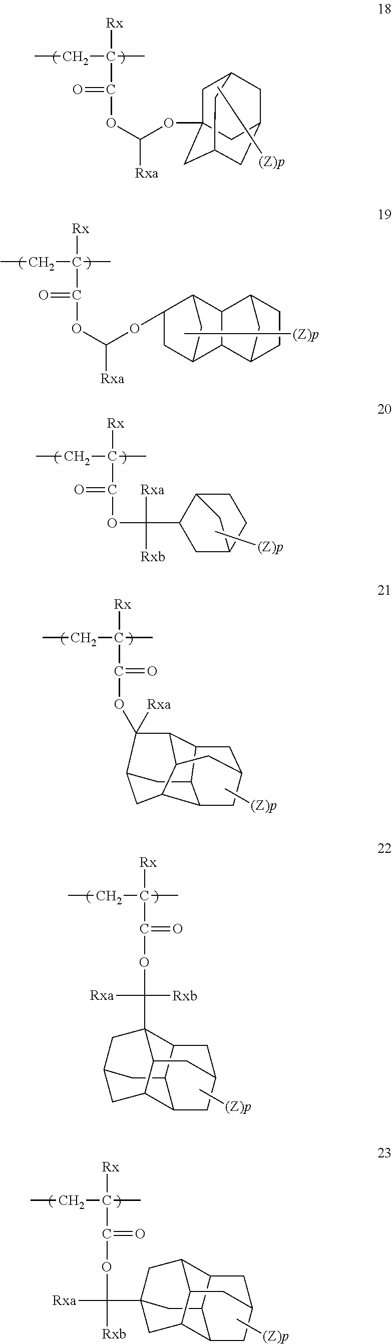

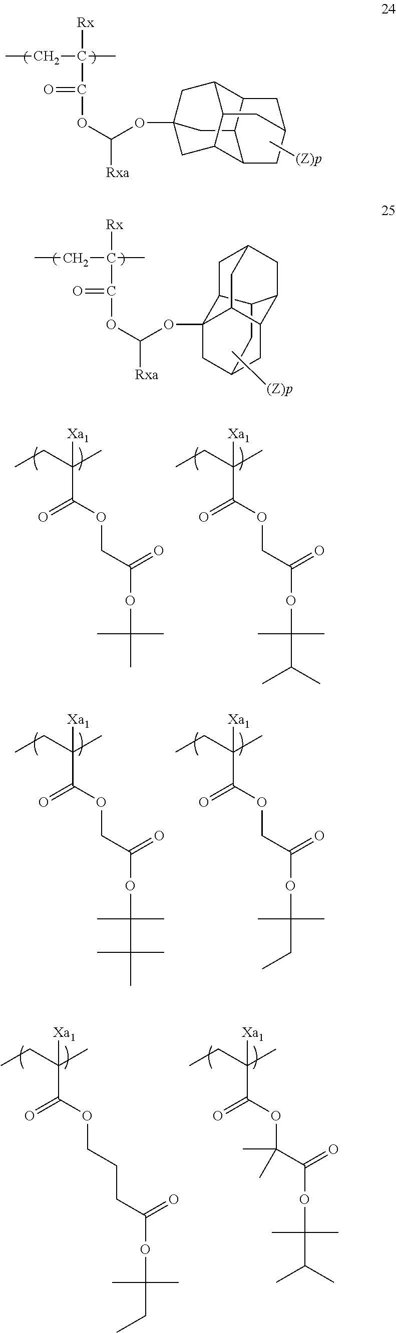

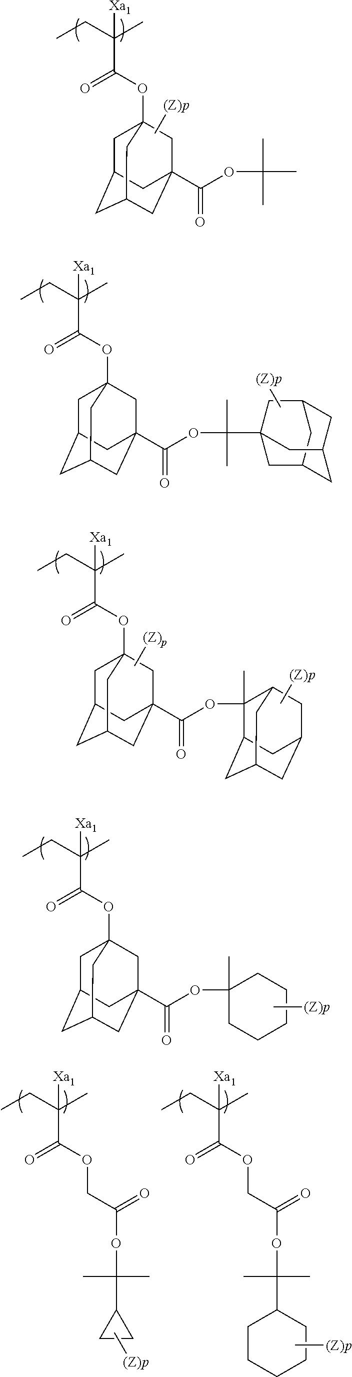

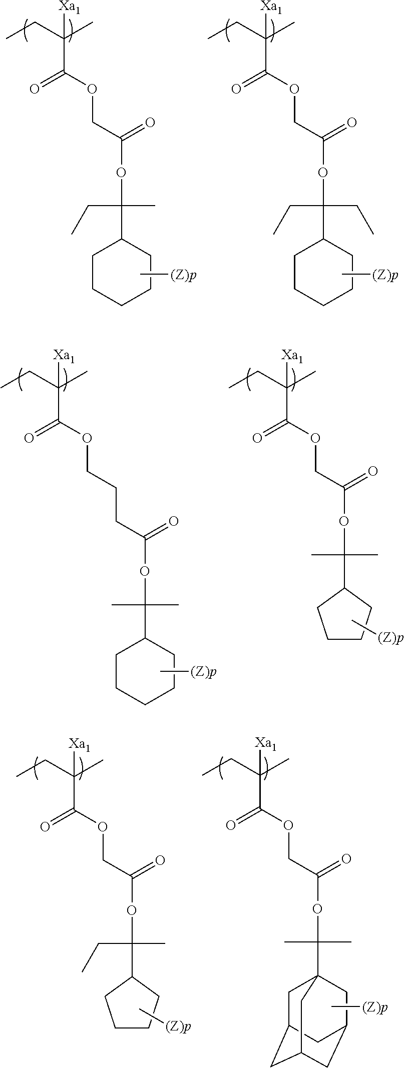

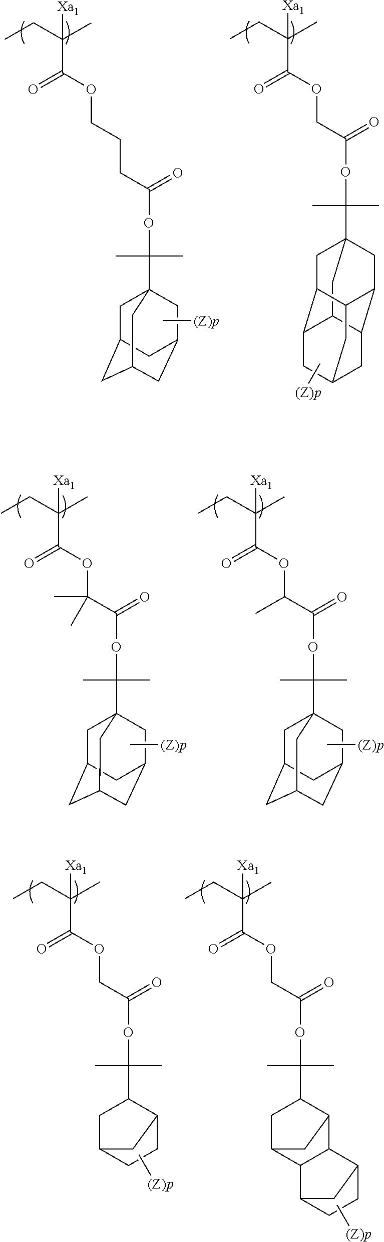

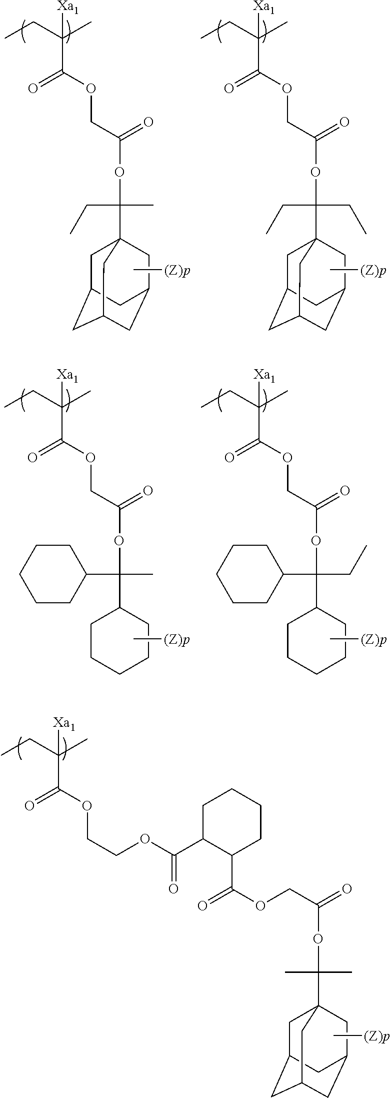

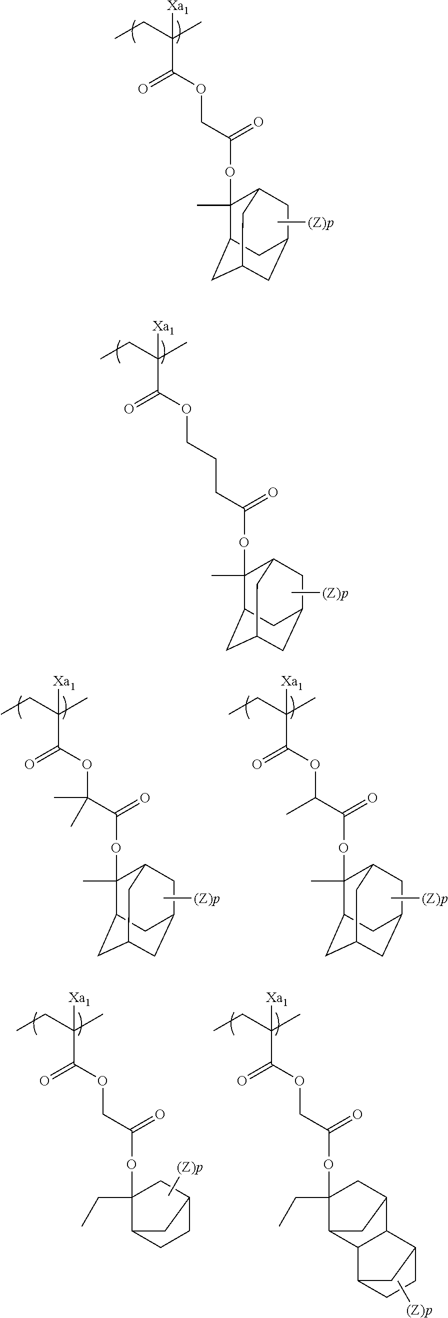

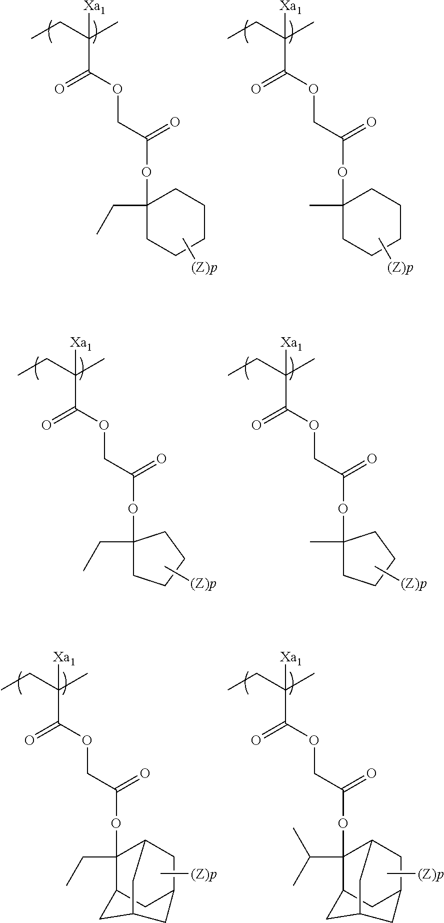

It is more preferred for the acid-decomposable resin to contain, as the repeating units of general formula (AI), any of the repeating units of general formula (I) below and/or any of the repeating units of general formula (II) below.

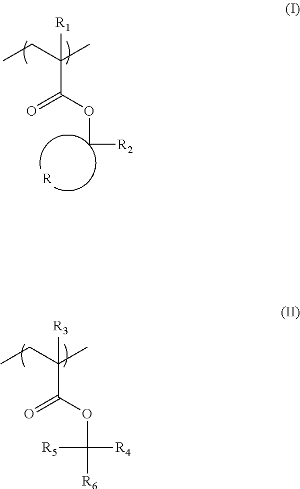

In general formulae (I) and (II),

each of R₁ and R₃ independently represents a hydrogen atom, a methyl group or any of the groups of the formula —CH₂—R₉. R₉ represents a monovalent organic group.

Each of R₂, R₄, R₅ and R₆ independently represents an alkyl group or a cycloalkyl group.

R represents an atomic group required for forming an alicyclic structure in cooperation with a carbon atom.

R₁ preferably represents a hydrogen atom, a methyl group, a trifluoromethyl group or a hydroxymethyl group.

The alkyl group represented by R₂ may be linear or branched, and one or more substituents may be introduced therein.

The cycloalkyl group represented by R₂ may be monocyclic or polycyclic, and a substituent may be introduced therein.

R₂ preferably represents an alkyl group, more preferably an alkyl group having 1 to 10 carbon atoms, further more preferably 1 to 5 carbon atoms. As examples thereof, there can be mentioned a methyl group and an ethyl group.

R represents an atomic group required for forming an alicyclic structure in cooperation with a carbon atom. The alicyclic structure formed by R is preferably an alicyclic structure of a single ring, and preferably has 3 to 7 carbon atoms, more preferably 5 or 6 carbon atoms.

R₃ preferably represents a hydrogen atom or a methyl group, more preferably a methyl group.

Each of the alkyl groups represented by R₄, R₅ and R₆ may be linear or branched, and one or more substituents may be introduced therein. The alkyl groups are preferably those each having 1 to 4 carbon atoms, such as a methyl group, an ethyl group, an n-propyl group, an isopropyl group, an n-butyl group, an isobutyl group and a t-butyl group.

Each of the cycloalkyl groups represented by R₄, R₅ and R₆ may be monocyclic or polycyclic, and a substituent may be introduced therein. The cycloalkyl groups are preferably a monocycloalkyl group, such as a cyclopentyl group or a cyclohexyl group, and a polycycloalkyl group, such as a norbornyl group, a tetracyclodecanyl group, a tetracyclododecanyl group or an adamantyl group.

As the repeating units of general formula (I), there can be mentioned, for example, those of general formula (1-a) below.

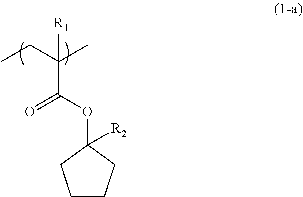

In the formula, R₁ and R₂ have the same meaning as in general formula (I).

The repeating units of general formula (II) are preferably those of general formula (II-1) below.

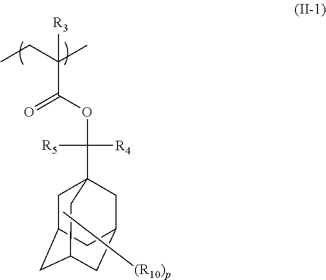

In general formula (II-1),

R₃ to R₅ have the same meaning as in general formula (II).

R₁₀ represents a substituent containing a polar group. When a plurality of R₁₀s exist, they may be identical to or different from each other. As the substituent containing a polar group, there can be mentioned, for example, a linear or branched alkyl group, or cycloalkyl group, in which a hydroxyl group, a cyano group, an amino group, an alkylamido group or a sulfonamido group is introduced. An alkyl group in which a hydroxyl group is introduced is preferred. As the branched alkyl group, an isopropyl group is especially preferred.

In the formula, p is an integer of 0 to 15, preferably in the range of 0 to 2, and more preferably 0 or 1.

It is more preferred for the acid-decomposable resin to be a resin containing, as the repeating units of general formula (AI), at least either any of the repeating units of general formula (I) or any of the repeating units of general formula (II). In another form, it is more preferred for the acid-decomposable resin to be a resin containing, as the repeating units of general formula (AI), at least two types selected from among the repeating units of general formula (I).

When the acid-decomposable resin contains a plurality of acid-decomposable repeating units, the following combinations are preferred. In the following formulae, R each independently represents a hydrogen atom or a methyl group.

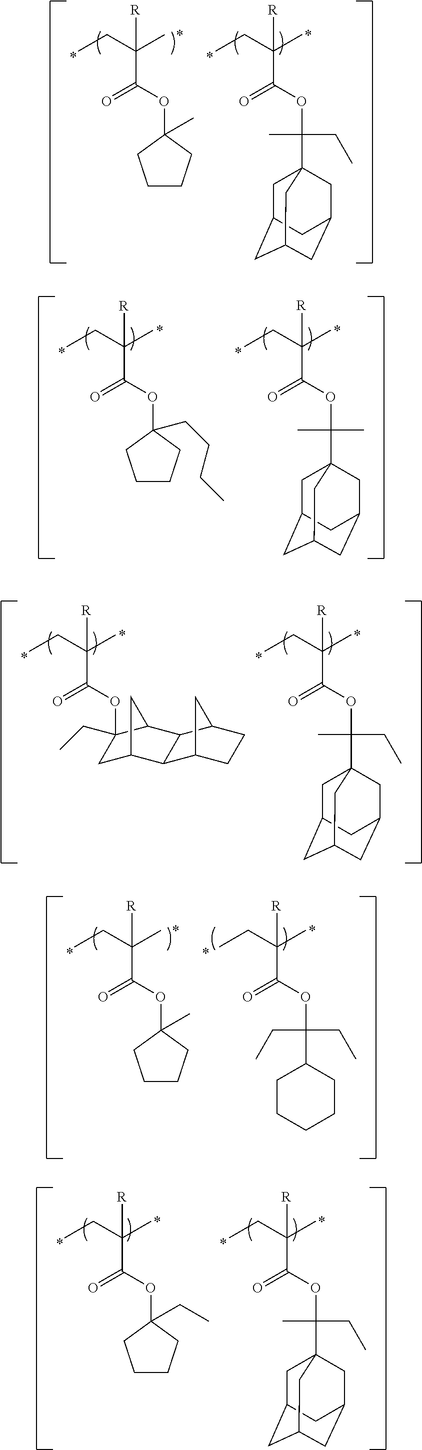

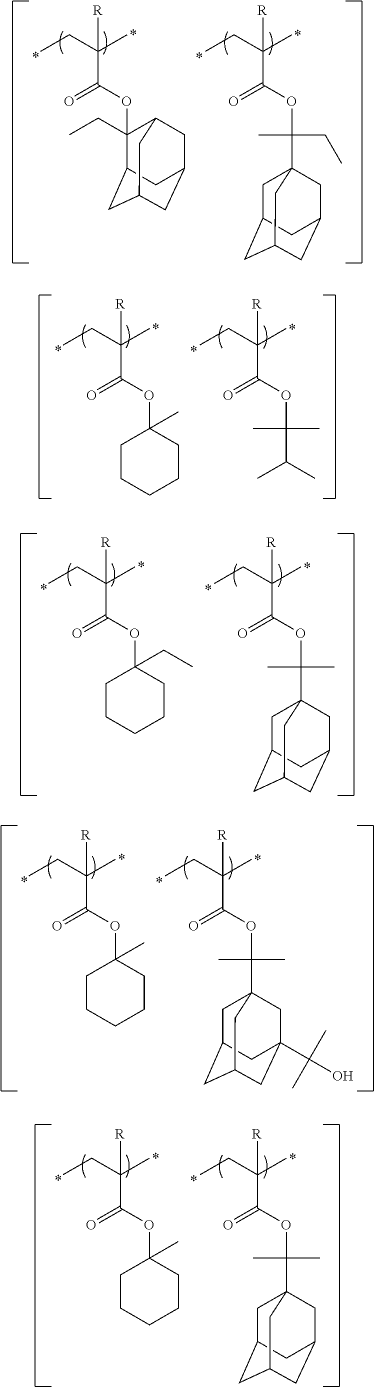

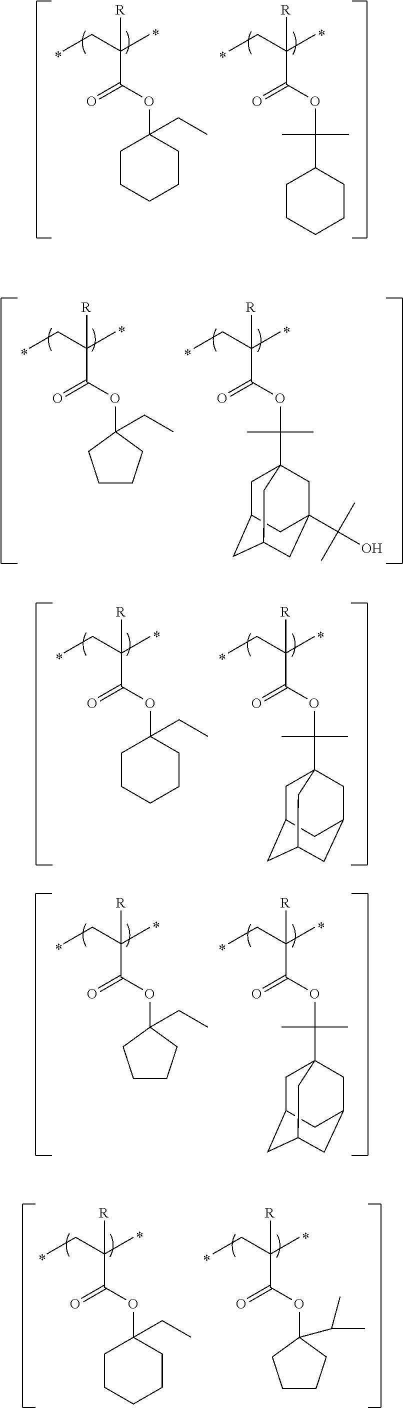

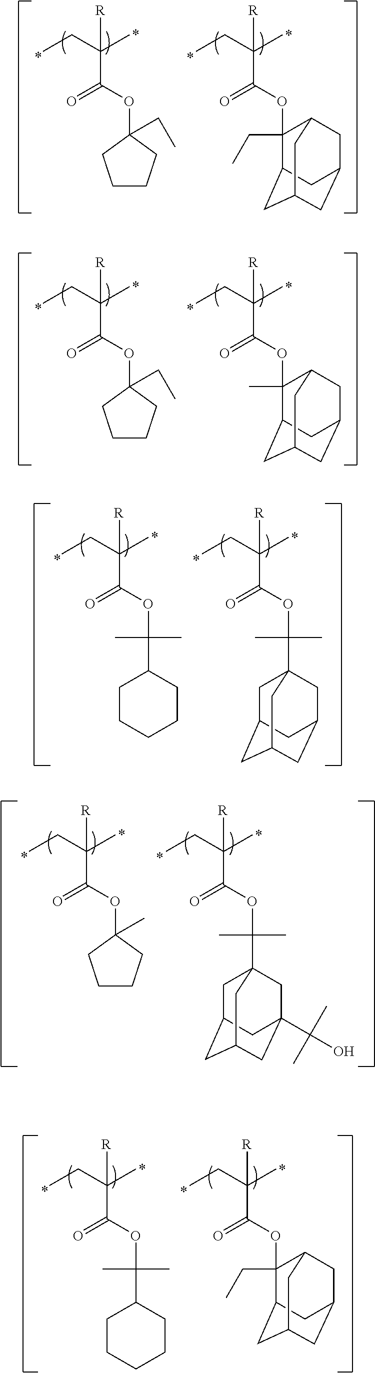

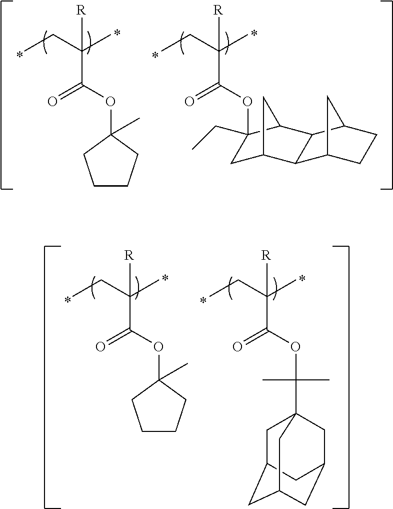

It is preferred for resin (A) to contain any of the repeating units having a lactone group represented by the following general formula (III).

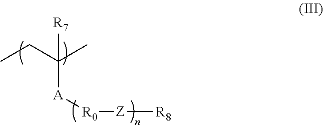

In formula (III),

A represents an ester bond (—COO—) or an amido bond (—CONH—).

Ro, each independently in the presence of two or more groups, represents an alkylene group, a cycloalkylene group or a combination thereof.

Z, each independently in the presence of two or more groups, represents an ether bond, an ester bond, a carbonyl group, an amido bond, a urethane bond

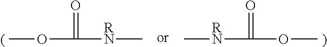

or a urea bond

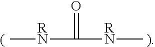

In the formulae, R represents a hydrogen atom, an alkyl group, a cycloalkyl group or an aryl group.

R₈ represents a monovalent organic group with a lactone structure.

n represents the number of repetitions of the structure of the formula —R₀—Z— and is an integer of 1 to 5.

R₇ represents a hydrogen atom, a halogen atom or an alkyl group.

Each of the alkylene group and cycloalkylene group represented by R₀ may have a substituent.

Z preferably represents an ether bond or an ester bond, most preferably an ester bond.

The alkyl group represented by R₇ is preferably an alkyl group having 1 to 4 carbon atoms, more preferably a methyl group or an ethyl group and most preferably a methyl group. The alkyl group represented by R₇ may be substituted. As substituents on R₇, there can be mentioned, for example, a halogen atom such as a fluorine atom, a chlorine atom or a bromine atom, a mercapto group, a hydroxyl group, an alkoxy group such as a methoxy group, an ethoxy group, an isopropoxy group, a t-butoxy group or a benzyloxy group, an acyl group such as an acetyl group or a propionyl group, an acetoxy group and the like. R₇ preferably represents a hydrogen atom, a methyl group, a trifluoromethyl group or a hydroxymethyl group.

The chain alkylene group represented by R₀ is preferably a chain alkylene having 1 to 10 carbon atoms, more preferably 1 to 5 carbon atoms, for example, a methylene group, an ethylene group, a propylene group or the like. The cycloalkylene group is preferably a cycloalkylene having 1 to 20 carbon atoms. As such, there can be mentioned, for example, cyclohexylene, cyclopentylene, norbornylene, adamantylene or the like. The chain alkylene groups are preferred from the viewpoint of the exertion of the effect of the present invention. A methylene group is especially preferred.

The substituent with a lactone structure represented by R₈ is not limited as long as the lactone structure is contained. As particular examples thereof, there can be mentioned the lactone structures of general formulae (LC1-1) to (LC1-17) to be shown hereinafter. Of these, the structures of general formula (LC1-4) are most preferred. In general formulae (LC1-1) to (LC1-17), n₂ is more preferably 2 or less.

R₈ preferably represents a monovalent organic group with an unsubstituted lactone structure or a monovalent organic group with a lactone structure substituted with a methyl group, a cyano group or an alkoxycarbonyl group. More preferably, R₈ represents a monovalent organic group with a lactone structure substituted with a cyano group (cyanolactone).

Specific examples of the repeating units having the groups with a lactone structure of general formula (III) will be shown below, which however in no way limit the scope of the present invention.

In the following specific examples, R represents a hydrogen atom, an optionally substituted alkyl group or a halogen atom. Preferably, R represents a hydrogen atom, a methyl group, a hydroxymethyl group or an acetoxymethyl group.

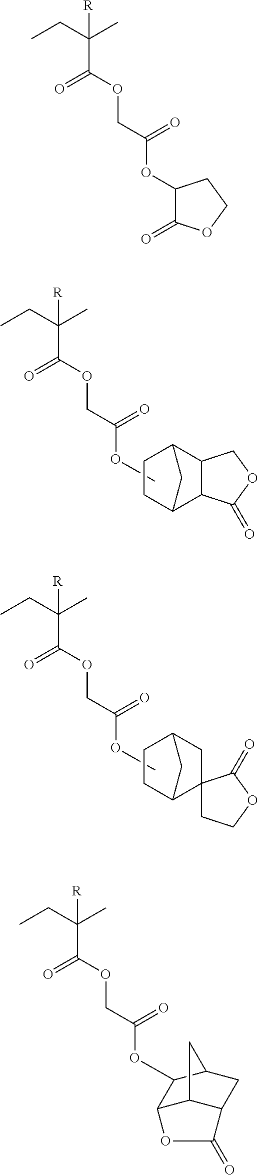

The repeating units of general formula (III-1) below are more preferred as the repeating units with a lactone structure.

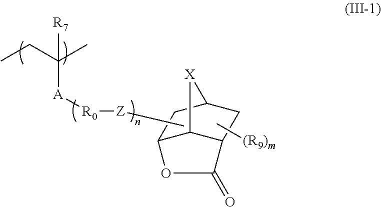

In general formula (III-1),

R₇, A, R₀, Z and n are as defined above with respect to general formula (III).

R₉, each independently in the presence of two or more groups, represents an alkyl group, a cycloalkyl group, an alkoxycarbonyl group, a cyano group, a hydroxyl group or an alkoxy group. In the presence of two or more groups, two R₉s may be bonded to each other to thereby form a ring.

X represents an alkylene group, an oxygen atom or a sulfur atom, and

m is the number of substituents and is an integer of 0 to 5. Preferably, m is 0 or 1.

The alkyl group represented by R₉ is preferably an alkyl group having 1 to 4 carbon atoms, more preferably a methyl group or an ethyl group and most preferably a methyl group. As the cycloalkyl group, there can be mentioned a cyclopropyl group, a cyclobutyl group, a cyclopentyl group or a cyclohexyl group. As the alkoxycarbonyl group, there can be mentioned a methoxycarbonyl group, an ethoxycarbonyl group, an n-butoxycarbonyl group, a t-butoxycarbonyl group or the like. These groups may have a substituent. As the substituent therefor, there can be mentioned a hydroxyl group, an alkoxy group such as a methoxy group or an ethoxy group, a cyano group, or a halogen atom such as a fluorine atom. More preferably, R₉ represents a methyl group, a cyano group or an alkoxycarbonyl group, still more preferably a cyano group.

As the alkylene group represented by X, there can be mentioned a methylene group, an ethylene group or the like. A methylene group is especially preferred.

When m is 1 or greater, the substitution site of at least one R₉ is preferably the α-position or β-position of the carbonyl group of the lactone. The substitution at the α-position is especially preferred.

Specific examples of the repeating units having groups with a lactone structure expressed by general formula (III-1) will be shown below, which however in no way limit the scope of the present invention. In the formulae, R represents a hydrogen atom, an optionally substituted alkyl group or a halogen atom, more preferably a hydrogen atom, a methyl group, a hydroxymethyl group or an acetoxymethyl group.

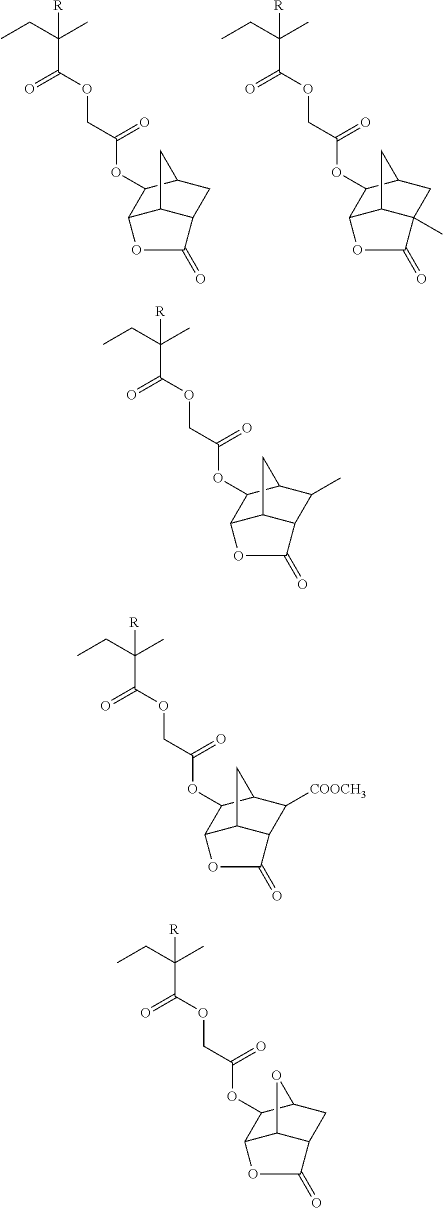

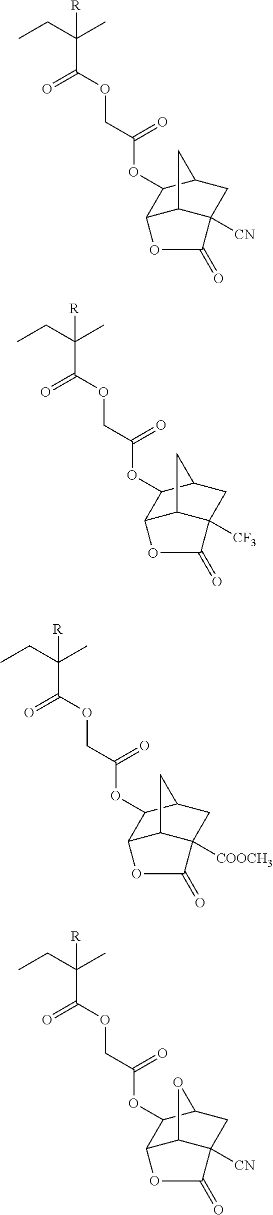

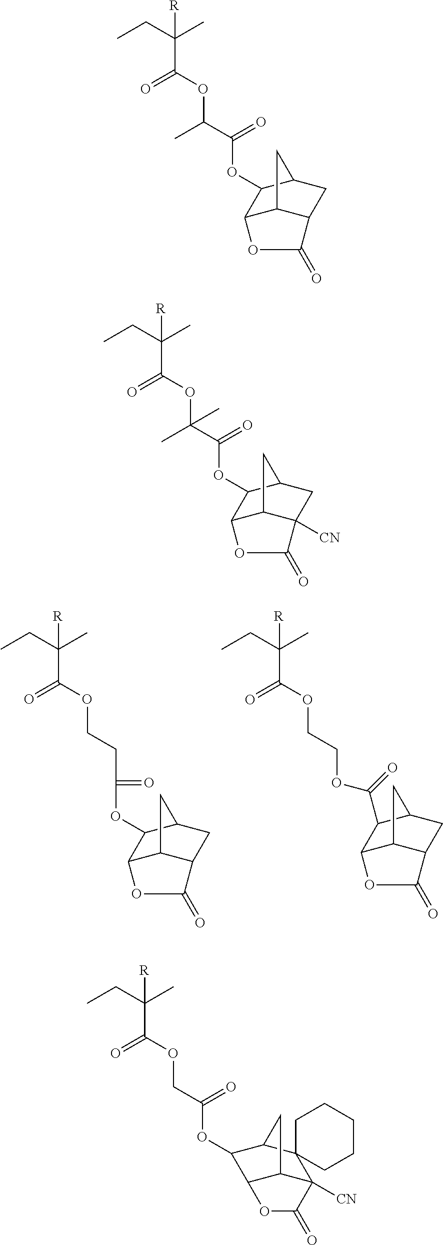

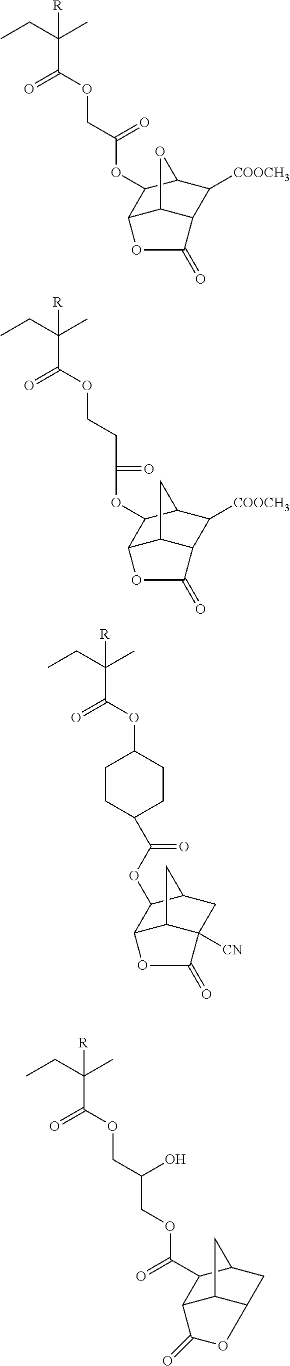

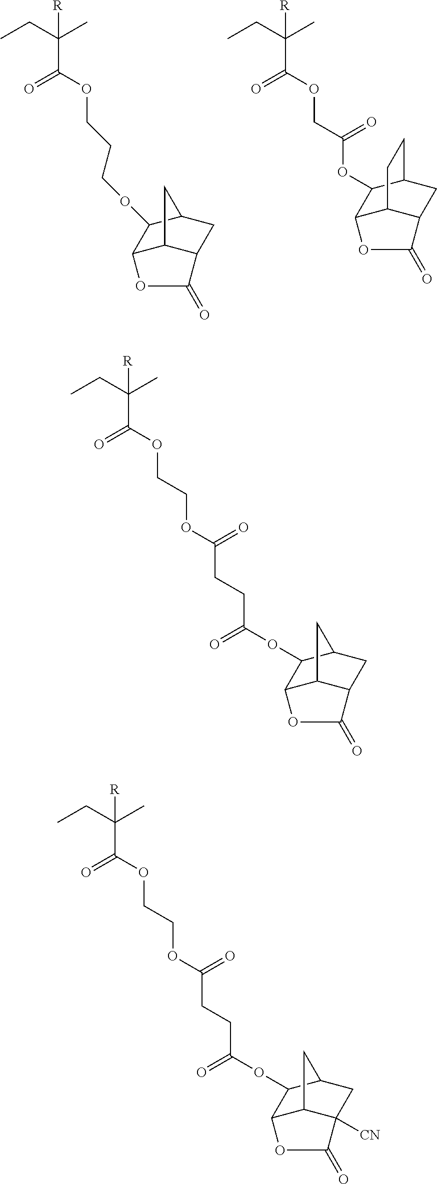

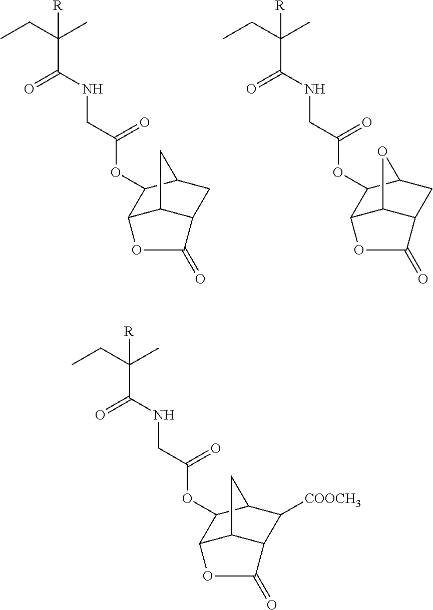

The content of the repeating units of general formula (III), the sum thereof when a plurality of repeating units are contained, is preferably in the range of 15 to 60 mol %, more preferably 20 to 60 mold and further preferably 30 to 50 mol %, based on all the repeating units contained in the resin.

Resin (A) may contain not only the units of general formula (III) but also repeating units having a lactone group.

Any lactone groups can be employed as long as a lactone structure is possessed therein. However, lactone structures of a 5 to 7-membered ring are preferred, and in particular, those resulting from condensation of lactone structures of a 5 to 7-membered ring with other cyclic structures effected in a fashion to form a bicyclo structure or spiro structure are preferred. The possession of repeating units having a lactone structure represented by any of the following general formulae (LC1-1) to (LC1-17) is more preferred. The lactone structures may be directly bonded to the principal chain of the resin. Preferred lactone structures are those of formulae (LC1-1), (LC1-4), (LC1-5), (LC1-6), (LC1-13), (LC1-14) and (LC1-17). The use of these specified lactone structures would ensure improvement in LWR and development defect.

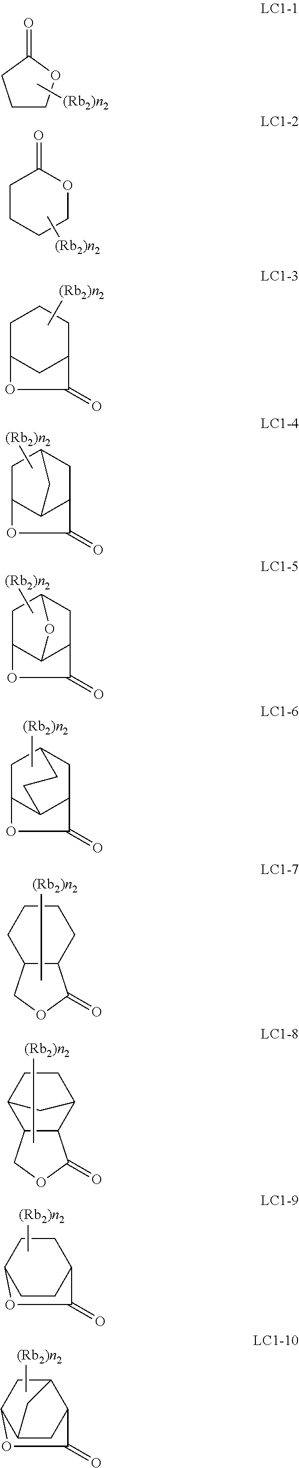

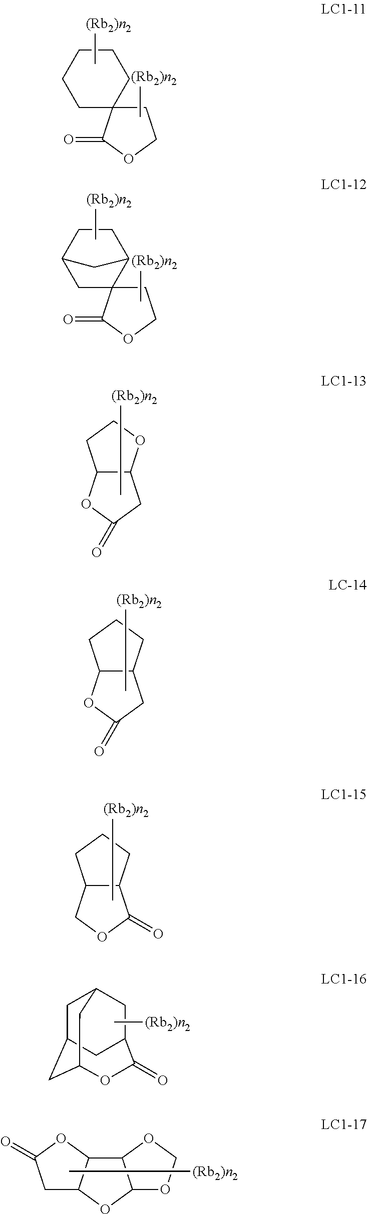

The presence of a substituent (Rb₂) on the portion of the lactone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded to each other to thereby form a ring.

It is also preferred for the repeating units having a lactone structure other than the repeating units of general formula (III) to be the repeating units of the following general formula (AII′).

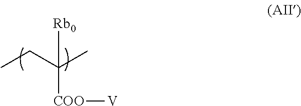

In general formula (AII′),

Rb₀ represents a hydrogen atom, a halogen atom or an optionally substituted alkyl group having 1 to 4 carbon atoms. As a preferred substituent optionally contained in the alkyl group represented by Rb₀, there can be mentioned a hydroxyl group or a halogen atom. As the halogen atom represented by Rb₀, there can be mentioned a fluorine atom, a chlorine atom, a bromine atom or an iodine atom. The Ab₀ is preferably a hydrogen atom, a methyl group, a hydroxymethyl group or a trifluoromethyl group. A hydrogen atom and a methyl group are especially preferred.

V represents a group with a structure represented by any of general formulae (LC1-1) to (LC1-17).

Specific examples of the repeating units having a lactone group other than the repeating units of general formula (III) will now be shown, which however in no way limit the scope of the present invention. In the formulae, Rx represents H, CH₃, CH₂OH or CF₃.

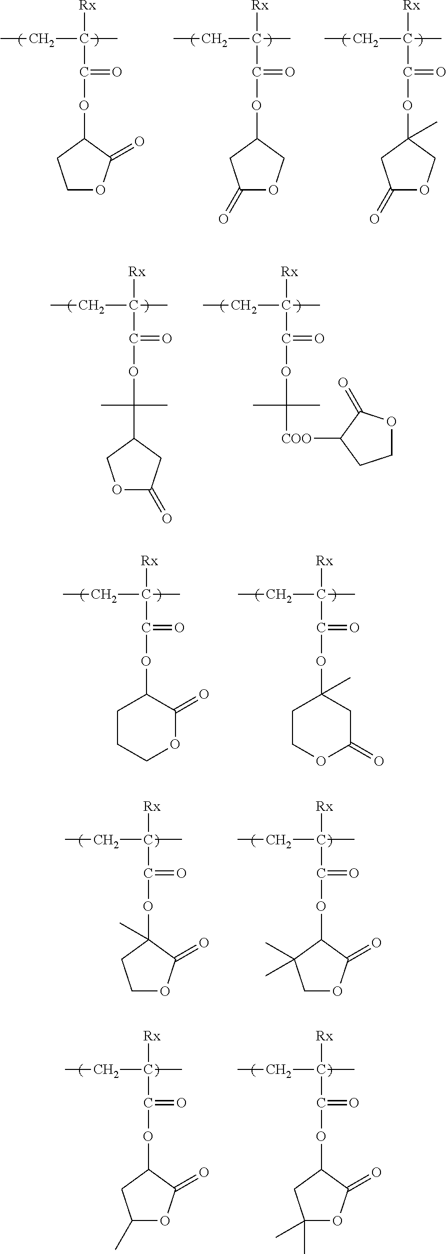

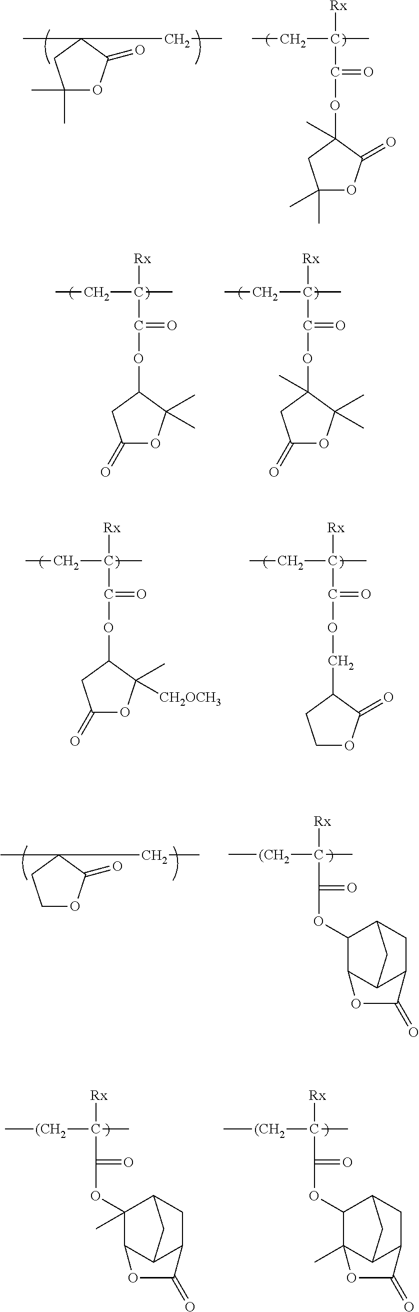

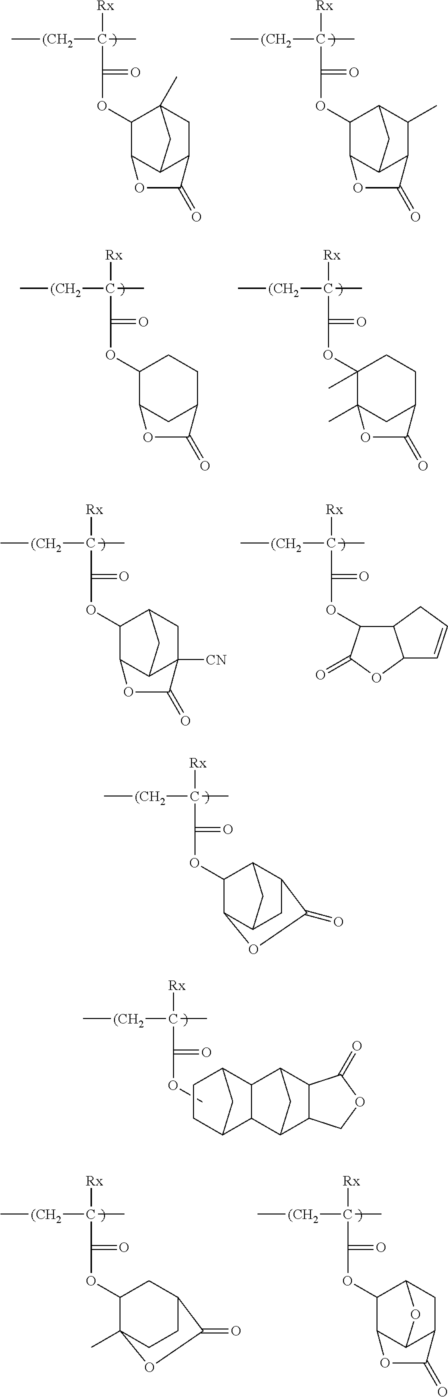

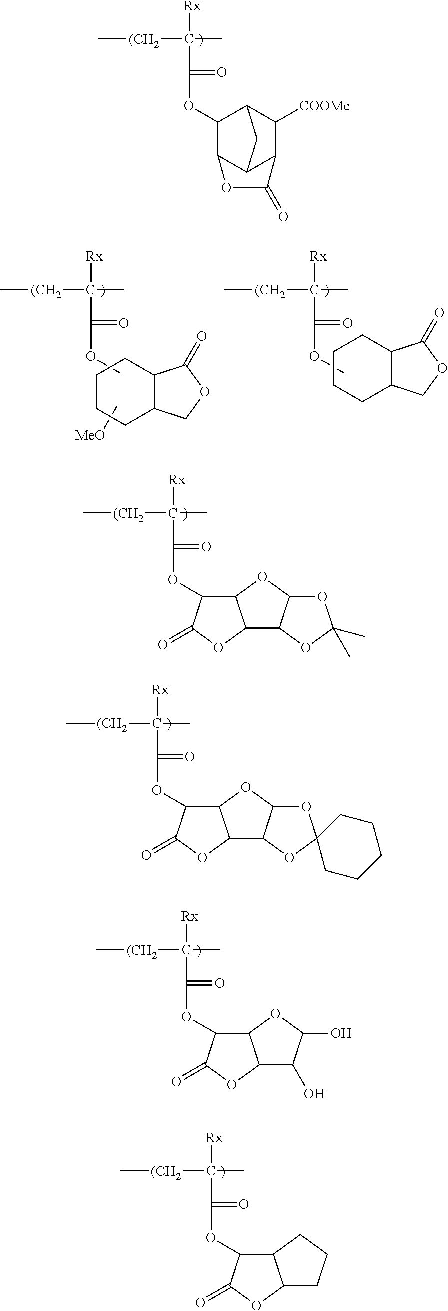

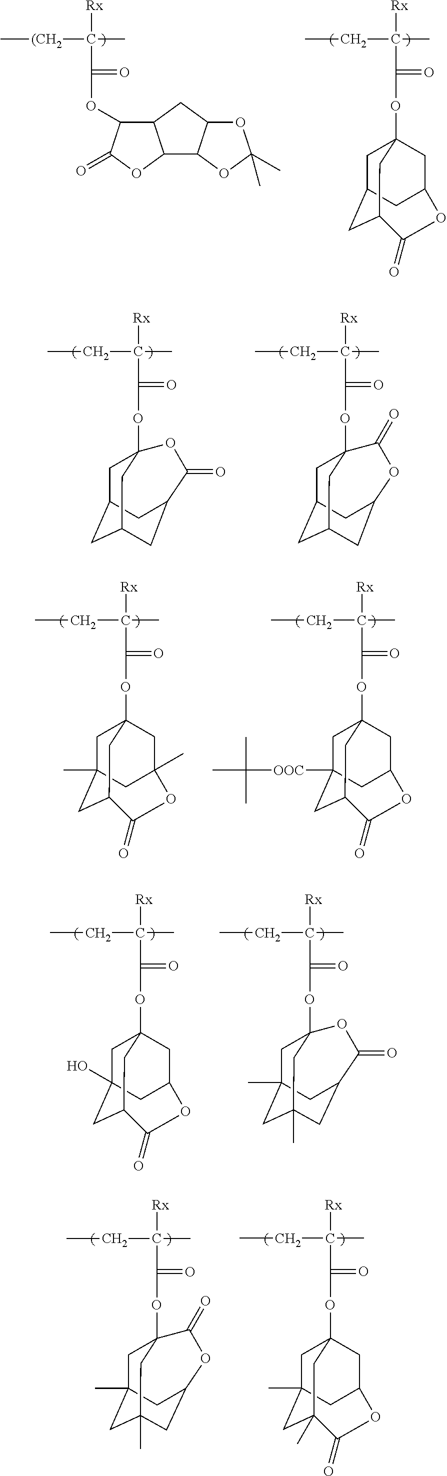

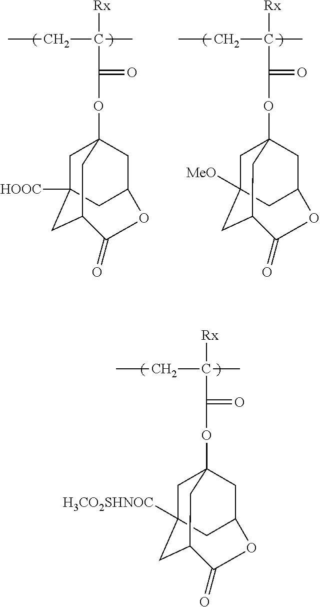

The repeating units having an especially preferred lactone group other than the repeating units of general formula (III) will be shown below. An improvement in pattern profile and iso-dense bias can be attained by selection of the most appropriate lactone group. In the formulae, Rx represents H, CH₃, CH₂OH or CF₃.

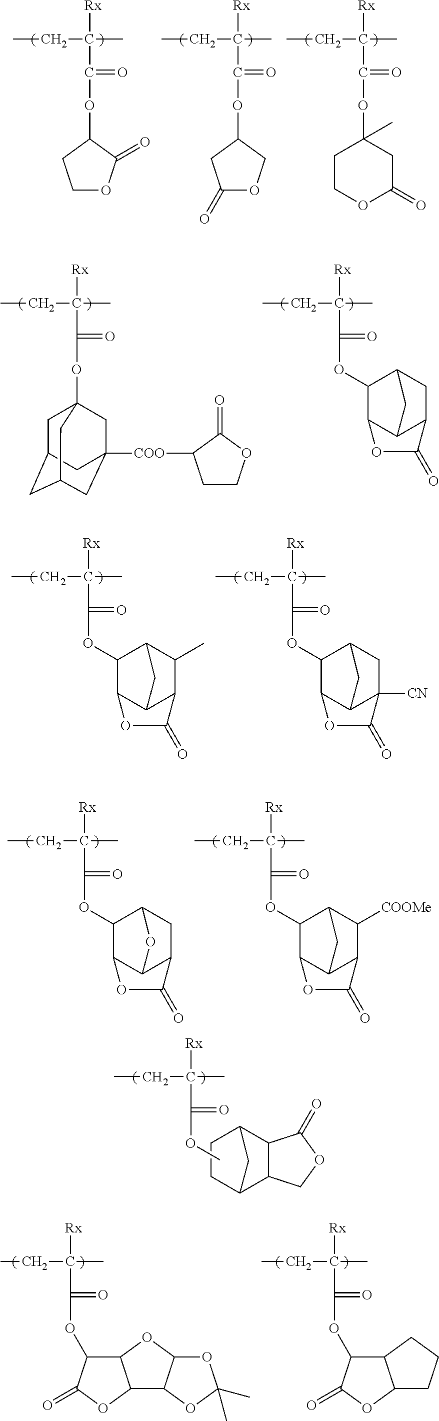

Each of the repeating units having a lactone group is generally present in the form of optical isomers. Any of the optical isomers may be used. It is appropriate to use both a single type of optical isomer alone and a plurality of optical isomers in the form of a mixture. When a single type of optical isomer is mainly used, the optical purity (ee) thereof is preferably 90 or higher, more preferably 95 or higher.

The content ratio of repeating units having a lactone other than the repeating units of general formula (III), the sum thereof when a plurality of repeating units are contained, is preferably in the range of 15 to 60 mol %, more preferably 20 to 50 mol % and further preferably 30 to 50 mol %, based on all the repeating units contained in the resin.

In order to enhance the effect of the present invention, it is practicable to simultaneously employ two or more lactone repeating units selected from among those of general formula (III). In the simultaneous employment, it is preferred to select two or more lactone repeating units from among those of general formula (III) in which n is 1 and simultaneously use them.

It is preferred for resin (A) to contain a repeating unit other than the repeating units of general formulae (AI) and (III), having a hydroxyl group or a cyano group. The containment of this repeating unit would realize enhancements of adhesion to substrate and developer affinity. The repeating unit having a hydroxyl group or a cyano group is preferably a repeating unit with a structure of alicyclic hydrocarbon substituted with a hydroxyl group or a cyano group, and preferably has no acid-decomposable group. In the alicyclic hydrocarbon structure substituted with a hydroxyl group or a cyano group, the alicyclic hydrocarbon structure preferably consists of an adamantyl group, a diamantyl group or a norbornane group. As preferred alicyclic hydrocarbon structures substituted with a hydroxyl group or a cyano group, there can be mentioned the partial structures of the following general formulae (VIIa) to (VIId).

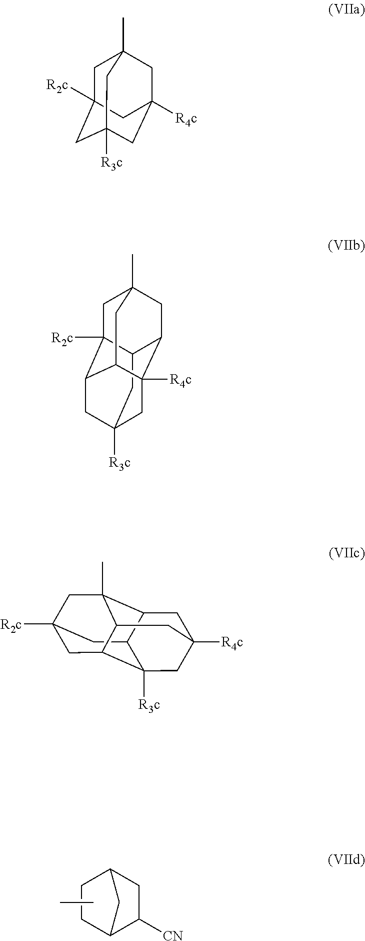

In general formulae (VIIa) to (VIIc),

each of R₂c to R₄c independently represents a hydrogen atom, a hydroxyl group or a cyano group, providing that at least one of the R₂c to R₄c represents a hydroxyl group or a cyano group. Preferably, one or two of the R₂c to R₄c are hydroxyl groups and the remainder is a hydrogen atom. In general formula (VIIa), more preferably, two of the R₂C to R₄c are hydroxyl groups and the remainder is a hydrogen atom.

As the repeating units having any of the partial structures of formulae (VIIa) to (VIId), there can be mentioned those of the following general formulae (AIIa) to (AIId).

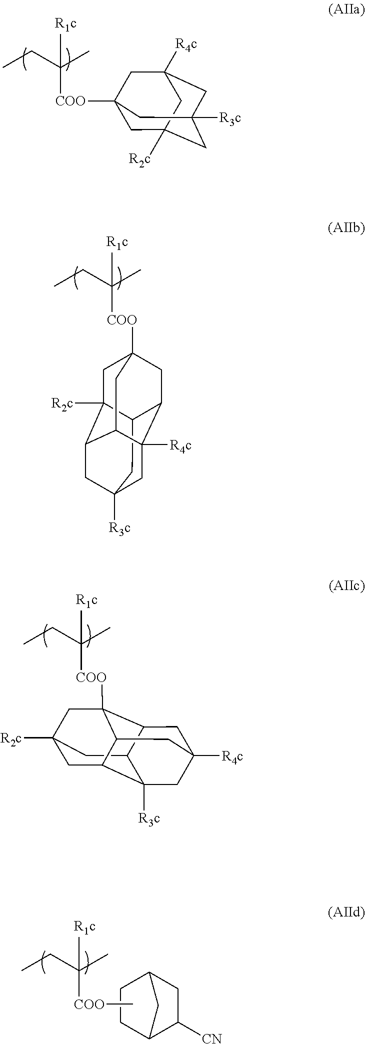

In general formulae (AIIa) to (AIId),

R₁c represents a hydrogen atom, a methyl group, a trifluoromethyl group or a hydroxymethyl group.

R₂c to R₄c have the same meaning as those of general formulae (VIIa) to (VIIc).

The content ratio of the repeating unit having a hydroxyl group or a cyano group, based on all the repeating units of resin (A), is preferably in the range of 5 to 40 mol %, more preferably 5 to 30 mol % and still more preferably 10 to 25 mol %.

Specific examples of the repeating units having a hydroxyl group or a cyano group will be shown below, which however in no way limit the scope of the present invention.

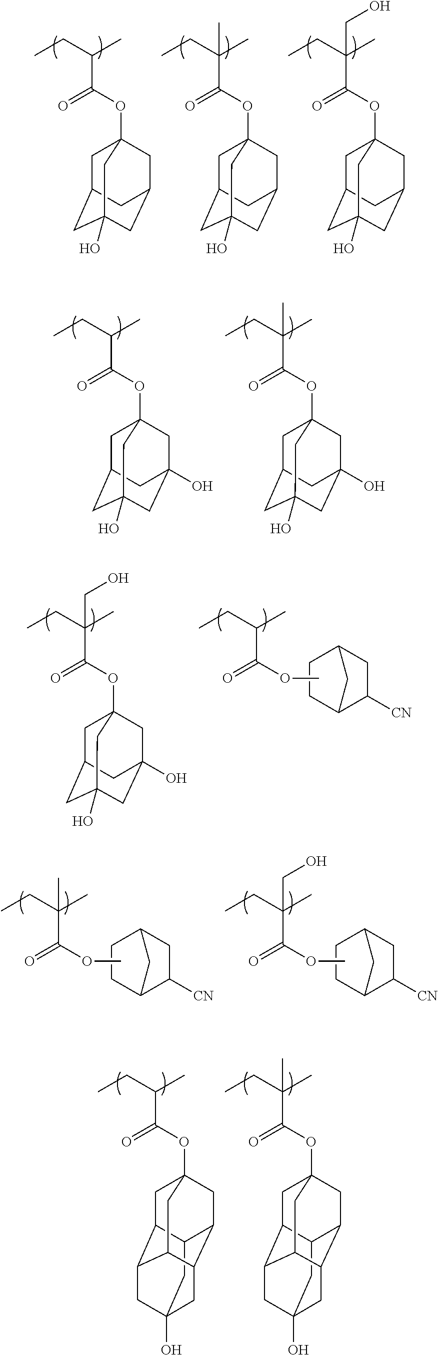

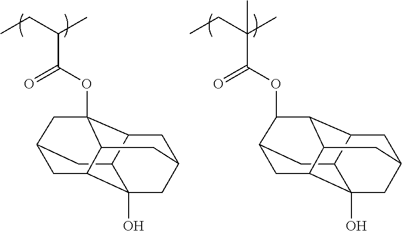

Resin (A) can contain a repeating unit having an alkali-soluble group. As the alkali-soluble group, there can be mentioned a carboxyl group, a sulfonamido group, a sulfonylimido group, a bisulfonylimido group or an aliphatic alcohol substituted at its α-position with an electron-withdrawing group (for example, a hexafluoroisopropanol group). The possession of a repeating unit having a carboxyl group is more preferred. The incorporation of the repeating unit having an alkali-soluble group would increase the resolving power in contact hole usage. The repeating unit having an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a monocyclic or polycyclic hydrocarbon structure. The repeating unit of acrylic acid or methacrylic acid is especially preferred.

The content ratio of the repeating unit having an alkali-soluble group based on all the repeating units of resin (A) is preferably in the range of 0 to 20 mol %, more preferably 3 to 15 mol % and still more preferably 5 to 10 mol %.

Specific examples of the repeating units having an alkali-soluble group will be shown below, which however in no way limit the scope of the present invention.

In the formulae, Rx represents H, CH₃, CH₂OH, or CF₃.

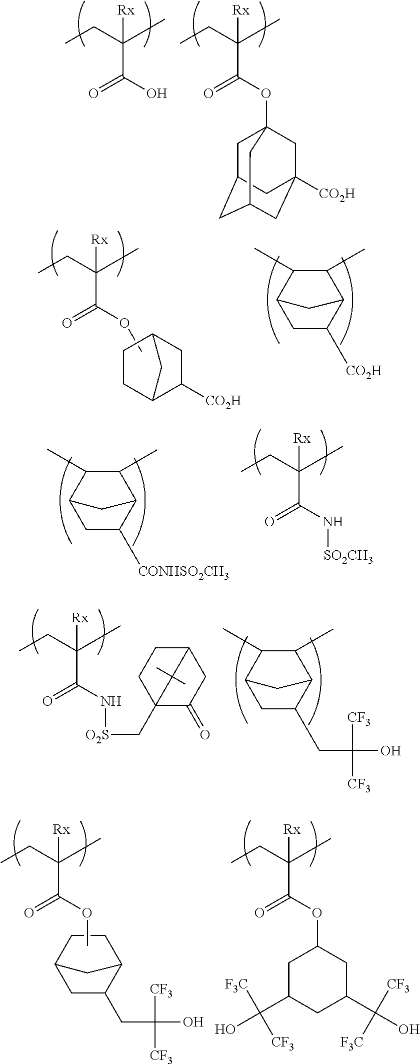

Resin (A) according to the present invention can further contain a repeating unit that has a structure of alicyclic hydrocarbon having no polar group, exhibiting no acid decomposability. As such a repeating unit, there can be mentioned any of the repeating units of general formula (IV) below.

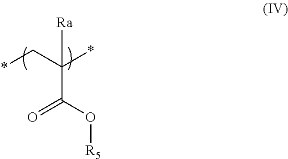

In general formula (IV), R₅ represents a hydrocarbon group having at least one cyclic structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group. Ra preferably represents a hydrogen atom, a methyl group, a trifluoromethyl group, a hydroxymethyl group or the like, more preferably a hydrogen atom and a methyl group.

The cyclic structures contained in R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5,2,1,0^{2,6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group protected by a protective group and an amino group protected by a protective group. The halogen atom is preferably a bromine, chlorine or fluorine atom, and the alkyl group is preferably a methyl, ethyl, butyl or t-butyl group. The alkyl group may further have a substituent. As the optional further substituent, there can be mentioned a halogen atom, an alkyl group, a hydroxyl group protected by a protective group or an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. The alkyl group is preferably an alkyl group having 1 to 4 carbon atoms. The substituted methyl group is preferably a methoxymethyl, methoxythiomethyl, benzyloxymethyl, t-butoxymethyl or 2-methoxyethoxymethyl group. The substituted ethyl group is preferably a 1-ethoxyethyl or 1-methyl-1-methoxyethyl group. The acyl group is preferably an aliphatic acyl group having 1 to 6 carbon atoms, such as a formyl, acetyl, propionyl, butyryl, isobutyryl, valeryl or pivaloyl group. The alkoxycarbonyl group is, for example, an alkoxycarbonyl group having 1 to 4 carbon atoms.

The content ratio of any of the repeating units that have a structure of alicyclic hydrocarbon having no polar group, exhibiting no acid decomposability, based on all the repeating units of resin (B), is preferably in the range of 0 to 40 mol %, more preferably 1 to 20 mol %.

Specific examples of the repeating units that have a structure of alicyclic hydrocarbon having no polar group, exhibiting no acid decomposability will be shown below, which however in no way limit the scope of the present invention. In the formulae, Ra represents H, CH₃, CH₂OH or CF₃.

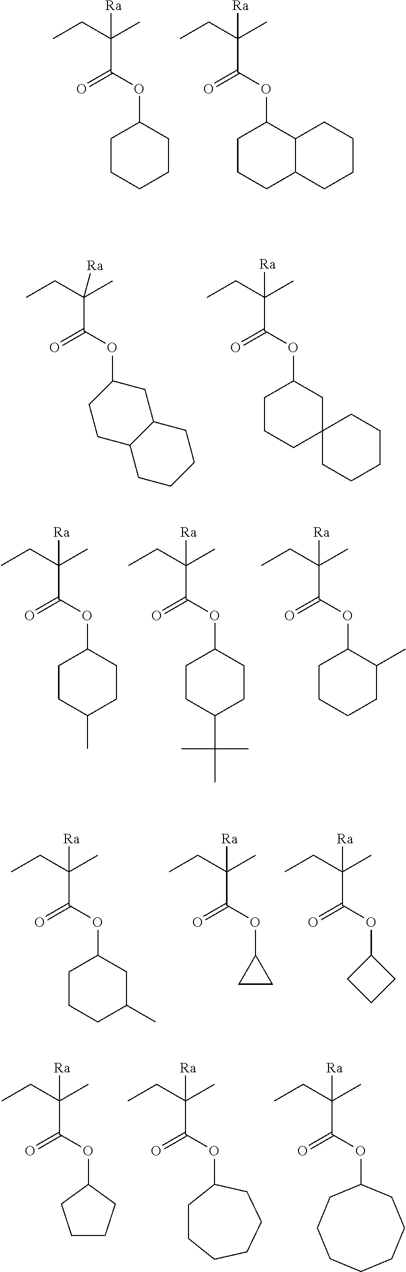

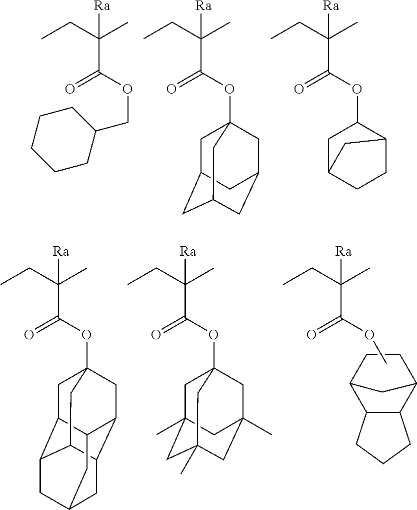

Resin (A) may have, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

The use of such repeating structural units would enable fine regulation of the required properties of resin (A), especially: (1) solubility in applied solvents, (2) film forming easiness (glass transition point), (3) alkali developability, (4) film thinning (selections of hydrophilicity/hydrophobicity and alkali-soluble group), (5) adhesion of unexposed area to substrate, and (6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters and the like.

In addition, any unsaturated compound capable of addition polymerization that is copolymerizable with monomers corresponding to the above various repeating structural units may be copolymerized therewith.

The molar ratios of individual repeating structural units contained in resin (A) are appropriately determined from the viewpoint of regulation of not only the dry etching resistance of the resist but also the standard developer adaptability, substrate adhesion, resist profile and generally required properties of the resist such as the resolving power, heat resistance and sensitivity.

When the composition of the present invention is one for ArF exposure, it is preferred for resin (B) to have no aromatic group and to contain an alicyclic hydrocarbon structure with single ring or multiple rings from the viewpoint of transparency to ArF beams.

From the viewpoint of the compatibility with resin (B) described above, it is preferred for resin (A) to contain neither a fluorine atom nor a silicon atom.

In resin (A), preferably, all the repeating units consist of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred for the acrylate repeating units to account for 50 mol % or less of all the repeating units. It is more preferred to employ a copolymer containing 20 to 50 mol % of (meth)acrylate repeating units having an acid-decomposable group, 20 to 50 mol % of (meth)acrylate repeating units having a lactone group, 5 to 30 mol % of (meth)acrylate repeating units having an alicyclic hydrocarbon structure substituted with a hydroxyl group or a cyano group and 0 to 20 mol % of other (meth)acrylate repeating units.

In the event of exposing the actinic-ray- or radiation-sensitive resin composition of the present invention to KrF excimer laser beams, electron beams, X-rays or high-energy light rays of wavelength 50 nm or less (EUV, etc.), it is preferred for resin (A) to further have hydroxystyrene repeating units. More preferably, resin (A) has hydroxystyrene repeating units, hydroxystyrene repeating units protected by an acid-decomposable group and acid-decomposable repeating units of a (meth)acrylic acid tertiary alkyl ester, etc.

As preferred hydroxystyrene repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl(meth)acrylate and a dialkyl(1-adamantyl)methyl(meth)acrylate are more preferred.

Resin (A) of the present invention can be synthesized by conventional techniques (for example, radical polymerization). As general synthetic methods, there can be mentioned, for example, a batch polymerization method in which a monomer species and an initiator are dissolved in a solvent and heated so as to accomplish polymerization and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or the solvent capable of dissolving the composition of the present invention, such as propylene glycol monomethyl ether acetate, propylene glycol monomethyl ether or cyclohexanone, to be described hereinafter. It is preferred to perform the polymerization with the use of the same solvent as employed in the actinic-ray- or radiation-sensitive resin composition of the present invention. This would inhibit any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

The weight average molecular weight of resin (A) in terms of polystyrene molecular weight as measured by GPC is preferably in the range of 1000 to 200,000, more preferably 2000 to 20,000, still more preferably 3000 to 15,000 and further preferably 5000 to 13,000. The regulation of the weight average molecular weight to 1000 to 200,000 would prevent deteriorations of heat resistance and dry etching resistance and also prevent deterioration of developability and increase of viscosity leading to poor film forming property.

Use is made of the resin whose dispersity (molecular weight distribution) is generally in the range of 1 to 3, preferably 1 to 2.6, more preferably 1 to 2 and most preferably 1.4 to 2.0. The lower the molecular weight distribution, the more excellent the resolving power and resist profile and the smoother the side wall of the resist pattern to thereby attain an excellence in roughness.

Resin (A) may be used either individually or in combination.

In the present invention, the content ratio of resin (A) based on the total solid content of the whole composition is preferably in the range of 30 to 99 mass %, more preferably 60 to 95 mass %.

<Compound that is Configured to Generate an Acid when Exposed to Actinic Rays or Radiation>

The composition according to the present invention contains a compound that is configured to generate an acid when exposed to actinic rays or radiation (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that generate an acid when exposed to actinic rays or radiation employed in microresists, etc., and mixtures thereof.

As the acid generator, a diazonium salt, a phosphonium salt, a sulfonium salt, an iodonium salt, an imide sulfonate, an oxime sulfonate, diazosulfone, disulfone and o-nitrobenzyl sulfonate can be exemplified.

Further, use can be made of compounds obtained by introducing any of the above groups or compounds that generate an acid when exposed to actinic rays or radiation in a polymer principal chain or side chain, for example, compounds described in U.S. Pat. No. 3,849,137, DE 3914407, JP-A's-63-26653, 55-164824, 62-69263, 63-146038, 63-163452, 62-153853, 63-146029, etc.

Furthermore, use can be made of compounds that generate an acid when exposed to light described in U.S. Pat. No. 3,779,778, EP 126,712, etc.

As preferred compounds among the acid generators, those represented by the following general formulae (ZI), (ZII) and (ZIII) can be exemplified.

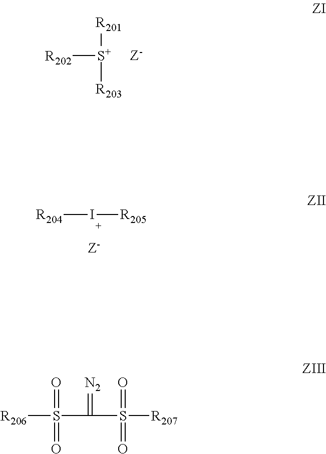

In the above general formula (Z₁),

each of R₂₀₁, R₂₀₂ and R₂₀₃ independently represents an organic group.

The number of carbon atoms in the organic group represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure. The ring structure may contain therein an oxygen atom, a sulfur atom, an ester group, an amido group or a carbonyl group. As the group formed by the mutual bonding of two of R₂₀₁ to R₂₀₃, there can be mentioned, for example, an alkylene group, such as a butylene group or a pentylene group.

Z— represents a nonnucleophilic anion.

As the nonnucleophilic anion represented by Z—, a sulfonate anion, a carboxylate anion, a sulfonylimido anion, a bis(alkylsulfonyl)imido anion, and a tris(alkylsulfonyl)methide anion can be exemplified.

The nonnucleophilic anion means an anion whose capability of inducing a nucleophilic reaction is extremely low. Any decomposition over time attributed to an intramolecular nucleophilic reaction can be suppressed by the use of this anion. Therefore, when this anion is used, the stability over time of the relevant composition and the film formed therefrom can be enhanced.

As the sulfonate anion, an aliphatic sulfonate anion, an aromatic sulfonate anion, and a camphor sulfonate anion can be exemplified.

As the carboxylate anion, an aliphatic carboxylate anion, an aromatic carboxylate anion, and an aralkyl carboxylate anion can be exemplified.

The aliphatic moiety of the aliphatic sulfonate anion may be an alkyl group or a cycloalkyl group, being preferably an alkyl group having 1 to 30 carbon atoms or a cycloalkyl group having 3 to 30 carbon atoms. As such, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a bornyl group can be exemplified.

As a preferred aromatic group of the aromatic sulfonate anion, an aryl group having 6 to 14 carbon atoms, such as a phenyl group, a tolyl group and a naphthyl group can be exemplified.

The alkyl group, cycloalkyl group and aryl group of the aliphatic sulfonate anion and aromatic sulfonate anion may have one or more substituents. As the substituent of the alkyl group, cycloalkyl group and aryl group of the aliphatic sulfonate anion and aromatic sulfonate anion, a nitro group, a halogen atom (fluorine atom, chlorine atom, bromine atom or iodine atom), a carboxy group, a hydroxy group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms) can be exemplified. The aryl group or ring structure of these groups may further have an alkyl group (preferably having 1 to 15 carbon atoms) or a cycloalkyl group (preferably having 3 to 15 carbon atoms) as its substituent.

As the aliphatic moiety of the aliphatic carboxylate anion, the same alkyl groups and cycloalkyl groups as mentioned with respect to the aliphatic sulfonate anion can be exemplified.

As the aromatic group of the aromatic carboxylate anion, the same aryl groups as mentioned with respect to the aromatic sulfonate anion can be exemplified.

As a preferred aralkyl group of the aralkyl carboxylate anion, an aralkyl group having 6 to 12 carbon atoms, such as a benzyl group, a phenethyl group, a naphthylmethyl group, a naphthylethyl group, and a naphthylbutyl group can be exemplified.

The alkyl group, cycloalkyl group, aryl group and aralkyl group of the aliphatic carboxylate anion, aromatic carboxylate anion and aralkyl carboxylate anion may have a substituent. As the substituent of the alkyl group, cycloalkyl group, aryl group and aralkyl group of the aliphatic carboxylate anion, aromatic carboxylate anion and aralkyl carboxylate anion, the same halogen atom, alkyl group, cycloalkyl group, alkoxy group, and alkylthio group, etc. as mentioned with respect to the aromatic sulfonate anion can be exemplified.

As the sulfonylimido anion, a saccharin anion can be exemplified.

The alkyl group of the bis(alkylsulfonyl)imido anion and tris(alkylsulfonyl)methyl anion is preferably an alkyl group having 1 to 5 carbon atoms. As such, a methyl group, an ethyl group, a propyl group, an isopropyl group, an n-butyl group, an isobutyl group, a sec-butyl group, a pentyl group, and a neopentyl group can be exemplified. As a substituent of these alkyl groups, a halogen atom, an alkyl group substituted with a halogen atom, an alkoxy group, an alkylthio group, an alkyloxysulfonyl group, an aryloxysulfonyl group, and a cycloalkylaryloxysulfonyl group can be exemplified. An alkyl group substituted with a fluorine atom is preferred.

As the other nonnucleophilic anions, phosphorus fluoride, boron fluoride and antimony fluoride can be exemplified.

The nonnucleophilic anion represented by Z— is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion having 4 to 8 carbon atoms or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

Nonnucleophilic anion represented by A- is preferably represented by general formula (LD1) below.

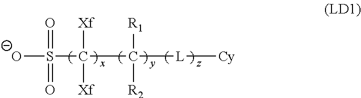

In the formula,

each of Xfs independently represents a fluorine atom or an alkyl group substituted with at least one fluorine atom.

Each of R₁ and R₂ independently represents a member selected from a hydrogen atom, a fluorine atom, an alkyl group and an alkyl group substituted with at least one fluorine atom.

Each of Ls independently represents a single bond or a bivalent connecting group.

Cy represents a group with a cyclic structure.

x is an integer of 1 to 20.

y is an integer of 0 to 10.

z is an integer of 0 to 10.

Xf represents a fluorine atom or an alkyl group substituted with at least one fluorine atom. The alkyl group preferably has 1 to 10 carbon atoms, more preferably 1 to 4 carbon atoms. The alkyl group substituted with at least one fluorine atom is preferably a perfluoroalkyl group.

Xf is preferably a fluorine atom or a perfluoroalkyl group having 1 to 4 carbon atoms. In particular, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉.

Each of R₁ and R₂ independently represents a member selected from a hydrogen atom, a fluorine atom, an alkyl group and an alkyl group substituted with at least one fluorine atom. Each of the alkyl group and the alkyl group of the alkyl group substituted with at least one fluorine atom preferably has 1 to 4 carbon atoms. Further preferably, each of the alkyl groups is a perfluoroalkyl group having 1 to 4 carbon atoms. In particular, there can be mentioned, for example, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉. Of these, CF₃ is preferred.

L represents a single bond or a bivalent connecting group. As the bivalent connecting group, there can be mentioned, for example, —COO—, —OCO—, —CONH—, —CO—, —O—, —S—, —SO—, —SO₂—, an alkylene group, a cycloalkylene group or an alkenylene group. Of these, —COO—, —OCO—, —CONH—, —CO—, —O— and —SO₂— are preferred. —COO—, —OCO— —CONH—, and —SO₂— are more preferred.

Cy represents a group with a cyclic structure. As the group with a cyclic structure, there can be mentioned, for example, a group with an alicyclic group, a group with an aryl group or a group with a heterocyclic structure.

The alicyclic group may be monocyclic or polycyclic. As the alicyclic group that is monocyclic, there can be mentioned, for example, a cycloalkyl group of a single ring, such as a cyclopenthyl group, a cyclohexyl group or a cyclooctyl group. As the alicyclic group that is polycyclic, there can be mentioned, for example, a cycloalkyl group of multiple rings, such as a norbornyl group, a tricyclodecanyl group, a tetracyclodecanyl group, a tetracyclododecanyl group or an adamantyl group. Of the mentioned groups, alicyclic groups with a bulky structure having at least 7 carbon atoms, such as a norbornyl group, a tricyclodecanyl group, a tetracyclodecanyl group, a tetracyclododecanyl group and an adamantyl group, are preferred from the view point of inhibition of in-film diffusion in the PEB (post-exposure bake) step and enhancement of MEEF (Mask Error Enhancement Factor).

The aryl group may be monocyclic or polycyclic. As the aryl group, there can be mentioned, for example, a phenyl group, a naphthyl group, a phenanthryl group or an anthryl group. Of these, a naphthyl group exhibiting relatively low light absorbance at 193 nm is preferred.

The group with a heterocyclic structure may be monocyclic or polycyclic. However, the polycyclic structure is preferred from the view point of inhibiting any acid diffusion. It is optional for the group with a heterocyclic structure to have aromaticity. As the heterocyclic structure having aromaticity, there can be mentioned, for example, a furan ring, a thiophene ring, a benzofuran ring, a benzothiophene ring, a dibenzofuran ring, a dibenzothiophene ring or a pyridine ring. As the heterocyclic structure having no aromaticity, there can be mentioned, for example, a tetrahydropyran ring, a lactone ring or a decahydroisoquinoline ring. It is especially preferred for the heterocyclic of the group with a heterocyclic structure to be a furan ring, a thiophene ring, a pyridine ring or a decahydroisoquinoline ring.

The above group with a cyclic structure may have a substituent. As the substituent, there can be mentioned, for example, an alkyl group, a cycloalkyl group, an aryl group, a hydroxyl group, an alkoxy group, an ester group, an amido group, a urethane group, a ureido group, a thioether group, a sulfonamide group or a sulfonic ester group. The alkyl group may be linear or branched. It is preferred for the alkyl group to have 1 to 12 carbon atoms. The cycloalkyl group may be monocyclic or polycyclic. It is preferred for the cycloalkyl group to have 3 to 12 carbon atoms. The aryl group preferably has 6 to 14 carbon atoms.

In the formula, x is preferably 1 to 8, more preferably 1 to 4 and most preferably 1; y is preferably 0 to 4, more preferably 0; and z is preferably 0 to 8, more preferably 0 to 4.

Also, the nonnucleophilic anion represented by Z— is preferably expressed by, for example, general formula (LD2) below.

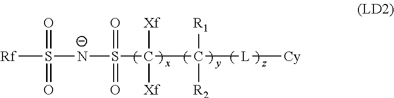

In general formula (LD2), Xf, R₁, R₂, L, Cy, x, y and z are as defined above in connection with general formula (LD1). Rf is a group containing a fluorine atom.

As the group containing a fluorine atom represented by Rf, there can be mentioned, for example, an alkyl group containing at least one fluorine atom, a cycloalkyl group containing at least one fluorine atom or an aryl group containing at least one fluorine atom.

These alkyl group, cycloalkyl group and aryl group may be those substituted with a fluorine atom, or those substituted with another substituent containing a fluorine atom. When Rf is a cycloalkyl group containing at least one fluorine atom or an aryl group containing at least one fluorine atom, the other substituent containing a fluorine atom can be, for example, an alkyl group substituted with at least one fluorine atom.

Further, these alkyl group, cycloalkyl group and aryl group may further be substituted with a substituent containing no fluorine atom. As this substituent, there can be mentioned, for example, any of those mentioned above with respect to Cy wherein no fluorine atom is contained.

As the alkyl group containing at least one fluorine atom represented by Rf, there can be mentioned, for example, any of those mentioned hereinbefore as the alkyl group substituted with at least one fluorine atom, represented by Xf. As the cycloalkyl group containing at least one fluorine atom represented by Rf, there can be mentioned, for example, a perfluorocyclopentyl group or a perfluorocyclohexyl group. As the aryl group containing at least one fluorine atom represented by Rf, there can be mentioned, for example, a perfluorophenyl group.

As the organic groups represented by R₂₀₁, R₂₀₂ and R₂₀₃ in the structural unit (ZI), there can be mentioned, for example, the corresponding groups of compounds (ZI-1), (ZI-2), (ZI-3) or (ZI-4) to be described hereinafter.

Compounds having two or more of the structures of the general formula (ZI) may be used as the acid generator. For example, use may be made of a compound having a structure in which at least one of the R₂₀₁ to R₂₀₃ of one of the compounds of the general formula (ZI) is bonded to at least one of the R₂₀₁ to R₂₀₃ of another of the compounds of the general formula (ZI).

As preferred (ZI) components, the following compounds (ZI-1) to (ZI-4) can be exemplified.

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group.

As the arylsulfonyl compound, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, a pyrrole residue, a furan residue, a thiophene residue, an indole residue, a benzofuran residue, and a benzothiophene residue can be exemplified. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, a methyl group, an ethyl group, a propyl group, an n-butyl group, a sec-butyl group, a t-butyl group, a cyclopropyl group, a cyclobutyl group, and a cyclohexyl group can be exemplified.

The aryl group, alkyl group or cycloalkyl group represented by R₂₀₁ to R₂₀₃ may have one or more substituents. As the substituent, an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxy group, and a phenylthio group can be exemplified. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 6 carbon atoms and an alkoxy group having 1 to 6 carbon atoms. The substituents may be contained in any one of the three R₂₀₁ to R₂₀₃, or alternatively may be contained in all three of R₂₀₁ to R₂₀₃. When R₂₀₁ to R₂₀₃ represent a phenyl group, the substituent preferably lies at the p-position of the phenyl group.

Now, the compounds (ZI-2) will be described.

The compounds (ZI-2) are compounds represented by the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a 2-oxoalkyl group, an alkoxycarbonylmethyl group, an allyl group, and a vinyl group. More preferred groups include a linear or branched 2-oxoalkyl group and an alkoxycarbonylmethyl group. Especially preferred is a linear or branched 2-oxoalkyl group.

As preferred alkyl groups and cycloalkyl groups represented by R₂₀₁ to R₂₀₃, a linear or branched alkyl group having 1 to 10 carbon atoms (for example, a methyl group, an ethyl group, a propyl group, a butyl group or a pentyl group) and a cycloalkyl group having 3 to 10 carbon atoms (for example, a cyclopentyl group, a cyclohexyl group or a norbornyl group) can be exemplified. As more preferred alkyl groups, a 2-oxoalkyl group and an alkoxycarbonylmethyl group can be exemplified. As more preferred cycloalkyl group, a 2-oxocycloalkyl group can be exemplified.

The 2-oxoalkyl group may be linear or branched. A group having >C═O at the 2-position of the above-described alkyl group can be preferably exemplified.

The 2-oxocycloalkyl group is preferably a group having >C═O at the 2-position of the above-described cycloalkyl group.

As preferred alkoxy groups of the alkoxycarbonylmethyl group, alkoxy groups having 1 to 5 carbon atoms can be exemplified. As such, there can be mentioned, for example, a methoxy group, an ethoxy group, a propoxy group, a butoxy group and a pentoxy group.

The organic groups containing no aromatic ring represented by R₂₀₁ to R₂₀₃ may further have one or more substituents. As the substituents, a halogen atom, an alkoxy group (having, for example, 1 to 5 carbon atoms), a hydroxy group, a cyano group and a nitro group can be exemplified.

The compounds (ZI-3) are those represented by the following general formula (ZI-3) which have a phenacylsulfonium salt structure.

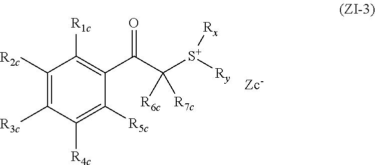

In the formula (ZI-3),

each of R_{1c} to R_{5c} independently represents a hydrogen atom, an alkyl group, a cycloalkyl group, an alkoxy group, a halogen atom, or a phenylthio group.

Each of R_{6c} and R_{7c} independently represents a hydrogen atom, an alkyl group, a cycloalkyl group, halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, and R_{6c} and R_{7c}, and Rₓ and R_{y} may be bonded with each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Zc- represents a nonnucleophilic anion. There can be mentioned the same nonnucleophilic anions as mentioned with respect to the Z— of the general formula (ZI).

The alkyl group represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 8 carbon atoms (for example, a cyclopentyl group or a cyclohexyl group).

The alkoxy group represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle generation during storage.

Each of the aryl groups represented by R_{6c} and R_{7c} preferably has 5 to 15 carbon atoms. As such, there can be mentioned, for example, a phenyl group or a naphthyl group.

When R_{6c} and R_{7c} are bonded to each other to thereby form a ring, the group formed by the bonding of R_{6c} and R_{7c} is preferably an alkylene group having 2 to 10 carbon atoms. As such, there can be mentioned, for example, an ethylene group, a propylene group, a butylene group, a pentylene group, a hexylene group or the like. Further, the ring formed by the bonding of R_{6c} and R_{7c} may have a heteroatom, such as an oxygen atom, in the ring.

As the alkyl groups and cycloalkyl groups represented by Rₓ and R_{y}, there can be mentioned the same alkyl groups and cycloalkyl groups as set forth above with respect to R_{1c} to R_{7c}.

As the 2-oxoalkyl group and 2-oxocycloalkyl group, there can be mentioned the alkyl group and cycloalkyl group represented by R_{1c} to R_{7c} having >C═O at the 2-position thereof.

With respect to the alkoxy group of the alkoxycarbonylalkyl group, there can be mentioned the same alkoxy groups as mentioned above with respect to R_{1c} to R_{5c}. As the alkyl group thereof, there can be mentioned, for example, an alkyl group having 1 to 12 carbon atoms, preferably a linear alkyl group having 1 to 5 carbon atoms (e.g., a methyl group or an ethyl group).

The allyl groups are not particularly limited. However, preferred use is made of an unsubstituted allyl group or an allyl group substituted with a cycloalkyl group of a single ring or multiple rings.

The vinyl groups are not particularly limited. However, preferred use is made of an unsubstituted vinyl group or a vinyl group substituted with a cycloalkyl group of a single ring or multiple rings.

As the ring structure that may be formed by the mutual bonding of Rₓ and R_{y}, there can be mentioned a 5-membered or 6-membered ring, especially preferably a 5-membered ring (namely, a tetrahydrothiophene ring), formed by bivalent Rₓ and R_{y} (for example, a methylene group, an ethylene group, a propylene group or the like) in cooperation with the sulfur atom of general formula (ZI-3).

Each of Rₓ and R_{y} is preferably an alkyl group or cycloalkyl group having preferably 4 or more carbon atoms. The alkyl group or cycloalkyl group has more preferably 6 or more carbon atoms and still more preferably 8 or more carbon atoms.

Specific examples of the cation part in the structural unit (ZI-3) will be described below.

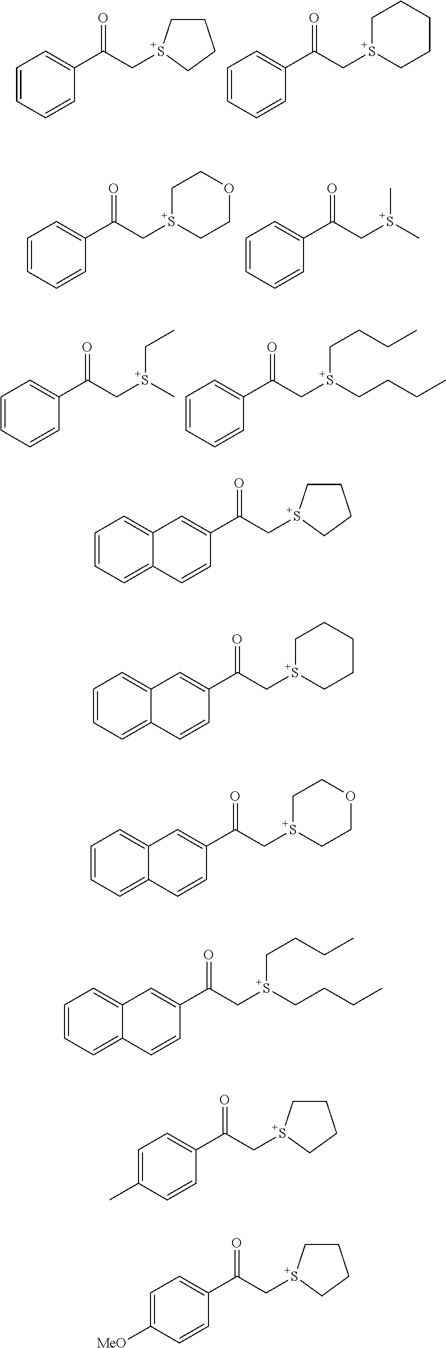

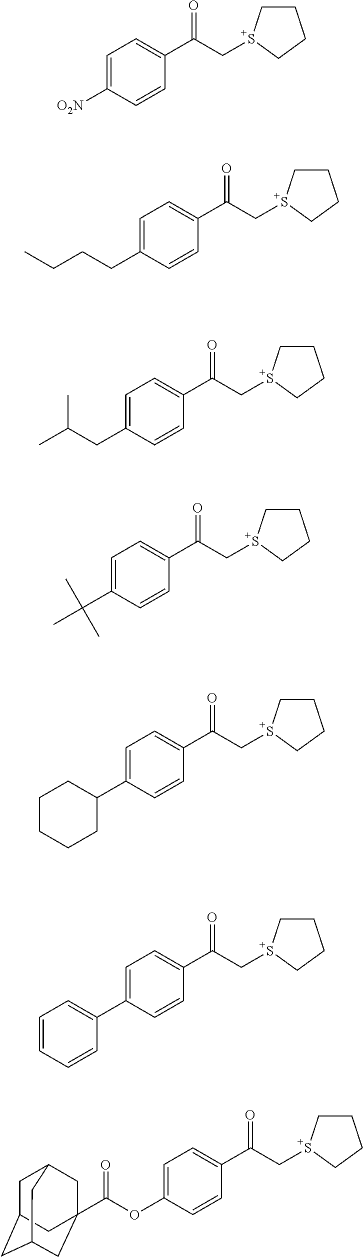

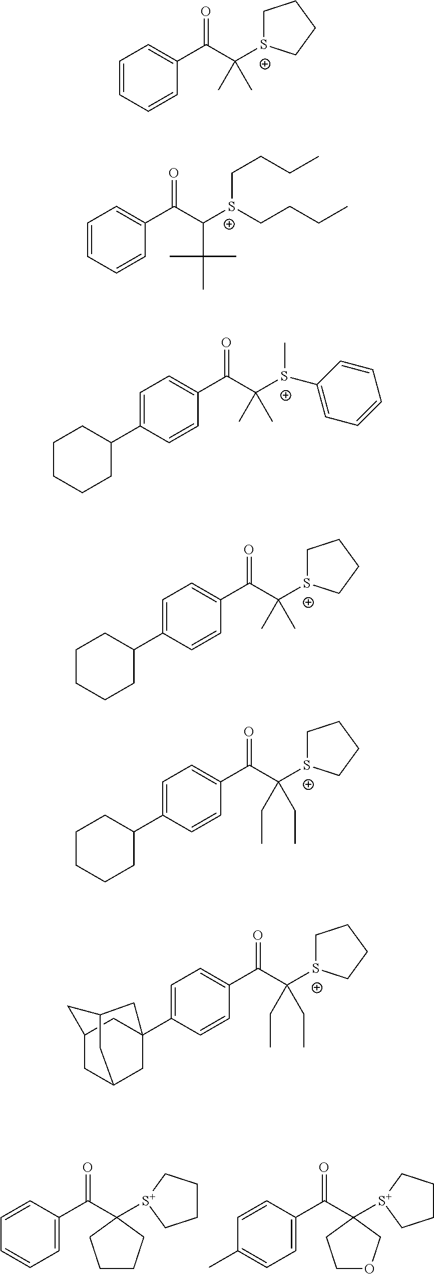

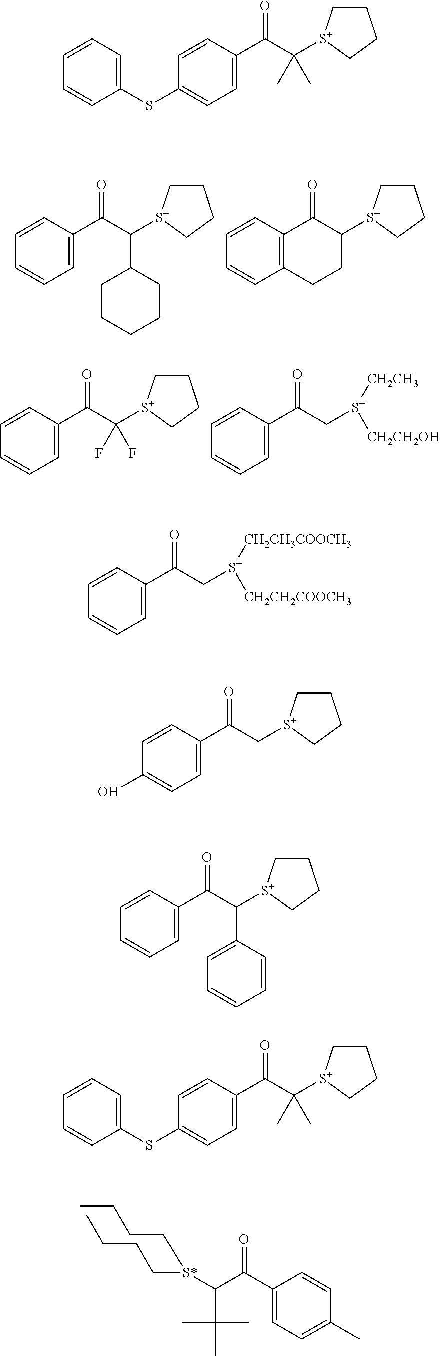

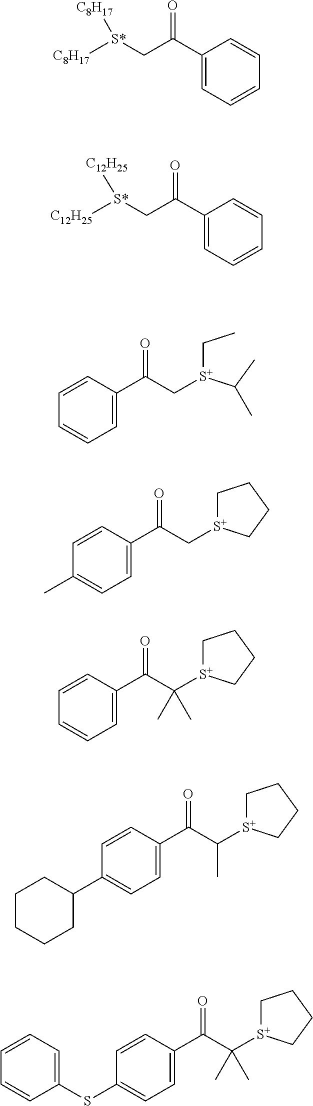

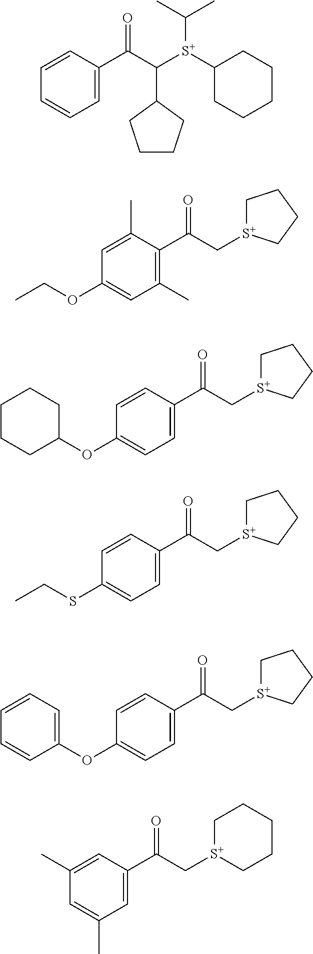

The structural units (ZI-4) are those of general formula (ZI-4) below.

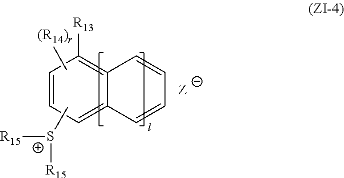

In general formula (ZI-4),

R₁₃ represents any of a hydrogen atom, a fluorine atom, a hydroxyl group, an alkyl group, a cycloalkyl group, an alkoxy group, an alkoxycarbonyl group and a group with a cycloalkyl skeleton of a single ring or multiple rings. These groups may have one or more substituents.

R₁₄, each independently in the instance of R₁₄s, represents any of an alkyl group, a cycloalkyl group, an alkoxy group, an alkoxycarbonyl group, an alkylcarbonyl group, an alkylsulfonyl group, a cycloalkylsulfonyl group and a group with a cycloalkyl skeleton of a single ring or multiple rings. These groups may have one or more substituents.

Each of R₁₅s independently represents an alkyl group, a cycloalkyl group or a naphthyl group, provided that the two R₁₅s may be bonded to each other to thereby form a ring. These groups may have one or more substituents.

In the formula, 1 is an integer of 0 to 2, and r is an integer of 0 to 8.

Z— represents a nonnucleophilic anion. As such, there can be mentioned any of the same nonnucleophilic anions as mentioned with respect to the Z— of the general formula (ZI).

In general formula (ZI-4), the alkyl groups represented by R₁₃, R₁₄ and R₁₅ may be linear or branched and preferably each have 1 to 10 carbon atoms. As such, there can be mentioned a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group and the like. Of these alkyl groups, a methyl group, an ethyl group, an n-butyl group, a t-butyl group and the like are preferred.

As the cycloalkyl groups represented by R₁₃, R₁₄ and R₁₅, there can be mentioned cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl, adamantyl and the like. Cyclopropyl, cyclopentyl, cyclohexyl and cyclooctyl are especially preferred.

The alkoxy groups represented by R₁₃ and R₁₄ may be linear or branched and preferably each have 1 to 10 carbon atoms. As such, there can be mentioned, for example, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group and the like. Of these alkoxy groups, a methoxy group, an ethoxy group, an n-propoxy group, an n-butoxy group and the like are preferred.

The alkoxycarbonyl group represented by R₁₃ and R₁₄ may be linear or branched and preferably has 2 to 11 carbon atoms. As such, there can be mentioned, for example, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group and the like. Of these alkoxycarbonyl groups, a methoxycarbonyl group, an ethoxycarbonyl group, an n-butoxycarbonyl group and the like are preferred.

As the groups with a cycloalkyl skeleton of a single ring or multiple rings represented by R₁₃ and R₁₄, there can be mentioned, for example, a cycloalkyloxy group of a single ring or multiple rings and an alkoxy group with a cycloalkyl group of a single ring or multiple rings. These groups may further have one or more substituents.

With respect to each of the cycloalkyloxy groups of a single ring or multiple rings represented by R₁₃ and R₁₄, the sum of carbon atoms thereof is preferably 7 or greater, more preferably in the range of 7 to 15. Further, having a cycloalkyl skeleton of a single ring is preferred. The cycloalkyloxy group of a single ring of which the sum of carbon atoms is 7 or greater is one composed of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally having a substituent selected from among an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group and the like, provided that the sum of carbon atoms thereof, including those of any optional substituent introduced in the cycloalkyl group, is 7 or greater.

As the cycloalkyloxy group of multiple rings of which the sum of carbon atoms is 7 or greater, there can be mentioned a norbornyloxy group, a tricyclodecanyloxy group, a tetracyclodecanyloxy group, an adamantyloxy group or the like.

With respect to each of the alkyloxy groups having a cycloalkyl skeleton of a single ring or multiple rings represented by R₁₃ and R₁₄, the sum of carbon atoms thereof is preferably 7 or greater, more preferably in the range of 7 to 15. Further, the alkoxy group having a cycloalkyl skeleton of a single ring is preferred. The alkoxy group having a cycloalkyl skeleton of a single ring of which the sum of carbon atoms is 7 or greater is one composed of an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with the above optionally substituted cycloalkyl group of a single ring, provided that the sum of carbon atoms thereof, including those of the substituents, is 7 or greater. For example, there can be mentioned a cyclohexylmethoxy group, a cyclopentylethoxy group, a cyclohexylethoxy group or the like. A cyclohexylmethoxy group is preferred.

As the alkoxy group having a cycloalkyl skeleton of multiple rings of which the sum of carbon atoms is 7 or greater, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like. Of these, a norbornylmethoxy group, a norbornylethoxy group and the like are preferred.

With respect to the alkyl group of the alkylcarbonyl group represented by R₁₄, there can be mentioned the same specific examples as mentioned above with respect to the alkyl groups represented by R₁₃ to R₁₅.

The alkylsulfonyl and cycloalkylsulfonyl groups represented by R₁₄ may be linear, branched or cyclic and preferably each have 1 to 10 carbon atoms. As such, there can be mentioned, for example, a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group and the like. Of these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group and the like are preferred.

Each of the groups may have one or more substituents. As such substituents, there can be mentioned, for example, a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group or the like.

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

The cyclic structure that may be formed by the bonding of the two R₁₅s to each other is preferably a 5- or 6-membered ring, especially a 5-membered ring (namely, a tetrahydrothiophene ring) formed by two bivalent R₁₅s in cooperation with the sulfur atom of general formula (ZI-4). The cyclic structure may condense with an aryl group or a cycloalkyl group. The bivalent R₁₅s may have substituents. As such substituents, there can be mentioned, for example, a hydroxyl group, a carboxyl group, a cyano group, a nitro group, an alkoxy group, an alkoxyalkyl group, an alkoxycarbonyl group, an alkoxycarbonyloxy group and the like as mentioned above. It is especially preferred for the R₁₅ of general formula (ZI-4) to be a methyl group, an ethyl group, the above-mentioned bivalent group allowing two R₁₅s to be bonded to each other so as to form a tetrahydrothiophene ring structure in cooperation with the sulfur atom of the general formula (ZI-4), or the like.

Each of R₁₃ and R₁₄ may have one or more substituents. As such substituents, there can be mentioned, for example, a hydroxyl group, an alkoxy group, an alkoxycarbonyl group, a halogen atom (especially, a fluorine atom) or the like.

In the formula, 1 is preferably 0 or 1, more preferably 1, and r is preferably 0 to 2.

Specific examples of the cation part in the structural unit (ZI-4) will be shown below.

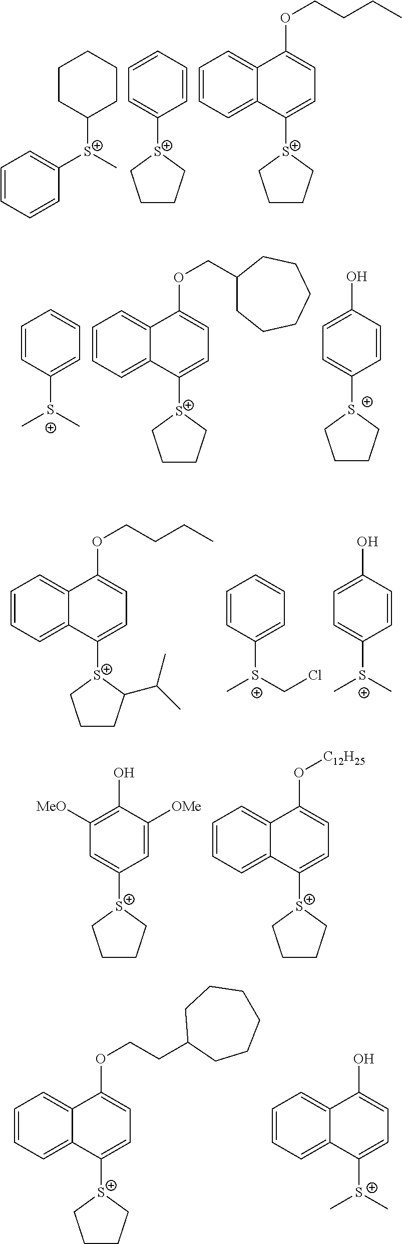

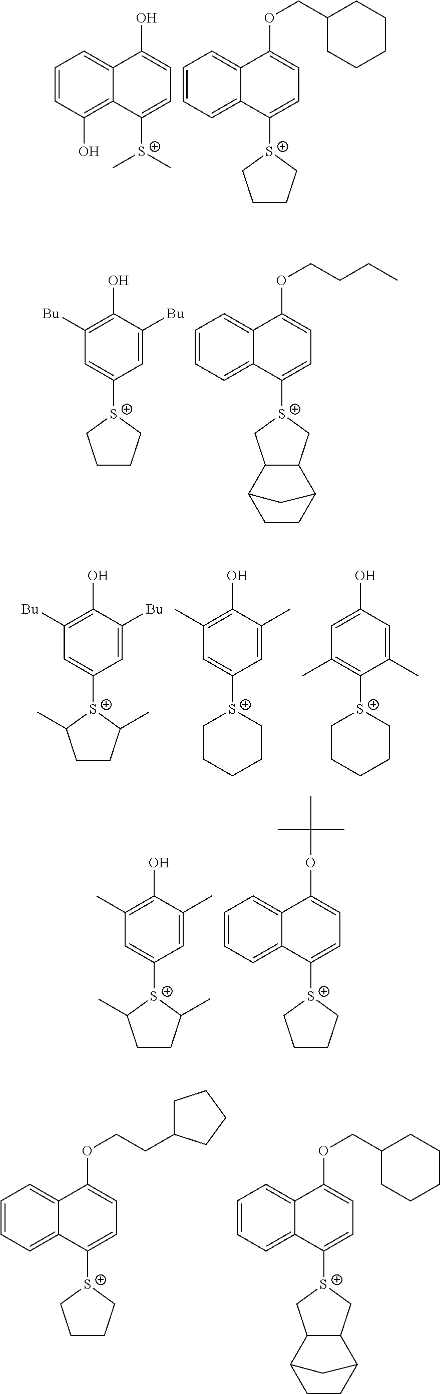

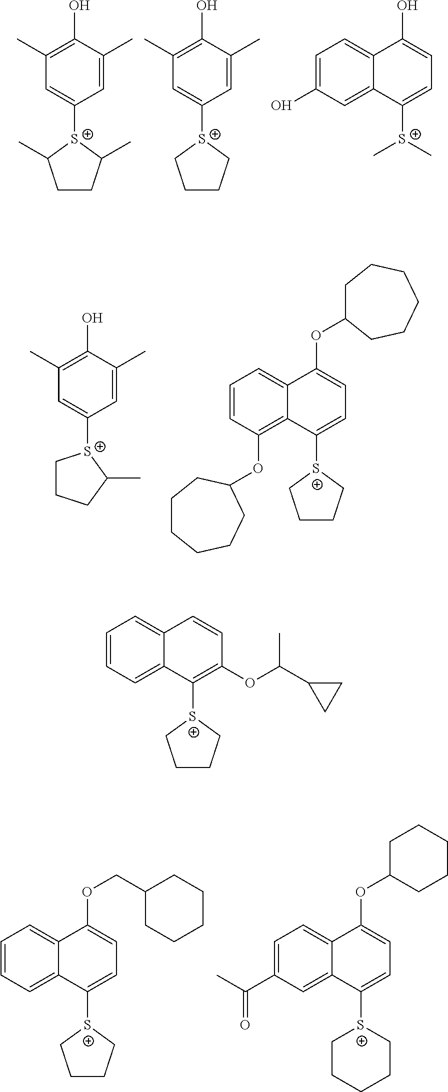

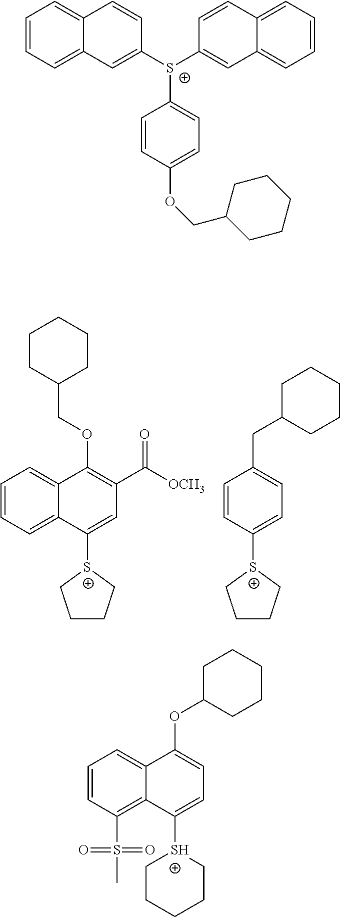

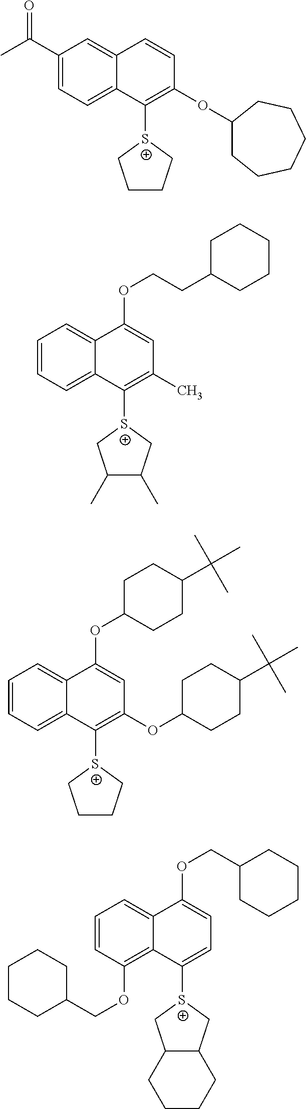

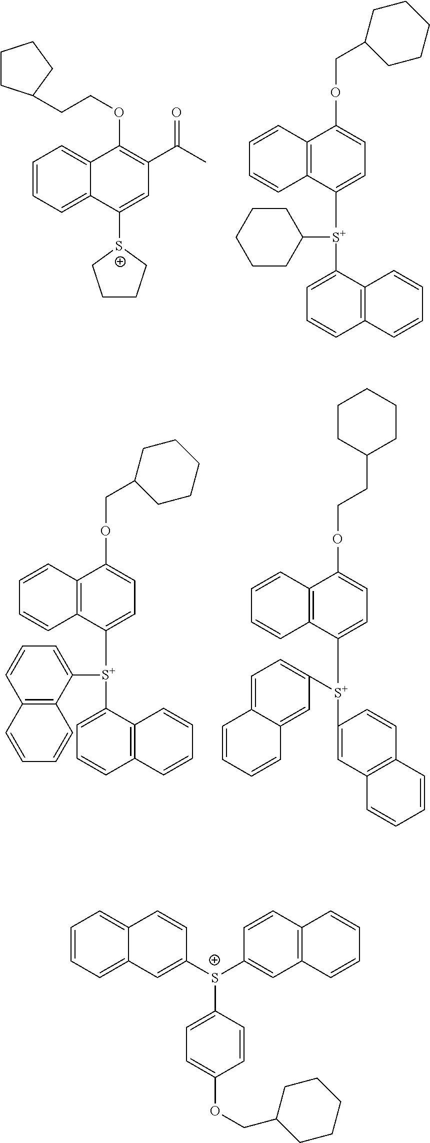

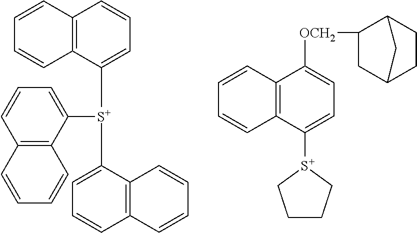

Now the general formulae (ZII) and (ZIII) will be described.

In general formulae (ZII) and (ZIII),

each of R₂₀₄ to R₂₀₇ independently represents an aryl group, an alkyl group or a cycloalkyl group.

The aryl group represented by each of R₂₀₄ to R₂₀₇ is preferably a phenyl group or a naphthyl group, more preferably a phenyl group. The aryl group may be one having a heterocyclic structure containing an oxygen atom, nitrogen atom, sulfur atom, etc. As the aryl group having a heterocyclic structure, a pyrrole residue, a furan residue, a thiophene residue, an indole residue, a benzofuran residue, and a benzothiophene residue can be exemplified.

As preferred alkyl groups and cycloalkyl groups represented by R₂₀₄ to R₂₀₇, a linear or branched alkyl group having 1 to 10 carbon atoms and a cycloalkyl group having 3 to 10 carbon atoms can be exemplified. As the alkyl group, for example, a methyl group, an ethyl group, a propyl group, a butyl group and a pentyl group can be exemplified. As the cycloalkyl group, for example, a cyclopentyl group, a cyclohexyl group and a norbornyl group can be exemplified.

The aryl group, alkyl group and cycloalkyl group represented by R₂₀₄ to R₂₀₇ may have one or more substituents. As a possible substituent on the aryl group, alkyl group and cycloalkyl group represented by R₂₀₄ to R₂₀₇, an alkyl group (having, for example, 1 to 15 carbon atoms), a cycloalkyl group (having, for example, 3 to 15 carbon atoms), an aryl group (having, for example, 6 to 15 carbon atoms), an alkoxy group (having, for example, 1 to 15 carbon atoms), a halogen atom, a hydroxy group, and a phenylthio group can be exemplified.

Z— represents a nonnucleophilic anion. As such, the same nonnucleophilic anions as mentioned with respect to the Z— in the general formula (ZI) can be exemplified.

As the acid generators, the compounds represented by the following general formulae (ZIV), (ZV) and (ZVI) can further be exemplified.

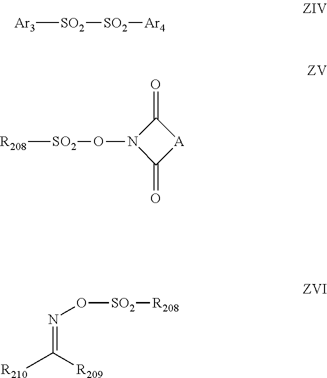

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the acid generators, the compounds represented by the general formulae (ZI) to (ZIII) are more preferred.

The acid generator is preferably a compound capable of generating an acid containing one sulfonic acid group or imido group. More preferably, the acid generator is a compound capable of generating a monovalent perfluoroalkanesulfonic acid, or a compound capable of generating a monovalent aromatic sulfonic acid substituted with a fluorine atom or a group containing a fluorine atom, or a compound capable of generating a monovalent imidic acid substituted with a fluorine atom or a group containing a fluorine atom. Further more preferably, the acid generator is a sulfonium salt of fluorinated alkanesulfonic acid, fluorinated benzenesulfonic acid, fluorinated imidic acid or fluorinated methide acid. With respect to useful acid generators, it is especially preferred for the generated acid to be a fluorinated alkanesulfonic acid, fluorinated benzenesulfonic acid or fluorinated imidic acid of −1 or below pKa. When these acid generators are used, the sensitivity can be enhanced.

Especially preferred examples of the acid generators will be shown below.

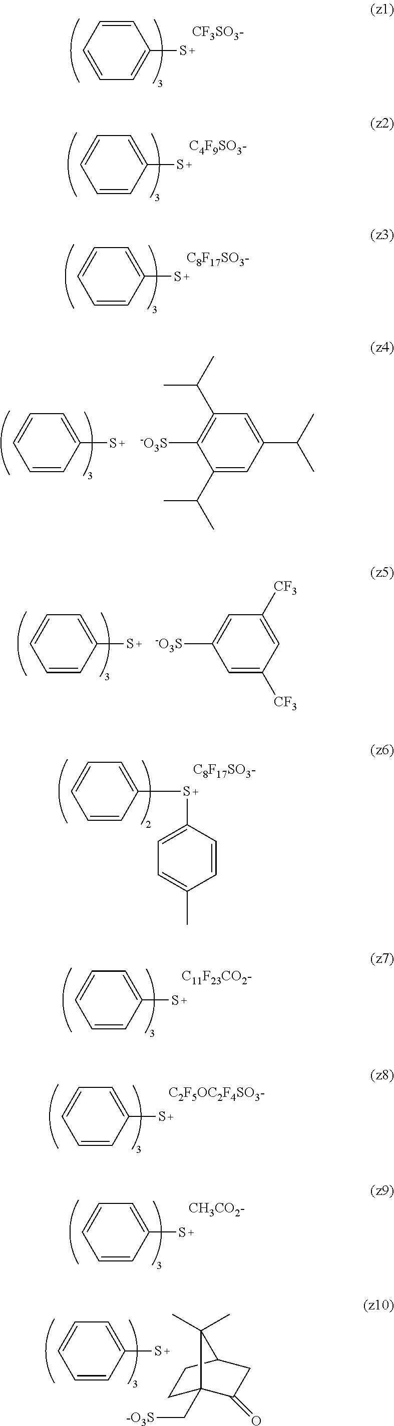

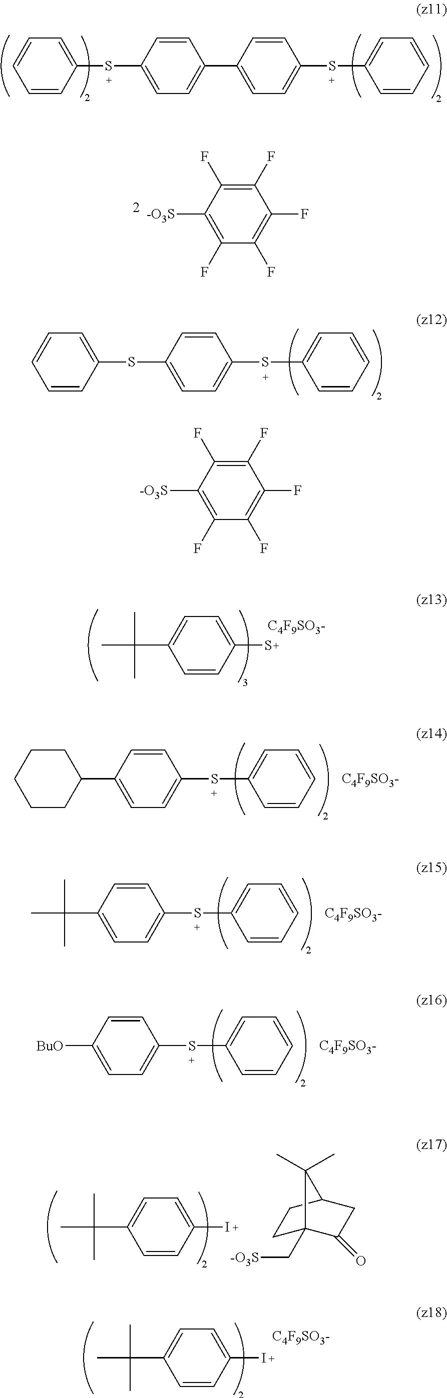

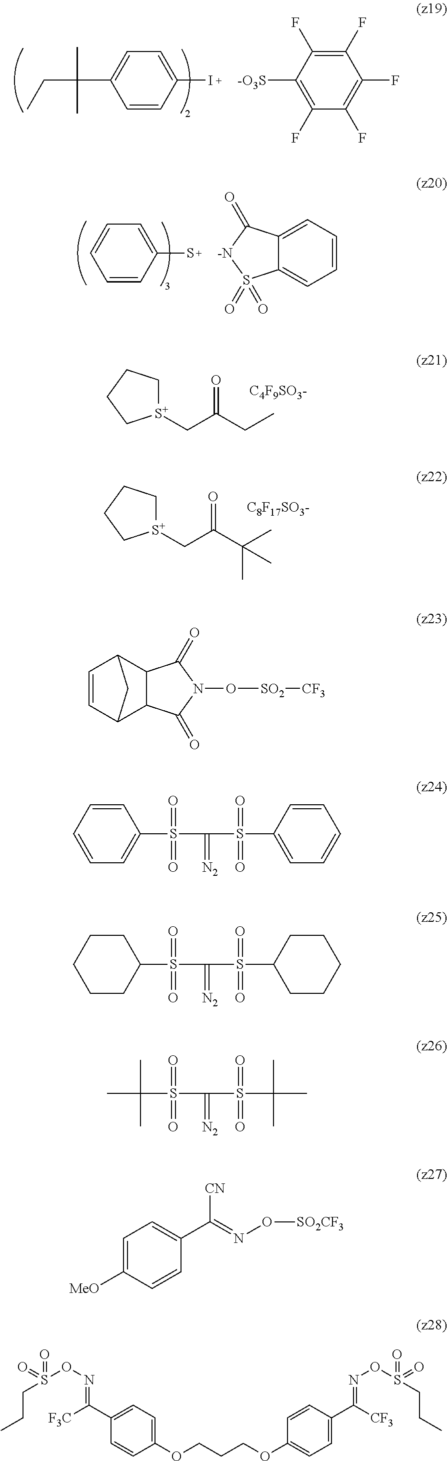

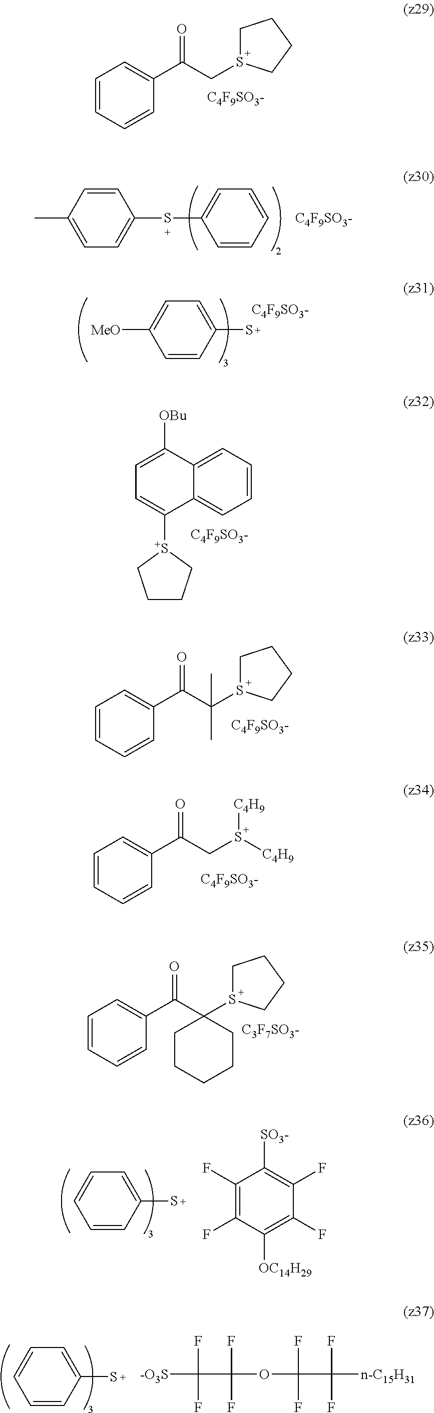

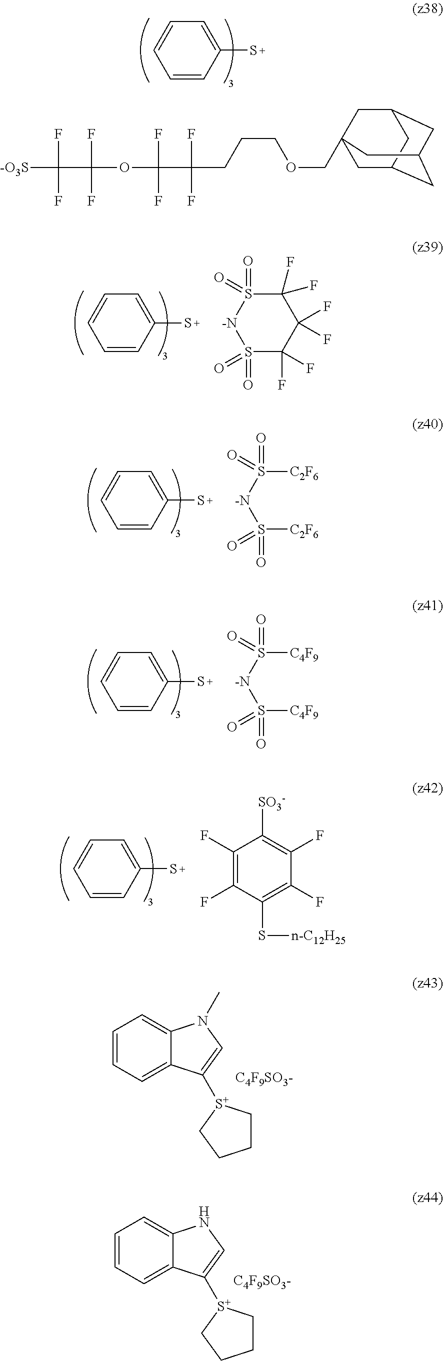

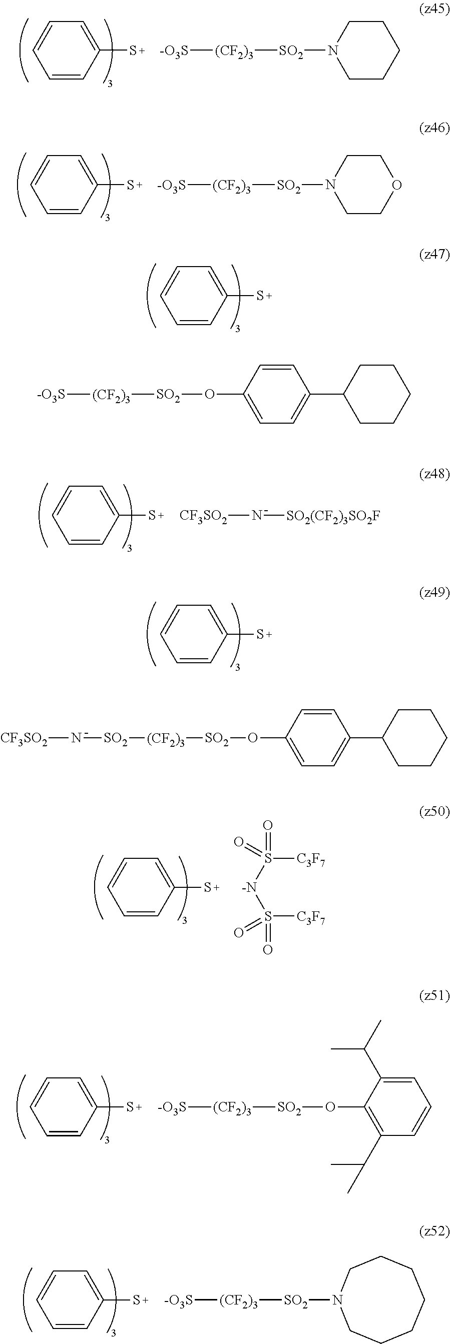

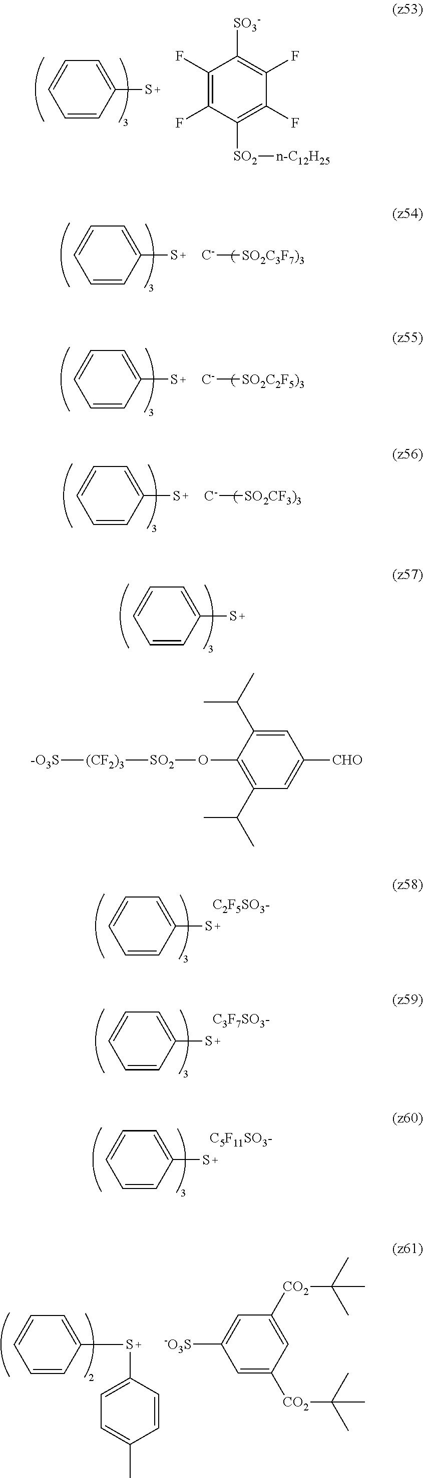

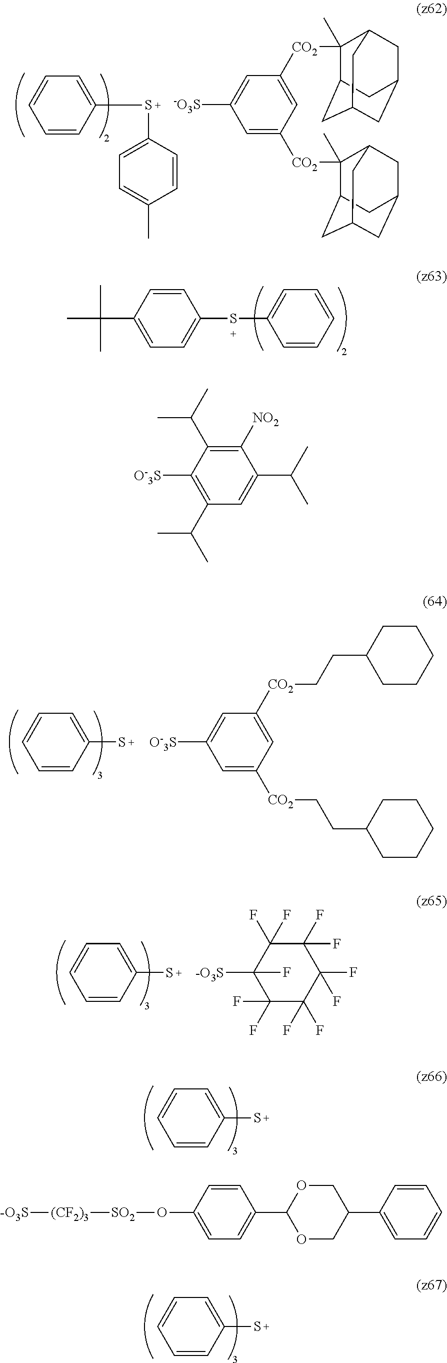

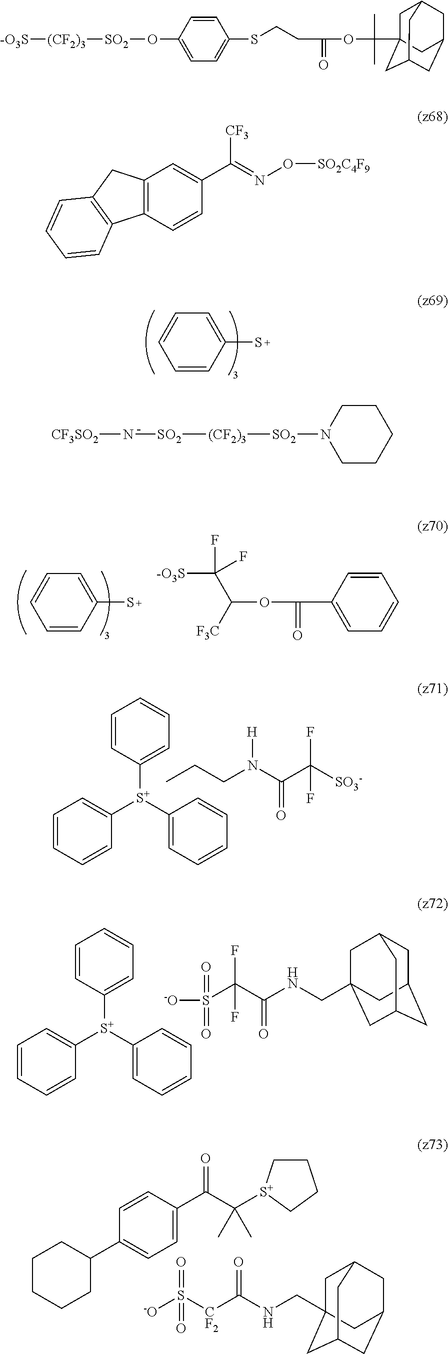

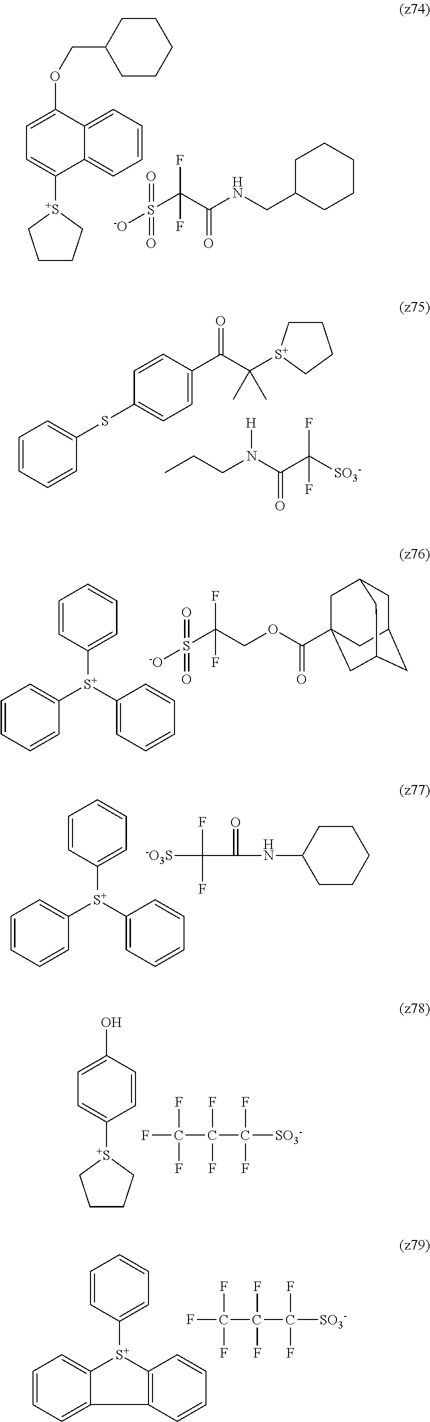

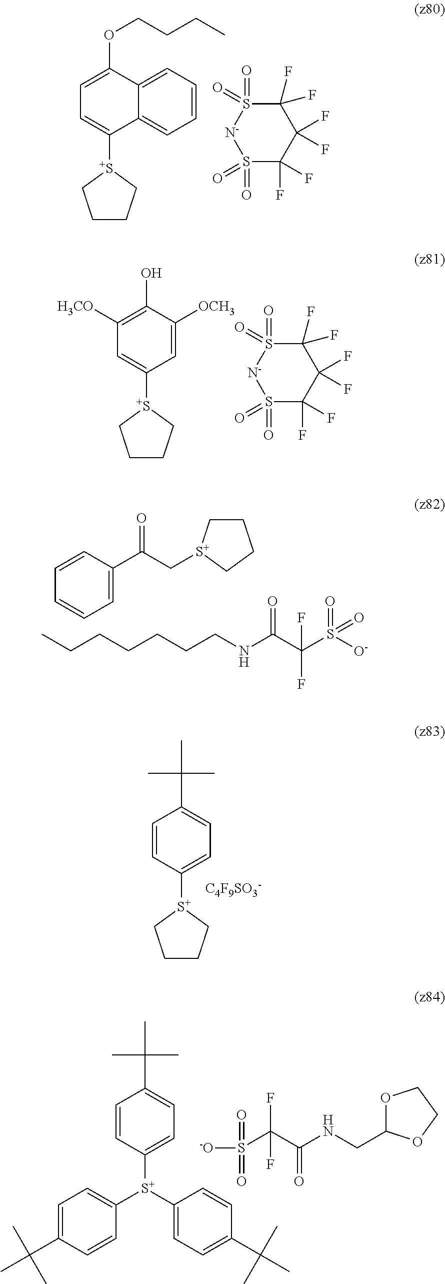

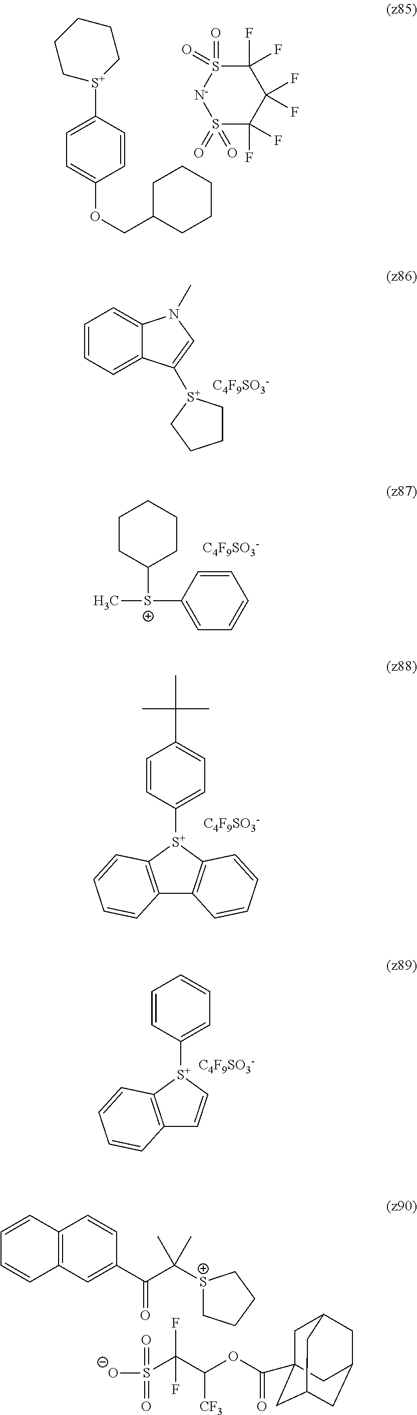

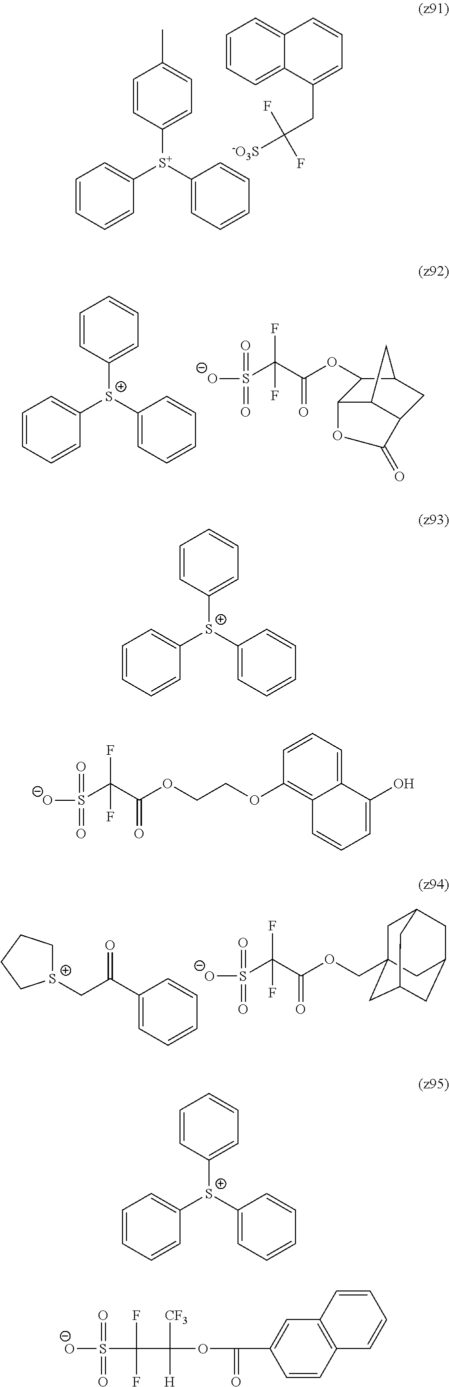

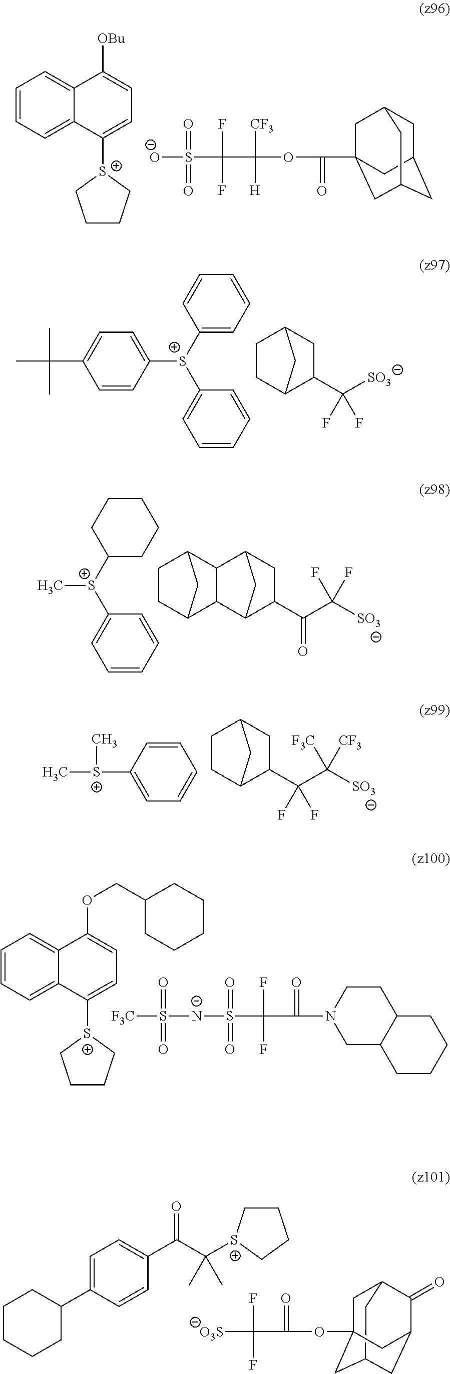

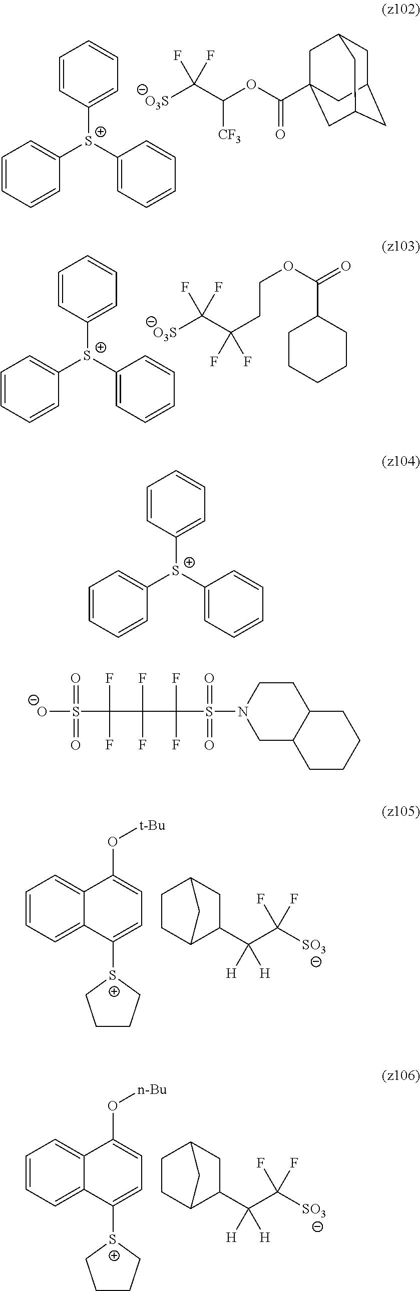

The acid generators can be used either individually or in combination of two or more kinds.

The content of the acid generator based on the total solids of the composition is preferably in the range of 0.1 to 30 mass %, more preferably 0.5 to 25 mass %, further more preferably 3 to 20 mass %, and especially preferably 3 to 15 mass %.

When the acid generator is represented by general formulae (ZI-3) or (ZI-4), the content thereof based on the total solids of the composition is preferably in the range of 5 to 20 mass %, more preferably 8 to 20 mass %, further more preferably 10 to 20 mass %, and especially preferably 10 to 15 mass %.

<Basic Compound>

The composition according to the present invention preferably contains a basic compound so as to decrease performance alteration over time from exposure to heating.

As preferred basic compounds, the compounds having the structures represented by the following formulae (A) to (E) can be exemplified.

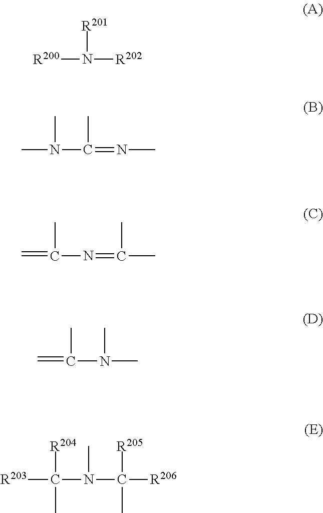

In the general formulae (A) and (E),

R²⁰⁰, R²⁰¹ and R²⁰² each independently represents a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded to each other to form a ring.

R²⁰³, R²⁰⁴, R²⁰⁵ and R²⁰⁶ each independently represents an alkyl group having 1 to 20 carbon atoms.

With respect to the above alkyl group, as a preferred substituted alkyl group, an aminoalkyl group having 1 to 20 carbon atoms, a hydroxyalkyl group having 1 to 20 carbon atoms, and a cyanoalkyl group having 1 to 20 carbon atoms can be exemplified.

More preferably, the alkyl groups are unsubstituted.

As preferred compounds, guanidine, aminopyrrolidine, pyrazole, pyrazoline, piperazine, aminomorpholine, aminoalkylmorpholine and piperidine can be exemplified. As more preferred compounds, those with an imidazole structure, a diazabicyclo structure, an onium hydroxide structure, an onium carboxylate structure, a trialkylamine structure, an aniline structure or a pyridine structure, alkylamine derivatives having a hydroxy group and/or an ether bond, and aniline derivatives having a hydroxy group and/or an ether bond can be exemplified.

As the compounds with an imidazole structure, imidazole, 2,4,5-triphenylimidazole, benzimidazole, and 2-phenylbenzoimidazole can be exemplified.

As the compounds with a diazabicyclo structure, 1,4-diazabicyclo[2,2,2]octane, 1,5-diazabicyclo[4,3,0]non-5-ene, and 1,8-diazabicyclo[5,4,0]undec-7-ene can be exemplified.

As the compounds with an onium hydroxide structure, tetrabutylammonium hydroxide, triarylsulfonium hydroxide, phenacylsulfonium hydroxide, and sulfonium hydroxides having a 2-oxoalkyl group, such as triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide can be exemplified.

As the compounds with an onium carboxylate structure, those having a carboxylate at the anion moiety of the compounds with an onium hydroxide structure, such as acetate, adamantane-1-carboxylate, and perfluoroalkyl carboxylate can be exemplified.

As the compounds with a trialkylamine structure, tri(n-butyl)amine and tri(n-octyl)amine can be exemplified.

As the aniline compounds, 2,6-diisopropylaniline, N,N-dimethylaniline, N,N-dibutylaniline, and N,N-dihexylaniline can be exemplified.

As the alkylamine derivatives having a hydroxy group and/or an ether bond, ethanolamine, diethanolamine, triethanolamine, N-phenyldiethanolamine, and tris(methoxyethoxyethyl)amine can be exemplified.

s the aniline derivatives having a hydroxy group and/or an ether bond, N,N-bis(hydroxyethyl)aniline can be exemplified.

As preferred basic compounds, an amine compound having a phenoxy group, an ammonium salt compound having a phenoxy group, an amine compound having a sulfonic ester group, and an ammonium salt compound having a sulfonic ester group can further be exemplified.

In these compounds, it is preferred for at least one alkyl group to be bonded to a nitrogen atom. More preferably, an oxygen atom is contained in the chain of the alkyl group, thereby forming an oxyalkylene group. With respect to the number of oxyalkylene groups in each molecule, one or more is preferred, three to nine more preferred, and four to six further more preferred. Of these oxyalkylene groups, the groups of the formulae —CH₂CH₂O—, —CH(CH₃)CH₂O— and —CH₂CH₂CH₂O— are especially preferred.

As specific examples of these compounds, there can be mentioned, for example, the compounds (C1-1) to (C3-3) given as examples in section [0066] of US Patent Application Publication No. 2007/0224539 A.

The basic compounds described above can be used either individually or in combination.

The total amount of basic compound used based on the solid contents of the actinic ray-sensitive or radiation-sensitive resin composition is preferably in the range of 0.001 to 10 mass %, and more preferably 0.01 to 5 mass %.

The molar ratio of the total amount of acid generators to the total amount of basic compounds is preferably in the range of 2.5 to 300, more preferably 5.0 to 200 and further more preferably 7.0 to 150. When this molar ratio is extremely lowered, the possibility of sensitivity and/or resolution deterioration is invited. On the other hand, when the molar ratio is extremely raised, any pattern thickening might occur during the period between exposure and postbake.

<Low-Molecular Compound Containing a Group that is Cleaved when Acted on by an Acid and Configured to Increase its Basicity by the Cleavage>

The composition according to the present invention may further contain a low-molecular compound containing a group that is cleaved when acted on by an acid and configured to increase its basicity by the cleavage [hereinafter also referred to as “low-molecular compound (D)”].

The group that is cleaved when acted on by an acid is not particularly limited. However, an acetal group, a carbonate group, a carbamate group, a tertiary ester group, a tertiary hydroxyl group and a hemiaminal ether group are preferably used. A carbamate group and a hemiaminal ether group are especially preferred.

The molecular weight of the low-molecular compound (D) containing a group that is cleaved when acted on by an acid is preferably in the range of 100 to 1000, more preferably 100 to 700 and most preferably 100 to 500.

As the compound (D), an amine derivative containing a group that is cleaved when acted on by an acid being connected to a nitrogen atom is preferred.

The compound (D) may contain a carbamate group with a protective group, the carbamate group being connected to a nitrogen atom. The protective group contained in the carbamate group can be represented, for example, by the following formula (d-1).

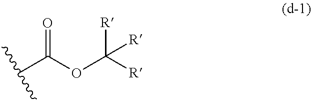

In the formula (d-1),

Each of R′s independently represents a hydrogen atom, a linear or branched alkyl group, a cycloalkyl group, an aryl group, an aralkyl group, or an alkoxyalkyl group. At least two of R′s may be connected to each other to form a ring.

Preferably, R′ represents a linear or branched alkyl group, a cycloalkyl group, or an aryl group. More preferably, R′ represents a linear or branched alkyl group, or a cycloalkyl group.

The compound (D) may have a structure in which any of the above-mentioned basic compounds are combined with the structure represented by general formula (d-1).

The compound (D) is especially preferred to be the one represented by general formula (A) below. Note that, the compound (D) may be any of the basic compounds described above as long as it is a low-molecular compound containing a group that is cleaved when acted on by an acid.

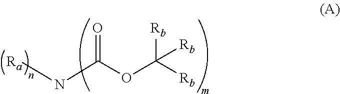

In the general formula (A), Ra represents a hydrogen atom, an alkyl group, a cycloalkyl group, an aryl group, or an aralkyl group. When n=2, two Ra's may be the same or different from each other, and may be connected to each other to form a bivalent heterocyclic hydrocarbon group (preferably having 20 or less carbon atoms) or its derivatives.

Each of Rb′s independently represents a hydrogen atom, an alkyl group, a cycloalkyl group, an aryl group, an aralkyl group, or an alkoxyalkyl group, with the proviso that when at least one of Rb′s are hydrogen atoms, at least one of the remainder represents a cyclopropyl group, 1-alkoxyalkyl group, or an aryl group.

At least two of Rb′s may be connected to each other to form a alicyclic hydrocarbon group, an aromatic hydrocarbon group, a heterocyclic hydrocarbon group, or their derivatives.

In the formula (A), n represents an integer of 0 to 2, m represents an integer of 1 to 3, and n+m=3.

In the formula (A), the alkyl group, the cycloalkyl group, the aryl group, and the aralkyl group represented by Ra and Rb may be substituted with a functional group such as a hydroxyl group, a cyano group, an amino group, a pyrrolidino group, a piperidino group, a morpholino group, and an oxo group; an alkoxy group; or a halogen atom. The same applies to the alkoxyalkyl group represented by Rb.

As the alkyl group, the cycloalkyl group, the aryl group, and the aralkyl group (these groups may be substituted with the above functional group, an alkoxy group, or a halogen atom) represented by Ra and/or Rb, the following groups can be exemplified:

a group derived from a linear or branched alkane such as methane, ethane, propane, butane, pentane, hexane, heptane, octane, nonane, decane, undecane, or dodecane; and the group derived from the alkane and substituted with one or more cycloalkyl groups such as a cyclobutyl group, a cyclopentyl group, or a cyclohexyl group;

a group derived from cycloalkane such as cyclobutane, cyclopentane, cyclohexane, cycloheptane, cyclooctane, norbornane, adamantane, or noradamantane; and the group derived from the cycloalkane and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from aromatic compound such as benzene, naphthalene, or anthracene; and the group derived from the atomatic compound and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from heterocyclic compound such as pyrrolidine, piperidine, morpholine, tetrahydrofuran, tetrahydropyrane, indole, indoline, quinoline, perhydroquinoline, indazole, or benzimidazole; the group derived from heterocyclic compound and substituted with one or more linear or branched alkyl group or a group derived from the aromatic compound;

a group derived from linear or branched alkane and substituted with a group derived from aromatic compound such as a phenyl group, a naphthyl group, or an anthracenyl group;

a group derived from cycloalkane and substituted with a group derived from aromatic compound such as a phenyl group, a naphthyl group, or an anthracenyl group; or

each of these groups substituted with a functional group such as a hydroroxyl group, a cyano group, an amino group, a pyrrolidino group, a piperidino group, a morpholino group, or an oxo group.

Further, as the bivalent heterocyclic hydrocarbon group (preferably having 1 to 20 carbon atoms) or its derivative, formed by mutual binding of Ra's, for example, the followings can be exemplified:

a group derived from heterocyclic compound such as pyrrolidine, piperidine, morpholine, 1,4,5,6-tetrahydropyrimidine, 1,2,3,4-tetrahydroquinoline, 1,2,3,6-tetrahydroquinoline, homopiperadine, 4-azabenzimidazole, benztriazole, 5-azabenztriazole, 1H-1,2,3-triazole, 1,4,7-triazacyclononane, tetrazole, 7-azaindole, indazole, benzimidazole, imidazo[1,2-a]pyridine, (1S,4S)-(+)2,5-azabicyclo[2.2.1]heptane, 1,5,7-triazabicyclo[4.4.0]dec-5-en, indole, indoline, 1,2,3,4-tetrahydroquinoxaline, perhydroquinoline, or 1,5,9-triazacyclododecane; or

the group derived from heterocyclic compound and substituted with at least one of a group derived from linear or branched alkane, a group derived from cycloalkane, a group derived from aromatic compound, a group derived from heterocyclic compound, or a functional group such as a hydroxyl group, a cyano group, an amino group, a pyrrolidino group, a piperidino group, a morpholino group, or an oxo group.

Particularly preferred examples of the compound (D) will be shown below, which however in no way limit the scope of the present invention.

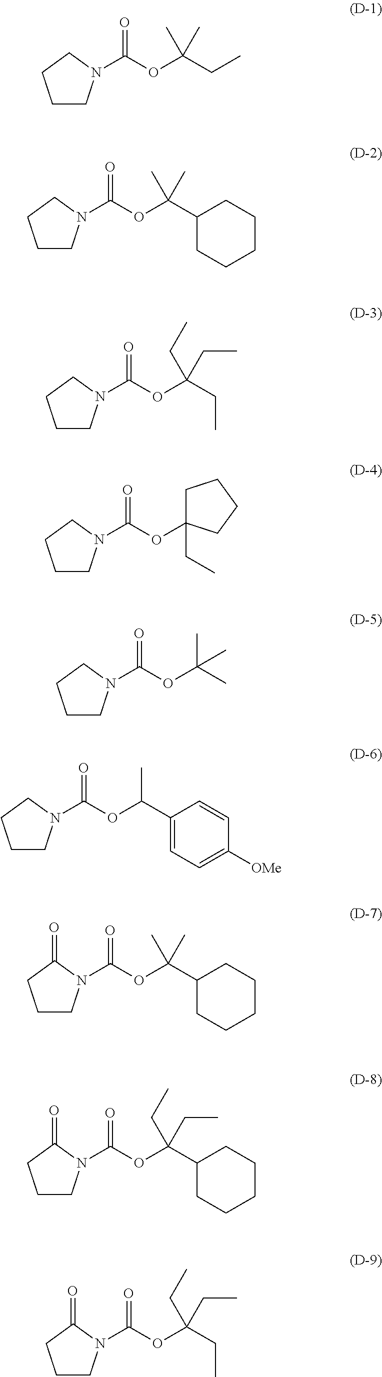

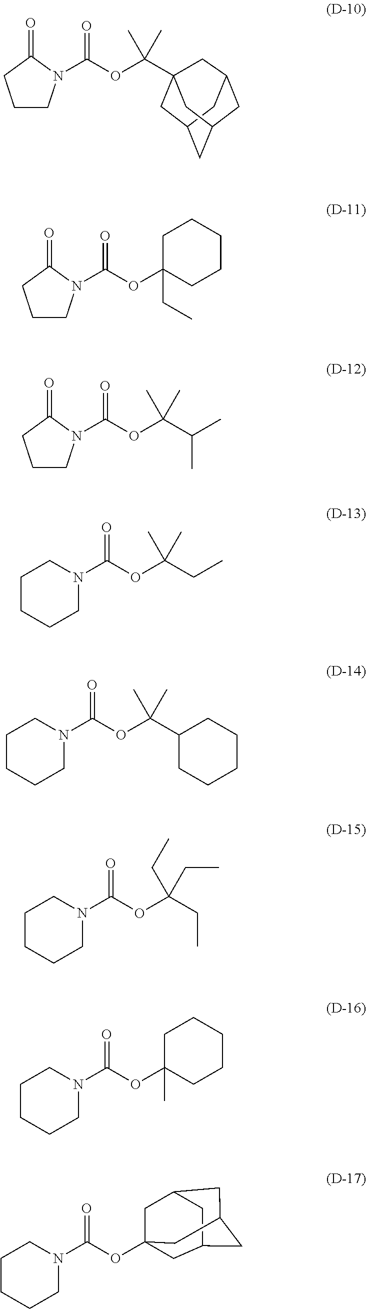

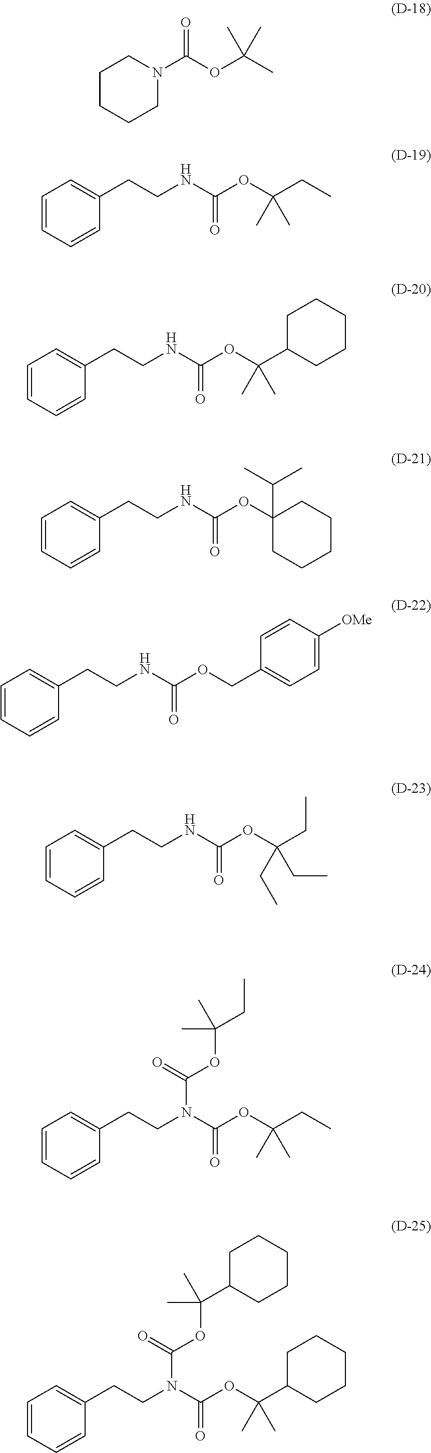

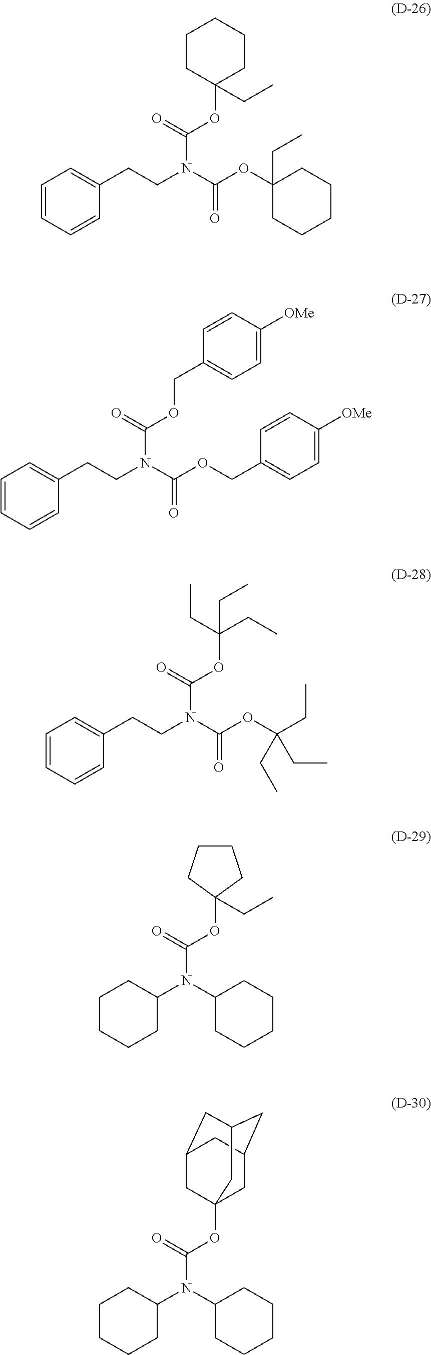 [SMILES: CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1 ; O=C(OC12CC3CC(CC(C3)C1)C2)N(C1CCCCC1)C1CCCCC1]

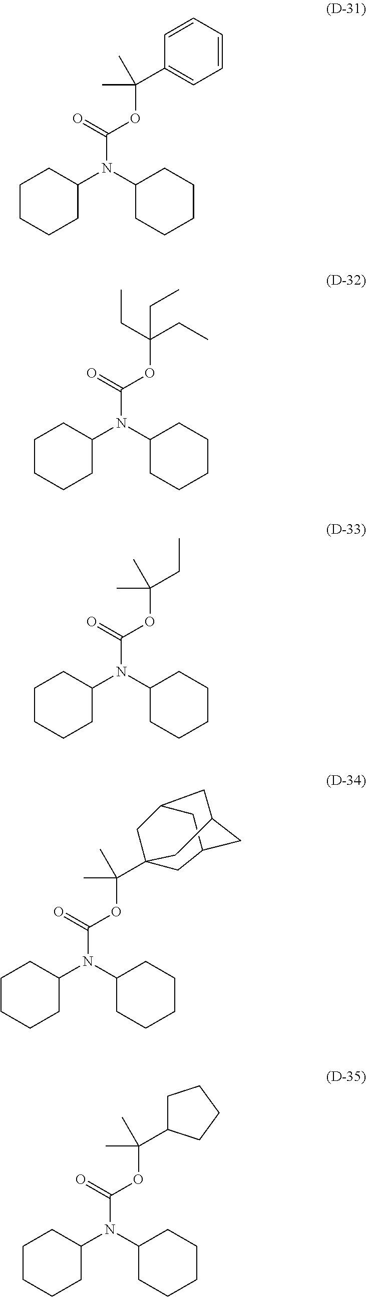 [SMILES: CC(C)(OC(=O)N(C1CCCCC1)C1CCCCC1)c1ccccc1 ; CCC(CC)(CC)OC(=O)N(C1CCCCC1)C1CCCCC1 ; CCC(C)(C)OC(=O)N(C1CCCCC1)C1CCCCC1 ; CC(C)(OC(=O)N(C1CCCCC1)C1CCCCC1)C12CC3CC(CC(C3)C1)C2 ; CC(C)(OC(=O)N(C1CCCCC1)C1CCCCC1)C1CCCC1]

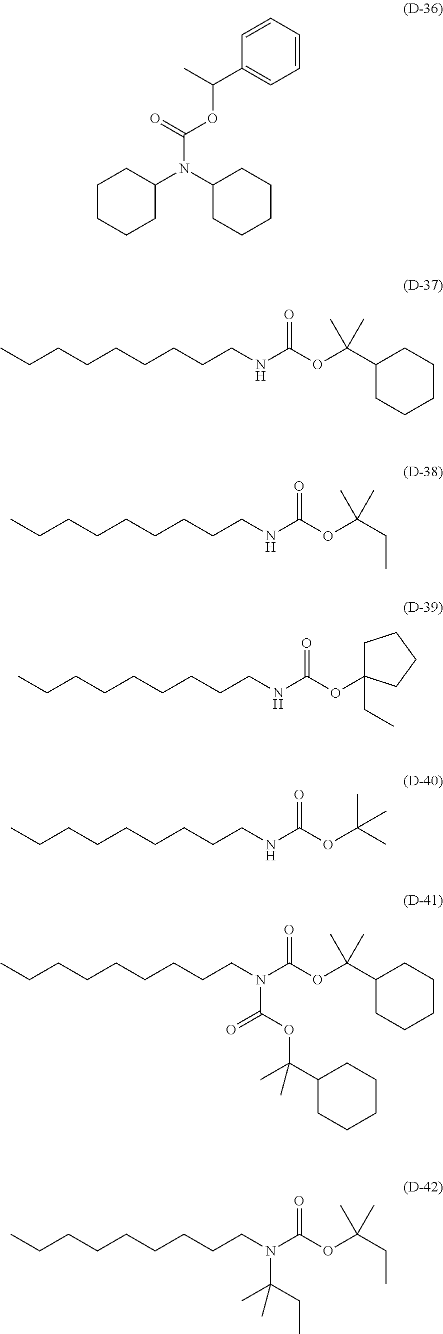

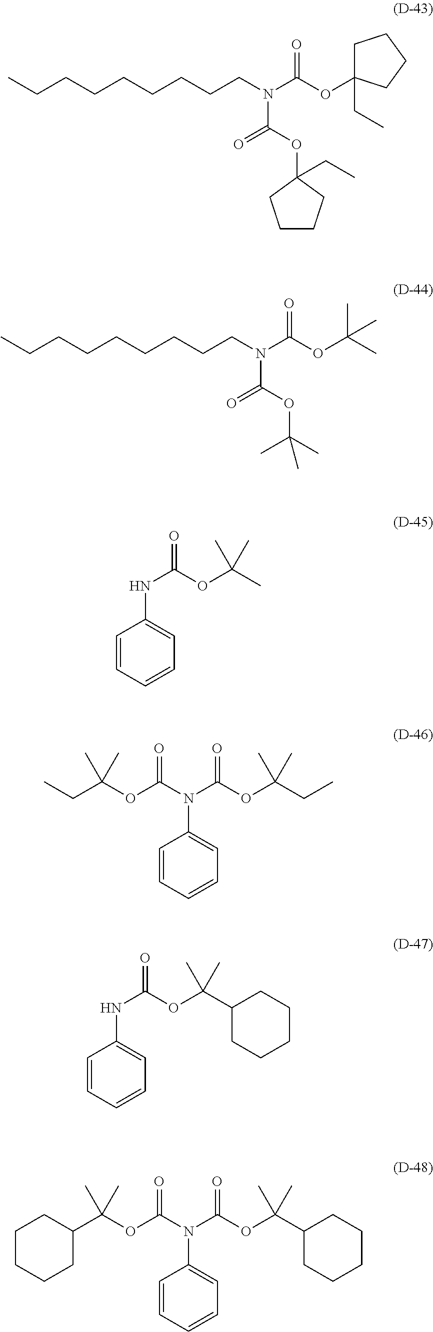

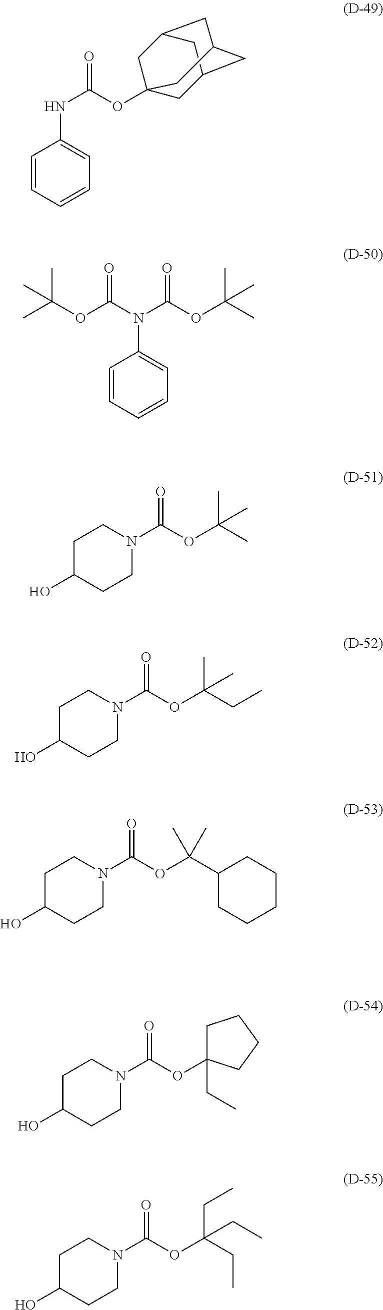

The compounds of general formula (A) can be synthesized by, for example, the method described in JP-A-2009-199021.

In the present invention, each of the low-molecular compounds (D) may be used alone, or two or more thereof may be used in a mixture.

In the present invention, the content of low-molecular compound (D), based on the total solids of the composition mixed with the above-mentioned basic compound, is generally in the range of 0.001 to 20 mass %, preferably 0.001 to 10 mass % and more preferably 0.01 to 5 mass %.

With respect to the ratio between acid generator and low-molecular compound (D) used in the composition, it is preferable that the molar ratio of acid generator/[low-molecular compound (D)+above-mentioned basic compound] be in the range of 2.5 to 300. Namely, the molar ratio is preferred to be 2.5 or higher from the viewpoint of sensitivity and resolution, and the molar ratio is preferred to be 300 or below from the viewpoint of inhibiting the lowering of resolution by thickening of resist pattern over time from exposure to baking treatment. The molar ratio of acid generator/[low-molecular compound (D)+above-mentioned basic compound] is more preferably in the range of 5.0 to 200, further more preferably 7.0 to 150.

<Solvent>

The composition according to the present invention may further contain solvent.

As the solvent, an organic solvent such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate and an alkyl pyruvate can be exemplified.

As alkylene glycol monoalkyl ether carboxylates, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate can be exemplified.

As alkylene glycol monoalkyl ethers, propylene glycol monomethyl ether, propylene glycol monoethyl ether, propylene glycol monopropyl ether, propylene glycol monobutyl ether, ethylene glycol monomethyl ether, and ethylene glycol monoethyl ether can be exemplified.

As alkyl lactates, methyl lactate, ethyl lactate, propyl lactate and butyl lactate can be exemplified.

As alkyl alkoxypropionates, ethyl 3-ethoxypropionate, methyl 3-methoxypropionate, methyl 3-ethoxypropionate, and ethyl 3-methoxypropionate can be exemplified.

As cyclolactones, β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone can be exemplified.

As optionally cyclized monoketone compounds, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone can be exemplified.

As alkylene carbonates, propylene carbonate, vinylene carbonate, ethylene carbonate, and butylene carbonate can be exemplified.

As alkyl alkoxyacetates, acetic acid 2-methoxyethyl ester, acetic acid 2-ethoxyethyl ester, acetic acid 2-(2-ethoxyethoxy)ethyl ester, acetic acid 3-methoxy-3-methylbutyl ester, and acetic acid 1-methoxy-2-propyl ester can be exemplified.

As alkyl pyruvates, methyl pyruvate, ethyl pyruvate and propyl pyruvate can be exemplified.

As a preferably usable solvent, there can be mentioned a solvent having a boiling point of 130° C. or higher measured under ordinary pressure. In particular, there can be mentioned cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate or propylene carbonate.

In the present invention, each of these solvents may be used alone, or two or more thereof may be used in combination.

In the present invention, a mixed solvent consisting of a mixture of a solvent having a hydroxyl group in its structure and a solvent having no hydroxyl group may be used as an organic solvent.

The solvent having a hydroxyl group and solvent having no hydroxyl group can appropriately be selected from among the compounds set forth above as examples.

The solvent having a hydroxyl group is preferably an alkylene group monoalkyl ether, an alkyl lactate or the like, more preferably propylene glycol monomethyl ether or ethyl lactate. The solvent having no hydroxyl group is preferably an alkylene glycol monoalkyl ether acetate, an alkyl alkoxypropionate, an optionally cyclized monoketone compound, a cyclolactone, an alkyl acetate or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

When employing a mixed solvent consisting of a mixture of a solvent having a hydroxy group in its structure and a solvent having no hydroxy group, the mass ratio between them is preferably in the range of 1/99 to 99/1, more preferably 10/90 to 90/10, and further more preferably 20/80 to 60/40.

The mixed solvent containing 50 mass % or more of a solvent having no hydroxy group is especially preferred from the viewpoint of uniform applicability.

It is preferred for the solvent to be a mixed solvent consisting of two or more solvents and to contain propylene glycol monomethyl ether acetate.

<Surfactant>

The composition according to the present invention may further contain one or more surfactants. As the surfactants, a fluorinated and/or siliconized surfactant (a fluorinated surfactant, a siliconized surfactant, or a surfactant containing both fluorine atom and silicon atom) or a combination of two or more thereof.

The composition according to the present invention when containing the above surfactant would, in the use of an exposure light source of 250 nm or below, especially 220 nm or below, realize favorable sensitivity and resolving power and produce a resist pattern with less adhesion and development defects.

As fluorinated and/or siliconized surfactants, there can be mentioned, for example, those described in section [0276] of US Patent Application Publication No. 2008/0248425. Further, as useful commercially available surfactants, fluorinated surfactants or siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS) can be exemplified. Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound, produced by a telomerization technique (also called a telomer process) or an oligomerization technique (also called an oligomer process). In particular, polymers each having a fluoroaliphatic group derived from such a fluoroaliphatic compound may be used as the surfactant. The fluorinated aliphatic compound can be synthesized by the process described in JP-A-2002-90991.

The polymer having a fluorinated aliphatic group is preferably a copolymer from a monomer having a fluorinated aliphatic group and a poly(oxyalkylene) acrylate and/or poly(oxyalkylene) methacrylate, in which copolymer may have an irregular distribution or may result from block copolymerization.

As the poly(oxyalkylene) group, a poly(oxyethylene) group, a poly(oxypropylene) group, and a poly(oxybutylene) group can be exemplified. Further, use can be made of a unit having alkylene groups of different chain lengths in a single chain, such as poly(oxyethylene-oxypropylene-oxyethylene block concatenation) or poly(oxyethylene-oxypropylene block concatenation).

Moreover, the copolymer from a monomer having a fluorinated aliphatic group and a poly(oxyalkylene) acrylate (or methacrylate) is not limited to two-monomer copolymers and may be a three or more monomer copolymer obtained by simultaneous copolymerization of two or more different monomers having a fluorinated aliphatic group, two or more different poly(oxyalkylene) acrylates (or methacrylates), etc.

For example, as a commercially available surfactant, there can be mentioned Megafac F178, F-470, F-473, F-475, F-476 or F-472 (produced by Dainippon Ink & Chemicals, Inc.). Further, there can be mentioned a copolymer from an acrylate (or methacrylate) having a C₆F₁₃ group and a poly(oxyalkylene) acrylate (or methacrylate), a copolymer from an acrylate (or methacrylate) having a C₆F₁₃ group, poly(oxyethylene) acrylate (or methacrylate) and poly(oxypropylene) acrylate (or methacrylate), a copolymer from an acrylate (or methacrylate) having a C₈F₁₇ group and a poly(oxyalkylene) acrylate (or methacrylate), a copolymer from an acrylate (or methacrylate) having a C₈F₁₇ group, poly(oxyethylene) acrylate (or methacrylate) and poly(oxypropylene) acrylate (or methacrylate), or the like.

Further, use may be made of surfactants other than the fluorinated and/or siliconized surfactants, described in section [0280] of US Patent Application Publication No. 2008/0248425.

These surfactants may be used either individually or in combination.

When the resist composition according to the present invention contains the surfactant, the total amount thereof used based on the total solids of the composition is preferably in the range of 0.0001 to 2 mass %, more preferably 0.0001 to 1.5 mass %, and most preferably 0.0005 to 1 mass %.

<Carboxylic Acid Onium Salt>

The composition according to the present invention may further contain a surfactant. Preferred carboxylic acid onium salt is a sulfonium salt and an iodonium salt. In particular, the especially preferred anion moiety thereof is a linear or branched alkylcarboxylate anion, and monocyclic or polycyclic cycloalkylcarboxylate anion each having 1 to 30 carbon atoms. A more preferred anion moiety is an anion of carboxylic acid wherein the alkyl group or the cycloalkyl group is partially or wholly fluorinated (hereinafter also called as fluorinated carboxylic acid anion). The alkyl or cycloalkyl chain may contain an oxygen atom. Accordingly, there would be achieved securement of the transparency in 220 nm or shorter light, enhancement of the sensitivity and resolving power, and improvement of the iso/dense dependency and exposure margin.

As the fluorinated carboxylic acid anion, any of the anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid can be exemplified.

When the composition according to the present invention contains the carboxylic acid onium salt, the total amount thereof used based on the total solids of the composition is preferably in the range of 0.1 to 20 mass %, more preferably 0.5 to 10 mass %, and most preferably 1 to 7 mass %.

<Dissolution Inhibiting Compound>

The composition according to the present invention may further contain a dissolution inhibiting compound. Here the “dissolution inhibiting compound” means compound having 3000 or less molecular weight that is decomposed by the action of an acid to increase the solubility in an alkali developer.

From the viewpoint of preventing lowering of the transmission at the wavelength of 220 nm or shorter, the dissolution inhibiting compound is preferably an alicyclic or aliphatic compound having an acid-decomposable group, such as any of cholic acid derivatives having an acid-decomposable group described in Proceeding of SPIE, 2724, 355 (1996). The acid-decomposable group and alicyclic structure can be the same as described earlier with respect to the resin (A).

When the composition according to the present invention is exposed to a KrF excimer laser or irradiated with electron beams, preferred use is made of one having a structure resulting from substitution of the phenolic hydroxy group of a phenol compound with an acid-decomposable group. The phenol compound preferably contains 1 to 9 phenol skeletons, more preferably 2 to 6 phenol skeletons.

When the composition according to the present invention contains the dissolution inhibiting compound, the total amount thereof used based on the total solids of the composition is preferably in the range of 3 to 50 mass %, and more preferably 5 to 40 mass %.

Specific examples of the dissolution inhibiting compound will be shown below.

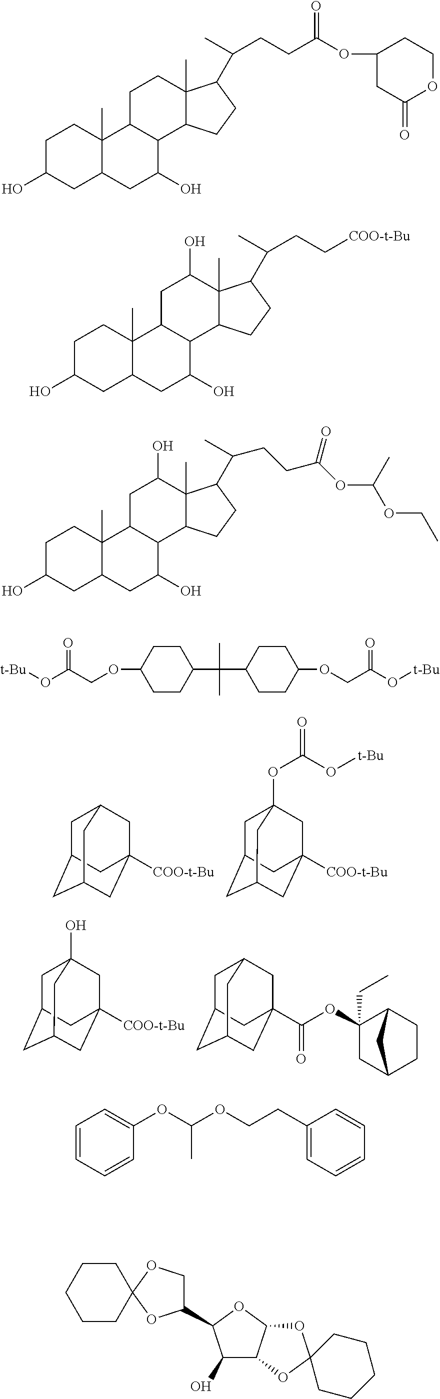

<Other Additives>

The composition according to the present invention may further contain a dye, a plasticizer, a photosensitizer, a light absorber, and/or a compound capable of increasing the solubility in a developer (for example, a phenolic compound of 1000 or less molecular weight or a carboxylated alicyclic or aliphatic compound), etc.

The above phenolic compound of 1000 or less molecular weight can be easily synthesized by persons of ordinary skill in the art while consulting the processes described in, for example, JP-As 4-122938 and 2-28531, U.S. Pat. No. 4,916,210, and EP 219294.

As the nonlimiting examples of the carboxylated alicyclic or aliphatic compound, a carboxylic acid derivative of steroid structure such as cholic acid, deoxycholic acid or lithocholic acid, an adamantanecarboxylic acid derivative, adamantanedicarboxylic acid, cyclohexanecarboxylic acid, and cyclohexanedicarboxylic acid can be exemplified.

<Method of Forming Pattern>

From the viewpoint of enhancement of resolving power, it is preferred that the positive photosensitive composition of the present invention be used with a coating thickness of 30 to 250 nm. More preferably, it is used with a coating thickness of 30 to 200 nm. This coating thickness can be attained by setting the solid content of the positive photosensitive composition within an appropriate range so as to cause the composition to have an appropriate viscosity, thereby improving the applicability and film forming property.

The total solid content of the positive photosensitive composition is generally in the range of 1 to 10 mass %, preferably 1 to 8.0 mass % and still preferably 1.0 to 7.0 mass %.

The composition of the present invention is used in such a manner that the above components are dissolved in a given organic solvent, preferably the above mixed solvent, and filtered and applied onto a given support in the following manner. The filter medium for the filtration preferably consists of a polytetrafluoroethylene, polyethylene or nylon having a pore size of 0.1 μm or less, especially 0.05 μm or less and still more preferably 0.03 μm or less.

For example, the composition is applied onto a substrate, such as one for use in the production of precision integrated circuit elements (e.g., silicon/silicon dioxide coating), by appropriate application means, such as a spinner or coater, and dried to thereby form a resist film.

The resist film is exposed through a given mask to actinic rays or radiation, preferably baked (heated), and developed and rinsed. Accordingly, a desirable pattern can be obtained.

As the actinic rays or radiation, there can be mentioned infrared rays, visible light, ultraviolet rays, far ultraviolet rays, X-rays, electron beams or the like. Among them, preferred use is made of far ultraviolet rays of especially 250 nm or less, more especially 220 nm or less and still more especially 1 to 200 nm wavelength, such as KrF excimer laser (248 nm), ArF excimer laser (193 nm) and F₂ excimer laser (157 nm), as well as X-rays, electron beams or the like. More preferred use is made of ArF excimer laser, F₂ excimer laser, EUV (13 nm) and electron beams.

Prior to the formation of a resist film, the substrate may be coated with an antireflection film.

As the antireflection film, use can be made of not only an inorganic film of titanium, titanium oxide, titanium nitride, chromium oxide, carbon, amorphous silicon or the like but also an organic film composed of a light absorber and a polymer material. Also, as the organic antireflection film, use can be made of commercially available organic antireflection films, such as the DUV30 Series and DUV40 Series produced by Brewer Science Inc. and AR-2, AR-3 and AR-5 produced by Shipley Co., Ltd.

In the development step, an alkali developer is used as follows. As the alkali developer for the composition, use can be made of any of alkaline aqueous solutions of an inorganic alkali, a primary amine, a secondary amine, a tertiary amine, an alcoholamine, a cycloamine, or the like.

Before the use of the above alkali developer, appropriate amounts of an alcohol and a surfactant may be added thereto.

The alkali concentration of the alkali developer is generally in the range of 0.1 to 20 mass %.

The pH value of the alkali developer is generally in the range of 10.0 to 15.0.

Before the use of the above alkaline aqueous solution, appropriate amounts of an alcohol and a surfactant may be added thereto.

Pure water can be used as the rinse liquid. Before the use, an appropriate amount of surfactant may be added thereto.

The development operation or rinse operation may be followed by the operation for removing any developer or rinse liquid adhering onto the pattern by the use of a supercritical fluid.

Exposure (liquid immersion exposure) may be carried out after filling the interstice between resist film and lens with a liquid (liquid immersion medium, liquid for liquid immersion) of refractive index higher than that of air at the time of irradiation with actinic rays or radiation. This would bring about an enhancement of resolving power.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any strain of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

Further, from the viewpoint of refractive index increase, use can be made of a medium of 1.5 or higher refractive index. Such a medium may be an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power.

The additive is preferably an aliphatic alcohol with a refractive index approximately equal to that of water, for example, methyl alcohol, ethyl alcohol, isopropyl alcohol or the like. The addition of an alcohol with a refractive index approximately equal to that of water is advantageous in that even when the alcohol component is evaporated from water to thereby cause a change of content concentration, the change of refractive index of the whole liquid can be minimized. On the other hand, when a substance being opaque in 193 nm rays or an impurity whose refractive index is greatly different from that of water is mixed in, the mixing would invite a strain of optical image projected on the resist film. Accordingly, it is preferred to use distilled water as the liquid immersion water. Furthermore, use may be made of pure water having been filtered through an ion exchange filter or the like.

Desirably, the electrical resistance of the water is 18.3 MQcm or higher, and the TOC (organic matter concentration) thereof is 20 ppb or below. Prior deaeration of the water is desired.

Raising the refractive index of the liquid for liquid immersion would enable an enhancement of lithography performance. From this viewpoint, an additive suitable for refractive index increase may be added to the water, or heavy water (D₂O) may be used in place of water.

### EXAMPLES

The present invention will be described in greater detail below with reference to the following Examples, which however in no way limit the scope of the present invention.

[Resin (A)]

### Synthetic Example 1

### Synthesis of Resin (A1)

In a nitrogen stream, 8.6 g of cyclohexanone was placed in a three-necked flask and heated at 80° C. A solution obtained by dissolving 9.8 g of 2-adamantylisopropyl methacrylate, 4.4 g of dihydroxyadamantyl methacrylate, 8.9 g of norbornane lactone methacrylate and further, 8 mol %, based on the monomers, of polymerization initiator V601 (produced by Wako Pure Chemical Industries, Ltd.) in 79 g of cyclohexanone was dropped thereinto over a period of 6 hours. After the completion of the dropping, reaction was continued at 80° C. for 2 hours. The thus obtained reaction mixture was allowed to stand still to cool and was dropped into a mixed liquid consisting of 800 ml/200 ml hexane/ethyl acetate over a period of 20 min. The thus precipitated powder was collected by filtration and dried, thereby obtaining 19 g of a desired resin (Al). The weight average molecular weight of the obtained resin in terms of standard polystyrene molecular weight was 8800 and the dispersity (Mw/Mn) thereof was 1.9.

In the same manner as in Synthetic Example 1, the following other resins (A2) to (A25) were synthesized.

The structures of the acid-decomposable resins (A) employed in the Examples are shown below. The following Table 1 indicates the molar ratios of individual repeating units (in order from the left in each structural formula), the weight average molecular weight (Mw) and the dispersity (Mw/Mn) with respect to each of the resins.

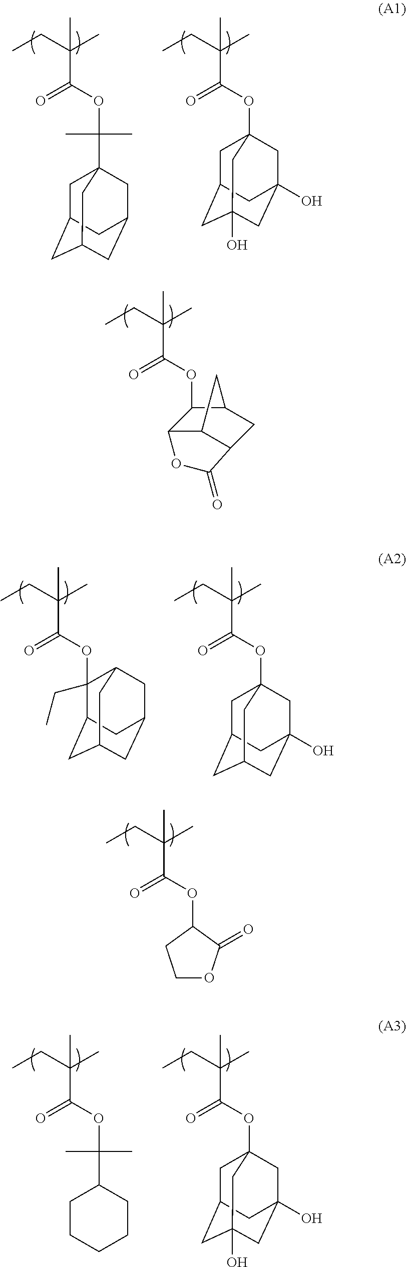

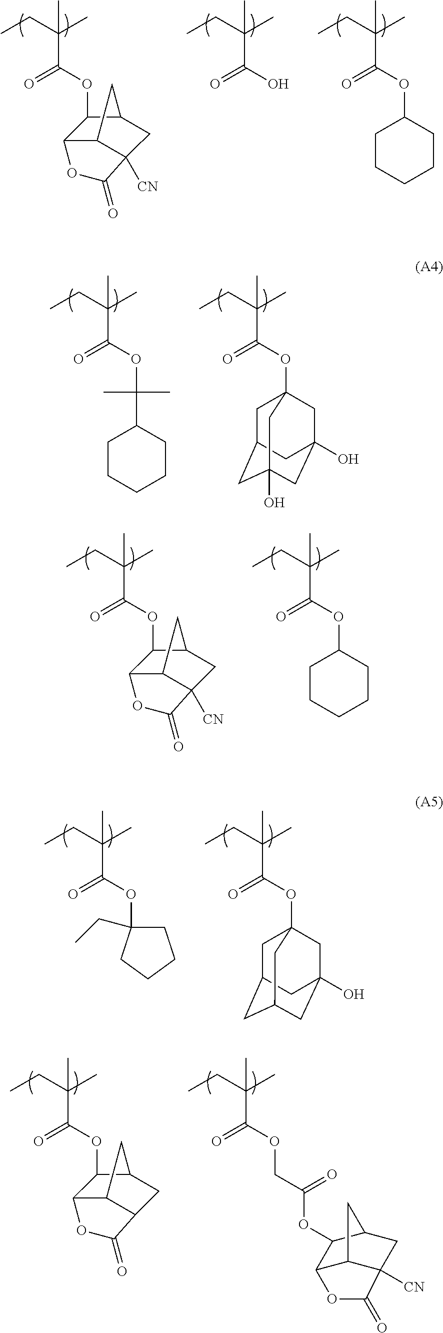

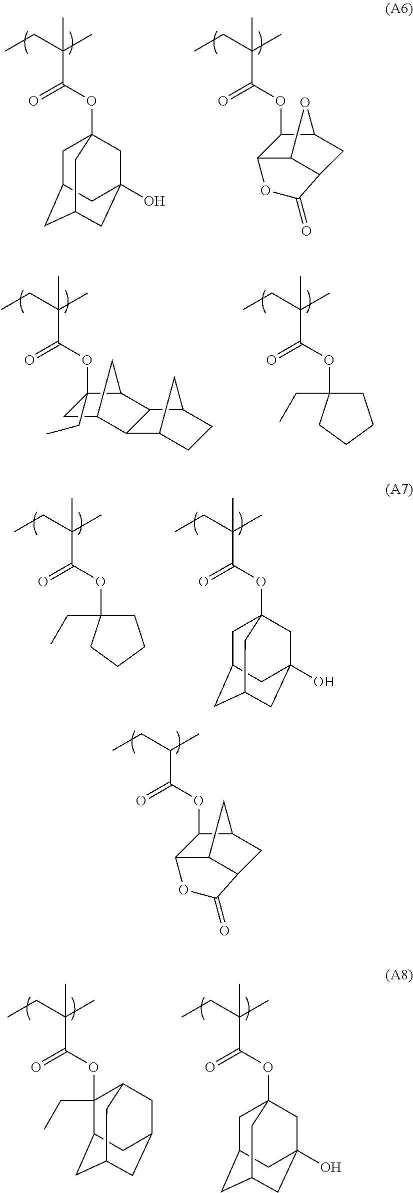

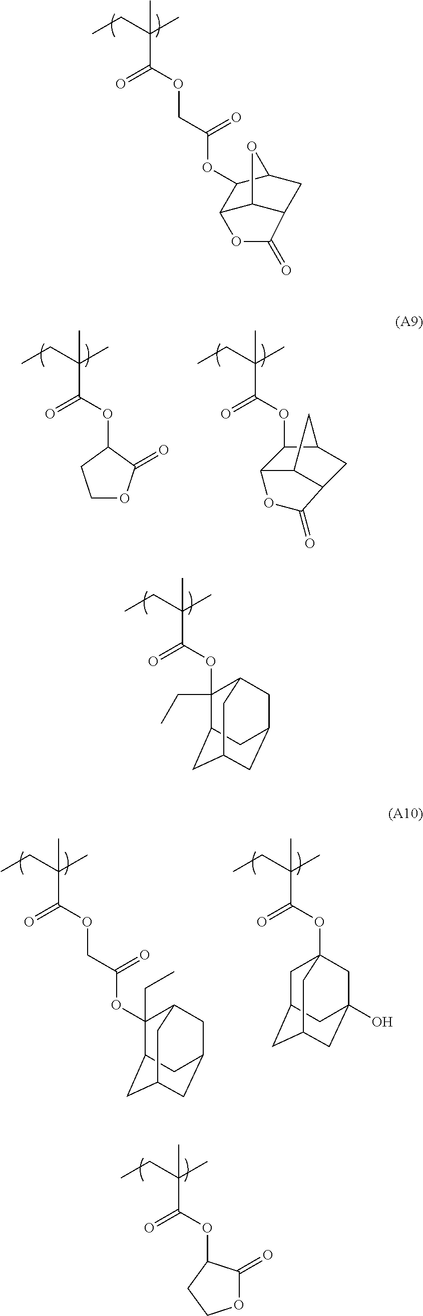

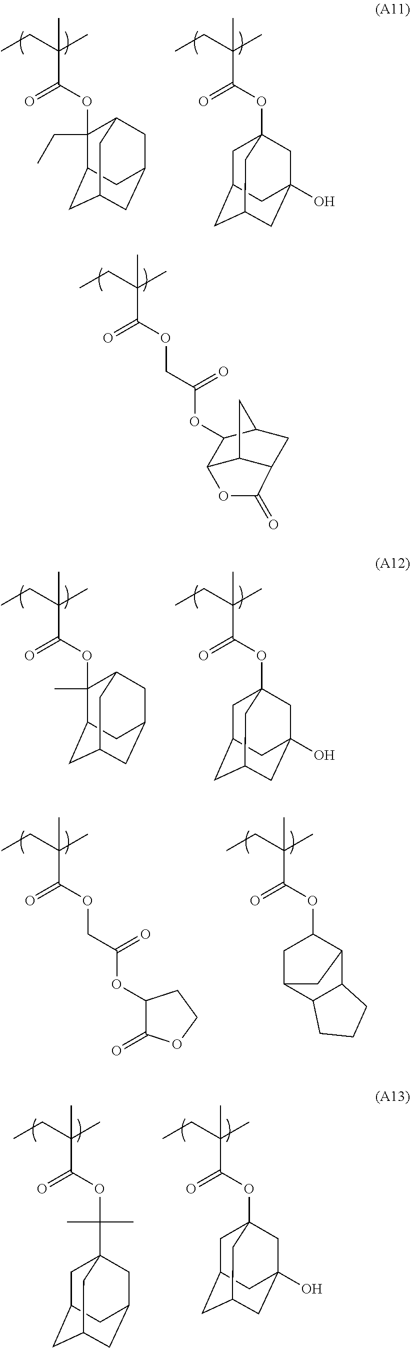

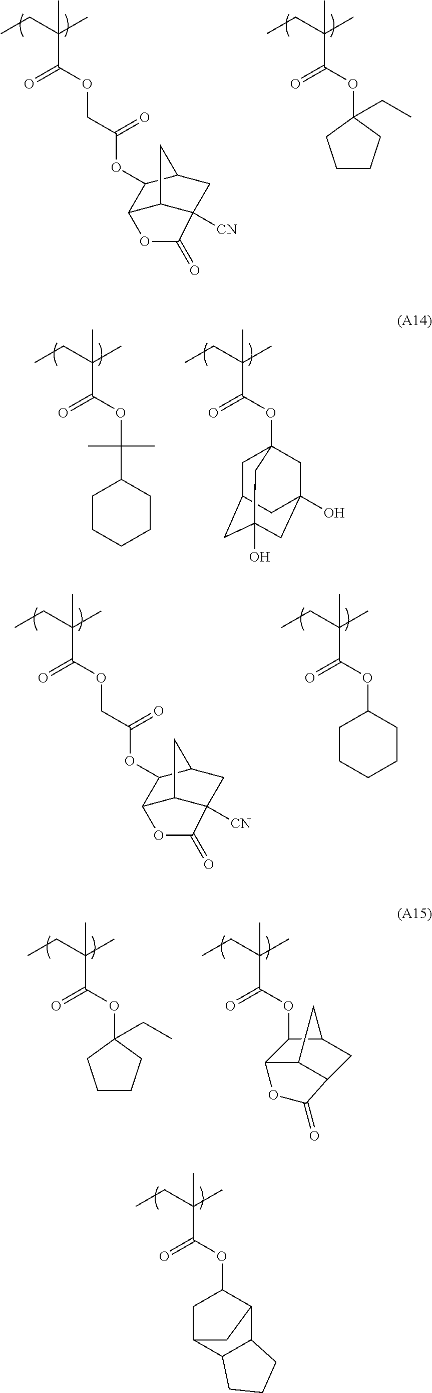

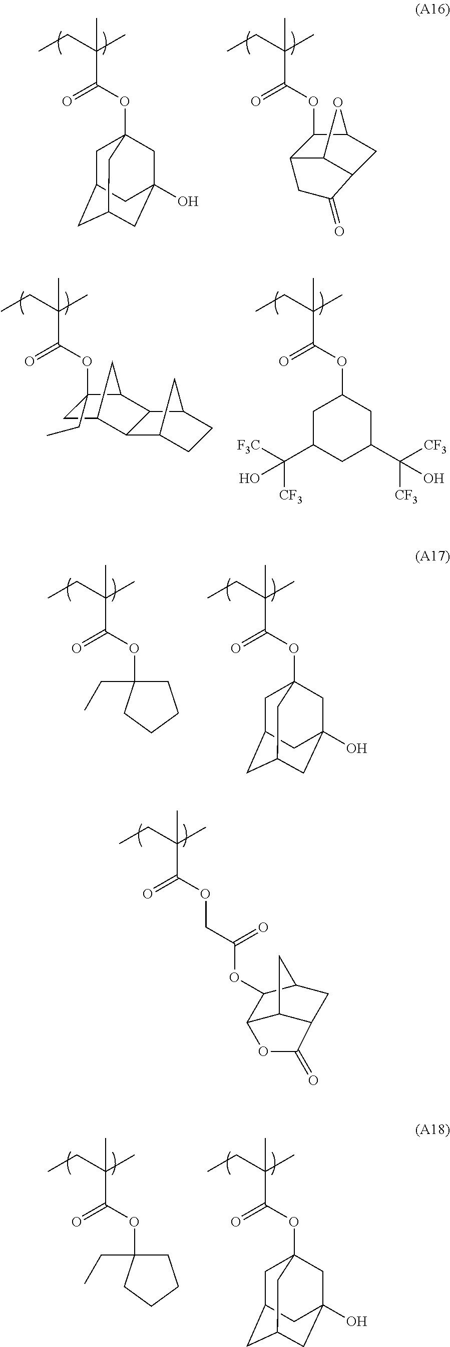

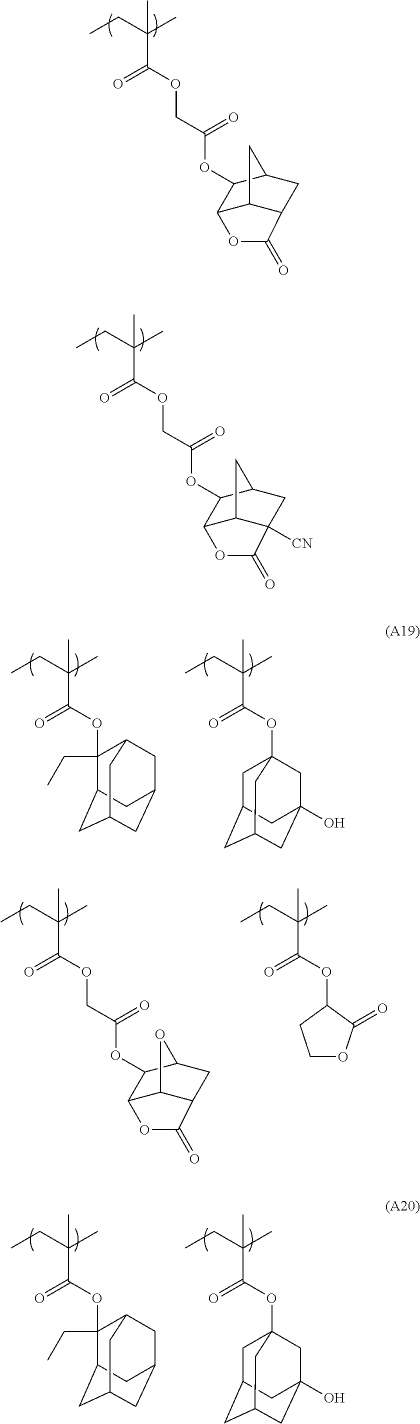

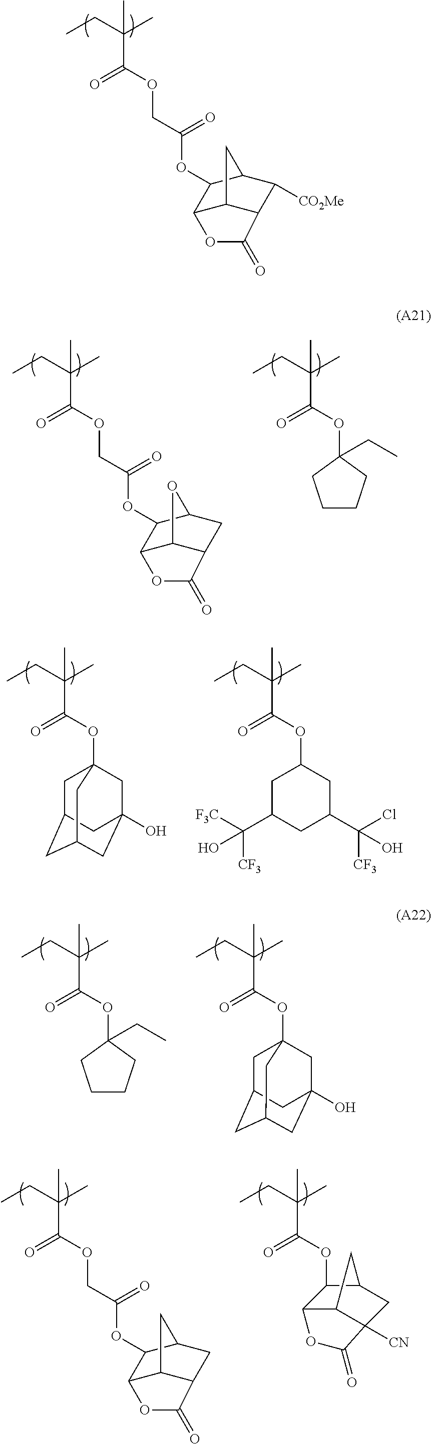

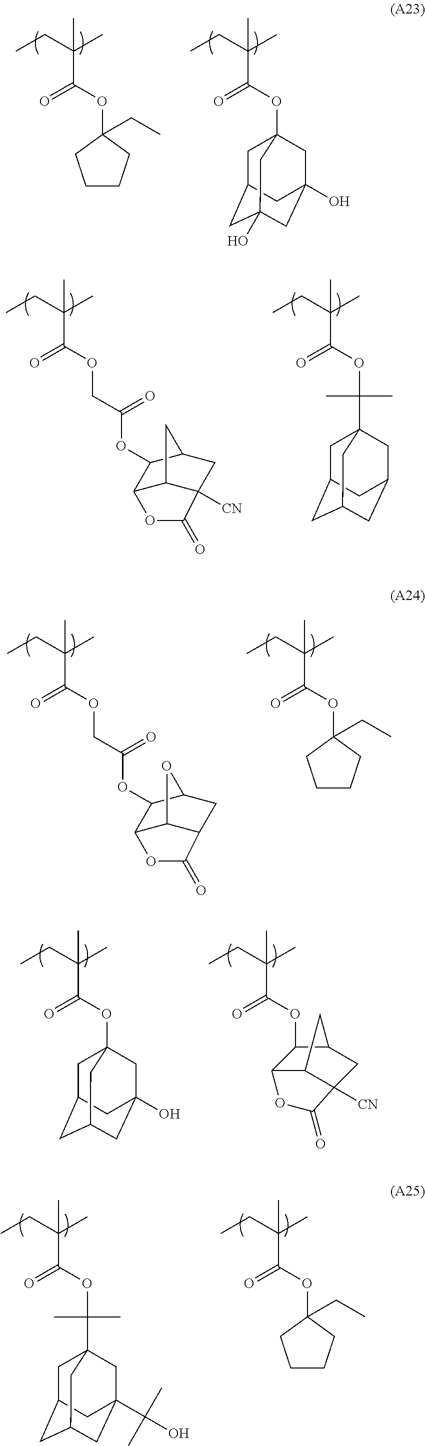

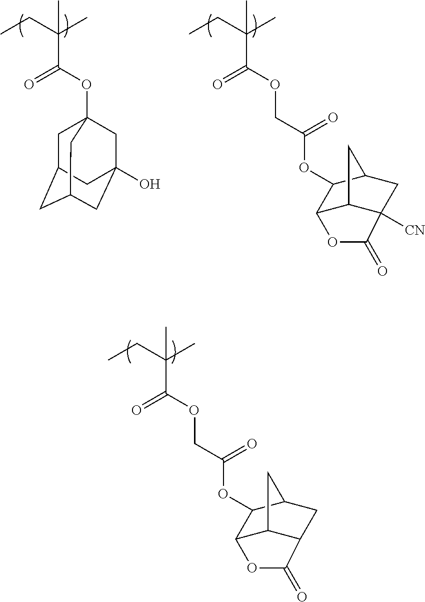

TABLE 1

| Resin (A) | Molar ratio | Mw | Mw/Mn |
|---|---|---|---|
| A1 | 39/18/43 | 8800 | 1.9 |
| A2 | 40/20/40 | 7000 | 1.6 |
| A3 | 40/10/35/5/10 | 10000 | 1.7 |
| A4 | 40/10/40/10 | 11000 | 1.8 |
| A5 | 40/15/20/25 | 8500 | 1.6 |
| A6 | 10/40/25/25 | 12000 | 1.8 |
| A7 | 50/20/30 | 6500 | 1.6 |
| A8 | 40/10/50 | 8000 | 1.7 |
| A9 | 25/25/50 | 9000 | 1.8 |
| A10 | 50/10/40 | 11000 | 1.8 |
| A11 | 50/10/40 | 8000 | 1.7 |
| A12 | 40/10/40/10 | 7000 | 1.7 |
| A13 | 20/15/35/30 | 10000 | 1.7 |
| A14 | 45/10/35/10 | 8500 | 1.7 |
| A15 | 50/40/10 | 10000 | 1.6 |
| A16 | 10/40/40/10 | 9000 | 1.8 |
| A17 | 55/10/35 | 12000 | 1.8 |
| A18 | 40/15/20/25 | 9000 | 1.7 |
| A19 | 40/15/30/15 | 7500 | 1.6 |
| A20 | 40/15/45 | 8000 | 1.6 |
| A21 | 40/40/10/10 | 9500 | 1.8 |
| A22 | 35/15/25/25 | 10000 | 1.7 |
| A23 | 30/15/40/15 | 8000 | 1.6 |
| A24 | 25/35/15/25 | 9000 | 1.8 |
| A25 | 15/30/10/23/22 | 10000 | 1.7 |

[Resin (B)]

### Synthetic Example

### Synthesis of Monomer 1

The following monomer 1 was synthesized in accordance with the methods described in US 2010/0152400A, WO 2010/067905A, WO 2010/067898A, and the like.

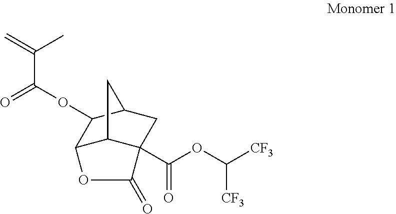 [SMILES: C=C(C)C(=O)OC1C2CC3C1OC(=O)C3(C(=O)OC(C(F)(F)F)C(F)(F)F)C2]

### Synthetic Example

### Synthesis of Monomer 2

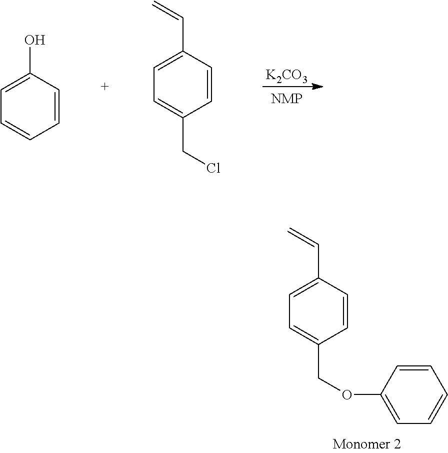

Phenol amounting to 10.0 g and 16.2 g of 4-(chloromethyl)styrene were dissolved in 57.0 g of N-methyl-2-pyrrolidone (NMP), and 17.6 g of potassium carbonate was added to the solution. The mixture was heated at 80° C. for 6 hours. The thus obtained reaction liquid was poured into 600 ml of water. The resultant deposit was collected by filtration, and washed with hexane. Thus, 16.0 g of monomer 2 was obtained (yield 71.7%).

The following monomers 3 to 6 were synthesized in the same manner as described above, except that use was made of corresponding phenols.

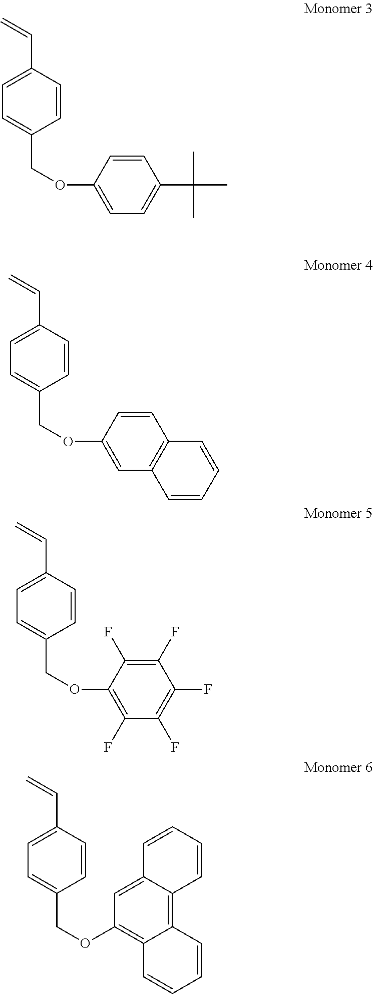

### Synthetic Example

### Synthesis of Monomer 7

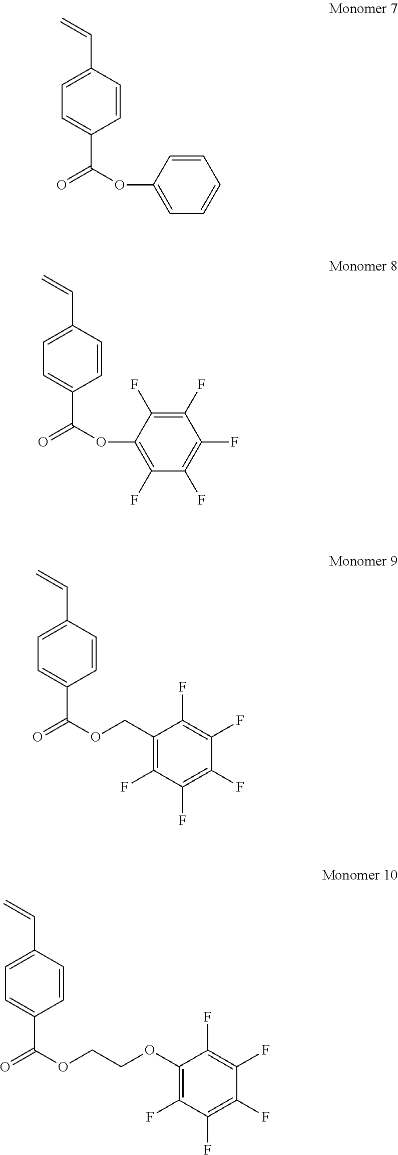 [SMILES: C=Cc1ccc(C(=O)Oc2ccccc2)cc1 ; C=Cc1ccc(C(=O)Oc2c(F)c(F)c(F)c(F)c2F)cc1 ; C=Cc1ccc(C(=O)OCc2c(F)c(F)c(F)c(F)c2F)cc1 ; C=Cc1ccc(C(=O)OCCOc2c(F)c(F)c(F)c(F)c2F)cc1]

Monomer 7 was synthesized by the method described in Organic Letters, 2008, vol. 10, No. 15, p. 3207-3210. Monomers 8 to 10 were synthesized in the same manner as described above, except that use was made of corresponding phenols or alcohols.

### Synthetic Example

### Synthesis of Monomer 11

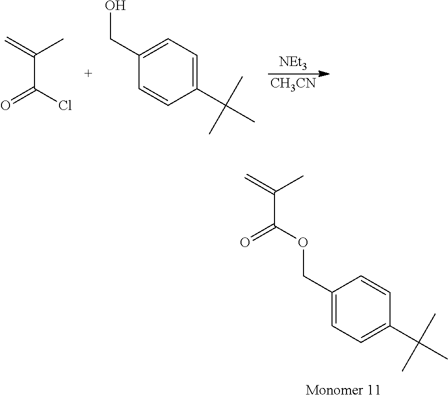

First, 10.0 g of 4-tert-butylbenzyl alcohol, 60.0 g of acetonitrile and 9.3 g of triethylamine were placed in a three-necked flask and agitated to thereby obtain a solution. The solution was cooled to 10° C. or below. While maintaining the reaction liquid at 10° C. or below, 12.2 g of methacryloyl chloride was dropped thereinto. After the completion of the dropping, the mixture was warmed to room temperature, and further agitated for 3 hours. A 1N aqueous HCl solution amounting to 150 ml was added to the reaction liquid, and extraction was performed with 200 ml of ethyl acetate. Thereafter, the extract was washed with a saturated aqueous solution of sodium hydrogen carbonate. Magnesium sulfate was added to the obtained organic phase, and filtered. Purification of the obtained concentrate was performed through a column chromatography. Thus, 10.5 g of monomer 11 was obtained (yield 74.5%).

The following monomers 12 to 15 were synthesized in the same manner as described above, except that use was made of corresponding phenols or alcohols.

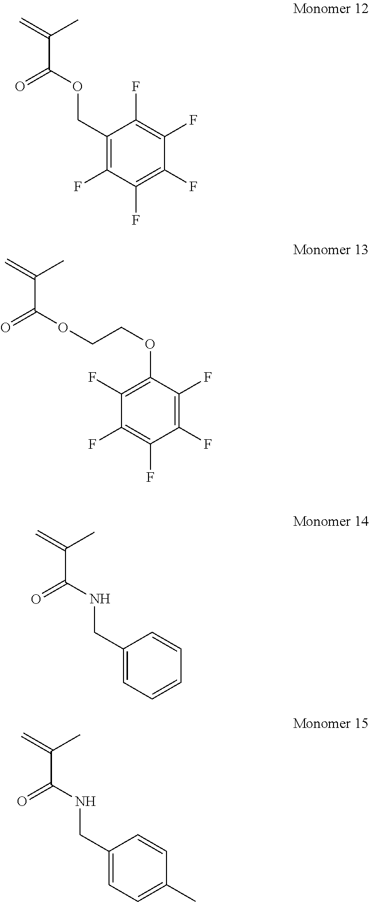 [SMILES: C=C(C)C(=O)OCc1c(F)c(F)c(F)c(F)c1F ; C=C(C)C(=O)OCCOc1c(F)c(F)c(F)c(F)c1F ; C=C(C)C(=O)NCc1ccccc1 ; C=C(C)C(=O)NCc1ccc(C)cc1]

### Synthetic Example 2

### Synthesis of Resin (B1)

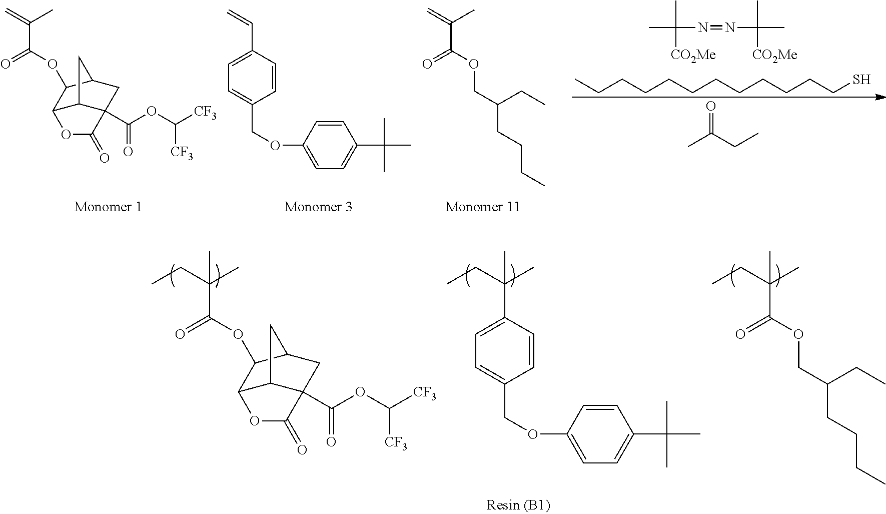

In a nitrogen gas stream, 2.10 g of methyl ethyl ketone was placed in a flask, and heated to 78° C. A solution obtained by dissolving 5.00 g of monomer 1, 0.72 g of monomer 3, 0.06 g of monomer 11, 0.10 g of polymerization initiator V-601 (produced by Wako Pure Chemical Industries, Ltd.) and 0.09 g or 1-dodecanethiol in 8.60 g of methyl ethyl ketone was dropped into the heated methyl ethyl ketone over a period of four hours. After the completion of dropping, reaction was continued at 78° C. for 2 hours. The thus obtained reaction liquid was allowed to stand still to cool, and was dropped into a liquid mixture of 93.50 g of heptane and 23.40 g of ethyl acetate. The thus precipitated powder was collected by filtration, and dried, thereby obtaining 3.80 g of resin (B-1) (yield 65.8%).

With respect to the obtained resin, the standard-polystyrene-equivalent weight average molecular weight was 11,700 and the dispersity (Mw/Mn) was 1.4.

The following resins (B2) to (B14), (B16) to (B21) and (BC1) were synthesized by the same way as above.

### Synthetic Example 3

### Synthesis of Resin (B15)

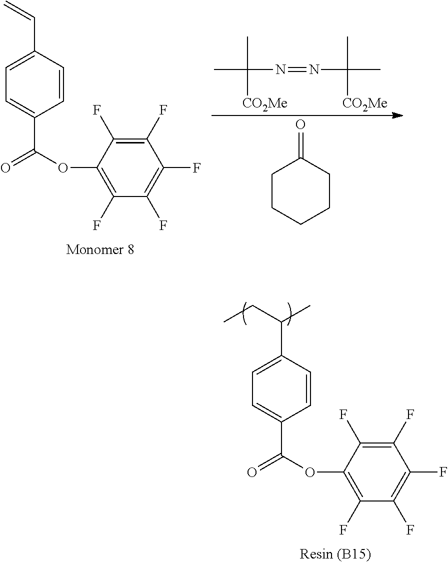

Monomer 8 amounting to 3.14 g and 5.80 g of cyclohexanone were placed in a flask, and the monomer was dissolved in the cyclohexanone. The solution was heated to 85° C. in a nitrogen gas stream, and 0.16 g of polymerization initiator V-601 (produced by Wako Pure Chemical Industries, Ltd.) was added to the heated solution. Reaction was continued for 6 hours. The thus obtained reaction liquid was allowed to stand still to cool and diluted with 6.56 g of cyclohexanone. The dilution was dropped into 109.90 g of methanol. The thus precipitated powder was collected by filtration, and dried, thereby obtaining 2.37 g of resin (B-15) (yield 75.4%). With respect to the obtained resin, the standard-polystyrene-equivalent weight average molecular weight was 23,300, and the dispersity (Mw/Mn) was 1.9.

The following resin (BC2) was synthesized in the same manner as described above.

The structures of the resins (B) employed in the Examples are shown below. The following Table 2 indicates the molar ratios of individual repeating units (in order from the left in each structural formula), the weight average molecular weight (Mw) and the dispersity (Mw/Mn) with respect to each of the resins.

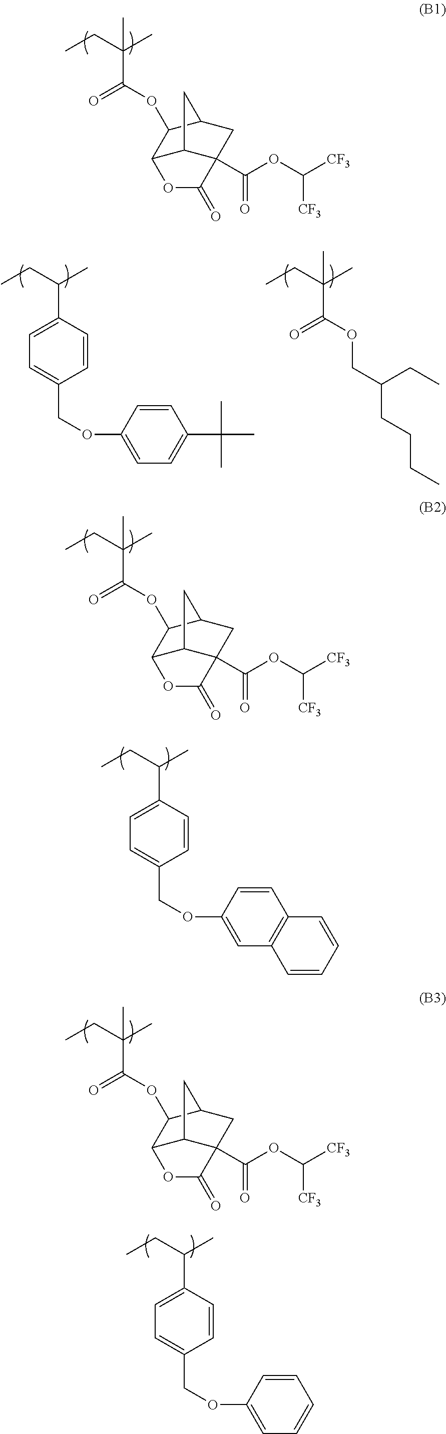

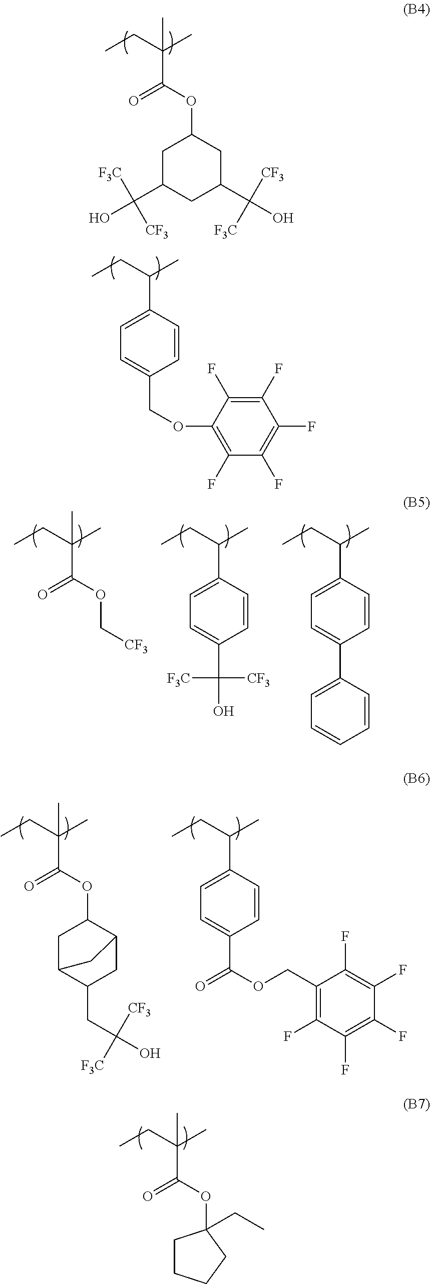

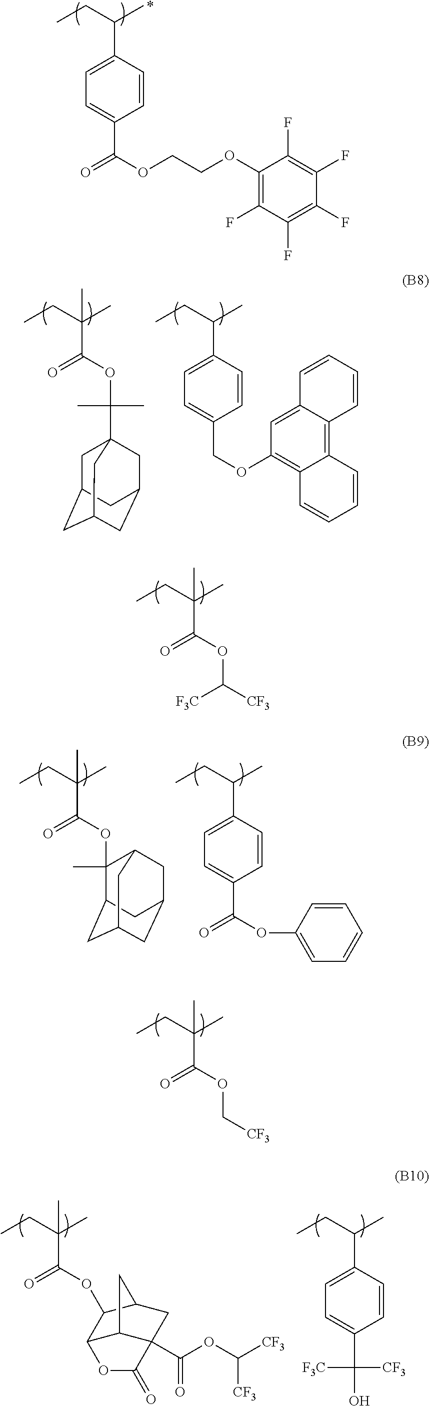

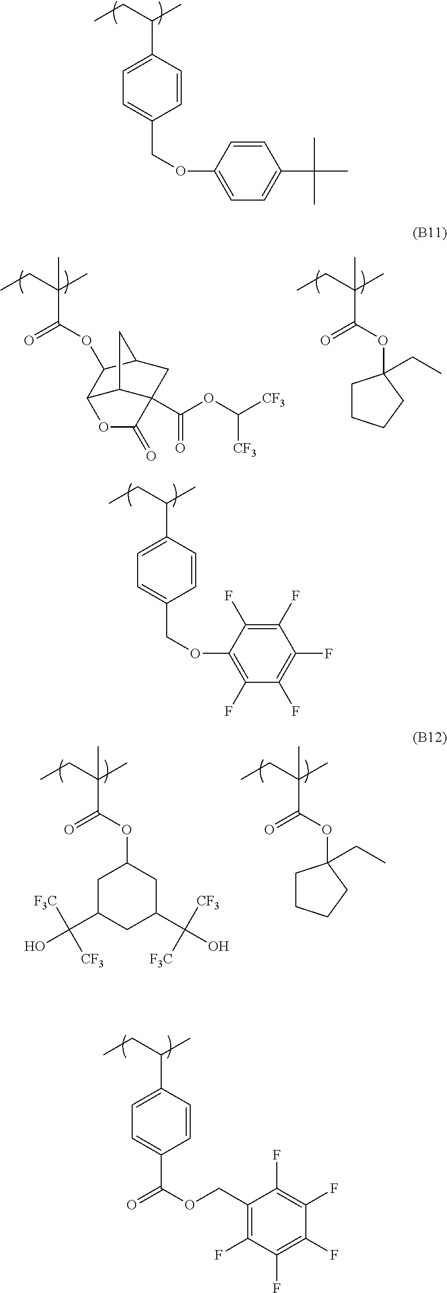

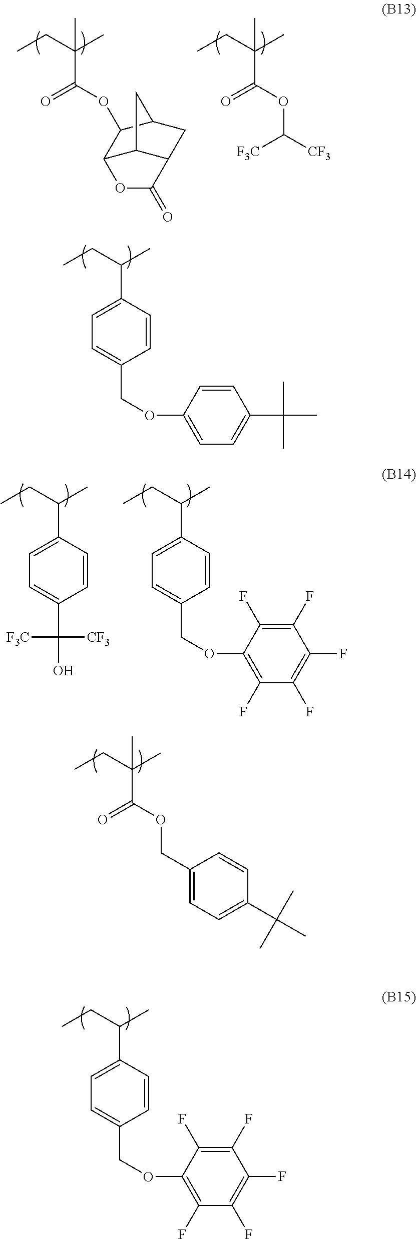

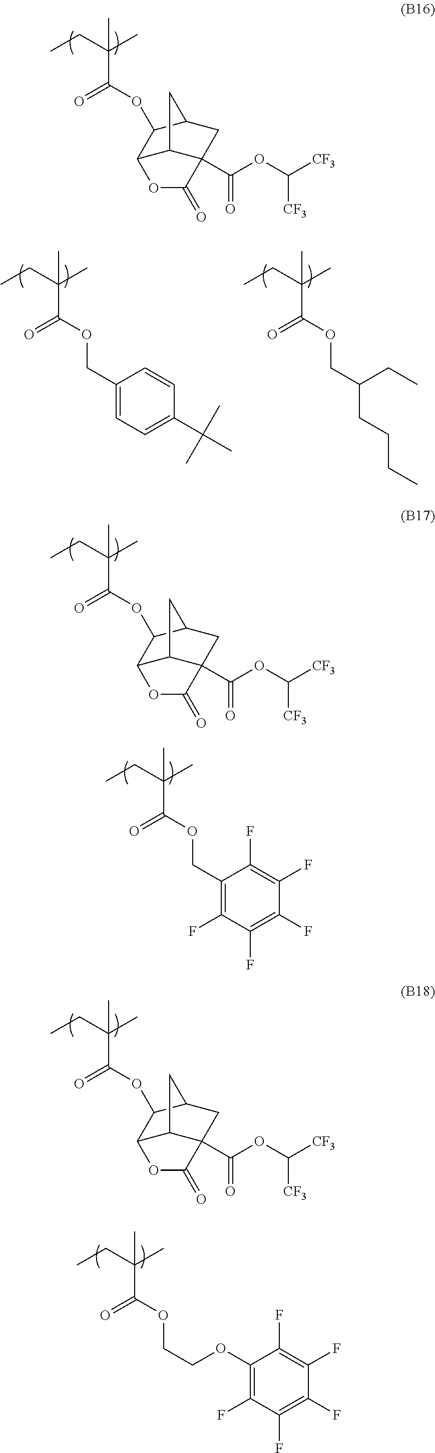

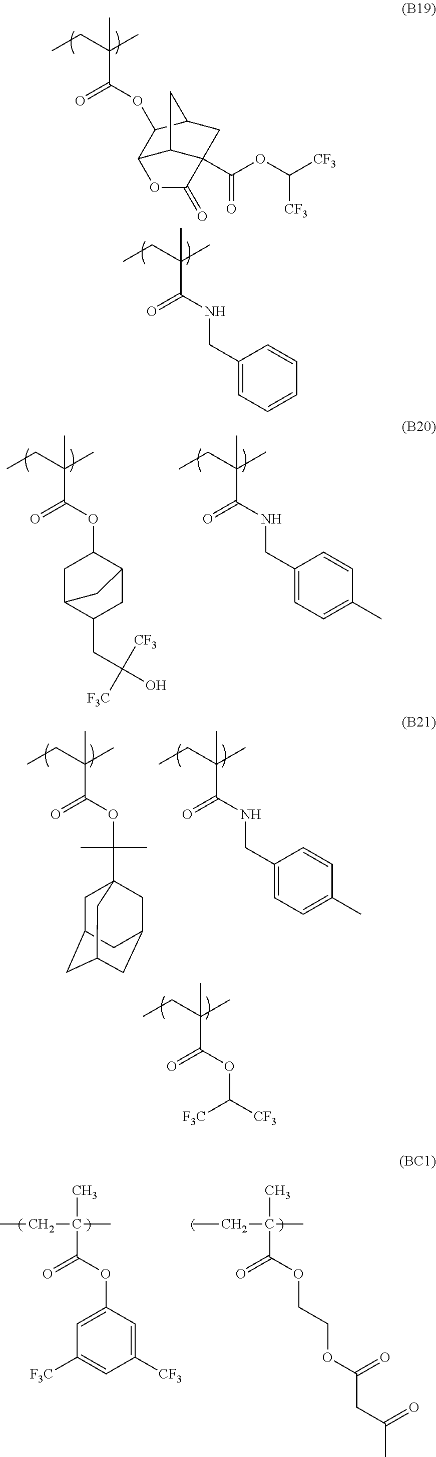

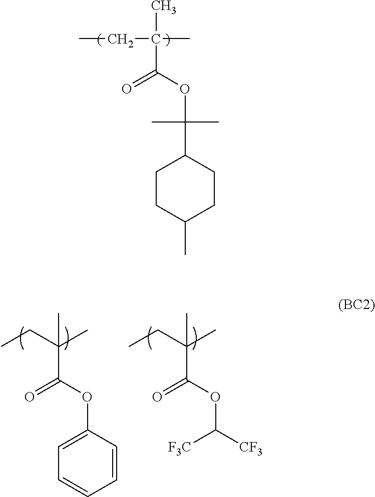

TABLE 2

| Polymer | Molar ratio (mol %) | | | Mw | Mw/Mn |
|---|---|---|---|---|---|
| B1 | 80 | 18 | 2 | 11700 | 1.4 |
| B2 | 70 | 30 | — | 12300 | 1.5 |
| B3 | 60 | 40 | — | 12000 | 1.4 |
| B4 | 40 | 60 | — | 8500 | 1.6 |
| B5 | 30 | 30 | 40 | 7400 | 1.6 |
| B6 | 50 | 50 | — | 9000 | 1.4 |
| B7 | 40 | 60 | — | 7700 | 1.6 |
| B8 | 30 | 40 | 30 | 12000 | 1.6 |
| B9 | 45 | 30 | 25 | 12500 | 1.5 |
| B10 | 50 | 30 | 20 | 9500 | 1.6 |
| B11 | 40 | 30 | 30 | 10100 | 1.7 |
| B12 | 30 | 30 | 40 | 9600 | 1.6 |
| B13 | 50 | 20 | 30 | 13100 | 1.5 |
| B14 | 50 | 25 | 25 | 7500 | 1.8 |
| B15 | 100 | — | — | 23300 | 1.9 |
| B16 | 80 | 18 | 2 | 11600 | 1.5 |
| B17 | 70 | 30 | — | 12100 | 1.6 |
| B18 | 60 | 40 | — | 11800 | 1.4 |
| B19 | 60 | 40 | — | 13100 | 1.7 |
| B20 | 50 | 50 | — | 12200 | 1.4 |
| B21 | 25 | 45 | 30 | 11600 | 1.6 |
| BC1 | 30 | 30 | 40 | 12500 | 1.6 |
| BC2 | 50 | 50 | — | 19500 | 1.8 |

<Preparation of Actinic-Ray- or Radiation-Sensitive Resin Compositions>

Referring to the following Table 3, the components were dissolved in solvents so as to obtain solutions of 5 mass % solid content. The solutions were passed through a polyethylene filter of 0.01 μm pore size, thereby obtaining an actinic-ray- or radiation-sensitive resin compositions (positive photo-sensitive resin compositions). The thus obtained positive photo-sensitive resin compositions were evaluated by the following methods. The results are given in Table 3.

<Image Performance Test>

[Exposure Condition: ArF Liquid-Immersion Exposure]

An organic antireflection film ARC29SR (produced by Nissan Chemical Industries, Ltd.) was applied onto a silicon wafer and baked at 205° C. for 60 seconds, thereby forming a 98 nm-thick antireflection film. Each of the prepared positive photo-sensitive resist compositions was applied thereonto and baked at 120° C. for 60 seconds, thereby forming a 120 nm-thick photo-sensitive film. The resultant wafer was exposed through a 6% half-tone mask of 75 nm 1:1 line and space pattern with the use of an ArF excimer laser liquid immersion scanner (manufactured by ASML, XT1700i, NA 1.20, C-Quad, outer sigma 0.981, inner sigma 0.895, XY deflection). Ultrapure water was used as the liquid for liquid immersion. Thereafter, the exposed wafer was heated at 100° C. for 60 seconds, developed with an aqueous solution of tetramethylammonium hydroxide (2.38 mass %) for 30 seconds, rinsed with pure water and spin dried, thereby obtaining a resist pattern.

[Development Defect]

With respect to each of the patterns formed on a silicon wafer (12-inch caliber) in the above-mentioned manner, random-mode measurement was carried out by means of a defect inspection apparatus KLA2360 (trade name) manufactured by KLA-Tencor Corporation. In the defect inspection apparatus, the pixel size was set at 0.16 μm and the threshold value at 20. Any development defects extracted from differences generated by superimposition between a comparative image and the pixel unit were detected, and the number of development defects per area was calculated. The evaluation marks o* (excellent), o (good), Δ (fair) and x (insufficient) were given when the calculated value was less than 0.5, 0.5 to less than 1.0, 1.0 to less than 5.0 and 5.0 or greater, respectively. The lower the value thereof, the better the performance exhibited.

[Receding Contact Angle]

Each of the prepared positive photo-sensitive resin compositions was applied onto a silicon wafer (8-inch caliber), and baked at 120° C. for 60 seconds, thereby forming a 120-nanometer-thick photosensitive film. The receding contact angle of each of the films with respect to a water droplet was measured in accordance with a dilation/contraction method by means of a dynamic contact angle meter (manufactured by Kyowa Interface Science Co., Ltd.). The receding contact angle was defined as the dynamic contact angle at which, in the five-second suction of a droplet of 35 μL initial size at a rate of 6 μL/s, the dynamic contact angle during suction was stabilized. The measurement was performed in an atmosphere of 23±3° C. and 45±5% relative humidity. The greater the receding contact angle, the greater the scan speed at which water tracking is ensured.

TABLE 3

| | | | Acid | Basic | | Organic | | Receding |
|---|---|---|---|---|---|---|---|---|
| | Resin (A) | Resin (B) | generator | compound | Surfactant | solvent | Development | contact angle |
| Ex. | (2 g) | (mg) | (mg) | (mg) | (mg) | (mass ratio) | defect | (°) |
| 1 | A1 | B1 | PAG1 | TMEA (10) | W-4 | S1-1/S2-1 | ◯* | 82 |
| | | (80) | (600) | | (2) | (8/2) | | |
| 2 | A2 | B2 | PAG2 | DIA (6) | W-1 | S1-1/S2-1 | ◯* | 80 |
| | | (80) | (400) | | (3) | (6/4) | | |
| 3 | A3 | B3 | PAG3/PAG5 | DIA (14) | W-3 | S1-1/S2-1 | ◯* | 78 |
| | | (100) | (610/50) | | (3) | (7/3) | | |
| 4 | A4 | B4 | PAG4 | DIA (10) | W-4 | S1-1/S2-1 | ◯ | 80 |
| | | (20) | (400) | | (2) | (8/2) | | |
| 5 | A5 | B5 | PAG5 | TOA (6) | — | S1-1/S2-1 | ◯ | 72 |
| | | (80) | (400) | | | (7/3) | | |
| 6 | A6 | B6 | PAG6 | DIA (10) | W-2 | S1-1/S2-2 | ◯ | 77 |
| | | (80) | (400) | | (2) | (9.5/0.5) | | |
| 7 | A7 | B7 | PAG7 | PEA (5) | W-4 | S1-1/S2-1 | Δ | 80 |
| | | (20) | (550) | | (2) | (8/2) | | |
| 8 | A8 | B8 | PAG8 | DIA (5) | W-5 | S1-1/S2-1 | Δ | 78 |
| | | (40) | (400) | | (3) | (8/2) | | |
| 9 | A9 | B9 | PAG1 | DIA (10) | W-5 | S1-1/S2-2 | Δ | 74 |
| | | (40) | (600) | | (3) | (9/1) | | |
| 10 | A10 | B10 | PAG2 | DHA (14) | W-1 | S1-1 | ◯* | 80 |
| | | (80) | (400) | | (3) | | | |
| 11 | A11 | B11 | PAG3 | PBI (8) | W-5 | S1-1/S2-1 | ◯ | 80 |
| | | (40) | (610) | | (3) | (8/2) | | |
| 12 | A12 | B12 | PAG4 | DIA (7) | W-5 | S1-1/S2-1 | ◯ | 79 |
| | | (80) | (400) | | (3) | (7/3) | | |
| 13 | A13 | B13 | PAG5 | DIA (10) | W-1 | S1-1/S2-1 | ◯ | 80 |
| | | (100) | (400) | | (3) | (8/2) | | |
| 14 | A14 | B14 | PAG6 | DIA (15) | W-5 | S1-1/S2-1 | ◯ | 80 |
| | | (80) | (400) | | (3) | (8/2) | | |
| 15 | A15 | B15 | PAG7 | DIA (10) | W-2 | S1-1/S2-3 | ◯ | 72 |
| | | (40) | (550) | | (2) | (8/2) | | |
| 16 | A7 | B16 | PAG5 | DIA (10) | W-4 | S1-1/S2-1 | ◯ | 80 |
| | | (50) | (400) | | (2) | (8/2) | | |
| 17 | A8 | B17 | PAG6 | DHA (14) | W-1 | S1-1/S2-1 | ◯ | 80 |
| | | (70) | (400) | | (3) | (6/4) | | |
| 18 | A9 | B18 | PAG7 | PBI (8) | W-3 | S1-1/S2-1 | ◯ | 80 |
| | | (80) | (550) | | (3) | (7/3) | | |
| 19 | A7 | B19 | PAG6 | DIA (15) | W-4 | S1-1/S2-1 | ◯ | 71 |
| | | (80) | (400) | | (2) | (8/2) | | |
| 20 | A1 | B20 | PAG3 | DIA/PEA | W-3 | S1-1/S2-1 | ◯ | 71 |
| | | (80) | (610) | (6/9) | (3) | (6/4) | | |
| 21 | A14 | B21 | PAG5 | TMEA (10) | — | S1-1/S2-1 | ◯ | 72 |
| | | (80) | (400) | | | (7/3) | | |
| 22 | A16 | B1 | PAG2/PAG7 | PEA (9) | W-1 | S1-1/S2-1 | ◯ | 82 |
| | | (80) | (50/550) | | (3) | (6/4) | | |
| 23 | A17 | B2 | PAG1/PAG8 | PEA (6) | W-4 | S1-1/S2-1 | ◯ | 80 |
| | | (80) | (600/60) | | (2) | (8/2) | | |
| 24 | A18 | B3 | PAG2/PAG7 | DIA (5) | W-2 | S1-1/S2-3 | ◯ | 78 |
| | | (100) | (50/550) | | (2) | (9/1) | | |
| 25 | A19 | B1/B3 | PAG3 | DIA (10) | W-3 | S1-1/S2-1 | ◯ | 81 |
| | | (40/5) | (610) | | (3) | (9/1) | | |
| 26 | A20 | B4/B5 | PAG4 | TMEA (10) | W-4 | S1-1/S2-1 | ◯ | 78 |
| | | (80/5) | (400) | | (2) | (9/1) | | |
| 27 | A21 | B7/B9 | PAG5 | DIA (6) | — | S1-1/S2-2 | Δ | 80 |
| | | (40/5) | (400) | | | (9.8/0.2) | | |
| 28 | A22 | B1/B4 | PAG2/PAG7 | DIA (14) | W-1 | S1-1/S2-1 | ◯ | 81 |
| | | (80/5) | (50/550) | | (3) | (8/2) | | |
| 29 | A23 | B1/B7 | PAG1/PAG8 | DIA (10) | W-3 | S1-1 | ◯ | 81 |
| | | (80/5) | (600/60) | | (3) | | | |
| 30 | A24 | B7/B4 | PAG2/PAG7 | TOA (6) | W-1 | S1-1/S2-1 | ◯ | 80 |
| | | (80/5) | (50/550) | | (3) | (7/3) | | |
| 31 | A25 | B7/B17 | PAG1 | DIA (10) | — | S1-1/S2-1 | Δ | 78 |
| | | (80/5) | (600) | | | (8/2) | | |
| 32 | A16/A17 | B1 | PAG2 | PEA (5) | W-3 | S1-1/S2-1 | ◯ | 82 |
| | (1 g/1 g) | (80) | (400) | | (3) | (9.8/0.2) | | |
| 33 | A15/A19 | B2 | PAG3 | DIA (5) | W-1 | S1-1 | ◯ | 80 |
| | (1 g/1 g) | (80) | (610) | | (3) | | | |
| 34 | A14/A15 | B3 | PAG4 | DIA (10) | — | S1-1/S2-2 | ◯ | 78 |
| | (0.5 g/1.5 g) | (100) | (400) | | | (9.8/0.2) | | |
| Compar. 1 | A1 | BC1 | PAG5 | DIA (10) | W-1 | S1-1/S2-1 | Δ | 65 |
| | | (80) | (400) | | (3) | (8/2) | | |
| Compar. 2 | A2 | BC2 | PAG5 | DIA (10) | W-1 | S1-1/S2-1 | X | 60 |
| | | (80) | (400) | | (3) | (8/2) | | |

The resins (A) and resins (B) correspond to those set forth hereinbefore by way of example.

The employed acid generators, basic compounds, surfactants and solvents are as follows.

(Acid Generator)

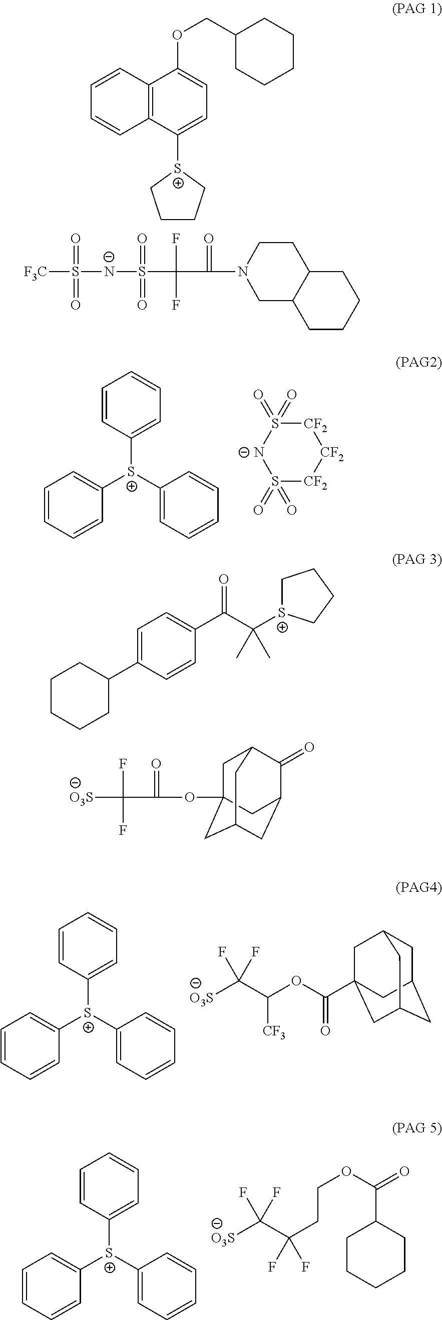

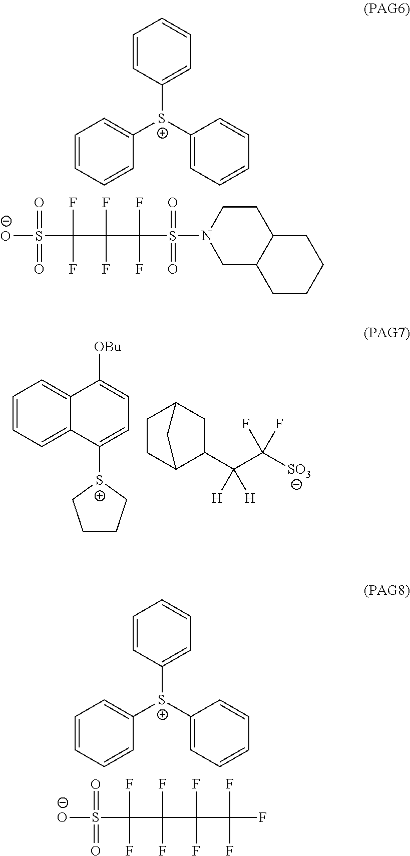

(Basic Compound)

DIA: 2,6-diisopropylaniline,

TMEA: tris(methoxyethoxyethyl)amine,

PEA: N-phenyldiethanolamine,

TOA: tri-n-octylamine,

PBI: 2-phenylbenzoimidazole, and

DHA: N,N-dihexylaniline.

(Surfactant)

W-1: Megafac F176 (produced by Dainippon Ink & Chemicals, Inc., fluorinated),

W-2: Megafac R08 (produced by Dainippon Ink & Chemicals, Inc., fluorinated and siliconized),

W-3: Troy Sol S-366 (produced by Troy Chemical Co., Ltd., fluorinated),

W-4: PF656 (produced by OMNOVA, fluorinated), and

W-5: PF6320 (produced by OMNOVA, fluorinated).

(Solvent)

51-1: propylene glycol monomethyl ether acetate (PGMEA),

S1-2: cyclohexanone,

S2-1: propylene glycol monomethyl ether (PGME),

S2-2: propylene carbonate, and

S2-3: γ-butyrolactone.

As apparent from Table 3, a pattern with fewer development defects and a film exhibiting a high receding contact angle were formed by using the compositions of the present invention. Namely, it has been proved that excellent developability and excellent immersion-liquid tracking properties can be simultaneously attained by using the compositions of the present invention.

1. An actinic-ray- or radiation-sensitive resin composition comprising:
a resin (B) containing at least either a fluorine atom or a silicon atom, the resin (B) containing any of repeating units of general formula (I) below;
a resin (A) that is configured to decompose when acted on by an acid to thereby increase its solubility in an alkali developer; and
a compound that is configured to generate an acid when exposed to actinic rays or radiation. 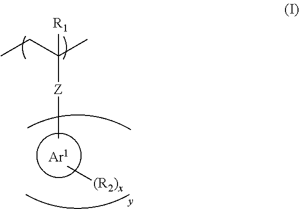
wherein
R₁ represents a hydrogen atom, an alkyl group or a halogen atom,
Ar¹ represents an aromatic ring,
R₂, when x≧2 each independently, represents a substituent,
Z represents a connecting group whose minimum number of connecting atoms is 3 or more,
x is an integer of 0 or greater, and
y is an integer of 1 or greater.

2. The composition according to claim 1, wherein the repeating units of general formula (I) above are expressed by general formula (I-A) below, 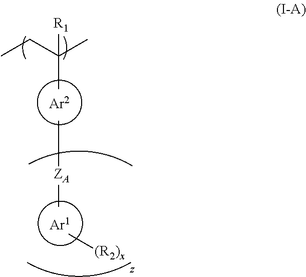
wherein
R₁ represents a hydrogen atom, an alkyl group or a halogen atom,
Ar¹ represents an aromatic ring,
R₂ represents a substituent,
Ar² represents an aromatic ring,
Z_{A} represents a single bond or a connecting group,
x is an integer of 0 or greater, and
z is an integer of 1 or greater.

3. The composition according to claim 2, wherein Ar² represents a benzene ring.

4. The composition according to claim 1, wherein the repeating units of general formula (I) above are expressed by general formula (I-B) below, 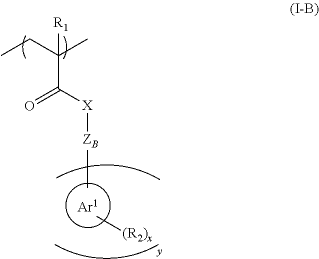
wherein
R₁ represents a hydrogen atom, an alkyl group or a halogen atom,
Ar¹ represents an aromatic ring,
R₂ represents a substituent,
Z_{B} represents a connecting group,
X represents O, NH or NR, in which R represents an alkyl group,
x is an integer of 0 or greater, and
y is an integer of 1 or greater.

5. The composition according to claim 4, wherein X represents O.

6. The composition according to claim 1, wherein the resin (B) further contains a repeating unit containing at least one group selected from the group consisting of groups (x), (y) and (z) below:
(x) an alkali-soluble group,
(y) a group that is configured to decompose when acted on by an alkali developer to thereby increase its solubility in the alkali developer, and
(z) a group that is configured to decompose when acted on by an acid to thereby increase its solubility in an alkali developer.

7. The composition according to claim 1, wherein the resin (B) further contains a repeating unit containing the group (y) that is configured to decompose when acted on by an alkali developer to thereby increase its solubility in the alkali developer.

8. The composition according to claim 7, wherein the group (y) contains a lactone structure.

9. The composition according to claim 1, wherein the resin (B) is contained in an amount of 0.1 to 10 mass % based on the total solids of the composition.

10. A resist film formed from the composition according to claim 1.

11. A method of forming a pattern, comprising:
forming the composition according to claim 1 into a film,
exposing the film to light, and
developing the exposed film.

12. The method according to claim 11, wherein the exposure is performed through an immersion liquid.
